(19) United States
(12) Patent Application Publication
(10) Pub. No.: US 2023/0320216 A1
(43) Pub. Date: Oct. 5, 2023

(54) LIGHT EMITTING ELEMENT AND POLYCYCLIC COMPOUND FOR LIGHT EMITTING ELEMENT

(71) Applicant: Samsung Display Co., Ltd., Yongin-si (KR)

(72) Inventors: MUN-KI SIM, Seoul (KR); JANG YEOL BAEK, Yongin-si (KR); Kyoung SUNWOO, Hwaseong-si (KR); MINJAE SUNG, Hwaseong-si (KR); CHANSEOK OH, Seoul (KR); MORAN HA, Asan-si (KR)

(21) Appl. No.: 18/167,034

(22) Filed: Feb. 9, 2023

(30) Foreign Application Priority Data
Apr. 1, 2022 (KR) 10-2022-0040961

(51) Int. Cl. H10K 85/60; C07F 5/02; C09K 11/06

(52) U.S. Cl. CPC H10K 85/658; C07F 5/027; C09K 11/06; H10K 50/121

(57) ABSTRACT

A light emitting element is provided to include a first electrode, a second electrode, and an emission layer disposed between the first electrode and the second electrode. The emission layer may include a polycyclic compound including a boron-containing core part and an electron donating group of a dibenzoheterole skeleton.

### CROSS-REFERENCE TO RELATED APPLICATION

This application claims priority to and the benefit of Korean Patent Application No. 10-2022-0040961, filed on Apr. 1, 2022, in the Korean Intellectual Property Office, the entire content of which is hereby incorporated by reference.

### BACKGROUND

### 1. Field

One or more aspects of embodiments of the present disclosure are directed to a light emitting element and a polycyclic compound for a light emitting element, and particularly, to a light emitting element including a plurality of materials as well as a polycyclic compound utilized as a light emitting material in an emission layer of the light emitting element.

### 2. Description of Related Art

Recently, the utilization of an organic electroluminescence display device as an image display device has been being actively investigated. The organic electroluminescence display device is a type or kind of a display device that is self-luminescent, in which holes and electrons injected from a first electrode and a second electrode of the organic electroluminescence display device recombine in an emission layer of the organic electroluminescence display device so that a light emitting material in the emission layer emits light to achieve display.

In order to increase an emission efficiency, decrease a driving voltage, and improve a lifetime (lifespan) of the organic electroluminescence display device, various techniques on phosphorescence emission that uses energy in a triplet state and/or delayed fluorescence emission that utilizes the generating phenomenon of singlet excitons by the collision of triplet excitons (triplet-triplet annihilation, TTA) are being investigated. For example, a material having thermally activated delayed fluorescence (TADF) utilizing delayed fluorescence phenomenon is being intensively researched.

### SUMMARY

One or more aspects of embodiments of the present disclosure are directed to a light emitting element showing high emission efficiency and long-life characteristics. One or more aspects of embodiments of the present disclosure are further directed to a polycyclic compound utilized as a material for a light emitting element having high emission efficiency and improved life characteristics.

Additional aspects will be set forth in part in the description which follows and, in part, will be apparent from the description, or may be learned by practice of the presented embodiments

One or more embodiments of the present disclosure provide a light emitting element including: a first electrode; a second electrode disposed on the first electrode; and an emission layer disposed between the first electrode and the second electrode, wherein the emission layer includes: a first compound represented by Formula 1; and at least one selected from among a second compound represented by Formula HT-1, a third compound represented by Formula ET-1, and a fourth compound represented by Formula M-b.

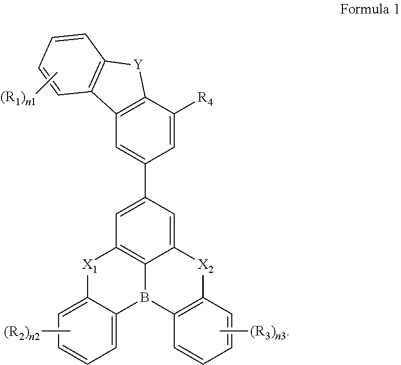

In Formula 1,

R₁ to R₃ may each independently be selected from hydrogen, deuterium, a cyano group, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,

R₄ may be selected from a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,

X₁ and X₂ may each independently be selected from NRₓ and O,

Y may be NR_{y} or O,

Rₓ and R_{y} may each independently be selected from a substituted or unsubstituted aryl group of 6 to 30 ring-forming carbon atoms and a substituted or unsubstituted heteroaryl group of 2 to 30 ring-forming carbon atoms, and

n1 to n3 may each independently be an integer of 0 to 4.

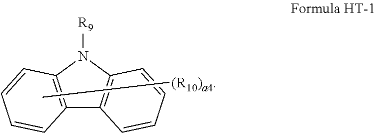

In Formula HT-1,

a4 may be an integer of 0 to 8, and

R₉ and R₁₀ may each independently be selected from hydrogen, deuterium, a substituted or unsubstituted aryl group of 6 to 60 ring-forming carbon atoms, and a substituted or unsubstituted heteroaryl group of 2 to 60 ring-forming carbon atoms.

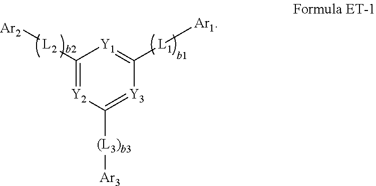

In Formula ET-1,

at least one selected from among Y₁ to Y₃ is N, and the remainder are CRₐ,

Rₐ may be selected from hydrogen, deuterium, a substituted or unsubstituted alkyl group of 1 to 20 carbon atoms, a substituted or unsubstituted aryl group of 6 to 60 ring-forming carbon atoms, and a substituted or unsubstituted heteroaryl group of 2 to 60 ring-forming carbon atoms,

b1 to b3 may each independently be an integer of 0 to 10,

L₁ to L₃ may each independently be selected from a direct linkage, a substituted or unsubstituted arylene group of 6 to 30 ring-forming carbon atoms, and a substituted or unsubstituted heteroarylene group of 2 to 30 ring-forming carbon atoms, and

Ar₁ to Ar₃ may each independently be selected from hydrogen, deuterium, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms.

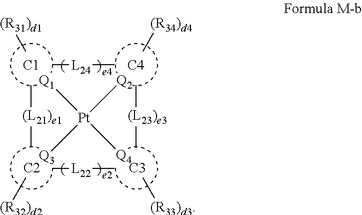

In Formula M-b,

Q₁ to Q₄ may each independently be C or N,

C1 to C4 may each independently be selected from a substituted or unsubstituted hydrocarbon ring of 5 to 30 ring-forming carbon atoms and a substituted or unsubstituted heterocyclic group of 2 to 30 ring-forming carbon atoms,

e1 to e4 may each independently be 0 or 1,

L₂₁ to L₂₄ may each independently be selected from a direct linkage,

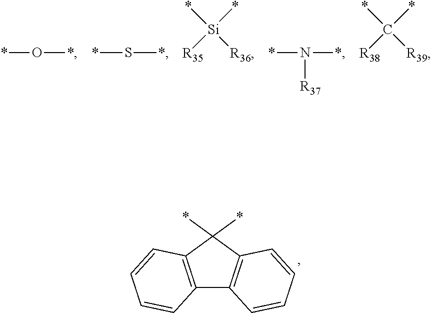

a substituted or unsubstituted divalent alkyl group of 1 to 20 carbon atoms, a substituted or unsubstituted arylene group of 6 to 30 ring-forming carbon atoms, and a substituted or unsubstituted heteroarylene group of 2 to 30 ring-forming carbon atoms,

d1 to d4 may each independently be an integer of 0 or 4, and

R₃₁ to R₃₉ may each independently be selected from hydrogen, deuterium, halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms, or may be combined with an adjacent group to form a ring.

In one or more embodiments, at least one selected from among X₁ and X₂ in the first compound represented by Formula 1 may be NRₓ.

In one or more embodiments, the first compound represented by Formula 1 may be represented by Formula 2.

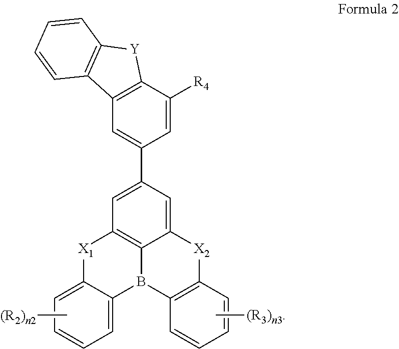

In Formula 2, R₂, R₃, R₄, X₁, X₂, Y, n2 and n3 may each independently be the same as defined in Formula 1.

In one or more embodiments, the first compound represented by Formula 1 may be represented by Formula 3-1 or Formula 3-2.

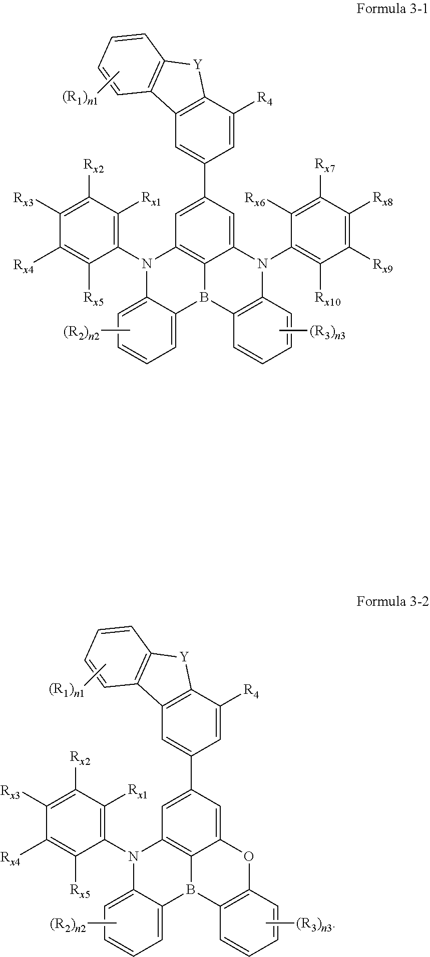

In Formula 3-1 and Formula 3-2, Rₓ₁ to Rₓ₁₀ may each independently be selected from hydrogen, deuterium, a substituted or unsubstituted alkyl group of 1 to 20 carbon atoms, and a substituted or unsubstituted aryl group of 6 to 20 ring-forming carbon atoms, and R₁ to R₄, Y, and n1 to n3 may each independently be the same as defined in Formula 1.

In one or more embodiments, the first compound represented by Formula 3-1 may be represented by Formula 3-1-1 or Formula 3-1-2.

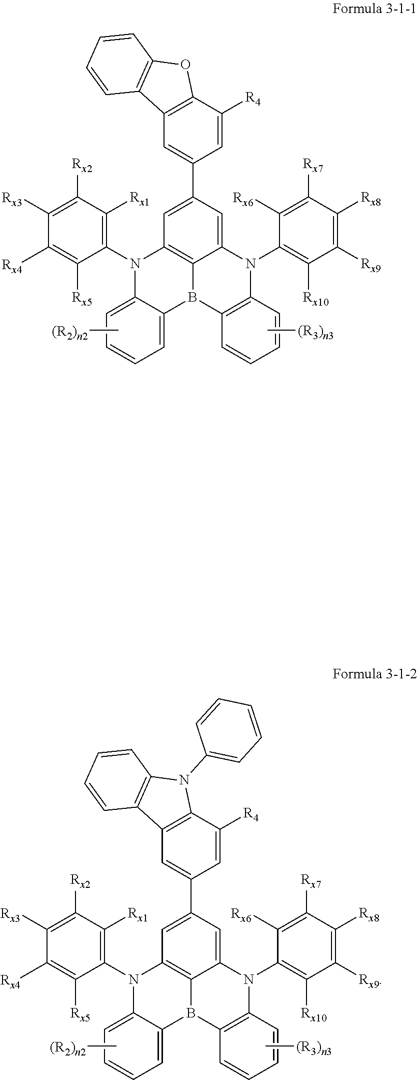

In Formula 3-1-1 and Formula 3-1-2, R₂ to R₄, n2, and n3 may each independently be the same as defined in Formula 1, and Rₓ₁ to Rₓ₀ may each independently be the same as defined in Formula 3-1.

In one or more embodiments, the first compound represented by Formula 3-2 may be represented by Formula 3-2-1 or Formula 3-2-2.

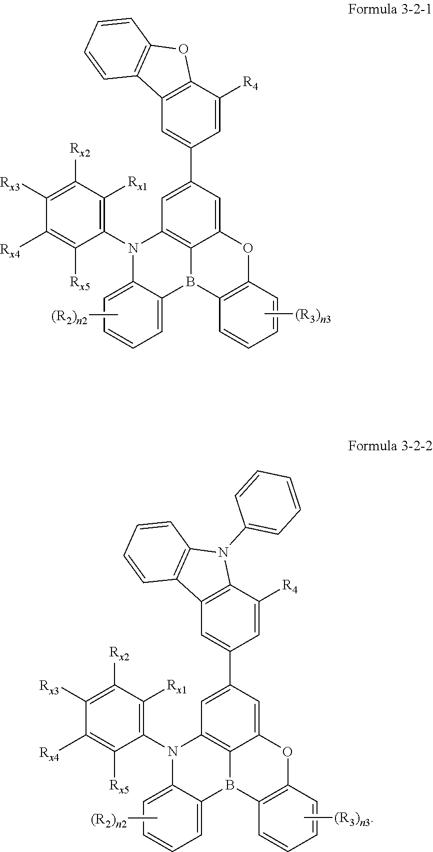

In Formula 3-2-1 and Formula 3-2-2, R₂ to R₄, n2, and n3 may each independently be the same as defined in Formula 1, and Rₓ₁ to Rₓ₅ may each independently be the same as defined in Formula 3-2.

In one or more embodiments, the first compound represented by Formula 1 may be represented by any one selected from among Formula 4-1 to Formula 4-3.

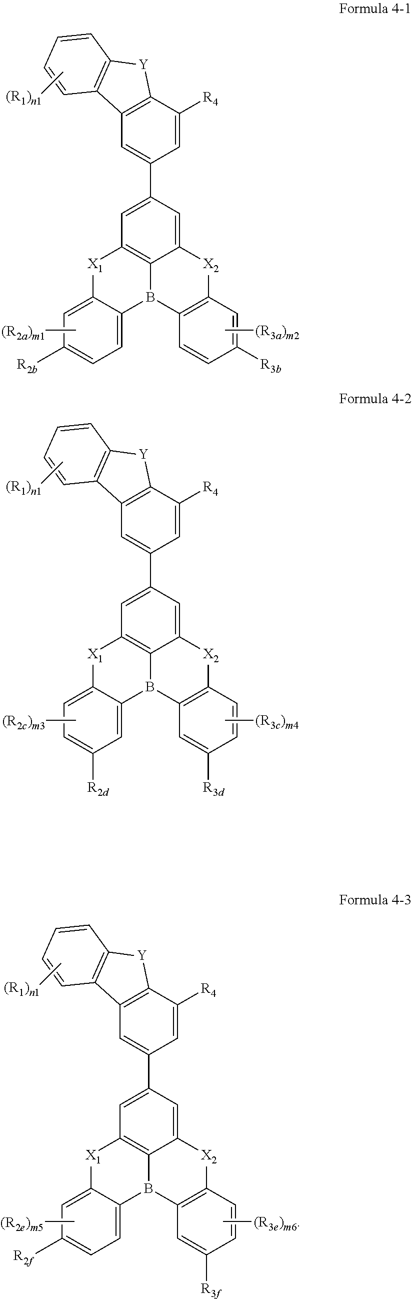

In Formula 4-1 to Formula 4-3,

R₂ₐ, R₃ₐ, R_{2c}, R_{3c}, R₂ₑ, and R₃ₑ may each independently be selected from hydrogen, deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,

R_{2b}, R_{3b}, R_{2d}, R_{3d}, R_{2f}, and R_{3f} may each independently be selected from deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,

m1 to m6 may each independently be an integer of 0 to 3, and

R₁, R₄, X₁, X₂, Y, and n1 may each independently be the same as defined in Formula 1.

In one or more embodiments, R₂ and R₃ in the first compound represented by Formula 1 may each independently be selected from hydrogen, deuterium, a substituted or unsubstituted t-butyl group, a substituted or unsubstituted phenyl group, a substituted or unsubstituted carbazole group, and a substituted or unsubstituted dibenzofuran group.

In one or more embodiments, R₄ in the first compound represented by Formula 1 may be selected from a substituted or unsubstituted t-butyl group, a substituted or unsubstituted phenyl group, a substituted or unsubstituted carbazole group, a substituted or unsubstituted dibenzofuran group, and a substituted or unsubstituted tetralinyl group.

In one or more embodiments, the emission layer may include the first compound, the second compound, and the third compound.

In one or more embodiments, the emission layer may include the first compound, the second compound, the third compound, and the fourth compound.

In one or more embodiments, the emission layer may be to emit thermally activated delayed fluorescence.

In one or more embodiments, the emission layer may be to emit light having an emission center wavelength of about 430 nm to about 490 nm.

In some embodiments, the polycyclic compound utilized as a material for a light emitting element may be represented by Formula 1.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. Above and/or other aspects of the present disclosure will become apparent and appreciated from the following description of embodiments taken in conjunction with the accompanying drawings. In the drawings:

FIG. 1 is a plan view showing a display device according to one or more embodiments of the present disclosure;

FIG. 2 is a cross-sectional view showing a part corresponding to line I-I′ in FIG. 1;

FIG. 3 is a cross-sectional view schematically showing a light emitting element of one or more embodiments of the present disclosure;

FIG. 4 is a cross-sectional view schematically showing a light emitting element of one or more embodiments of the present disclosure;

FIG. 5 is a cross-sectional view schematically showing a light emitting element of one or more embodiments of the present disclosure;

FIG. 6 is a cross-sectional view schematically showing a light emitting element of one or more embodiments of the present disclosure;

FIG. 7 is a cross-sectional view showing a display device according to one or more embodiments of the present disclosure;

FIG. 8 is a cross-sectional view showing a display device according to one or more embodiments of the present disclosure;

FIG. 9 is a cross-sectional view showing a display device according to one or more embodiments of the present disclosure; and

FIG. 10 is a cross-sectional view showing a display device according to one or more embodiments of the present disclosure.

### DETAILED DESCRIPTION

The present disclosure may have one or more suitable modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

Like reference numerals refer to like elements throughout the present disclosure, and duplicative descriptions thereof may not be provided for conciseness. In the drawings, the dimensions of structures are exaggerated for clarity of illustration. It will be understood that, although the terms first, second, etc. may be utilized herein to describe one or more suitable elements, these elements should not be limited by these terms. These terms are only utilized to distinguish one element from another element. Thus, a first element could be termed a second element without departing from the teachings of the present disclosure. Similarly, a second element could be termed a first element. As utilized herein, the singular forms are intended to include the plural forms as well, unless the context clearly indicates otherwise.

In the present disclosure, it will be further understood that the terms “comprise(s)/include(s)” and/or “comprising/including,” when utilized in this specification, specify the presence of stated features, numerals, steps, operations, elements, parts, or the combination thereof, but do not preclude the presence or addition of one or more other features, numerals, steps, operations, elements, parts, or the combination thereof. As used herein, the terms “and”, “or”, and “and/or” include any and all combinations of one or more of the associated listed items. Expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. Further, the use of “may” when describing embodiments of the present invention refers to “one or more embodiments of the present disclosure.”

In the present disclosure, when a layer, a film, a region, a plate, etc. is referred to as being “on” or “above” another part, it can be “directly on” the other part, or intervening layers may also be present. In contrast, when a layer, a film, a region, a plate, etc. is referred to as being “under” or “below” another part, it can be “directly under” the other part, or intervening layers may also be present. Also, when an element is referred to as being disposed “on” another element, it can be disposed under the other element.

In the present disclosure, the term “substituted or unsubstituted” corresponds to substituted or unsubstituted with at least one substituent selected from the group consisting of deuterium, a halogen(for example, F, Cl, Br, I, etc.), a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the exemplified substituents may be substituted or unsubstituted. For example, a biphenyl group may be interpreted as an aryl group, or a phenyl group substituted with a phenyl group.

In the present disclosure, the term “forming a ring via the combination with an adjacent group” may refer to forming a substituted or unsubstituted hydrocarbon ring, or a substituted or unsubstituted heterocycle via the combination with an adjacent group. The hydrocarbon ring may include an aliphatic hydrocarbon ring and an aromatic hydrocarbon ring. The heterocycle may include an aliphatic heterocycle and an aromatic heterocycle. The hydrocarbon ring and the heterocycle may be monocycles or polycycles. In some embodiments, the ring formed via the combination with an adjacent group may be combined with another ring to form a spiro structure.

In the present disclosure, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. For another example, in 4,5-dimethylphenanthrene, two methyl groups may be interpreted as “adjacent groups” to each other.

In the present disclosure, halogen may be fluorine, chlorine, bromine, or iodine.

In the present disclosure, an alkyl group may be a linear, branched, or cyclic type or kind. The carbon number of the alkyl group may be 1 to 50, 1 to 30, 1 to 20, 1 to 10, or 1 to 6. Examples of the alkyl group may include methyl group, ethyl group, n-propyl group, isopropyl group, n-butyl group, s-butyl group, t-butyl group, i-butyl group, 2-ethylbutyl group, 3,3-dimethylbutyl group, n-pentyl group, i-pentyl group, neopentyl group, t-pentyl group, cyclopentyl group, 1-methylpentyl group, 3-methylpentyl group, 2-ethylpentyl group, 4-methyl-2-pentyl group, n-hexyl group, 1-methylhexyl group, 2-ethylhexyl group, 2-butylhexyl group, cyclohexyl group, 4-methylcyclohexyl group, 4-t-butylcyclohexyl group, n-heptyl group, 1-methylheptyl group, 2,2-dimethylheptyl group, 2-ethylheptyl group, 2-butylheptyl group, n-octyl group, t-octyl group, 2-ethyloctyl group, 2-butyloctyl group, 2-hexyloctyl group, 3,7-dimethyloctyl group, cyclooctyl group, n-nonyl group, n-decyl group, adamantyl group, 2-ethyldecyl group, 2-butyldecyl group, 2-hexyldecyl group, 2-octyldecyl group, n-undecyl group, n-dodecyl group, 2-ethyldodecyl group, 2-butyldodecyl group, 2-hexyldocecyl group, 2-octyldodecyl group, n-tridecyl group, n-tetradecyl group, n-pentadecyl group, n-hexadecyl group, 2-ethylhexadecyl group, 2-butylhexadecyl group, 2-hexylhexadecyl group, 2-octylhexadecyl group, n-heptadecyl group, n-octadecyl group, n-nonadecyl group, n-eicosyl group, 2-ethyleicosyl group, 2-butyleicosyl group, 2-hexyleicosyl group, 2-octyleicosyl group, n-heneicosyl group, n-docosyl group, n-tricosyl group, n-tetracosyl group, n-pentacosyl group, n-hexacosyl group, n-heptacosyl group, n-octacosyl group, n-nonacosyl group, n-triacontyl group, etc., without limitation.

In the present disclosure, an alkenyl group may refer to a hydrocarbon group including one or more carbon-carbon double bonds in the middle or at the terminal of an alkyl group having a carbon number of 2 or more. The alkenyl group may be a linear chain or a branched chain. The carbon number of the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl group, a styrylvinyl group, etc., without limitation.

In the present disclosure, an alkynyl group may refer to a hydrocarbon group including one or more carbon-carbon triple bonds in the middle or at the terminal of an alkyl group having a carbon number of 2 or more. The alkynyl group may be a linear chain or a branched chain. The carbon number of the alkynyl group is not specifically limited, but may be 2 to 30, 2 to 20, or 2 to 10. Examples of the alkynyl group may include an ethynyl group, a propynyl group, etc., without limitation.

In the present disclosure, a hydrocarbon ring group may refer to an optional functional group or substituent derived from an aliphatic hydrocarbon ring. The hydrocarbon ring group may be a saturated hydrocarbon ring group of 5 to 20 ring-forming carbon atoms.

In the present disclosure, an aryl group may refer to an optional functional group or substituent derived from an aromatic hydrocarbon ring. The aryl group may be a monocyclic aryl group or a polycyclic aryl group. The carbon number for forming rings in the aryl group may be 6 to 60, 6 to 30, 6 to 20, or 6 to 15. Examples of the aryl group may include phenyl group, naphthyl group, fluorenyl group, anthracenyl group, phenanthryl group, biphenyl group, terphenyl group, quaterphenyl group, quinquephenyl group, sexiphenyl group, triphenylenyl group, pyrenyl group, benzofluorantheny group I, chrysenyl group, etc., without limitation.

In the present disclosure, a fluorenyl group may be substituted, and two substituents may be combined with each other to form a spiro structure. Examples of a substituted fluorenyl group are as follows, but embodiments of the present disclosure are not limited thereto.

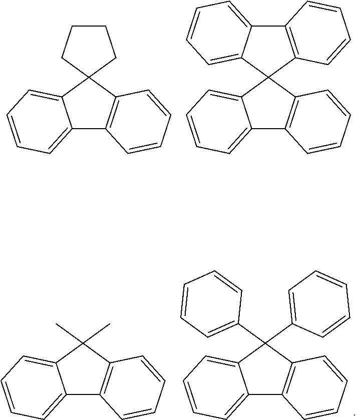

In the present disclosure, a heterocyclic group may refer to an optional functional group or substituent derived from a ring including one or more selected from among B, O, N, P, Si, and S as heteroatoms. The heterocyclic group may include an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

In the present disclosure, a heterocyclic group may include one or more selected from among B, O, N, P, Si and S as heteroatoms. When the heterocyclic group includes two or more heteroatoms, the two or more heteroatoms may be the same or different. The heterocyclic group may be a monocyclic heterocyclic group or a polycyclic heterocyclic group and has the concept including a heteroaryl group. The carbon number for forming rings of the heterocyclic group may be 2 to 30, 2 to 20, and 2 to 10.

In the present disclosure, an aliphatic heterocyclic group may include one or more selected from among B, O, N, P, Si, and S as heteroatoms. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the present disclosure, a heteroaryl group may include one or more selected from among B, O, N, P, Si, and S as heteroatoms. When the heteroaryl group includes two or more heteroatoms, the two or more heteroatoms may be the same or different. The heteroaryl group may be a monocyclic heterocyclic group or polycyclic heterocyclic group. The carbon number for forming rings of the heteroaryl group may be 2 to 60, 2 to 30, 2 to 20, or 2 to 10. Examples of the heteroaryl group may include thiophene group, furan group, pyrrole group, imidazole group, pyridine group, bipyridine group, pyrimidine group, triazine group, acridyl group, pyridazine group, pyrazinyl group, quinoline group, quinazoline group, quinoxaline group, phenoxazine group, phthalazine group, pyrido pyrimidine group, pyrido pyrazine group, pyrazino pyrazine group, isoquinoline group, indole group, carbazole, N-arylcarbazole group, N-heteroarylcarbazole group, N-alkylcarbazole group, benzoxazole group, benzimidazole group, benzothiazole group, benzocarbazole group, benzothiophene group, dibenzothiophene group, thienothiophene group, benzofuran group, phenanthroline group, thiazole group, isooxazole group, oxazole group, oxadiazole group, thiadiazole group, phenothiazine group, dibenzosilole group, dibenzofuran group, etc., without limitation.

In the present disclosure, the same explanation on the above-described aryl group may be applied to an arylene group except that the arylene group is a divalent group. The same explanation on the above-described heteroaryl group may be applied to a heteroarylene group except that the heteroarylene group is a divalent group.

In the present disclosure, a boron group may refer to the above-defined alkyl group or aryl group, combined with a boron atom. The boron group may include an alkyl boron group and an aryl boron group. Examples of the boron group may include a dimethylboron group, a diethylboron group, a t-butylmethylboron group, a diphenylboron group, a phenylboron group, etc., without limitation.

In the present disclosure, a silyl group may include an alkyl silyl group and an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the present disclosure, the carbon number of a carbonyl group is not specifically limited, but the carbon number may be 1 to 40, 1 to 30, or 1 to 20. For example, the carbonyl group may have the structures below, but is not limited thereto.

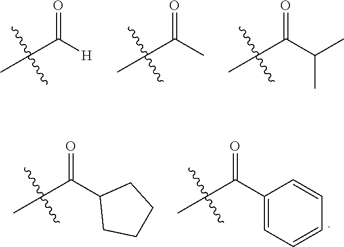

In the present disclosure, the carbon number of a sulfinyl group and sulfonyl group is not specifically limited, but may be 1 to 30. The sulfinyl group may include an alkyl sulfinyl group and an aryl sulfinyl group. The sulfonyl group may include an alkyl sulfonyl group and an aryl sulfonyl group.

In the present disclosure, a thio group may include an alkyl thio group and an aryl thio group. The thio group may refer to the above-defined alkyl group or aryl group combined with a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the present disclosure, an oxy group may refer to the above-defined alkyl group or aryl group which is combined with an oxygen atom. The oxy group may include an alkoxy group and an aryl oxy group. The alkoxy group may be a linear, branched, or cyclic chain. The carbon number of the alkoxy group is not specifically limited but may be, for example, 1 to 20 or 1 to 10. Non-limiting examples of the oxy group may include methoxy, ethoxy, n-propoxy, isopropoxy, butoxy, pentyloxy, hexyloxy, octyloxy, nonyloxy, decyloxy, benzyloxy, etc.

In the present disclosure, the carbon number of an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., without limitation.

In the present disclosure, alkyl groups in an alkylthio group, alkylsulfoxy group, alkylaryl group, alkylamino group, alkylboron group, alkyl silyl group, and alkyl amine group may be the same as the examples of the above-described alkyl group.

In the present disclosure, aryl groups in an aryloxy group, arylthio group, arylsulfoxy group, aryl amino group, arylboron group, aryl silyl group, and aryl amine group may be the same as the examples of the above-described aryl group.

In the present disclosure, a direct linkage may refer to a single bond.
In the present disclosure, [symbol] may refer to a position to be connected.

Hereinafter, embodiments of the present disclosure will be explained in more detail referring to the drawings.

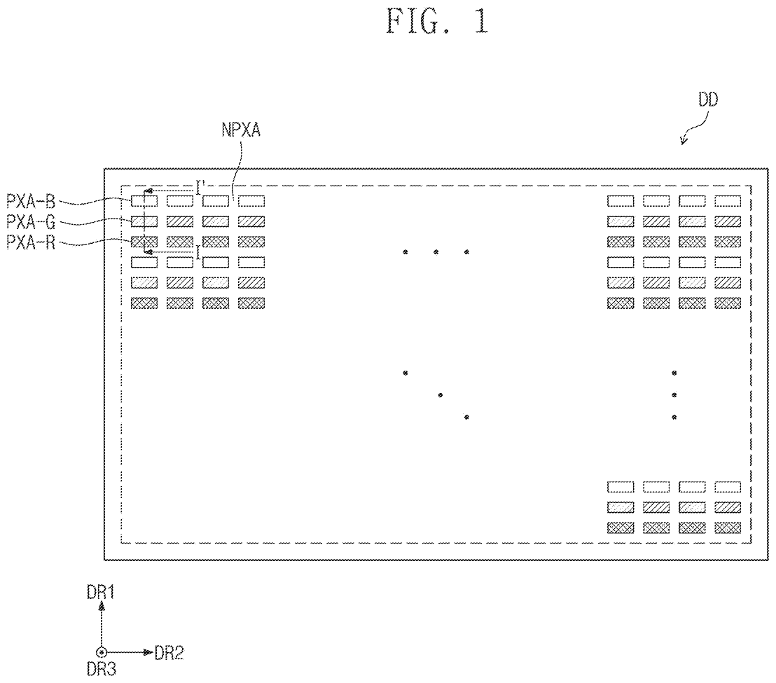

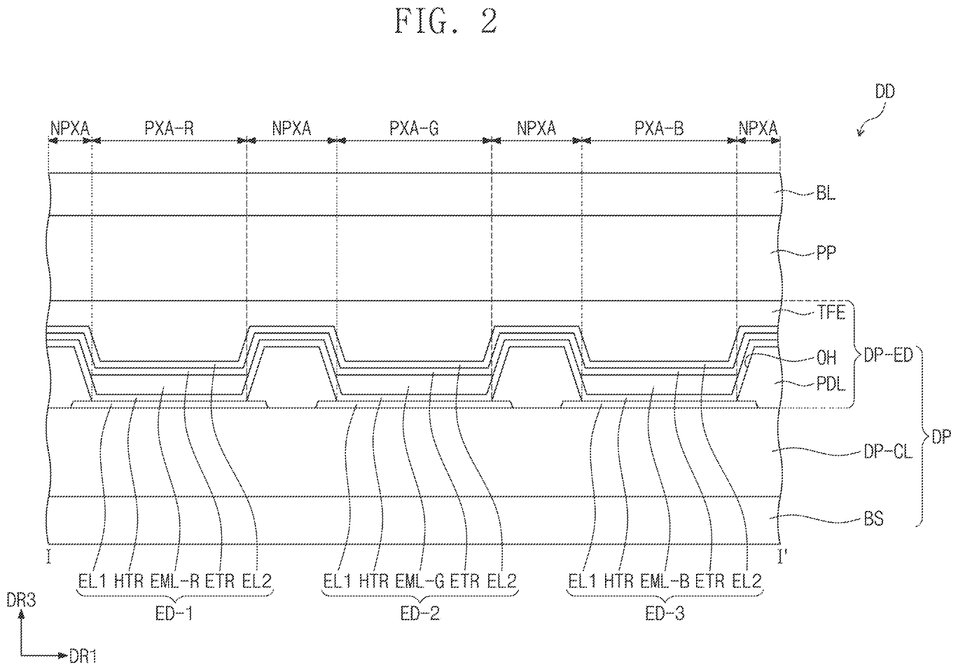

FIG. 1 is a plan view showing a display device DD according to one or more embodiments of the present disclosure. FIG. 2 is a cross-sectional view of a display device DD according to one or more embodiments of the present disclosure. FIG. 2 is a cross-sectional view showing a part corresponding to line I-I′ of FIG. 1.

The display device DD may include a display panel DP and an optical layer PP disposed on the display panel DP. The display panel DP may include light emitting elements ED-1, ED-2, and ED-3. The display device DD may include a plurality of light emitting elements ED-1, ED-2, and ED-3. The optical layer PP may be disposed on the display panel DP and control reflected light by external light at the display panel DP. The optical layer PP may include, for example, a polarization layer or a color filter layer. In some embodiments, different from the drawings, the optical layer PP may not be provided in the display device DD.

On the optical layer PP, a base substrate BL may be disposed. The base substrate BL may be a member providing a base surface where the optical layer PP is disposed. The base substrate BL may be a glass substrate, a metal substrate, a plastic substrate, etc. However, embodiments of the present disclosure is not limited thereto, and the base substrate BL may be an inorganic layer, an organic layer, or a composite material layer. In some embodiments, different from the drawings, the base substrate BL may not be provided.

The display device DD according to one or more embodiments may further include a plugging layer. The plugging layer may be disposed between a display element layer DP-ED and a base substrate BL. The plugging layer may be an organic layer. The plugging layer may include at least one selected from among an acrylic resin, a silicon-based resin, and an epoxy-based resin.

The display panel DP may include a base layer BS, a circuit layer DP-CL provided on the base layer BS and a display element layer DP-ED. The display element layer DP-ED may include a pixel definition layer PDL, light emitting elements ED-1, ED-2, and ED-3 disposed in the pixel definition layer PDL, and an encapsulating layer TFE disposed on the light emitting elements ED-1, ED-2, and ED-3.

The base layer BS may be a member providing a base surface where the display element layer DP-ED is disposed. The base layer BS may be a glass substrate, a metal substrate, a plastic substrate, etc. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors.

Each of the transistors may include a control electrode, an input electrode, and an output electrode. For example, the circuit layer DP-CL may include switching transistors and driving transistors for driving the light emitting elements ED-1, ED-2, and ED-3 of the display element layer DP-ED.

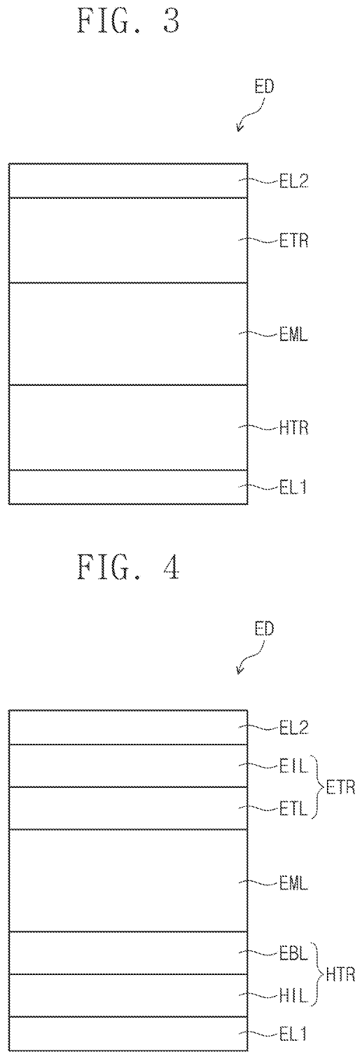

In one or more embodiments, light emitting elements ED-1, ED-2, and ED-3 may have the structures of the light emitting elements ED according to FIG. 3 to FIG. 6, which will be explained later. Each of the light emitting elements ED-1, ED-2, and ED-3 may include a first electrode EL1, a hole transport region HTR, emission layers EML-R, EML-G, and/or EML-B, an electron transport region ETR, and a second electrode EL2.

In FIG. 2, shown is an embodiment where the emission layers EML-R, EML-G, and EML-B of light emitting elements ED-1, ED-2, and ED-3, respectively, are disposed in opening portions OH defined in a pixel definition layer PDL, and a hole transport region HTR, an electron transport region ETR, and a second electrode EL2 are provided as common layers in all light emitting elements ED-1, ED-2, and ED-3. However, embodiments of the present disclosure are not limited thereto. Different from FIG. 2, in one or more embodiments, the hole transport region HTR and the electron transport region ETR may be patterned and provided in the opening portions OH defined in the pixel definition layer PDL. For example, in one or more embodiments, the hole transport region HTR, the emission layers EML-R, EML-G, and EML-B, and the electron transport region ETR of the light emitting elements ED-1, ED-2, and ED-3 may be patterned by an ink jet printing method and provided.

An encapsulating layer TFE may cover the light emitting elements ED-1, ED-2, and ED-3. The encapsulating layer TFE may encapsulate the display element layer DP-ED. The encapsulating layer TFE may be a thin film encapsulating layer. The encapsulating layer TFE may be one layer or a stacked layer of a plurality of layers. The encapsulating layer TFE may include at least one insulating layer. The encapsulating layer TFE according to one or more embodiments may include at least one inorganic layer (hereinafter, encapsulating inorganic layer). In some embodiments, the encapsulating layer TFE may include at least one organic layer (hereinafter, encapsulating organic layer) and at least one encapsulating inorganic layer.

The encapsulating inorganic layer protects the display element layer DP-ED from moisture/oxygen, and the encapsulating organic layer protects the display element layer DP-ED from foreign materials such as dust particles. The encapsulating inorganic layer may include silicon nitride, silicon oxy nitride, silicon oxide, titanium oxide, aluminum oxide, or one or more combinations thereof, without specific limitation. The encapsulating organic layer may include an acrylic compound, an epoxy-based compound, etc. The encapsulating organic layer may include a photopolymerizable organic material, without specific limitation.

The encapsulating layer TFE may be disposed on the second electrode EL2 and may be disposed while filling the opening portion OH.

Referring to FIG. 1 and FIG. 2, the display device DD may include a non-luminous area NPXA and luminous areas PXA-R, PXA-G, and PXA-B. The luminous areas PXA-R, PXA-G, and PXA-B may be areas emitting light produced from the light emitting elements ED-1, ED-2, and ED-3, respectively. The luminous areas PXA-R, PXA-G, and PXA-B may be separated from each other on a plane.

The luminous areas PXA-R, PXA-G, and PXA-B may be areas separated by the pixel definition layer PDL. The non-luminous areas NPXA may be areas between neighboring luminous areas PXA-R, PXA-G, and PXA-B and may be areas corresponding to the pixel definition layer PDL. In some embodiments of the present disclosure, each of the luminous areas PXA-R, PXA-G, and PXA-B may correspond to each pixel. The pixel definition layer PDL may divide the light emitting elements ED-1, ED-2, and ED-3. The emission layers EML-R, EML-G, and EML-B of the light emitting elements ED-1, ED-2, and ED-3 may be disposed and divided in the opening portions OH defined in the pixel definition layer PDL.

The luminous areas PXA-R, PXA-G, and PXA-B may be divided into a plurality of groups according to the color of light produced from the light emitting elements ED-1, ED-2, and ED-3. In the display device DD, shown in FIG. 1 and FIG. 2, three luminous areas PXA-R, PXA-G, and PXA-B emitting red light, green light, and blue light, respectively, are illustrated as an example. For example, the display device DD of one or more embodiments may include a red luminous area PXA-R, a green luminous area PXA-G, and a blue luminous area PXA-B, which are separated from each other.

In the display device DD according to one or more embodiments, a plurality of light emitting elements ED-1, ED-2, and ED-3 may be to emit light having different wavelength regions. For example, in one or more embodiments, the display device DD may include a first light emitting element ED-1 emitting red light, a second light emitting element ED-2 emitting green light, and a third light emitting element ED-3 emitting blue light. For example, the red luminous area PXA-R, the green luminous area PXA-G, and the blue luminous area PXA-B of the display device DD may correspond to the first light emitting element ED-1, the second light emitting element ED-2, and the third light emitting element ED-3, respectively.

However, embodiments of the present disclosure are not limited thereto, for example, the first to third light emitting elements ED-1, ED-2, and ED-3 may be to emit light in substantially the same wavelength region, or at least one thereof may be to emit light in a different wavelength region. For example, in one embodiment, all the first to third light emitting elements ED-1, ED-2, and ED-3 may be to emit blue light.

The luminous areas PXA-R, PXA-G, and PXA-B in the display device DD according to one or more embodiments may be arranged in a stripe shape. Referring to FIG. 1, in some embodiments, a plurality of red luminous areas PXA-R may be arranged with each other along a second direction axis DR2, a plurality of green luminous areas PXA-G may be arranged with each other along the second direction axis DR2, and a plurality of blue luminous areas PXA-B may be arranged along the second direction axis DR2. In some embodiments, the red luminous area PXA-R, the green luminous area PXA-G, and the blue luminous area PXA-B may be arranged by turns along a first direction axis DR1.

In FIG. 1 and FIG. 2, the areas of the luminous areas PXA-R, PXA-G, and PXA-B are shown similar, but embodiments of the present disclosure are not limited thereto. The areas of the luminous areas PXA-R, PXA-G, and PXA-B may be different from each other according to the wavelength region of light emitted. In some embodiments, the areas of the luminous areas PXA-R, PXA-G, and PXA-B may refer to areas on a plane defined by the first direction axis DR1 and the second direction axis DR2.

In some embodiments, the arrangement type or kind of the luminous areas PXA-R, PXA-G, and PXA-B is not limited to the configuration shown in FIG. 1, and the arrangement order of the red luminous areas PXA-R, the green luminous areas PXA-G, and the blue luminous areas PXA-B may be provided in one or more suitable combinations according to the properties of display quality required for the display device DD. For example, the arrangement type or kind of the luminous areas PXA-R, PXA-G, and PXA-B may be a pentile (PENTILE®) arrangement type or kind (for example, an RGBG matrix, an RGBG structure, or an RGBG matrix structure), or a diamond (Diamond Pixel™) arrangement type or kind (e.g., a display (e.g., an OLED display) containing red, blue, and green (RGB) luminous areas arranged in the shape of diamonds). PENTILE® is a duly registered trademark of Samsung Display Co., Ltd. Diamond Pixel™ is a trademark of Samsung Display Co., Ltd.

In some embodiments, the areas of the luminous areas PXA-R, PXA-G, and PXA-B may be different from each other. For example, in one or more embodiments, the area of the green luminous area PXA-G may be smaller than the area of the blue luminous area PXA-B, but embodiments of the present disclosure are not limited thereto.

In the display device DD shown in FIG. 2, at least one selected from among the first to third light emitting elements ED-1, ED-2, and ED-3 may include a polycyclic compound disclosed in the present disclosure, which will be explained later.

Hereinafter, FIG. 3 to FIG. 6 are cross-sectional views schematically showing light emitting elements according to one or more embodiments. The light emitting element ED according to one or more embodiments may include a first electrode EL1, a second electrode EL2 oppositely disposed to the first electrode EL1, and at least one functional layer disposed between the first electrode EL1 and the second electrode EL2. In one or more embodiments, the light emitting element ED may include a first compound, which will be explained later, in the at least one functional layer. In some embodiments, the polycyclic compound disclosed in the present disclosure may be referred to as the first compound in the present disclosure.

The light emitting element ED may include a hole transport region HTR, an emission layer EML, an electron transport region ETR, and/or the like, stacked in order (in the stated order) as the at least one functional layer. Referring to FIG. 3, in one or more embodiments, the light emitting element ED may include a first electrode EL1, a hole transport region HTR, an emission layer EML, an electron transport region ETR, and a second electrode EL2, stacked in order (in the stated order). In some embodiments, the light emitting element ED may include the polycyclic compound disclosed in the present disclosure, which will be explained later, in the emission layer EML.

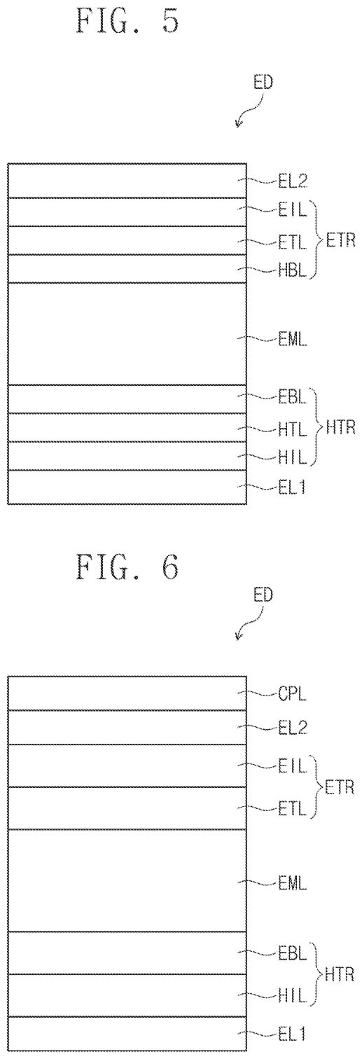

When compared with FIG. 3, FIG. 4 shows the cross-sectional view of a light emitting element ED according to one or more embodiments, wherein a hole transport region HTR may include a hole injection layer HIL and a hole transport layer HTL, and an electron transport region ETR may include an electron injection layer EIL and an electron transport layer ETL. In addition, when compared with FIG. 3, FIG. 5 shows the cross-sectional view of a light emitting element ED according to one or more embodiments, wherein a hole transport region HTR may include a hole injection layer HIL, a hole transport layer HTL, and an electron blocking layer EBL, and an electron transport region ETR may include an electron injection layer EIL, an electron transport layer ETL, and a hole blocking layer HBL. When compared with FIG. 4, FIG. 6 shows the cross-sectional view of a light emitting element ED according to one or more embodiments, including a capping layer CPL disposed on the second electrode EL2.

In one or more embodiments, the emission layer EML may include a first compound including a core part including a boron atom and a nitrogen atom as ring-forming atoms, and an electron donating group (EDG) substituted at the core part. In the first compound of the present disclosure, the electron donating group (EDG) may include a dibenzoheterole skeleton and may be substituted at the para direction to the boron atom of the core part.

In some embodiments, the emission layer EML may include at least one selected from among a second compound, a third compound, and a fourth compound. The second compound may include a substituted or unsubstituted carbazole. The third compound may include a hexagonal ring including at least one nitrogen atom as a ring-forming atom. The fourth compound may be an organometallic complex. The fourth compound may be an organometallic complex compound including platinum (Pt) or iridium (Ir) as a central metal (e.g., as a coordinating metal).

In the light emitting element ED according to one or more embodiments, the first electrode EL1 has conductivity (e.g., is a conductor). The first electrode EL1 may be formed utilizing a metal material, a metal alloy, or a conductive compound. The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), compounds of two or more selected therefrom, mixtures of two or more selected therefrom, and oxides thereof.

When the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Also, the first electrode EL1 may have a structure of a plurality of layers including a reflective layer or a transflective layer formed utilizing the above materials, and a transmissive conductive layer formed utilizing ITO, IZO, ZnO, or ITZO. For example, the first electrode EL1 may have a three-layer structure of ITO/Ag/ITO. However, embodiments of the present disclosure are not limited thereto. The first electrode EL1 may include the above-described metal materials, combinations of two or more metal materials selected from the above-described metal materials, or oxides of the above-described metal materials. The thickness of the first electrode EL1 may be from about 700 Å to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may have a single layer formed utilizing a single material, a single layer formed utilizing a plurality of different materials, or a multi-layered structure including a plurality of layers formed utilizing a plurality of different materials.

The hole transport region HTR may include at least one selected from among a hole injection layer HIL, a hole transport layer HTL, a buffer layer or an emission auxiliary layer, and an emission blocking layer EBL. In some embodiments, though not shown, the hole transport region HTR may include a plurality of stacked hole transport layers.

In some embodiments, differently, the hole transport region HTR may have the structure of a single layer of a hole injection layer HIL or a hole transport layer HTL, and may have a structure of a single layer formed utilizing a hole injection material and a hole transport material. In some embodiments, the hole transport region HTR may have a structure of a single layer formed utilizing a plurality of different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The thickness of the hole transport region HTR may be, for example, about 50 Å to about 15,000 Å. The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1.

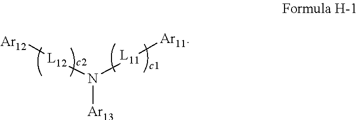

In Formula H-1, L₁₁ and L₁₂ may each independently be selected from a direct linkage, a substituted or unsubstituted arylene group of 6 to 30 ring-forming carbon atoms, and a substituted or unsubstituted heteroarylene group of 2 to 30 ring-forming carbon atoms. c1 and c2 may each independently be an integer of 0 to 10. In some embodiments, when c1 or c2 is an integer of 2 or more, a plurality of L₁₁ and L₁₂ may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁₁ and Ar₁₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-1, Ar₁₃ may be a substituted or unsubstituted aryl group of 6 to 30 ring-forming carbon atoms.

The compound represented by Formula H-1 may be a monoamine compound. In some embodiments, the compound represented by Formula H-1 may be a diamine compound in which at least one selected from among Ar₁₁ to Ar₁₃ may include an amine group as a substituent. In some embodiments, the compound represented by Formula H-1 may be a carbazole-based compound in which at least one selected from among Ar₁₁ and Ar₁₂ may include a substituted or unsubstituted carbazole group, or a fluorene-based compound in which at least one selected from among Ar₁₁ and Ar₁₂ may include a substituted or unsubstituted fluorene group.

The compound represented by Formula H-1 may be represented by any one selected from among the compounds in Compound Group H. However, the compounds shown in Compound Group H are only illustrations, and the compound represented by Formula H-1 is not limited to the compounds represented in Compound Group H.

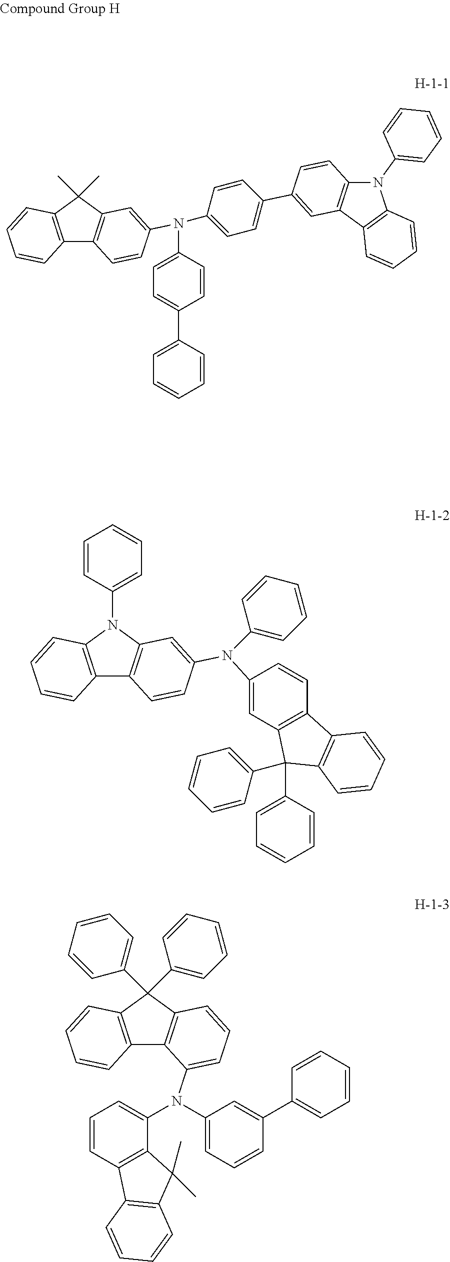 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

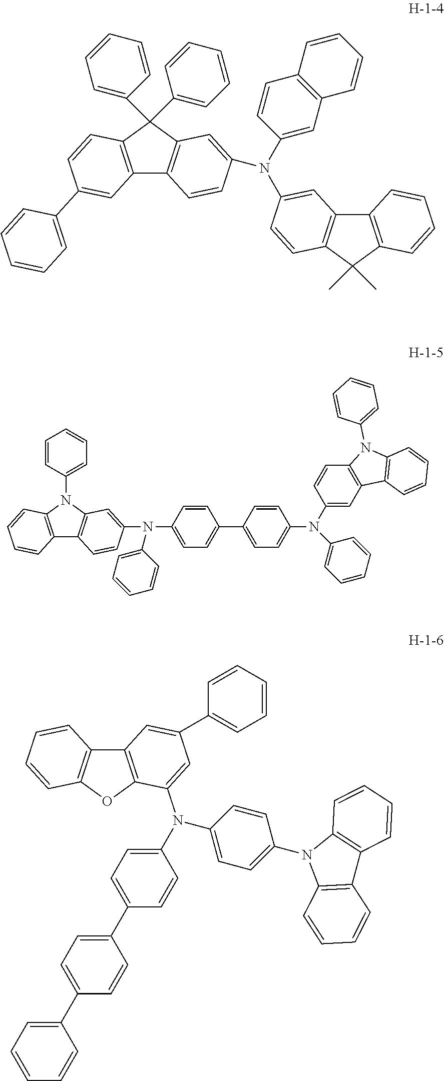 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

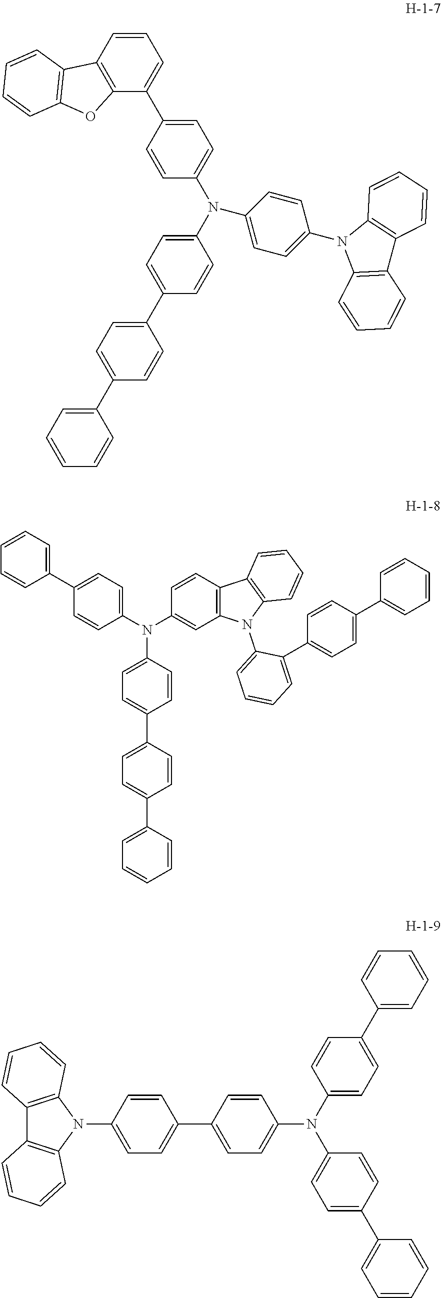 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

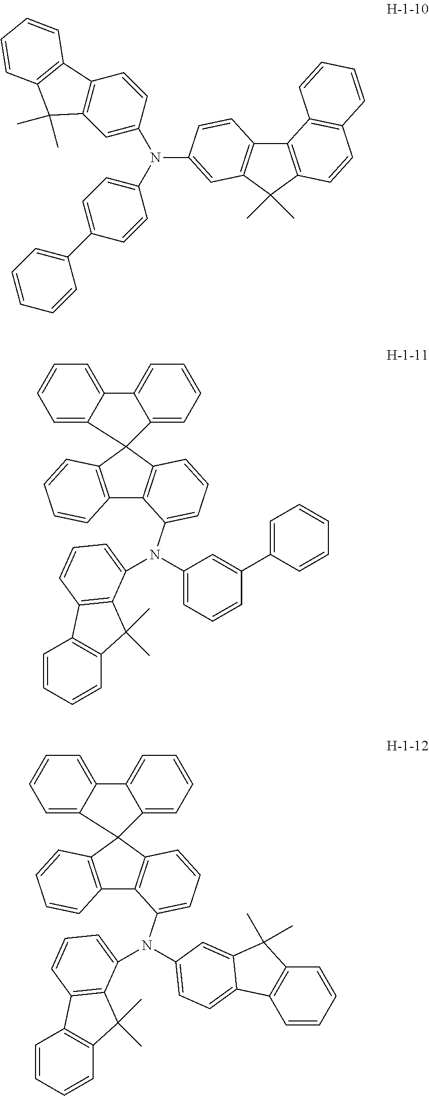 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

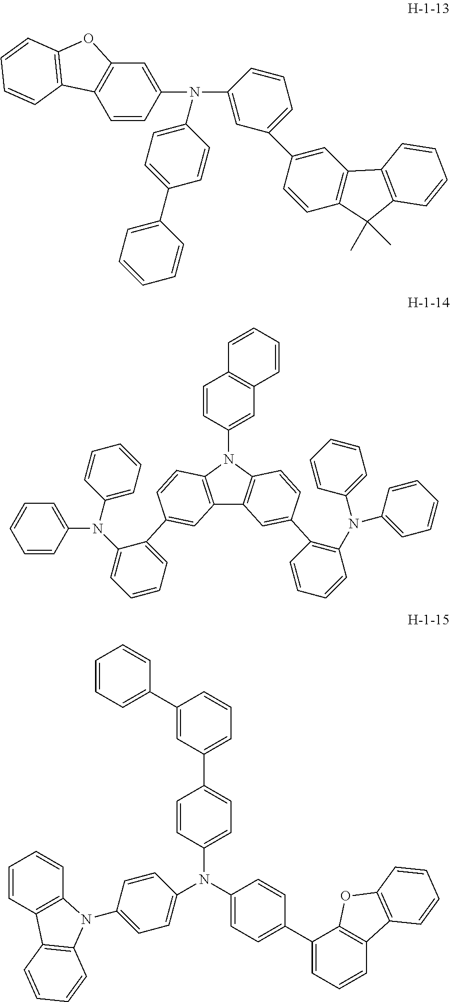 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

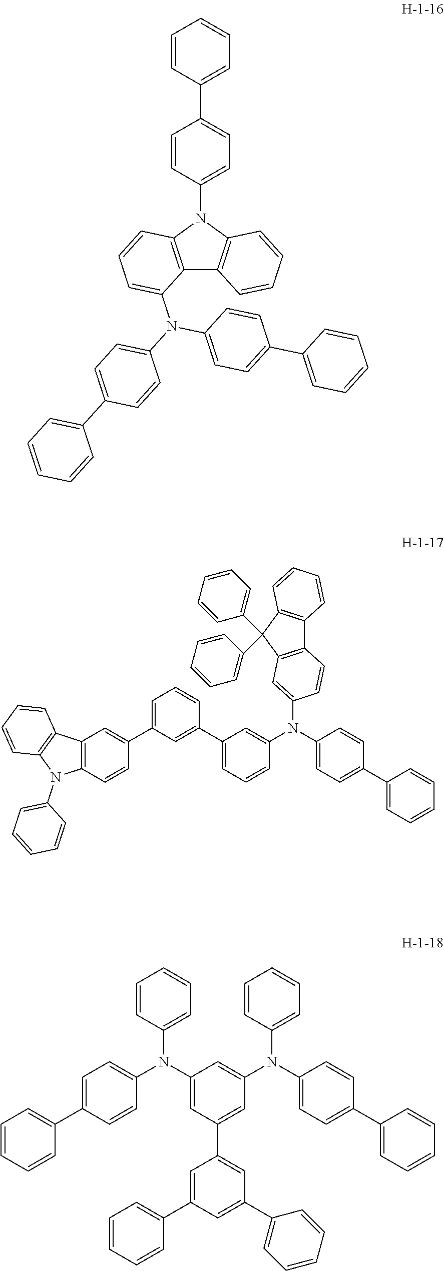 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

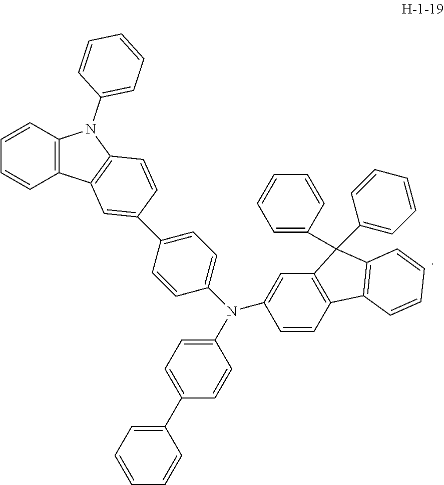 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(1-naphthyl)-N-phenylamino]-triphenylamine (1-TNATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalen-1-yl)-N,N′-diphenyl-benzidine (NPB) (or NPD, α-NPD), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HATCN).

The hole transport region HTR may include carbazole derivatives such as N-phenylcarbazole and polyvinylcarbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. When the hole transport region HTR includes a hole injection layer HIL, the thickness of the hole injection region HIL may be, for example, from about 30 Å to about 1,000 Å. When the hole transport region HTR includes a hole transport layer HTL, the thickness of the hole transport layer HTL may be from about 30 Å to about 1,000 Å. For example, when the hole transport region HTR includes an electron blocking layer, the thickness of the electron blocking layer EBL may be from about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without substantial increase of a driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one selected from among metal halide compounds, quinone derivatives, metal oxides, and cyano group-containing compounds, without limitation. For example, the p-dopant may include metal halide compounds such as CuI and RbI, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one selected from among a buffer layer and an electron blocking layer EBL in addition to the hole injection layer HIL and the hole transport layer HTL. The buffer layer may compensate resonance distance according to the wavelength of light emitted from an emission layer EML and may increase emission efficiency. As materials included in the buffer layer, materials which may be included in the hole transport region HTR may be utilized. The electron blocking layer EBL is a layer playing the role of blocking the injection of electrons from the electron transport region ETR to the hole transport region HTR. The emission auxiliary layer may improve the charge balance of holes and electrons. When the hole transport region HTR includes an electron blocking layer EBL, the electron blocking layer EBL may include the function as the emission auxiliary layer.

The emission layer EML is provided on the hole transport region HTR. The emission layer EML may have a thickness of, for example, about 100 Å to about 1,000 Å or about 100 Å to about 300 Å. The emission layer EML may include a single layer formed utilizing a single material, a single layer formed utilizing a plurality of different materials, or a multi-layered structure having a plurality of layers formed utilizing a plurality of different materials.

In one or more embodiments, in the light emitting element ED, the emission layer EML may include a plurality of light emitting materials. In one or more embodiments, the emission layer EML may include a first compound and at least one selected from among a second compound, a third compound, and a fourth compound. In one or more embodiments, in the light emitting element ED, the emission layer EML may include at least one host and at least one dopant. For example, in one embodiment, the emission layer EML may include a first dopant, and a first host and a second host, which are different from each other.

In one or more embodiments, the emission layer EML may include a first compound represented by Formula 1. The first compound corresponds to the polycyclic compound disclosed in the present disclosure.

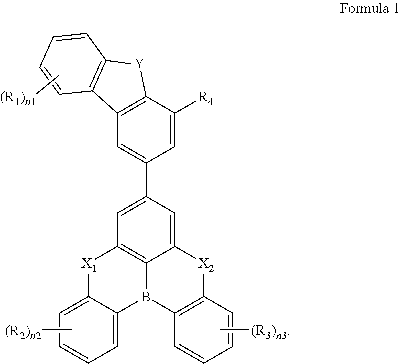

In Formula 1, R₁ to R₃ may each independently be selected from hydrogen, deuterium, a cyano group, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms.

In one or more embodiments, in the polycyclic compound represented by Formula 1, R₁ to R₃ may each independently be selected from hydrogen, deuterium, a substituted or unsubstituted alkyl group of 1 to 10 carbon atoms, a substituted or unsubstituted aryl group of 6 to 20 ring-forming carbon atoms, and a substituted or unsubstituted heteroaryl group of 2 to 20 ring-forming carbon atoms. For example, R₁ may be hydrogen or deuterium. R₂ and R₃ may each independently be selected from hydrogen, deuterium, a substituted or unsubstituted t-butyl group, a substituted or unsubstituted carbazole group, a substituted or unsubstituted phenyl group, and a substituted or unsubstituted dibenzofuran group. R₁ to R₃ may each independently be a substituent substituted with deuterium, a cyano group, a t-butyl group, and/or a phenyl group.

In Formula 1, n1 to n3 may each independently be an integer of 0 to 4. In some embodiments, when n1 is an integer of 2 or more, each of a plurality of R₁s may be all the same, or at least one may be different from the remainder. In some embodiments, when n2 is an integer of 2 or more, each of a plurality of R₂s may be all the same, or at least one may be different from the remainder. In some embodiment, when n3 is an integer of 2 or more, each of a plurality of R₃s may be all the same, or at least one may be different from the remainder. An embodiment in which n1 is 0 may be the same as an embodiment in which n1 is 4, and R₁ is hydrogen. The embodiment in which n1 is 0 may be understood as the polycyclic compound represented by Formula 1 where R₁ is hydrogen. An embodiment in which n2 is 0 may be the same as an embodiment in which n2 is 4, and R₂ is hydrogen. The embodiment in which n2 is O may be understood as the polycyclic compound represented by Formula 1 where R₂ is hydrogen. An embodiment in which n3 is 0 may be the same as an embodiment in which n3 is 4, and R₃ is hydrogen. The embodiment in which n3 is 0 may be understood as the polycyclic compound represented by Formula 1 where R₃ is hydrogen.

In Formula 1, R₄ may be a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. For example, R₄ may be a substituted or unsubstituted t-butyl group, a substituted or unsubstituted phenyl group, a substituted or unsubstituted carbazole group, a substituted or unsubstituted dibenzofuran group, or a substituted or unsubstituted tetralinyl group. When R₄ is substituted, R₄ may be a substituent which is substituted with deuterium, a methyl group, and/or a t-butyl group.

In Formula 1, X₁ and X₂ may each independently be NRₓ or O, and Y may be NR_{y} or O. In one embodiment, at least one selected from among X₁ and X₂ may be NRₓ. For example, when both X₁ and X₂ are NRₓ, two Rₓ may be the same or different.

Rₓ and R_{y} may each independently be a substituted or unsubstituted aryl group of 6 to 30 ring-forming carbon atoms, or a substituted or unsubstituted heteroaryl group of 2 to 30 ring-forming carbon atoms. In one embodiment, Rₓ and R_{y} may each independently be a substituted or unsubstituted aryl group of 6 to 20 ring-forming carbon atoms. For example, Rₓ and R_{y} may each independently be selected from a substituted or unsubstituted phenyl group, a substituted or unsubstituted biphenyl group, and a substituted or unsubstituted terphenyl group.

In one or more embodiments, when substituted, each of Rₓ and R_{y} may be a substituent substituted with deuterium, a substituted or unsubstituted alkyl group of 1 to 20 carbon atoms, and/or a substituted or unsubstituted aryl group of 6 to 20 ring-forming carbon atoms. For example, each of Rₓ and R_{y} may be a substituent substituted with a t-butyl group and/or a phenyl group. However, embodiments of the present disclosure are not limited thereto.

In some embodiments, the polycyclic compound may include at least one deuterium as a substituent. For example, in one embodiment, at least one selected from among R₁ to R₄ of Formula 1 may include deuterium, and/or a substituent including deuterium.

The polycyclic compound of the present disclosure may include a core part of a fused ring including one boron atom (B) and two nitrogen atoms (N) as ring-forming atoms, and an electron donating group (EDG) with a high electron density, that is connected with the core part and may provide the core of the fused ring with electron density.

In one or more embodiments, the polycyclic compound may include—a structure in which an electron donating group (EDG) having a dibenzoheterole skeleton at the para direction to the boron atom (B), and may reduce electron deficiency and reduce the instability of the boron atom (B) in the molecule. For example, in one or more embodiments, in the polycyclic compound, the electron donating group is bonded to the core part at carbon at position 2 of the dibenzoheterole to show a short wavelength and achieve deep blue color. In some embodiments, in the polycyclic compound, a substituent is introduced at carbon at position 4 of the dibenzoheterole of the electron donating group of the dibenzoheterole skeleton, bonded to the core part, which may reduce intramolecular interaction of the polycyclic compound. Accordingly, the polycyclic compound of the present disclosure may contribute to the improvement of emission efficiency and lifetime.

In one or more embodiments, the polycyclic compound represented by Formula 1 may be represented by Formula 2. Formula 2 corresponds to Formula 1 where Rᵢ is hydrogen. In Formula 2, the same definitions as those explained referring to Formula 1 may be applied for R₂, R₃, R₄, X₁, X₂, Y, n2, and n3.

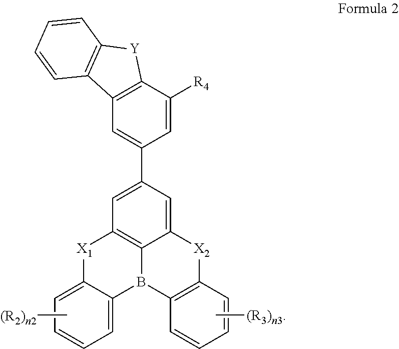

In one or more embodiments, the polycyclic compound represented by Formula 1 may be represented by Formula 3-1 or Formula 3-2. Formula 3-1 and Formula 3-2 correspond to Formula 1 where X₁ and X₂ are embodied. Formula 3-1 corresponds to Formula 1 where both X₁ and X₂ are NRₓ, and Formula 3-2 corresponds to Formula 1 where any one selected from among X₁ and X₂ is NRₓ, and the remainder is an oxygen atom (O). Meanwhile, in Formula 3-1 and Formula 3-2, the same definitions as those explained in Formula 1 may be applied for R₁ to R₄, Y, and n1 to n3.

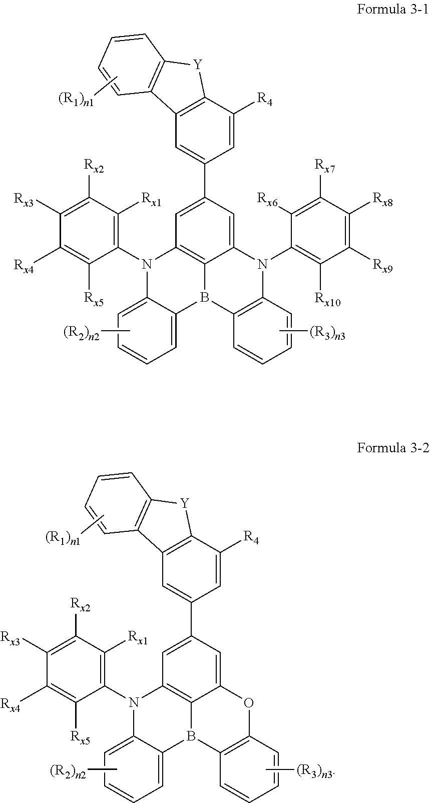

In Formula 3-1 and Formula 3-2, Rₓ₁ to Rₓ₁₀ may each independently be selected from hydrogen, deuterium, a substituted or unsubstituted alkyl group of 1 to 20 carbon atoms, and a substituted or unsubstituted aryl group of 6 to 20 ring-forming carbon atoms. For example, Rₓ₁ to Rₓ₀ may each independently be selected from hydrogen, deuterium, a substituted or unsubstituted t-butyl group, and a substituted or unsubstituted phenyl group.

In one or more embodiments, at least one selected from among Rₓ₁ to Rₓ₅ may be a substituted or unsubstituted alkyl group of 1 to 20 carbon atoms, or a substituted or unsubstituted aryl group of 6 to 20 ring-forming carbon atoms, and the remainder may be hydrogen atoms. In some embodiments, at least one selected from among Rₓ₆ to Rₓ₀ may be a substituted or unsubstituted alkyl group of 1 to 20 carbon atoms, or a substituted or unsubstituted aryl group of 6 to 20 ring-forming carbon atoms, and the remainder may be hydrogen atoms. For example, at least one selected from among Rₓ₁ to Rₓ₅ may be a substituted or unsubstituted t-butyl group or a substituted or unsubstituted phenyl group, and at least one selected from among Rₓ₆ to Rₓ₀ may be a substituted or unsubstituted t-butyl group or a substituted or unsubstituted phenyl group.

In one or more embodiments, the polycyclic compound represented by Formula 3-1 may be represented by Formula 3-1-1 or Formula 3-1-2. Formula 3-1-1 and Formula 3-1-2 correspond to Formula 3 where R₁ is hydrogen, and Y is embodied.

In some embodiments, Formula 3-1-1 and Formula 3-1-2 correspond to Formula 1 where R₁ is hydrogen, and X₁, X₂, and Y are embodied. Meanwhile, in Formula 3-1-1 and Formula 3-1-2, the same definitions as those explained in Formula 1 may be applied for R₂ to R₄, n2, and n3, and the same definitions as those explained in Formula 3-1 may be applied for Rₓ₁ to Rₓ₀.

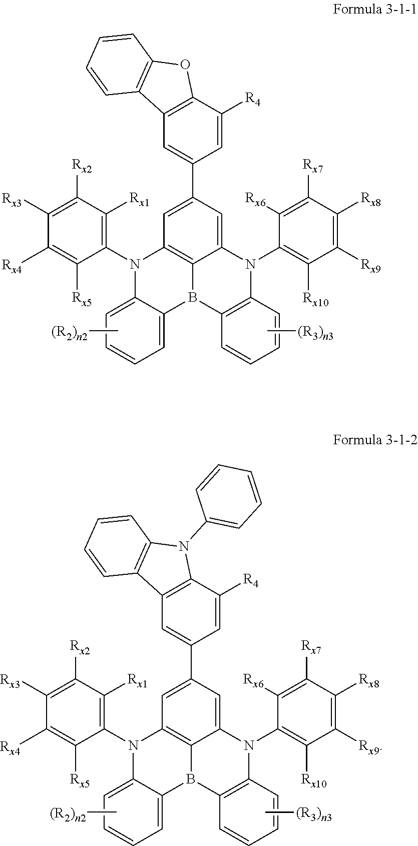

In one or more embodiments, the polycyclic compound represented by Formula 3-2 may be represented by Formula 3-2-1 or Formula 3-2-2. Formula 3-2-1 and Formula 3-2-2 correspond to Formula 3 where R₁ is hydrogen, and Y is embodied. In some embodiments, Formula 3-2-1 and Formula 3-2-2 correspond to Formula 1 where R₁ is hydrogen, and X₁, X₂, and Y are embodied. Meanwhile, in Formula 3-2-1 and Formula 3-2-2, the same definitions as those explained in Formula 1 may be applied for R₂ to R₄, n2, and n3, and the same definitions as those explained in Formula 3-2 may be applied for Rₓ₁ to Rₓ₅.

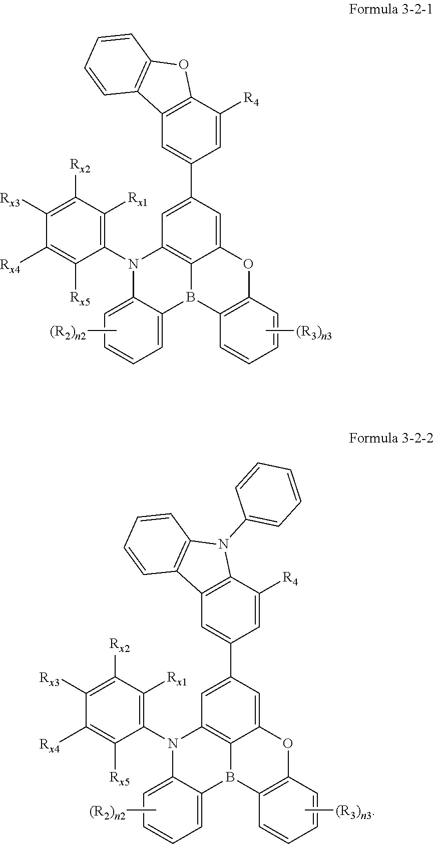

The polycyclic compound represented by Formula 1 may be represented by any one selected from among Formula 4-1 to Formula 4-3. Formula 4-1 to Formula 4-3 correspond to Formula 1 where R₂ and R₃ are embodied. In Formula 4-1 to Formula 4-3, the same definitions as those explained in Formula 1 may be applied for R₁, R₄, X₁, X₂, Y, and n1.

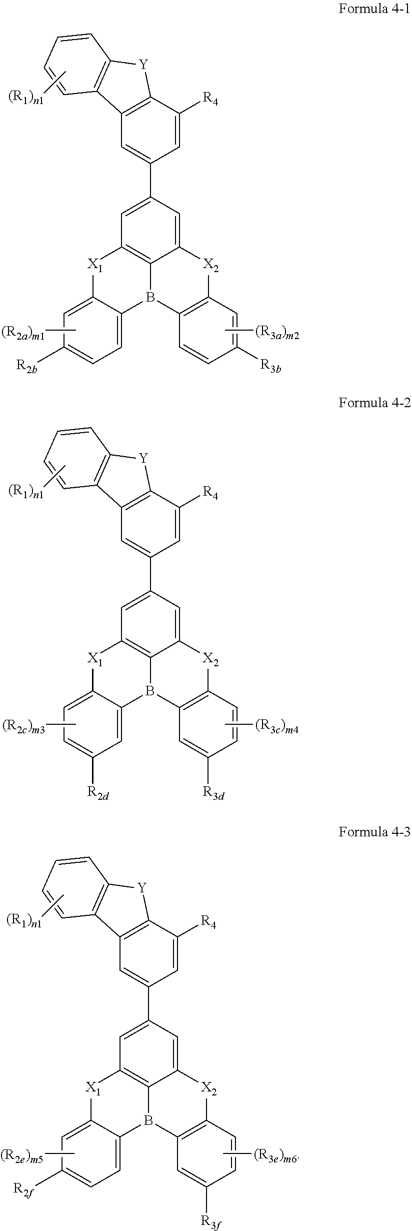

In Formula 4-1 to Formula 4-3, R₂ₐ, R₃ₐ, R_{2c}, R_{3c}, R₂ₑ, and R₃ₑ may each independently be selected from hydrogen, deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms.

In one or more embodiments, R₂ₐ, R₃ₐ, R_{2c}, R_{3c}, R₂ₑ, and R₃ₑ may each independently be selected from hydrogen, deuterium, a substituted or unsubstituted alkyl group of 1 to 10 carbon atoms, a substituted or unsubstituted aryl group of 6 to 20 ring-forming carbon atoms, and a substituted or unsubstituted heteroaryl group of 2 to 20 ring-forming carbon atoms. For example, R₂ₐ, R₃ₐ, R_{2c}, R_{3c}, R₂ₑ, and R₃ₑ may each independently be selected from hydrogen, deuterium, a substituted or unsubstituted t-butyl group, and a substituted or unsubstituted phenyl group. When substituted, each of R₂ₐ, R₃ₐ, R_{2c}, R_{3c}, R₂ₑ, and R₃ₑ may be a substituent substituted with deuterium, a t-butyl group, and/or a phenyl group.

In Formula 4-1 to Formula 4-3, R_{2b}, R_{3b}, R_{2d}, R_{3d}, R_{2f}, and R_{3f} may each independently be selected from deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms.

In one or more embodiments, R_{2b}, R_{3b}, R_{2d}, R_{3d}, R_{2f}, and R_{3f} may each independently be selected from a substituted or unsubstituted alkyl group of 1 to 10 carbon atoms, a substituted or unsubstituted aryl group of 6 to 20 ring-forming carbon atoms, and a substituted or unsubstituted heteroaryl group of 2 to 20 ring-forming carbon atoms. For example, each of R_{2b}, R_{3b}, R_{2d}, R_{3d}, R_{2f}, and R_{3f} may be selected from a substituted or unsubstituted t-butyl group, a substituted or unsubstituted carbazole group, a substituted or unsubstituted phenyl group, and a substituted or unsubstituted dibenzofuran group. When substituted, each of R_{2b}, R_{3b}, R_{2d}, R_{3d}, R_{2f}, and R_{3f} may be a substituent substituted with deuterium, a cyano group, a t-butyl group, and/or a phenyl group.

In Formula 4-1 to Formula 4-3, m1 to m6 may each independently be an integer of 0 to 3. When each of m1 to m6 is an integer of 2 or more, each of a plurality of R₂ₐs may be the same, or at least one may be different from the remainder; each of a plurality of R₃ₐs may be the same, or at least one may be different from the remainder; each of a plurality of R_{2c}s may be the same, or at least one may be different from the remainder; each of a plurality of R_{3c}s may be the same, or at least one may be different from the remainder; each of a plurality of R₂ₑs may be the same, or at least one may be different from the remainder; each of a plurality of R₃ₑs may be the same, or at least one may be different from the remainder. In some embodiments, an embodiment in which m1 is 0 may be the same as an embodiment in which m1 is 3, and R₂ₐ is a hydrogen atom. The embodiment in which m1 is 0 may be understood as the polycyclic compound represented by Formula 1 where R₂ₐ is hydrogen. The same explanation may be applied for embodiments in which m2 to m6 are 0.

In one or more embodiments, the first compound may be any one selected from among the compounds represented in Compound Group 1. In one or more embodiment, the light emitting element ED may include at least one selected from among the compounds represented in Compound Group 1 as the first compound in an emission layer EML.

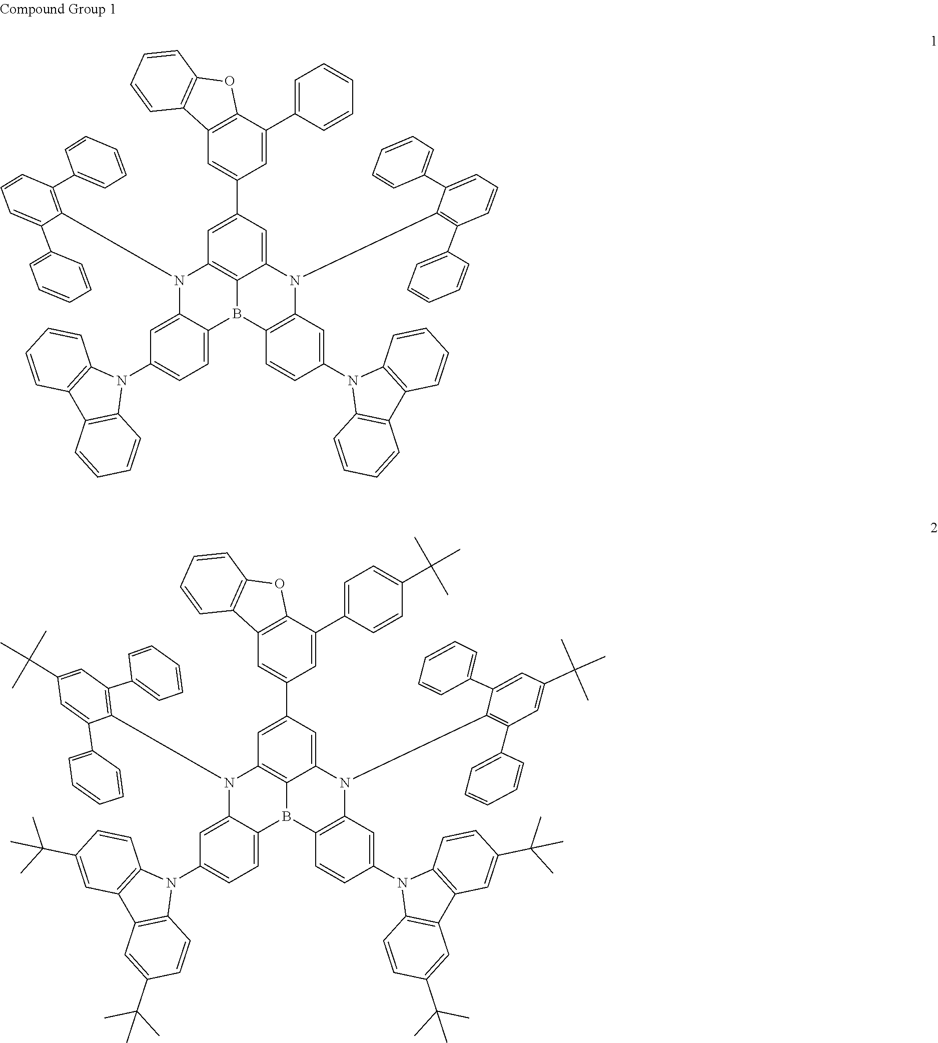 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5cc(-c6ccccc6)c6oc7ccccc7c6c5)cc2c43)cc1 ; CC(C)(C)c1ccc(-c2cc(-c3cc4c5c(c3)N(c3c(-c6ccccc6)cc(C(C)(C)C)cc3-c3ccccc3)c3cc(-n6c7ccc(C(C)(C)C)cc7c7cc(C(C)(C)C)ccc76)ccc3B5c3ccc(-n5c6ccc(C(C)(C)C)cc6c6cc(C(C)(C)C)ccc65)cc3N4c3c(-c4ccccc4)cc(C(C)(C)C)cc3-c3ccccc3)cc3c2oc2ccccc23)cc1]

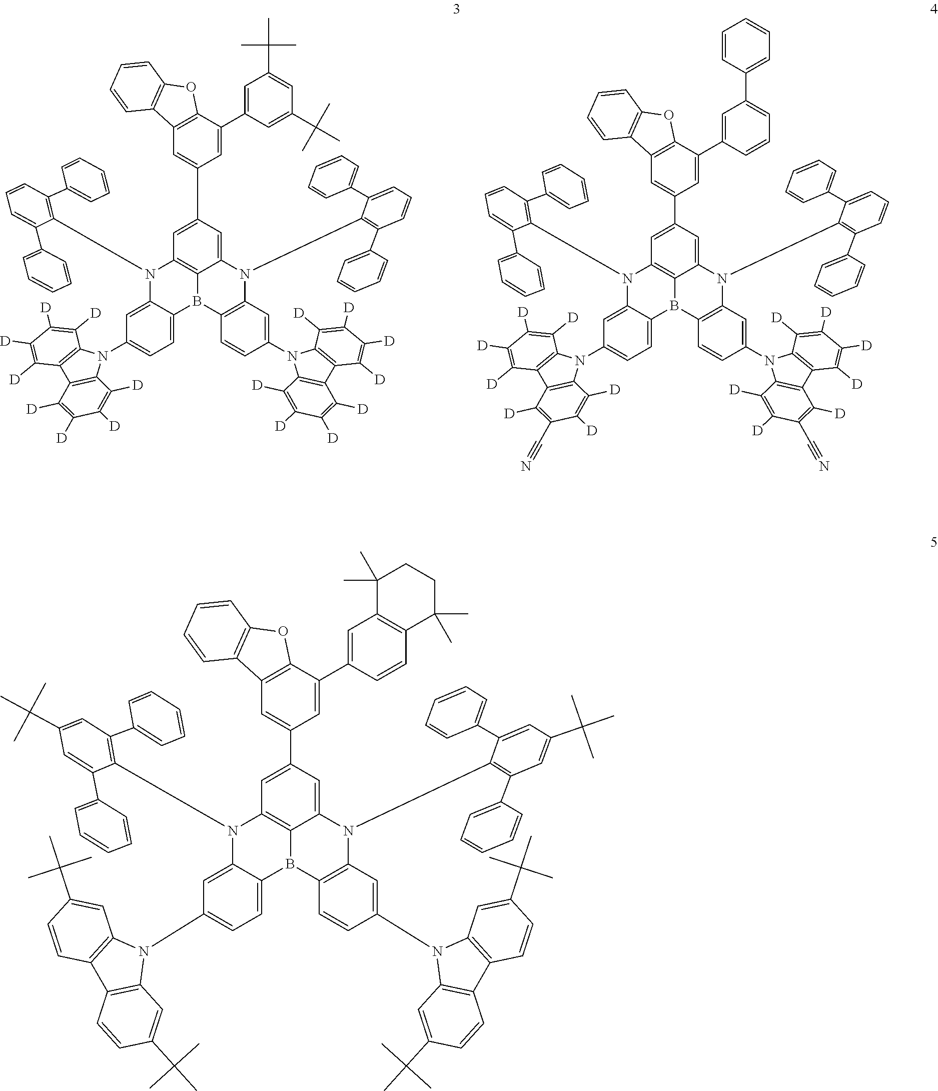

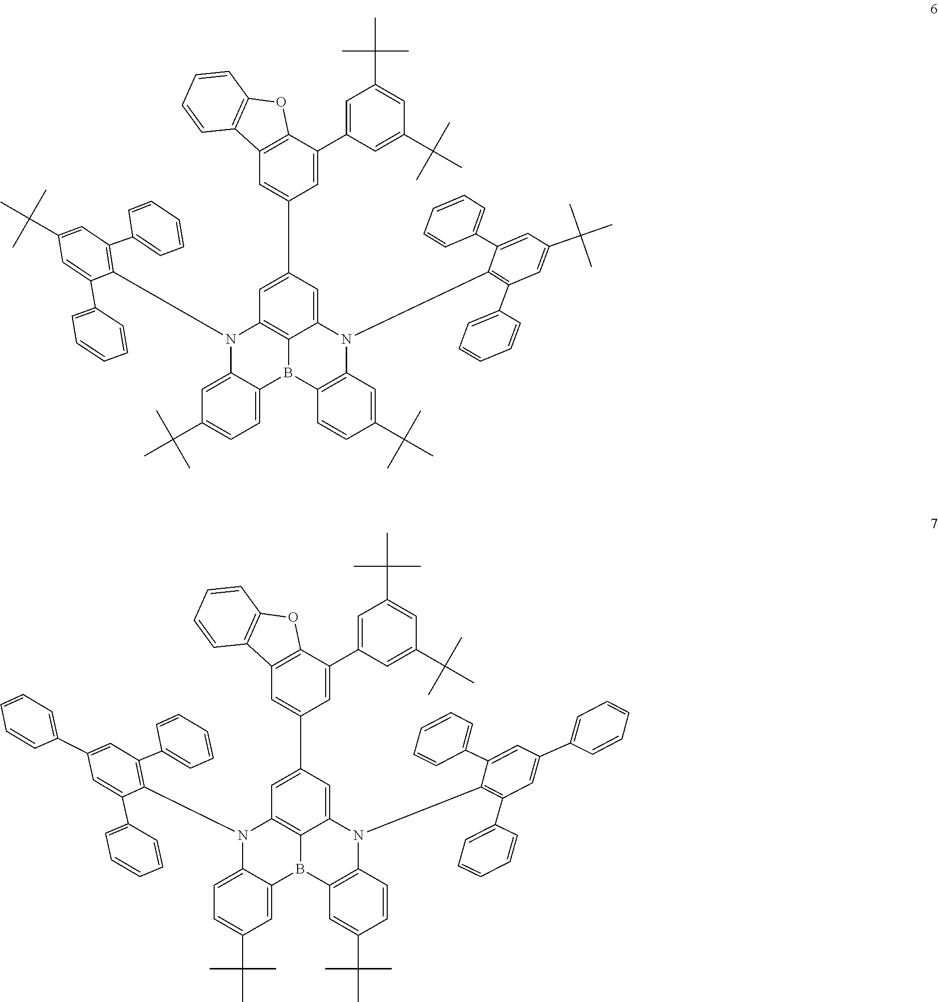 [SMILES: CC(C)(C)c1cc(-c2cc(-c3cc4c5c(c3)N(c3c(-c6ccccc6)cc(C(C)(C)C)cc3-c3ccccc3)c3cc(C(C)(C)C)ccc3B5c3ccc(C(C)(C)C)cc3N4c3c(-c4ccccc4)cc(C(C)(C)C)cc3-c3ccccc3)cc3c2oc2ccccc23)cc(C(C)(C)C)c1 ; CC(C)(C)c1cc(-c2cc(-c3cc4c5c(c3)N(c3c(-c6ccccc6)cc(-c6ccccc6)cc3-c3ccccc3)c3ccc(C(C)(C)C)cc3B5c3cc(C(C)(C)C)ccc3N4c3c(-c4ccccc4)cc(-c4ccccc4)cc3-c3ccccc3)cc3c2oc2ccccc23)cc(C(C)(C)C)c1]

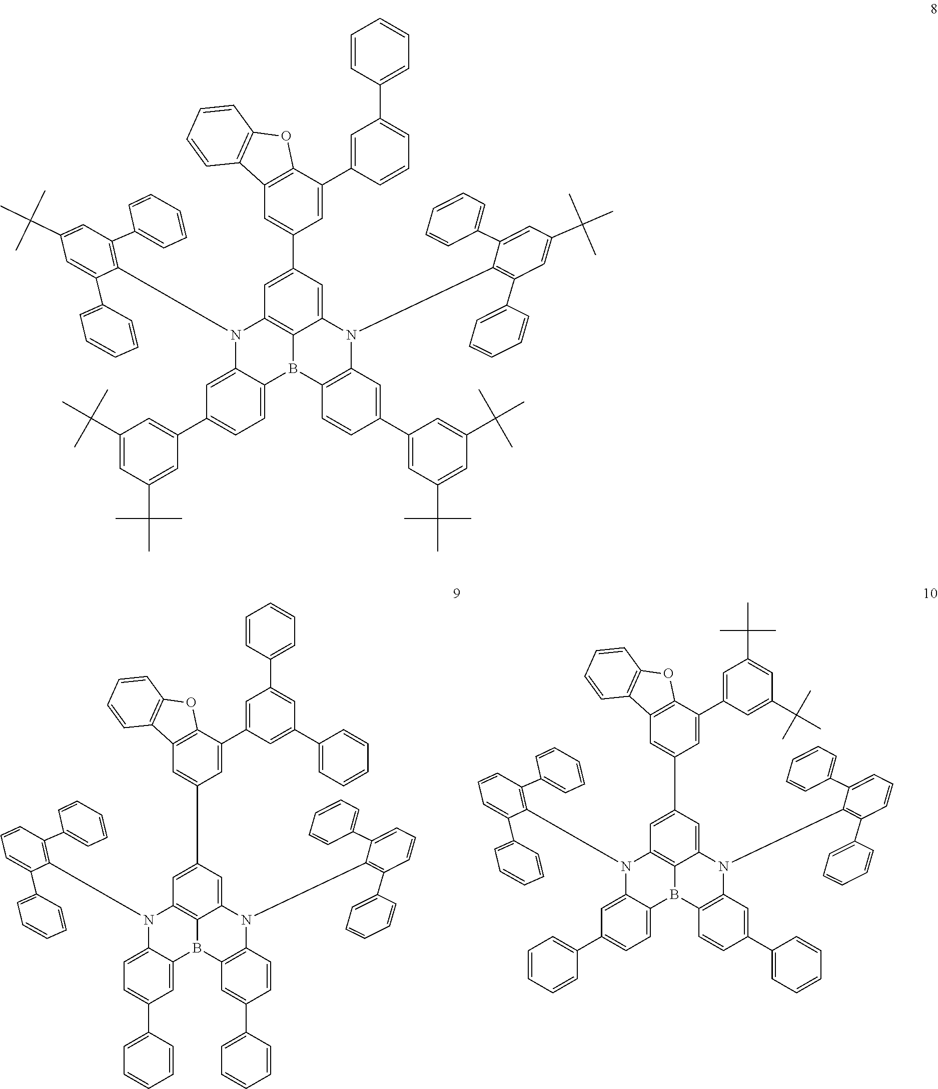

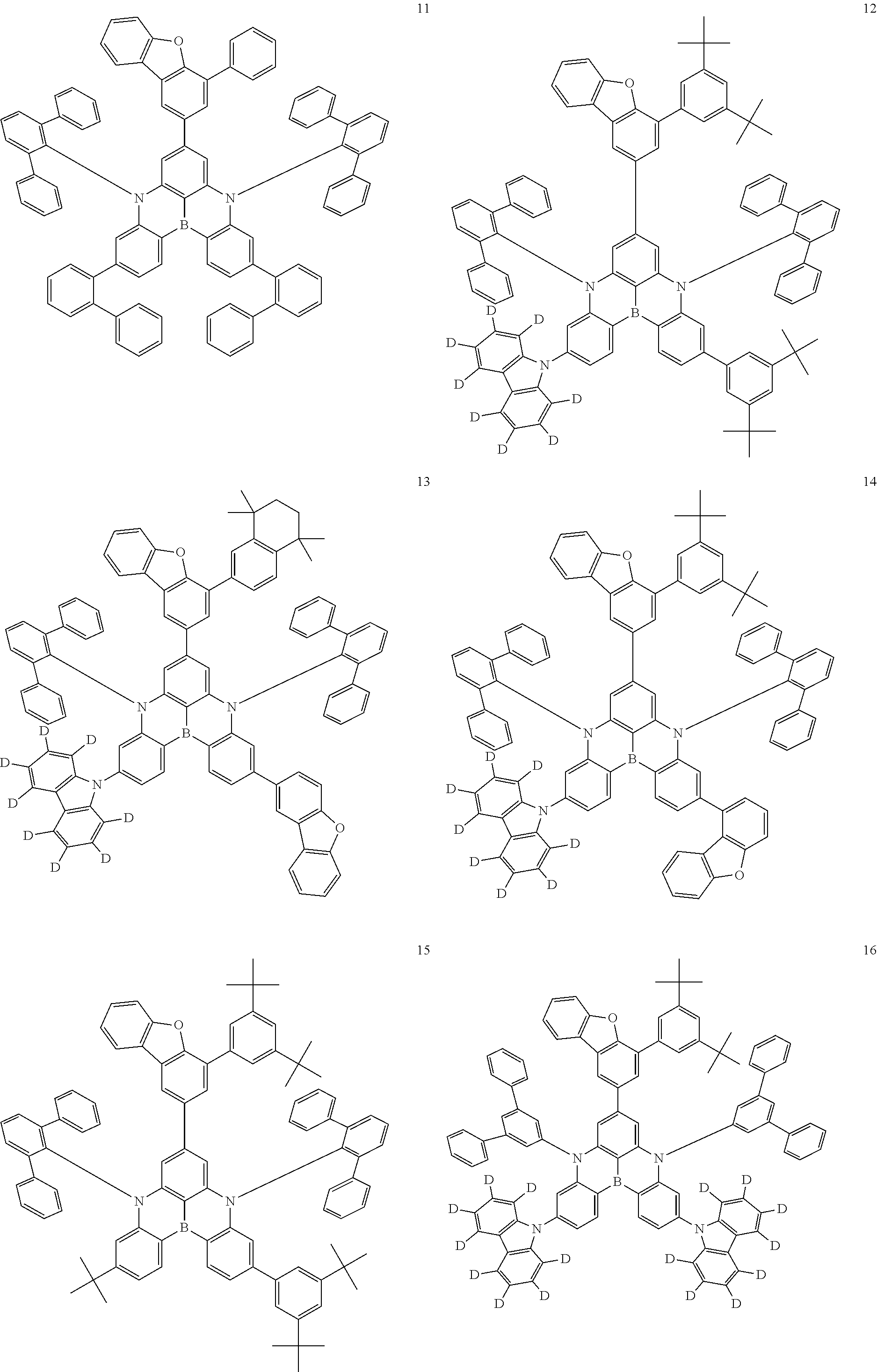

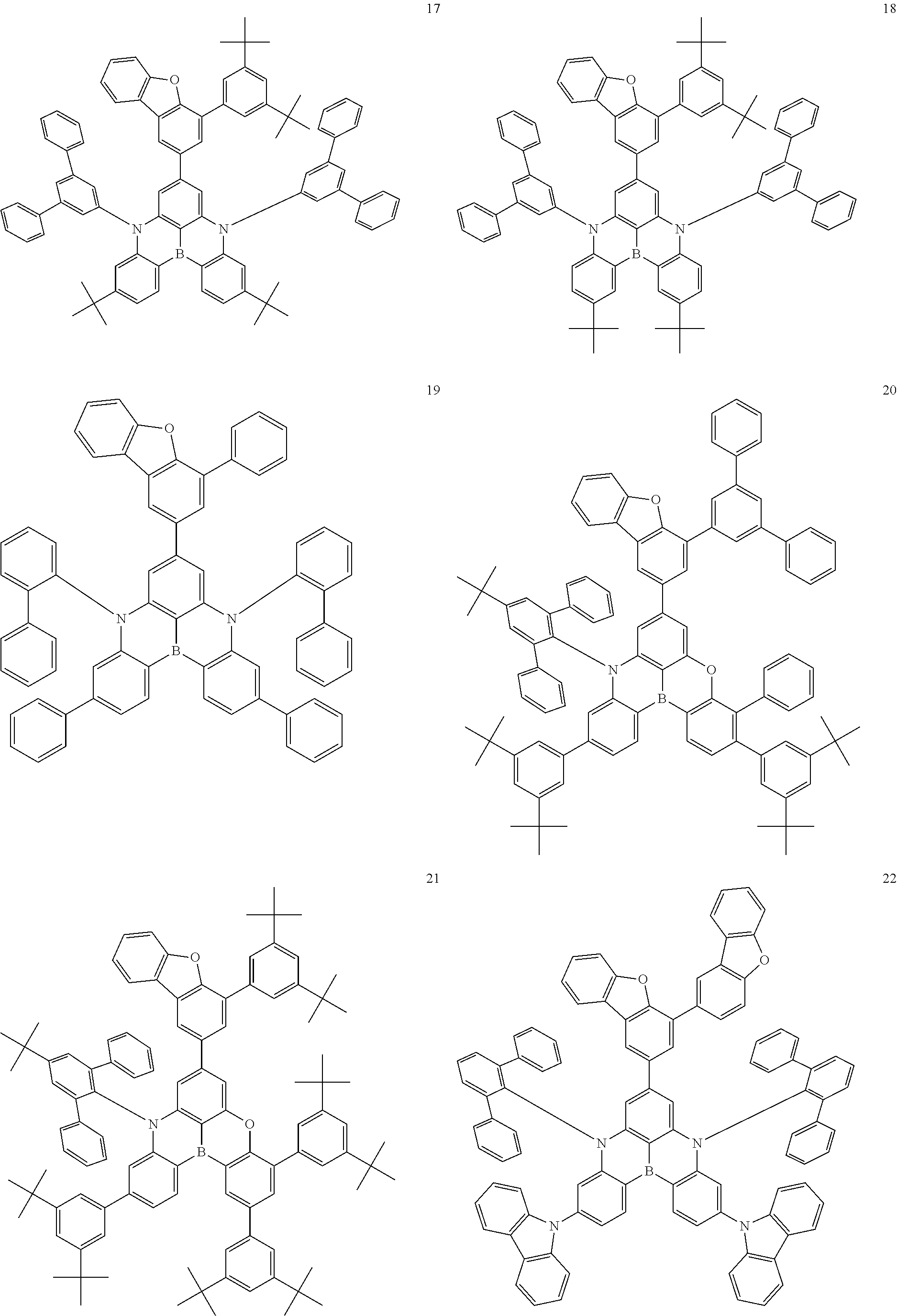

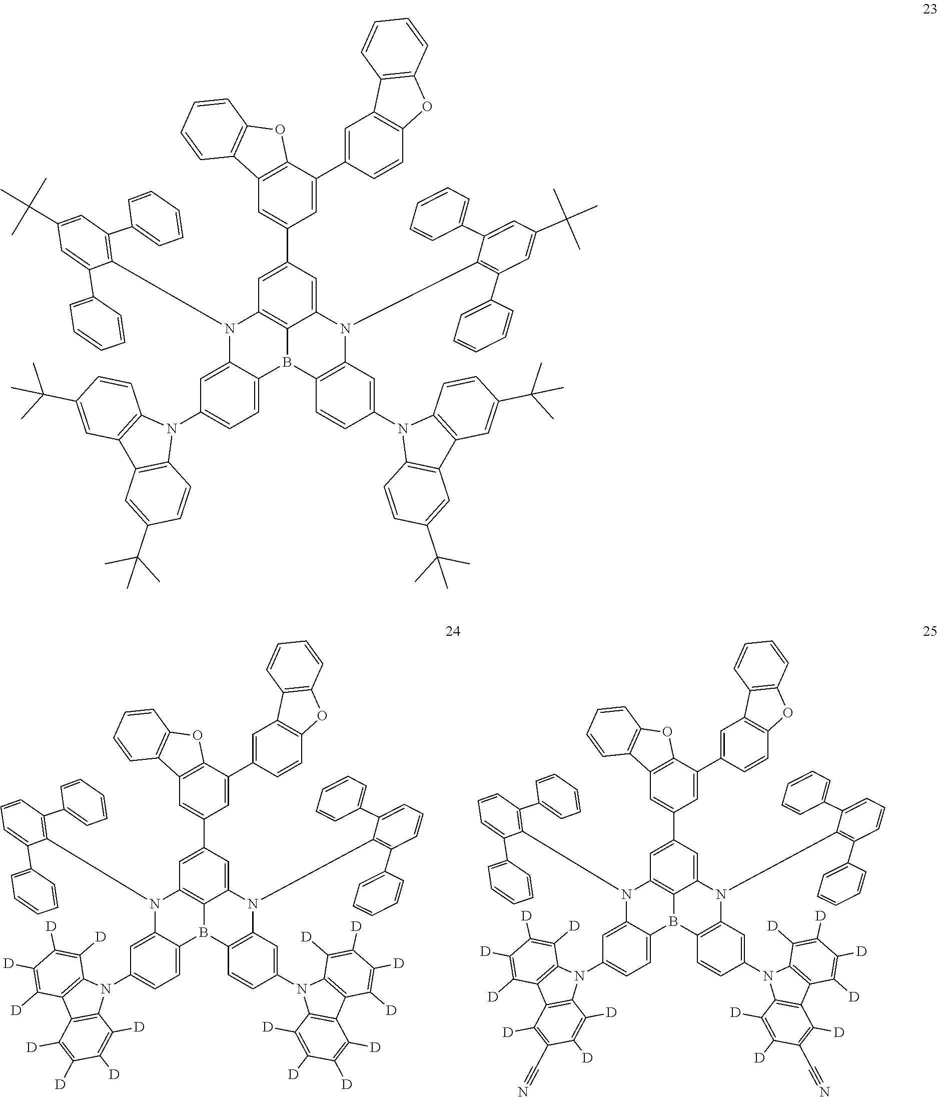

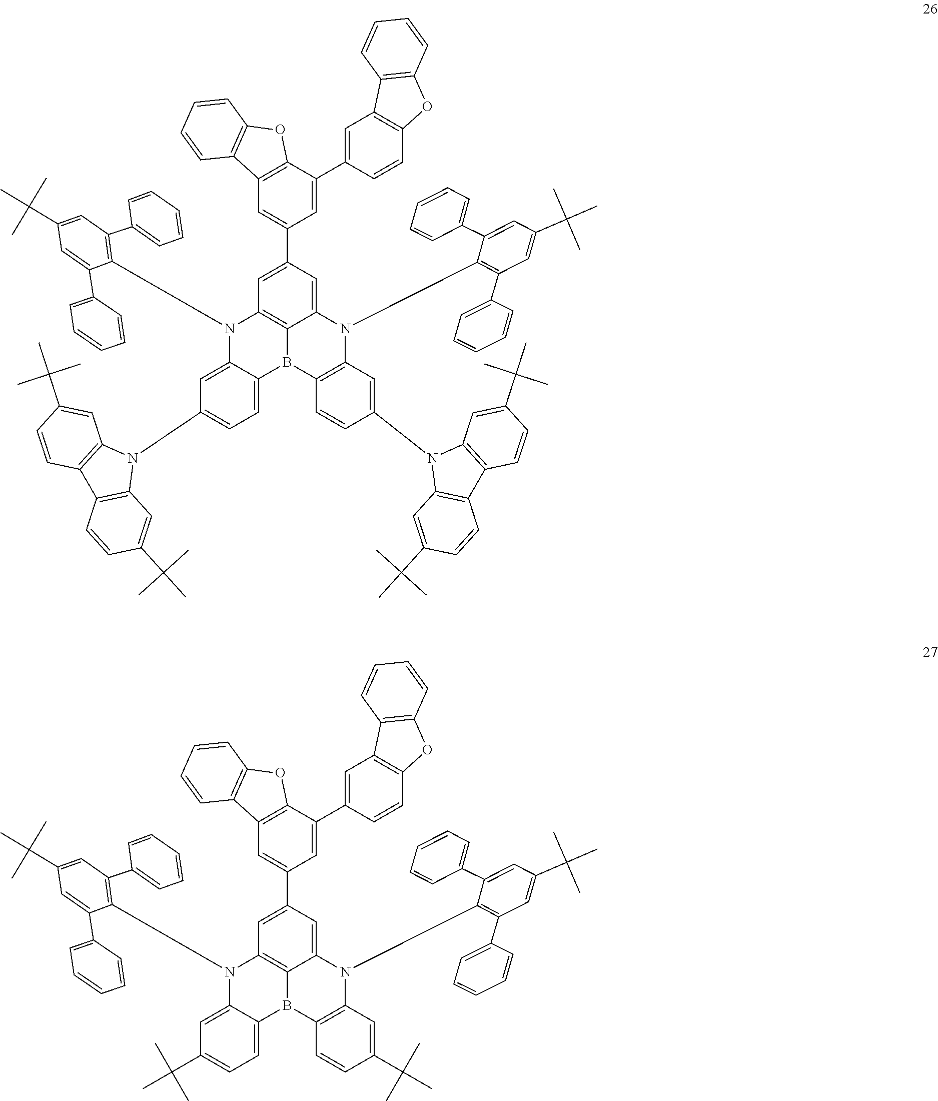

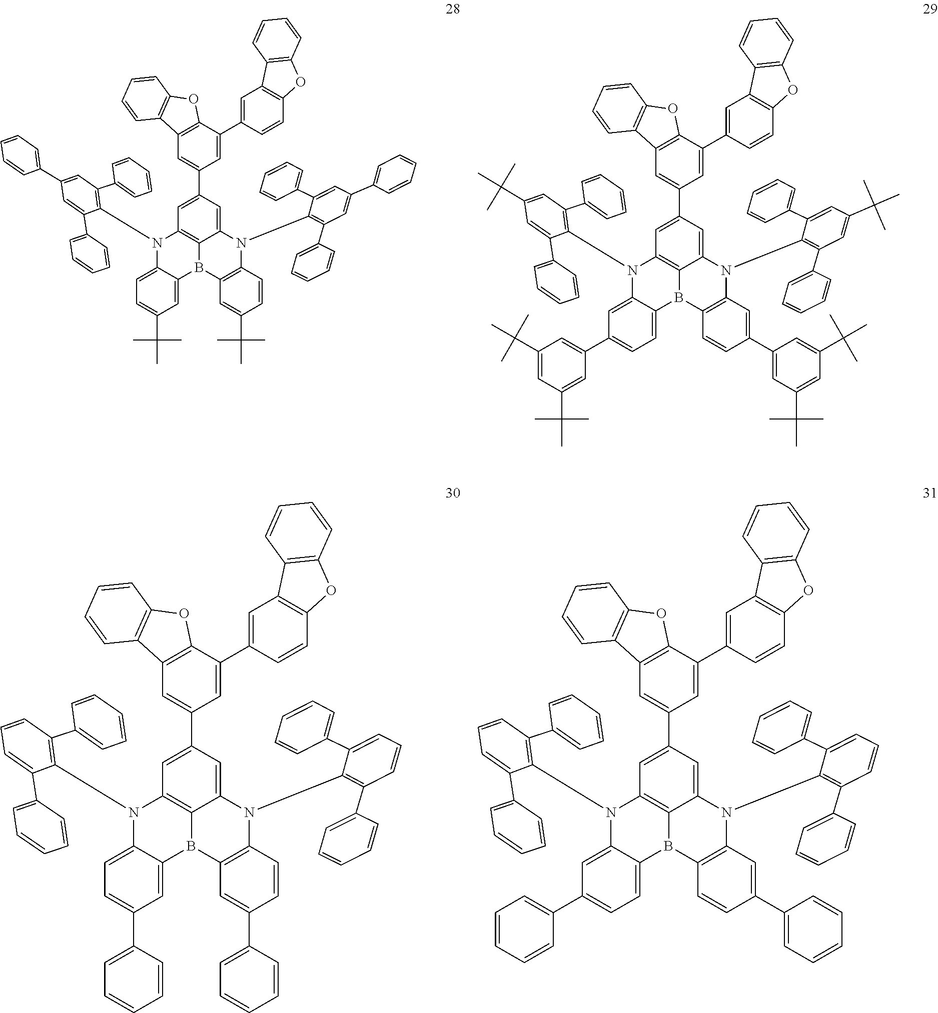

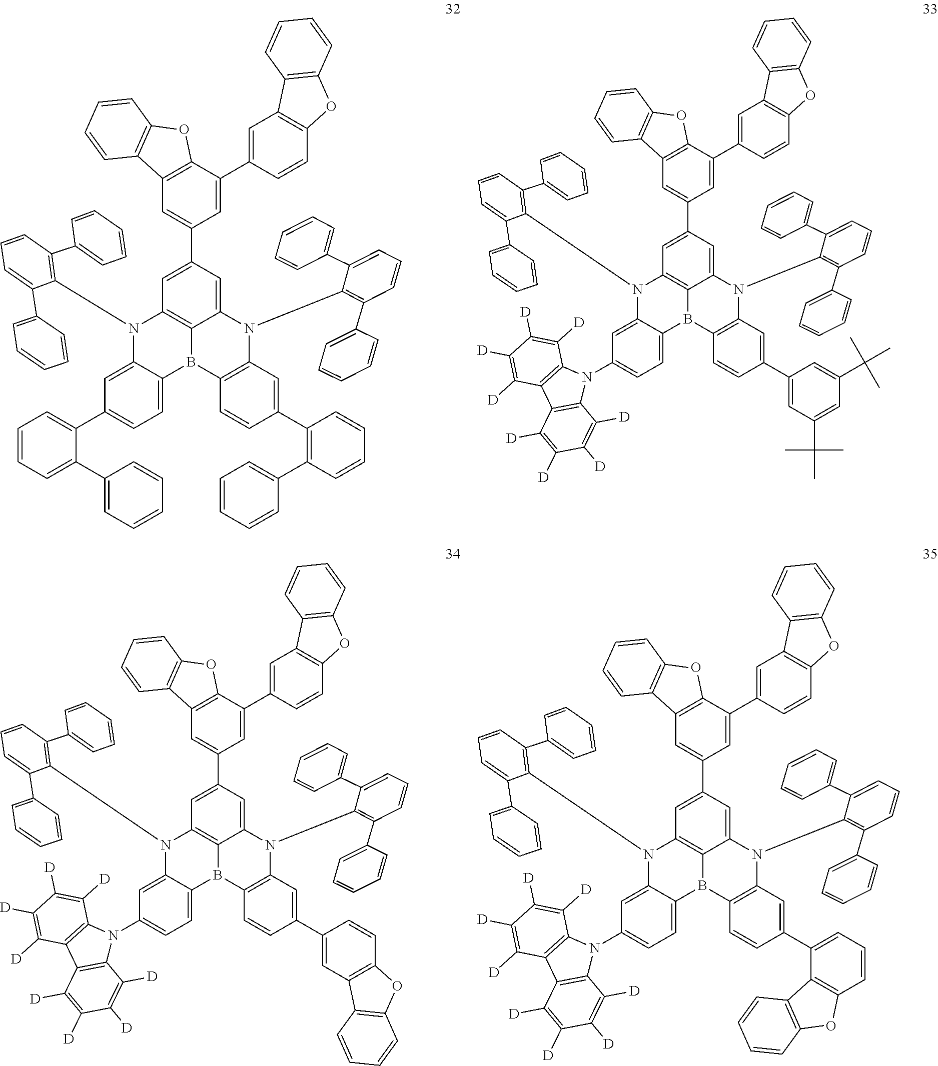

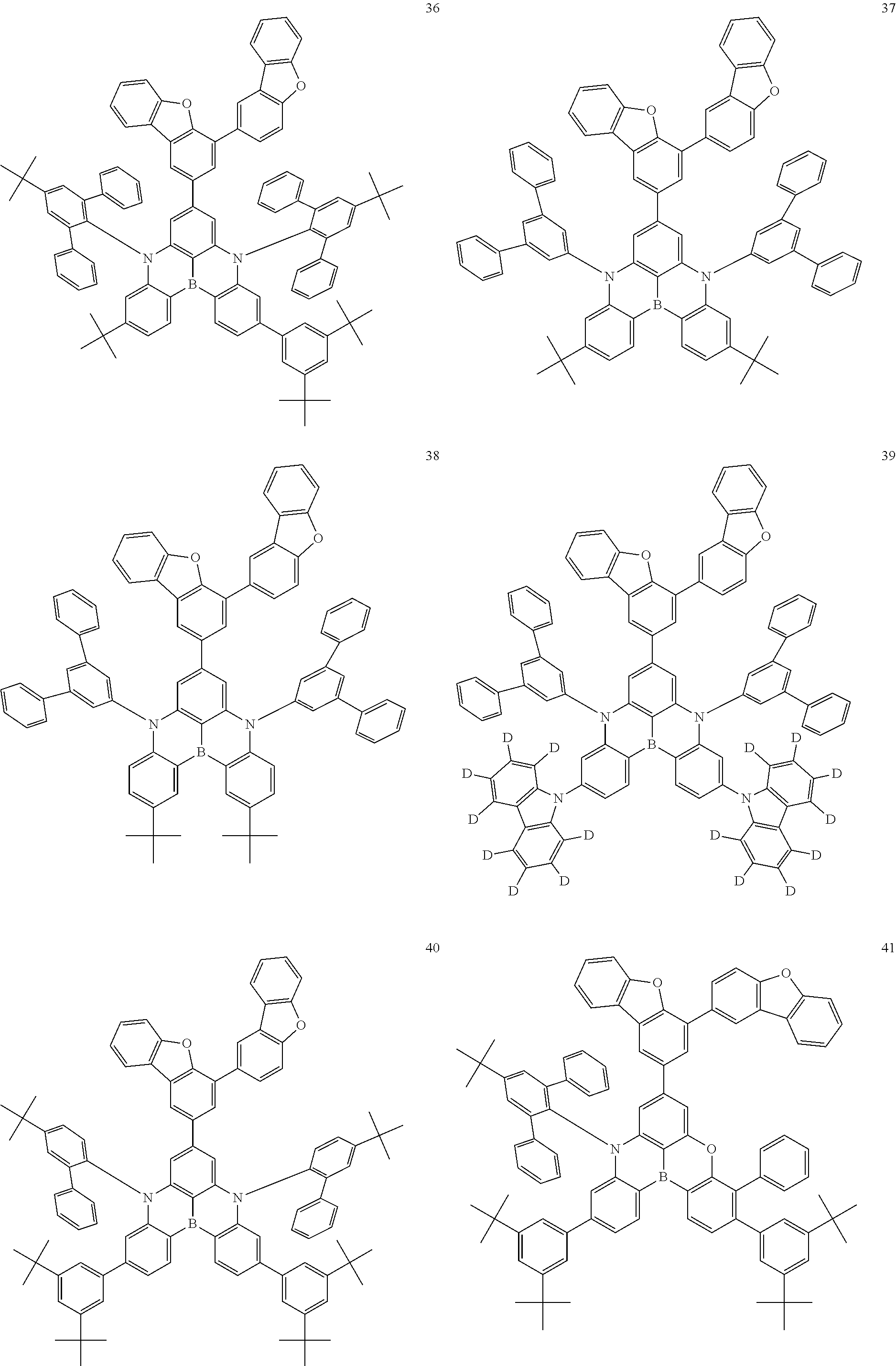

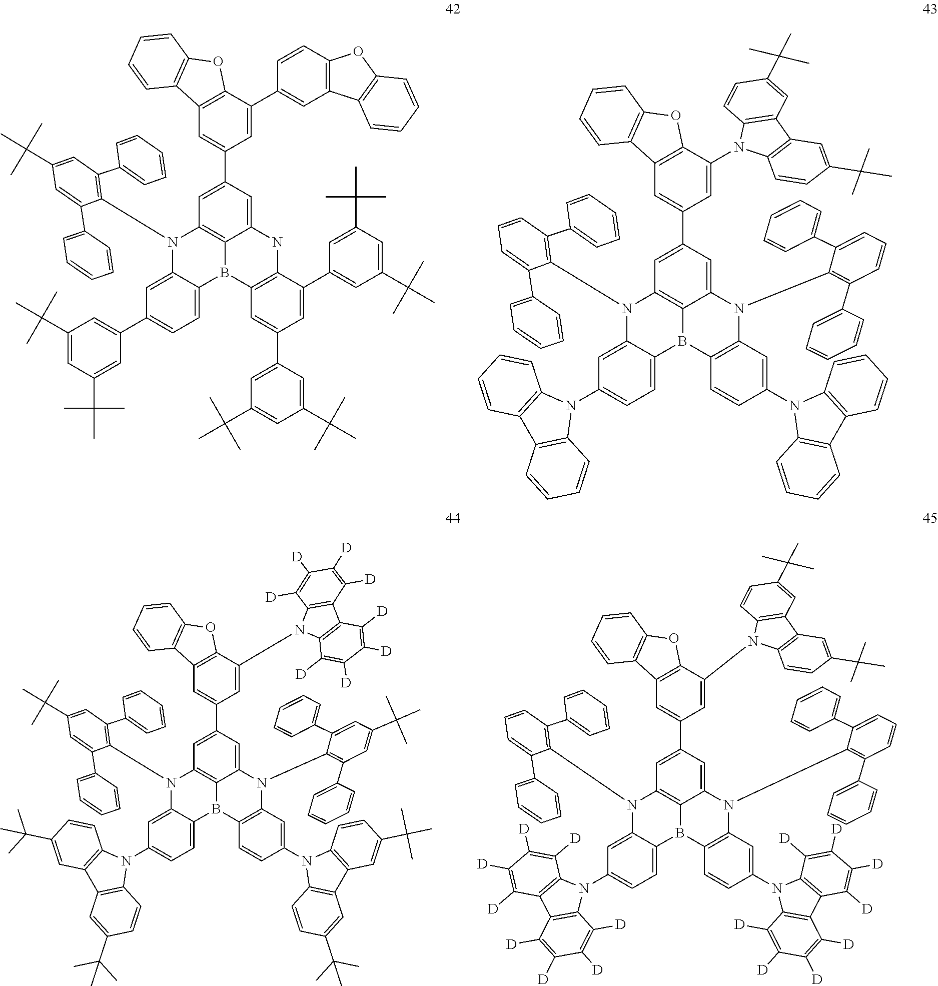

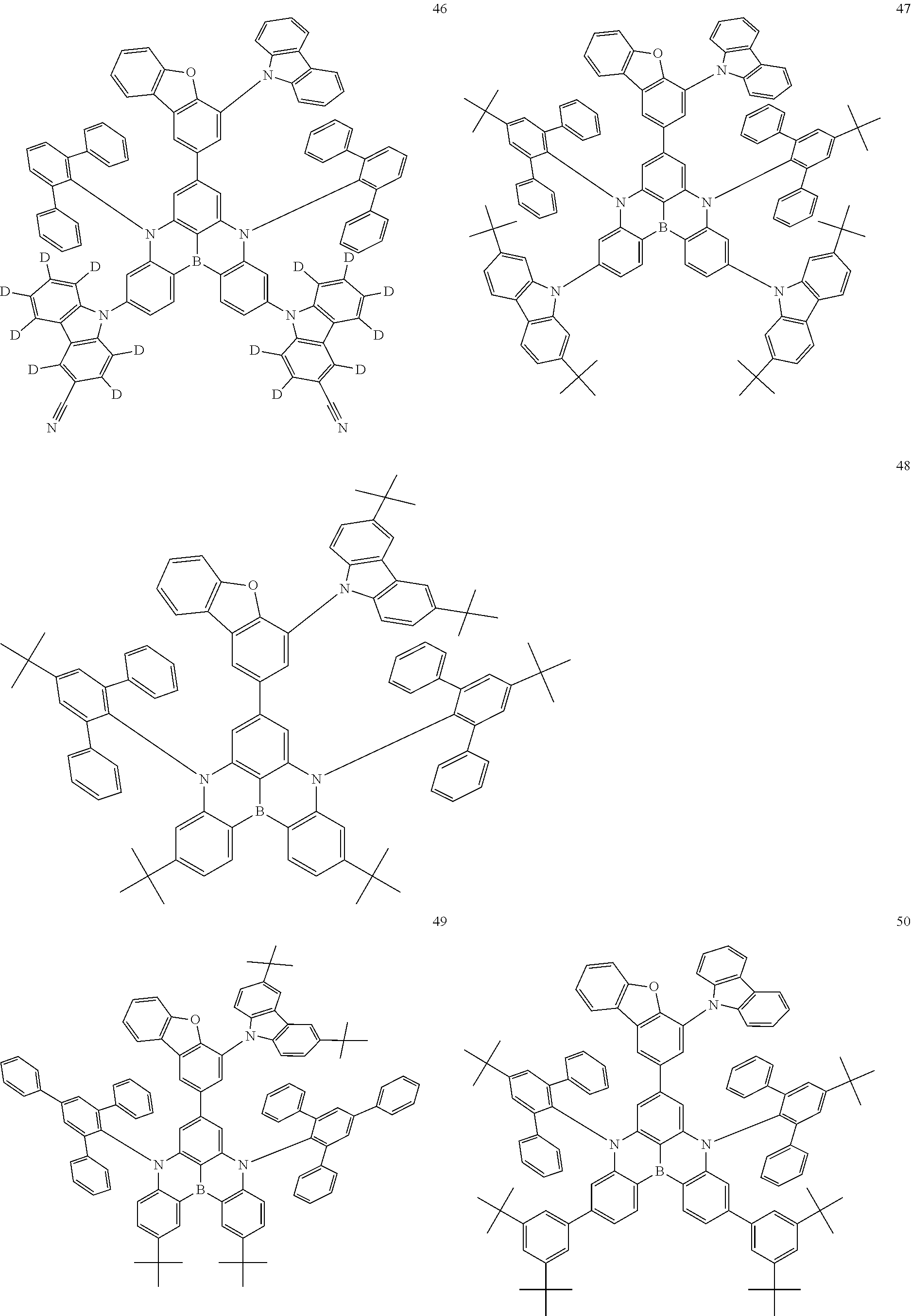

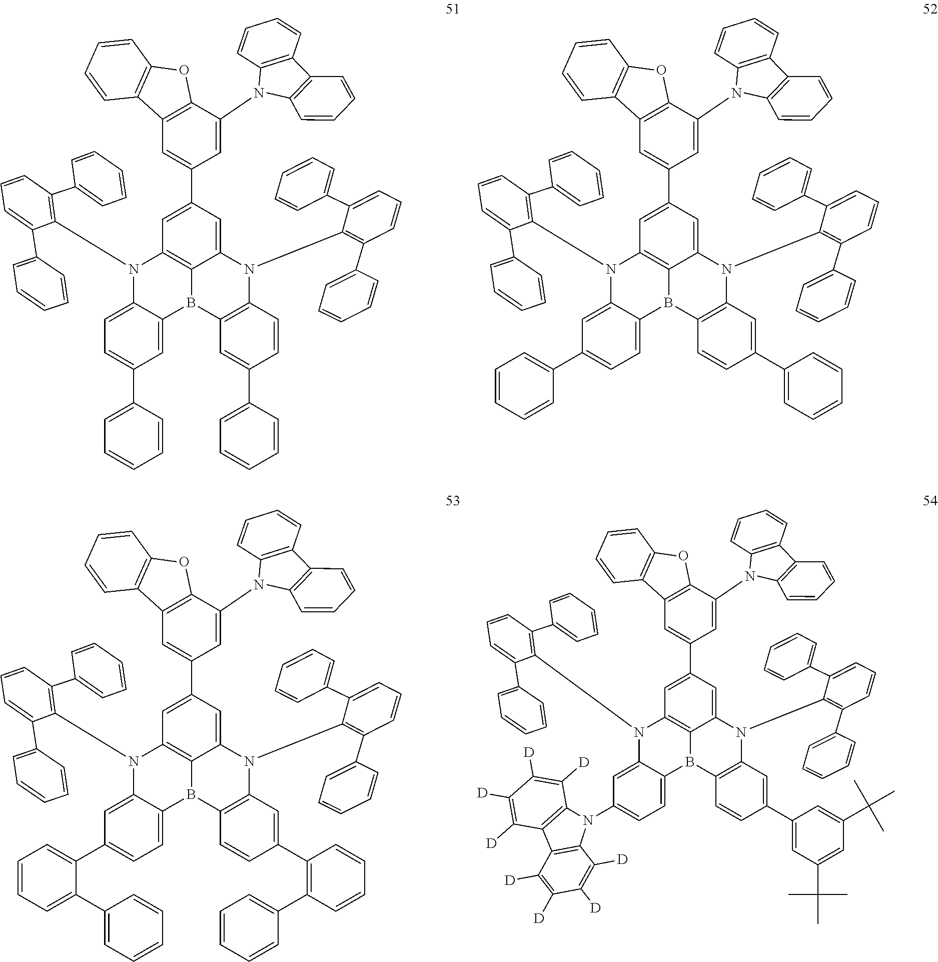

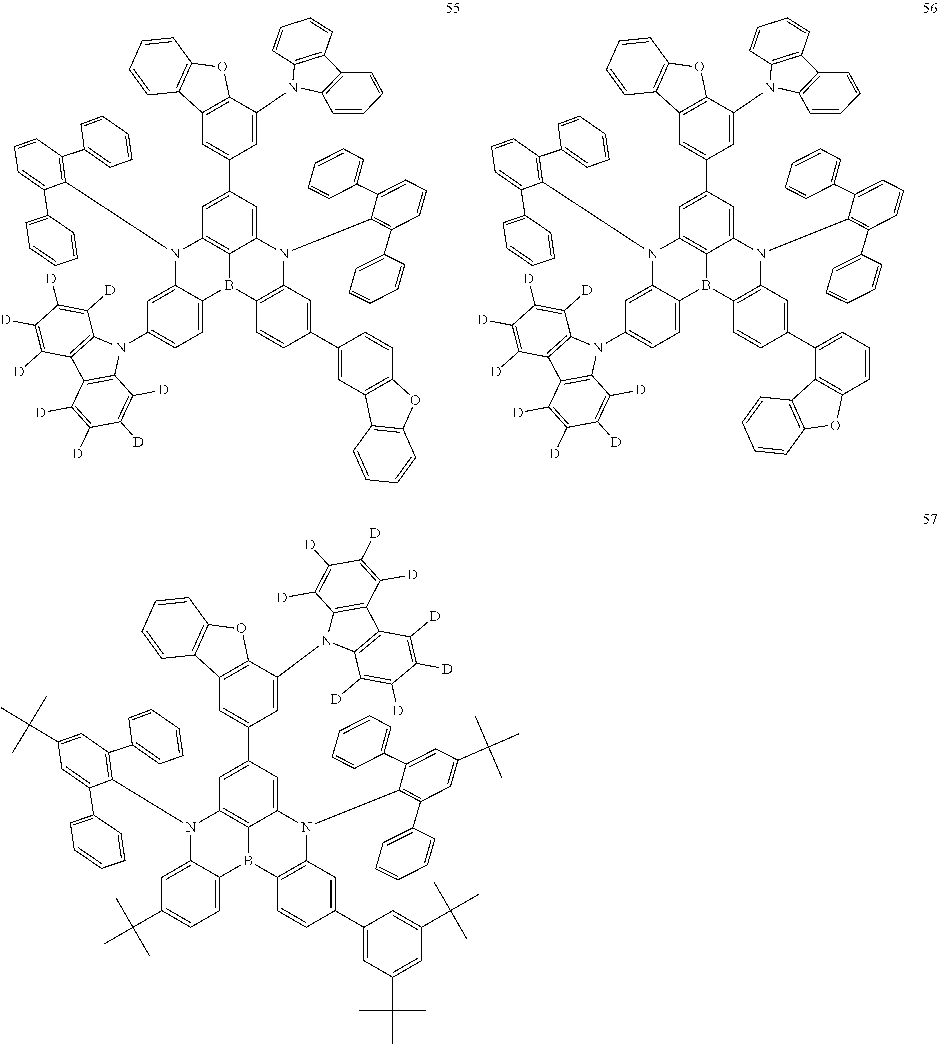

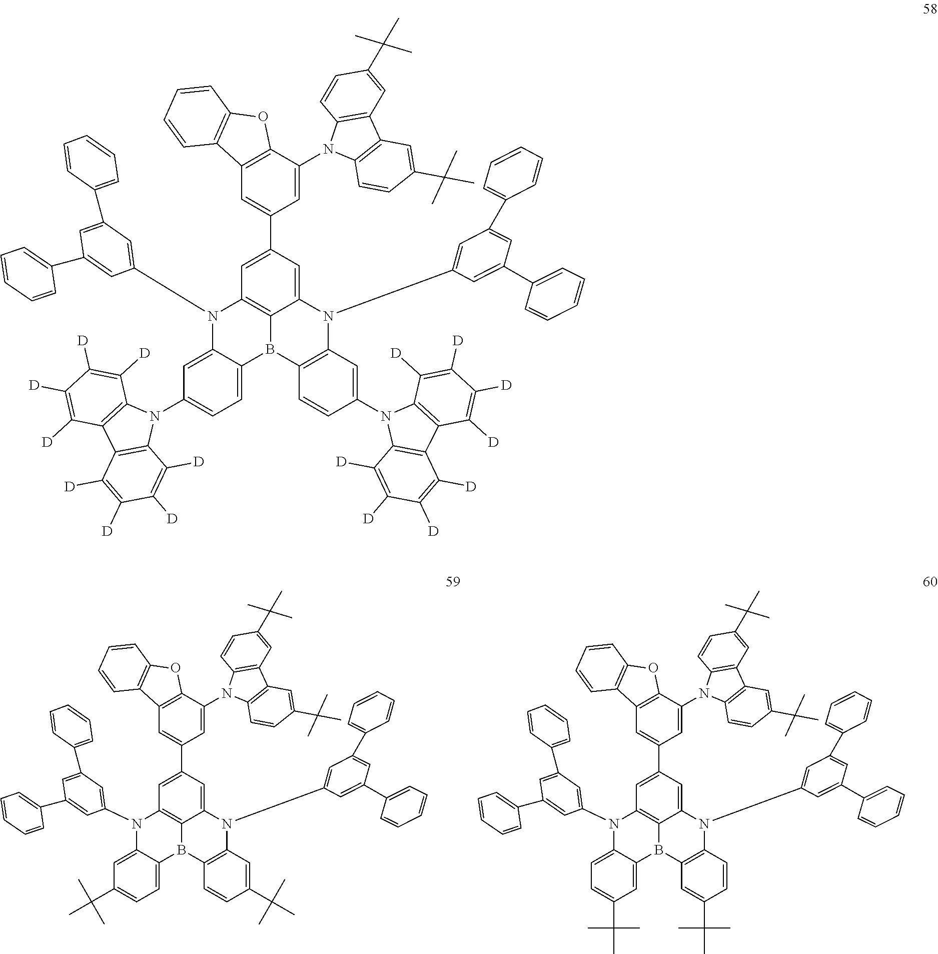

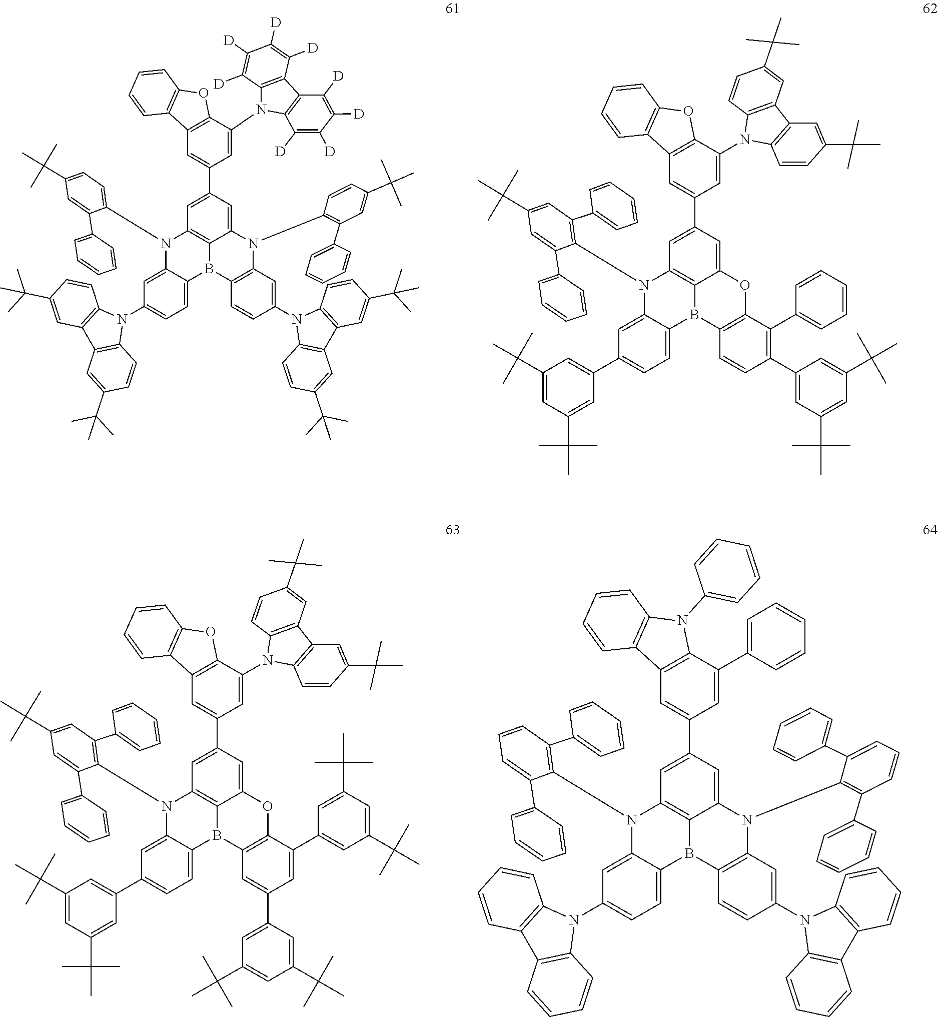

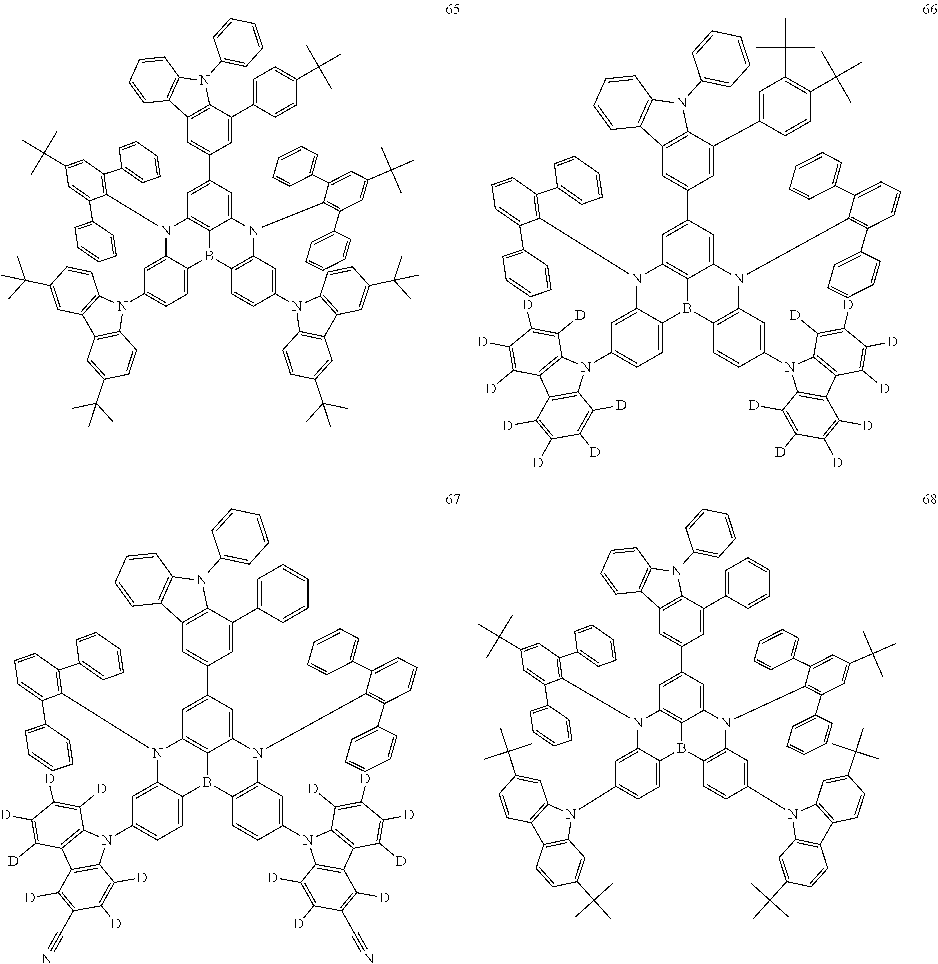

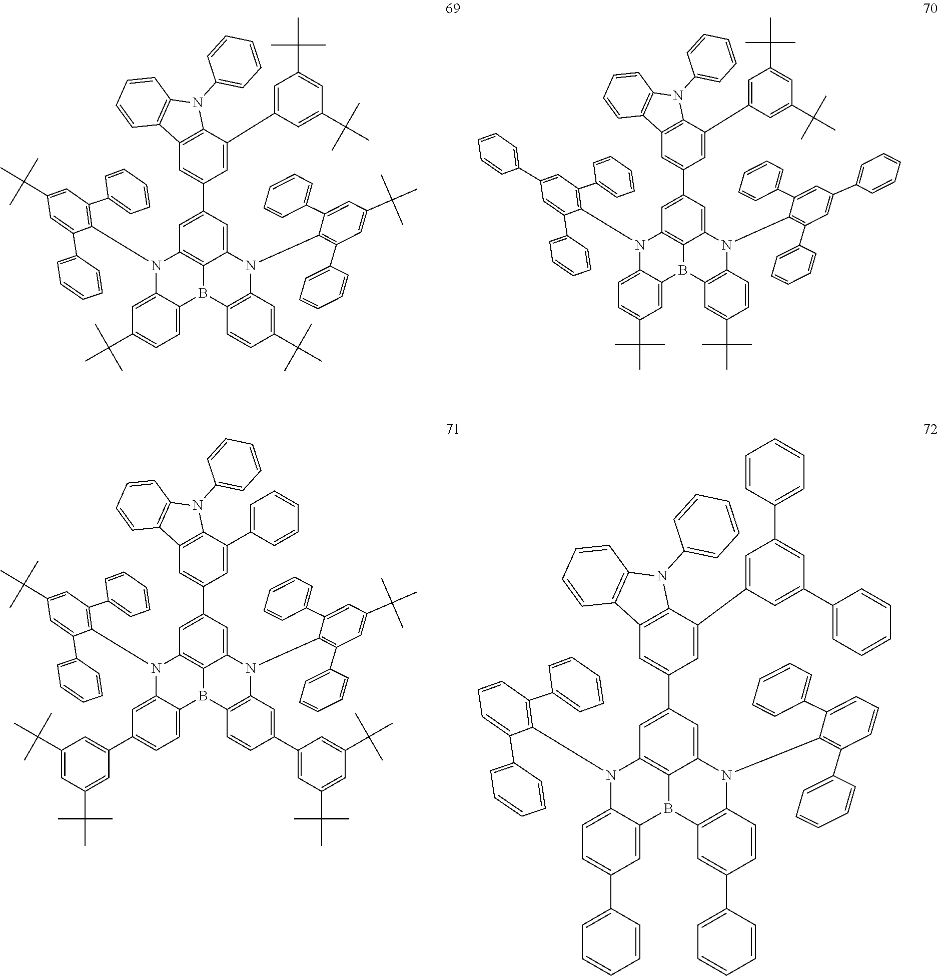

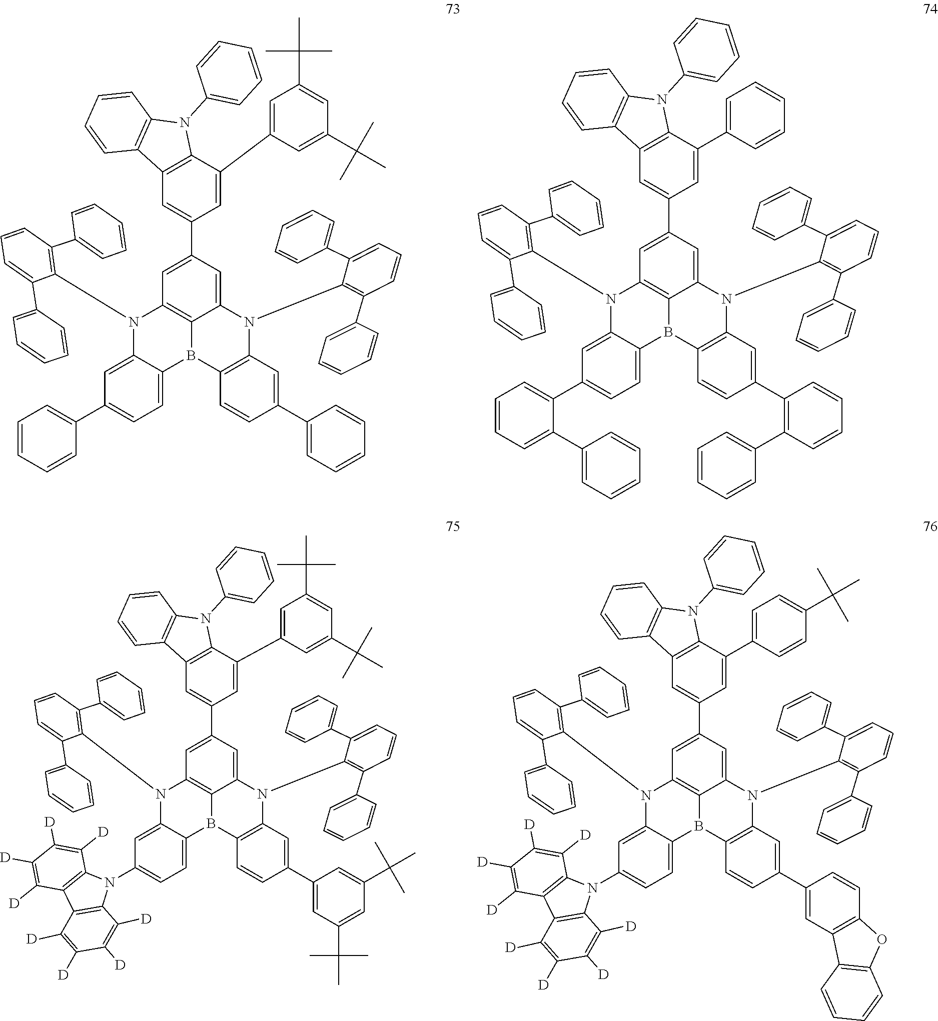

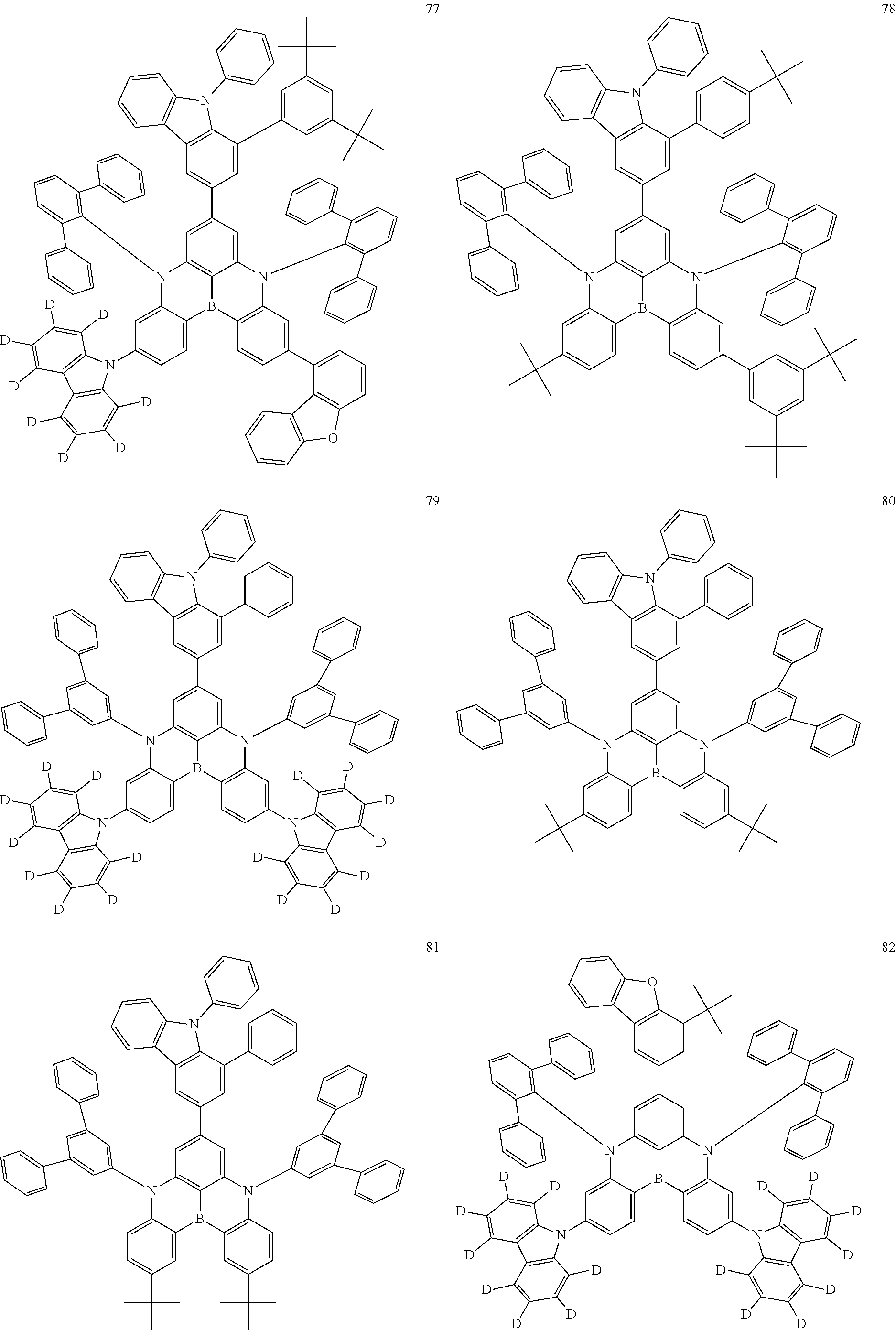

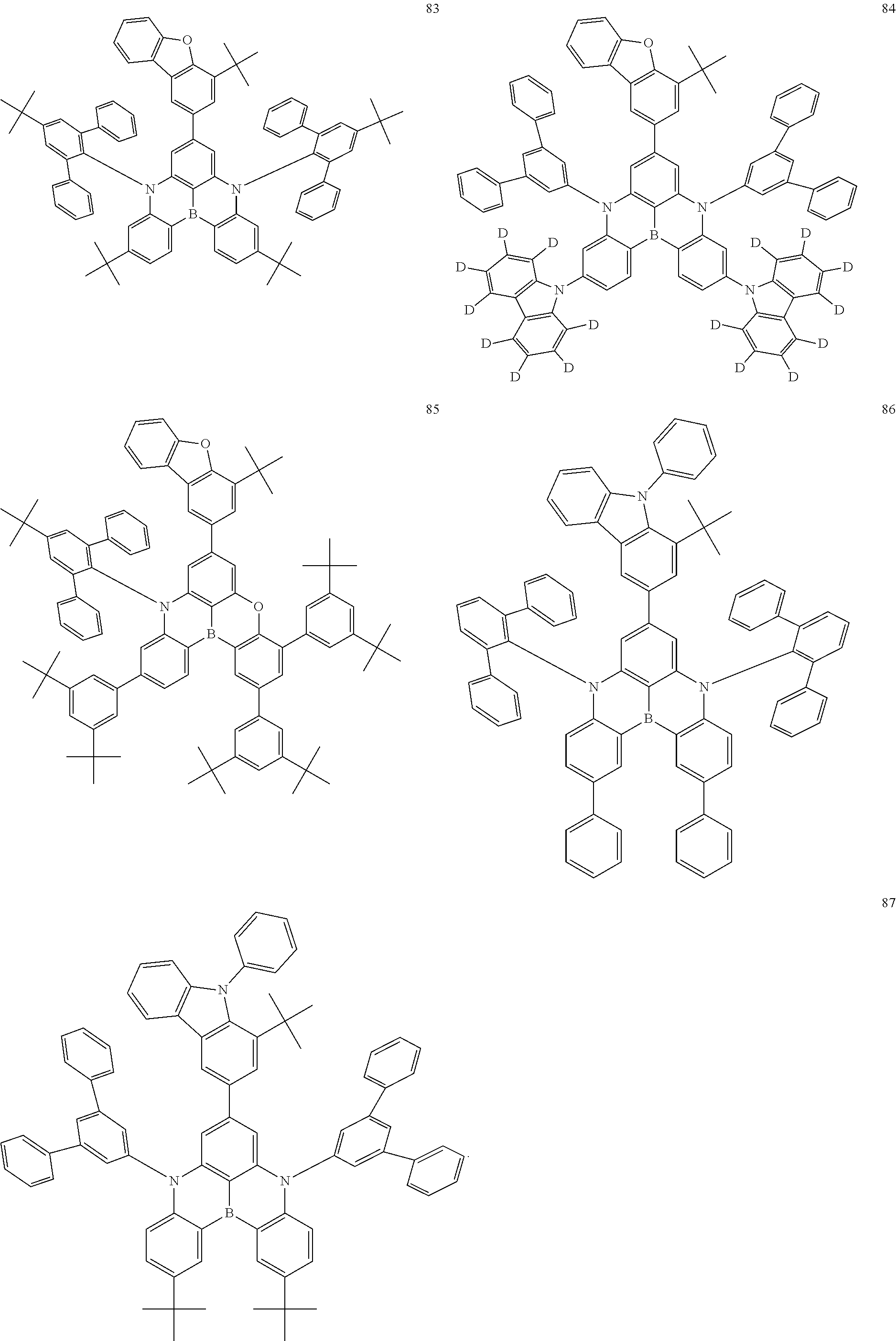

In the structures of the compounds in Compound Group 1, “D” refers to deuterium.

The polycyclic compound of the present disclosure includes a core part of a fused ring including one boron atom and two nitrogen atoms as ring-forming atoms, and an electron donating group of a dibenzoheterole skeleton bonded at the para direction to the boron atom of the core part, and may show high stability. In addition, due to the influence of the electron donating group bonded at the para position to the boron atom, the polycyclic compound of the present disclosure may improve absorbance even further. Accordingly, when the polycyclic compound of the present disclosure is utilized as the material of a light emitting element, due to the increased absorbance, energy transfer from a host material in the light emitting element may become easy and efficient; thus, the emission efficiency and life characteristics of the light emitting element may be improved.

In one or more embodiments, the polycyclic compound represented by Formula 1 may be a light emitting material having an emission center wavelength in a wavelength region of about 430 nm to about 490 nm. For example, in one or more embodiments, the polycyclic compound represented by Formula 1 may be a blue thermally activated delayed fluorescence (TADF) dopant. For example, in one or more embodiments, in the light emitting element ED, the emission layer EML may include at least one selected from among the polycyclic compounds represented in Compound Group 1 as a thermally activated delayed fluorescence dopant. However, embodiments of the present disclosure are not limited thereto. For example, in one or more embodiments, when the polycyclic compound is utilized as a light emitting material, the polycyclic compound may be utilized as a dopant emitting light in one or more suitable wavelength regions, such as a red emitting dopant and a green emitting dopant.

In one or more embodiments, in the light emitting element ED, the emission layer EML may be to emit delayed fluorescence. For example, the emission layer EML may be to emit thermally activated delayed fluorescence (TADF).

In some embodiments, the emission layer EML of the light emitting element ED may be to emit blue light. For example, in one or more embodiments, the emission layer EML of the light emitting element ED may be to emit blue light in a region of about 490 nm or less. However, embodiments of the present disclosure are not limited thereto, for example, the emission layer EML may be to emit green light or red light.

In one or more embodiments, in the light emitting element ED, the emission layer EML may include a host. The host may not emit light in the light emitting element ED but may play the role of transferring energy to a dopant. The emission layer EML may include one or more hosts. For example, the emission layer EML may include two different types (kinds) of hosts. When the emission layer EML includes two types (kinds) of hosts, the two types (kinds) of hosts may include a hole transport host and an electron transport host. However, embodiments of the present disclosure are not limited thereto, and the emission layer EML may include one type or kind of a host, or a mixture of two or more different types (kinds) of hosts.

In one or more embodiments, the emission layer EML may include two different hosts. The host may include a second compound and a third compound which is different from the second compound. The host may include a second compound having a hole transport moiety and the third compound having an electron transport moiety. In some embodiments, in the light emitting element ED, the second compound and the third compound of the host may form exciplexes. In these embodiments, the triplet energy of the exciplex formed by the hole transport host and the electron transport host may correspond to a difference between a lowest unoccupied molecular orbital (LUMO) energy level of the electron transport host and a highest occupied molecular orbital (HOMO) energy level of the hole transport host.

For example, the absolute value of the triplet energy level (T1) of the exciplex formed by the hole transport host and the electron transport host may be about 2.4 eV to about 3.0 eV. In some embodiments, the triplet energy level of exciplex may be a smaller value than the energy gap of each host material. The exciplex may have the triplet energy of about 3.0 eV or less, that is the energy gap between the hole transport host and the electron transport host.

In one or more embodiments, the emission layer EML may include a first compound represented by Formula 1, and at least one selected from among a second compound represented by Formula HT-1, a third compound represented by Formula ET-1, and a fourth compound represented by Formula M-b.

For example, in one or more embodiments, the second compound may be utilized as a hole transport host material of an emission layer EML.

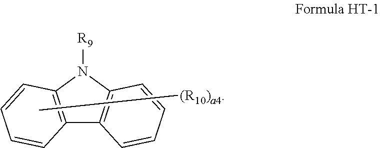

In Formula HT-1, a4 may be an integer of 0 to 8. When a4 is an integer of 2 or more, each of a plurality of R₁₀s may be the same, or at least one may be different. R₉ and R₁₀ may each independently be selected from hydrogen, deuterium, a substituted or unsubstituted aryl group of 6 to 60 ring-forming carbon atoms, and a substituted or unsubstituted heteroaryl group of 2 to 60 ring-forming carbon atoms. For example, in some embodiments, R₉ may be selected from a substituted phenyl group, an unsubstituted dibenzofuran group, and a substituted fluorenyl group. R₁₀ may be a substituted or unsubstituted carbazole group.

The second compound may be represented by any one selected from among the compounds in Compound Group 2. In one or more embodiments, the light emitting element ED may include any one selected from among the compounds in Compound Group 2. In Compound Group 2, “D” is deuterium, and “Ph” is a phenyl group.

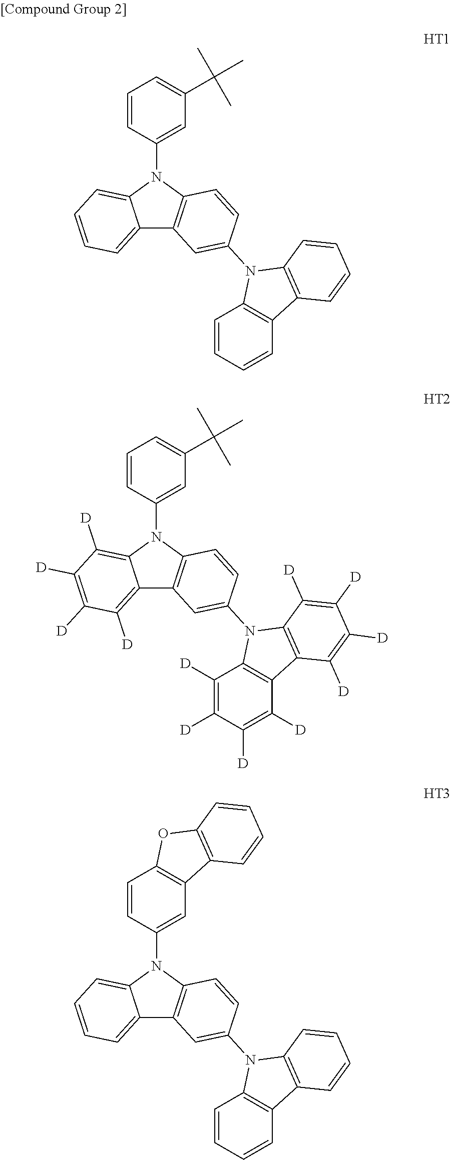

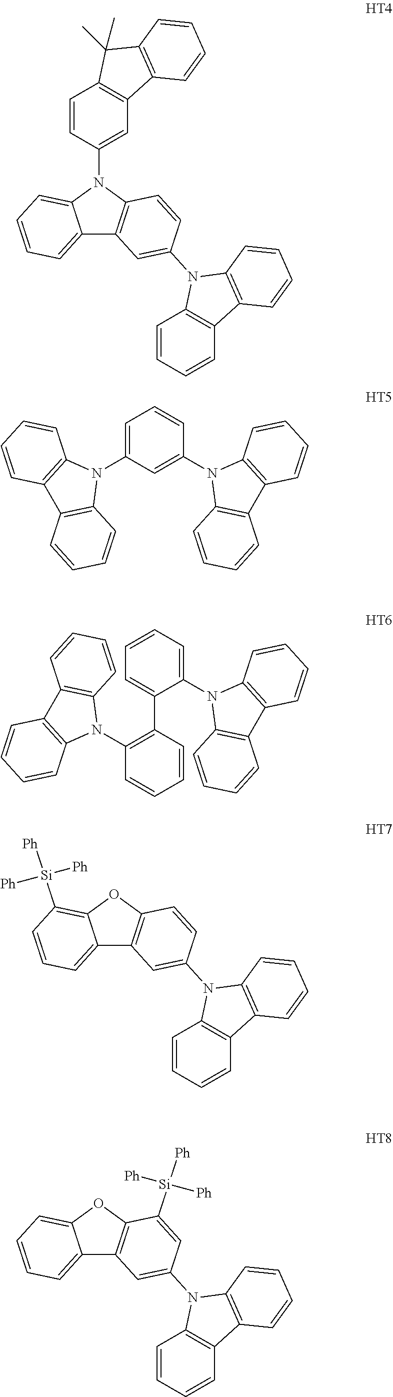

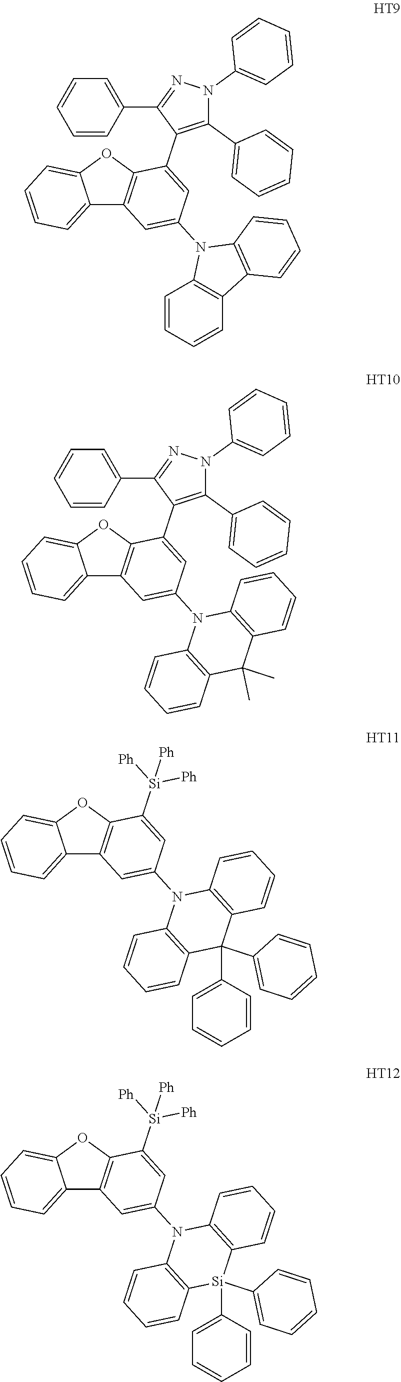

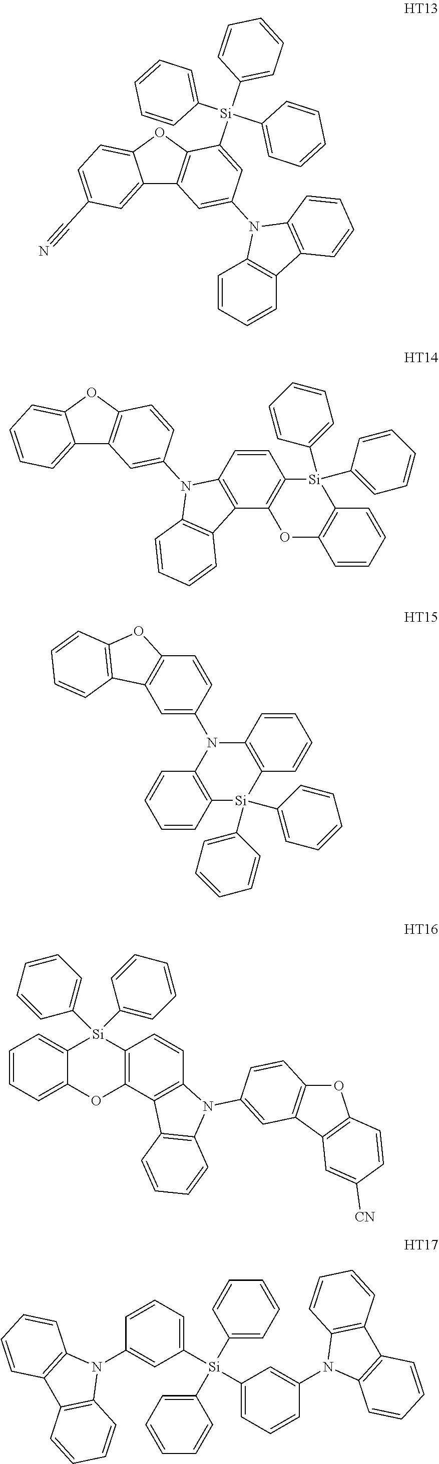

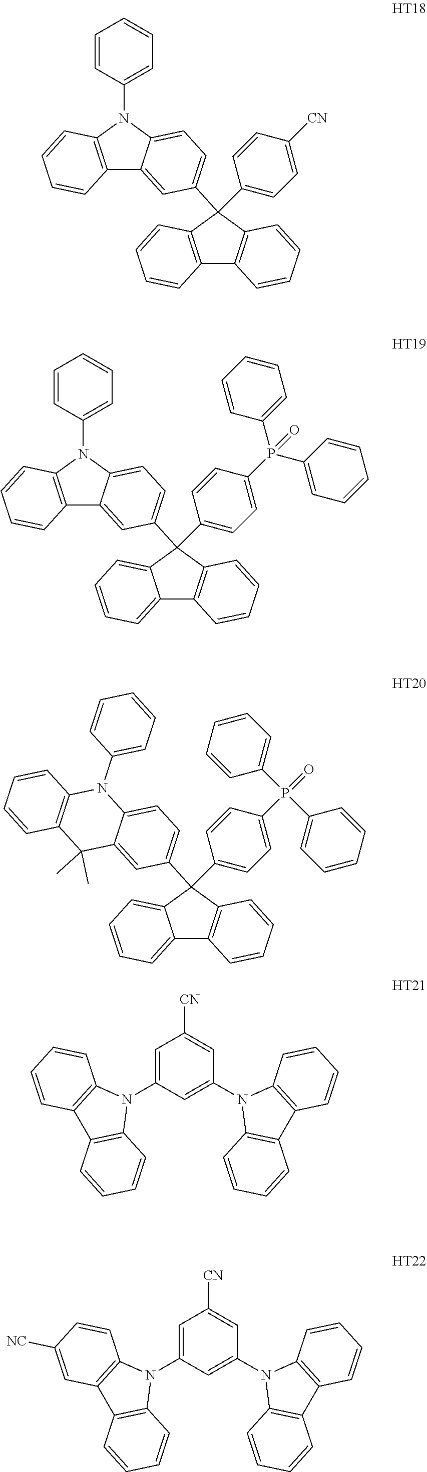 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

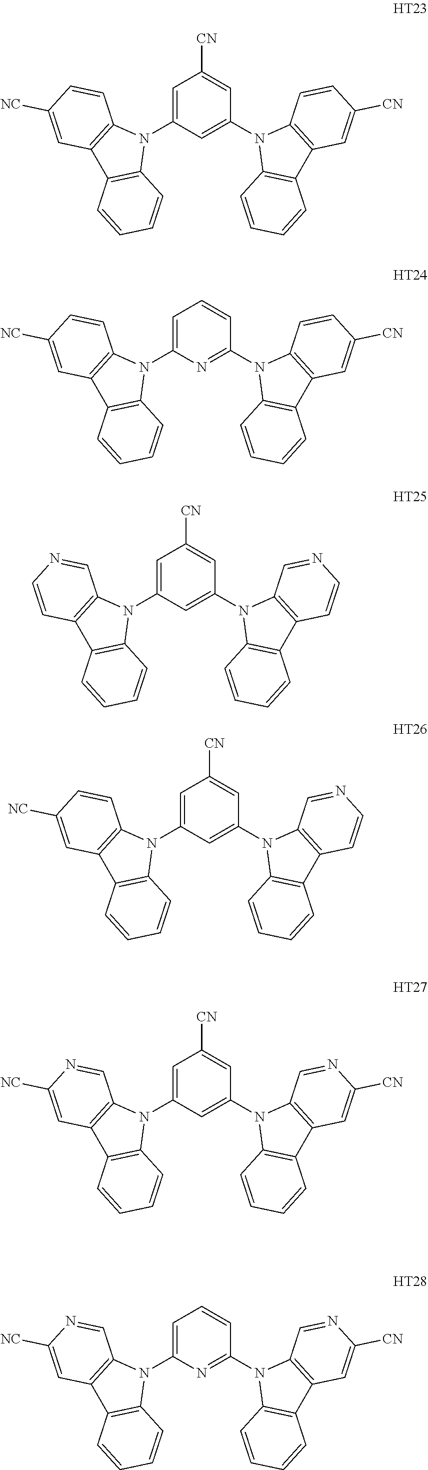 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

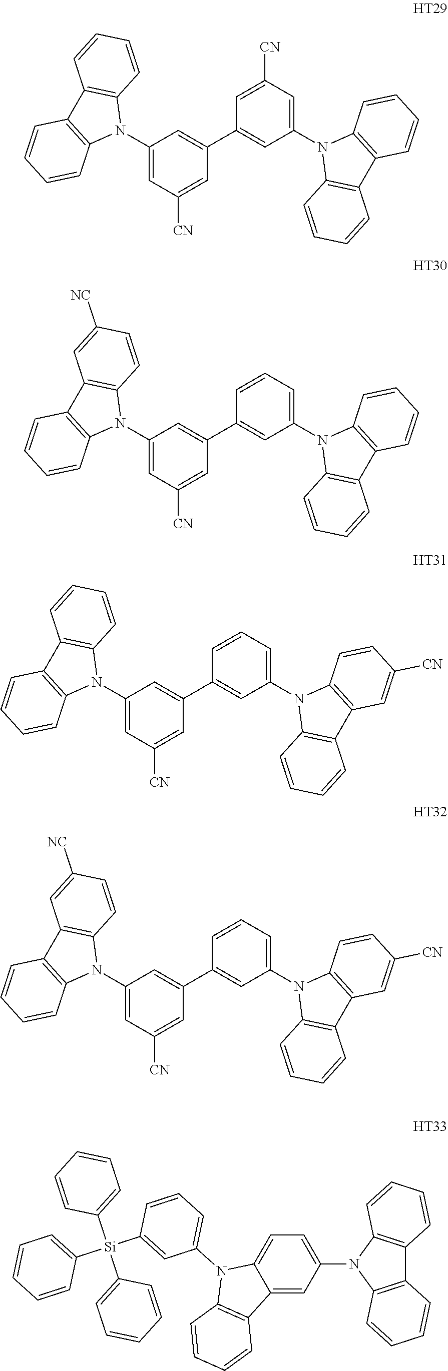 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

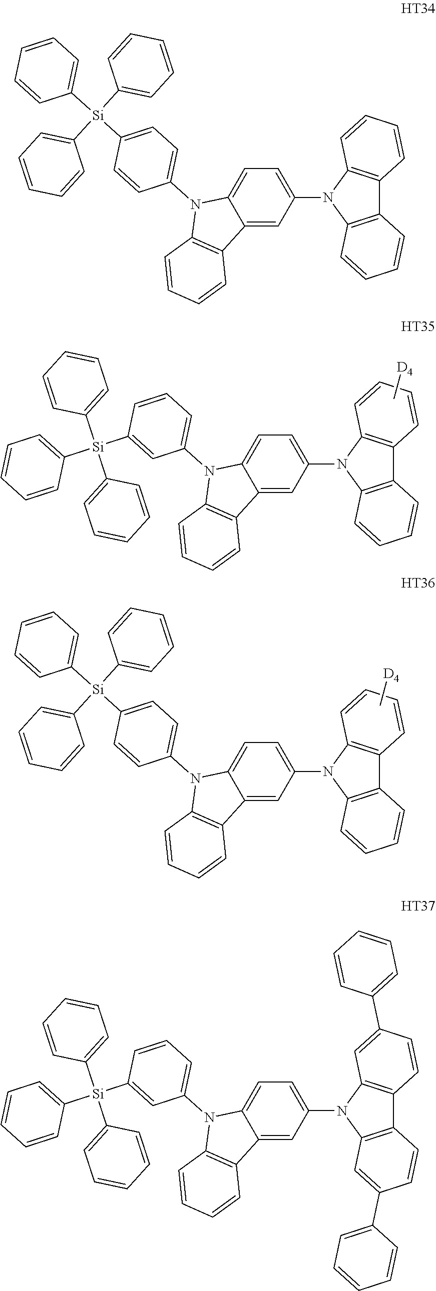

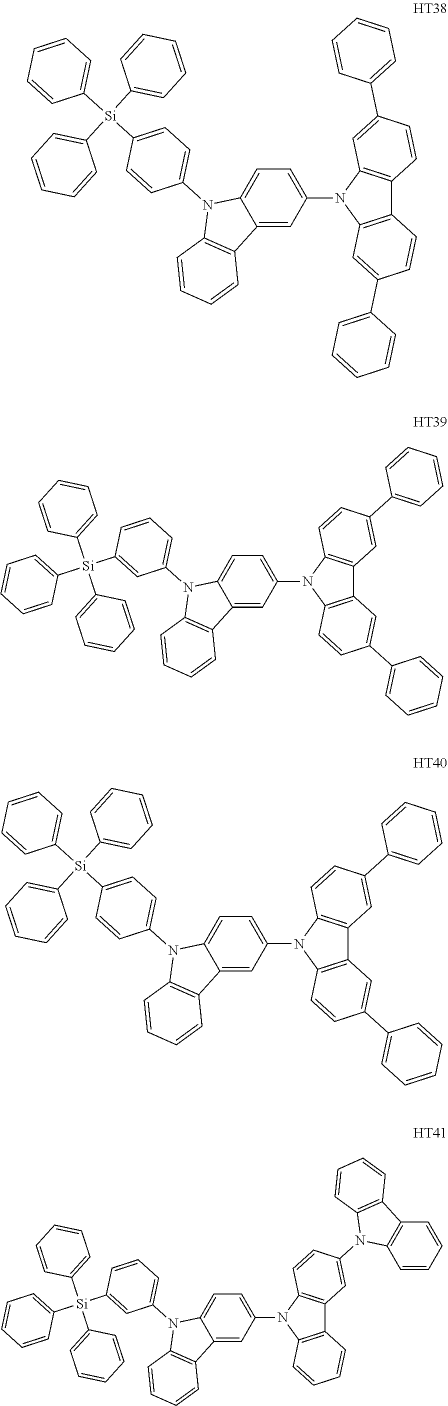 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

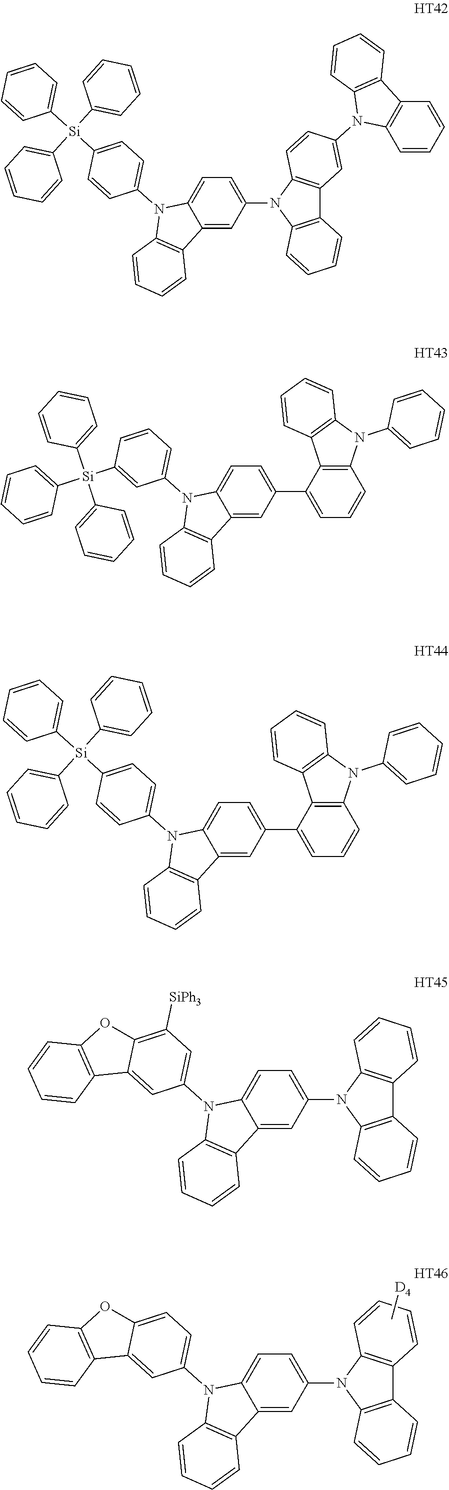

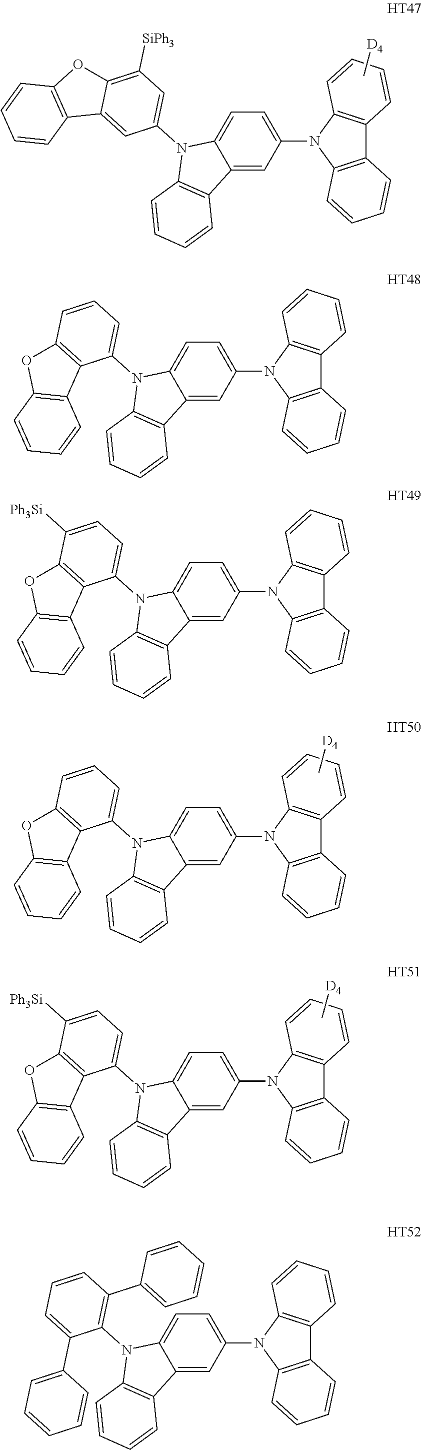

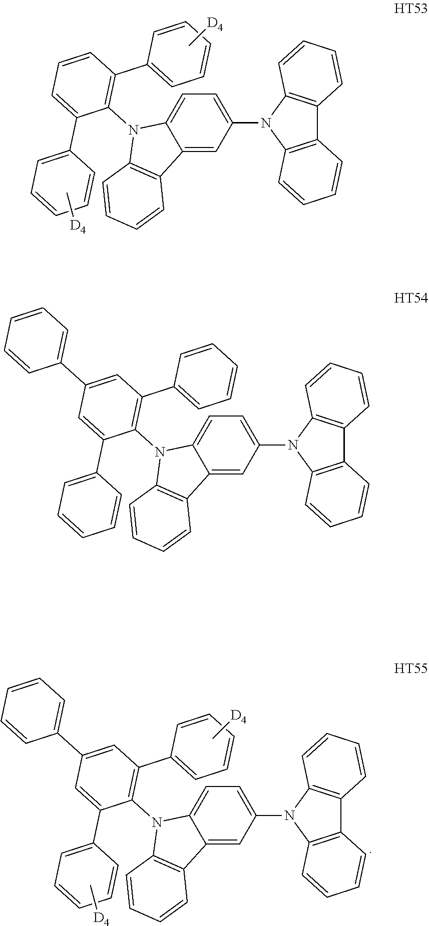

In one or more embodiments, the emission layer EML may include a third compound represented by Formula ET-1. For example, the third compound may be utilized as an electron transport host material in the emission layer EML.

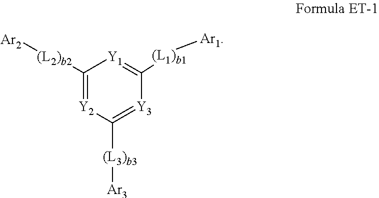

In Formula ET-1, at least one selected from among Y₁ to Y₃ may be N, and the remainder may be CRₐ, and Rₐ may be selected from hydrogen, deuterium, a substituted or unsubstituted alkyl group of 1 to 20 carbon atoms, a substituted or unsubstituted aryl group of 6 to 60 ring-forming carbon atoms, and a substituted or unsubstituted heteroaryl group of 2 to 60 ring-forming carbon atoms.

b1 to b3 may each independently be an integer of 0 to 10. L₁ to L₃ may each independently be selected from a direct linkage, a substituted or unsubstituted arylene group of 6 to 30 ring-forming carbon atoms, and a substituted or unsubstituted heteroarylene group of 2 to 30 ring-forming carbon atoms.

Ar₁ to Ar₃ may each independently be selected from hydrogen, deuterium, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms. For example, in one or more embodiments, Ar₁ to Ar₃ may be selected from substituted or unsubstituted phenyl groups and substituted or unsubstituted carbazole groups.

The third compound may be represented by any one selected from among the compounds in Compound Group 3. In one or more embodiments, the light emitting element ED may include any one selected from among the compounds in Compound Group 3. In Compound Group 3, “D” is deuterium.

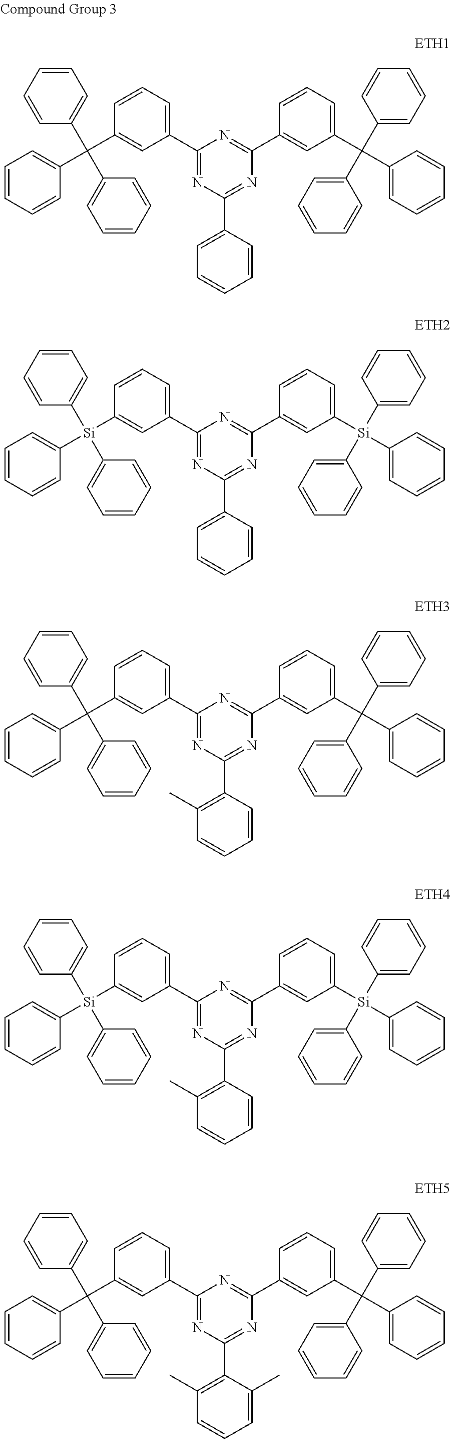

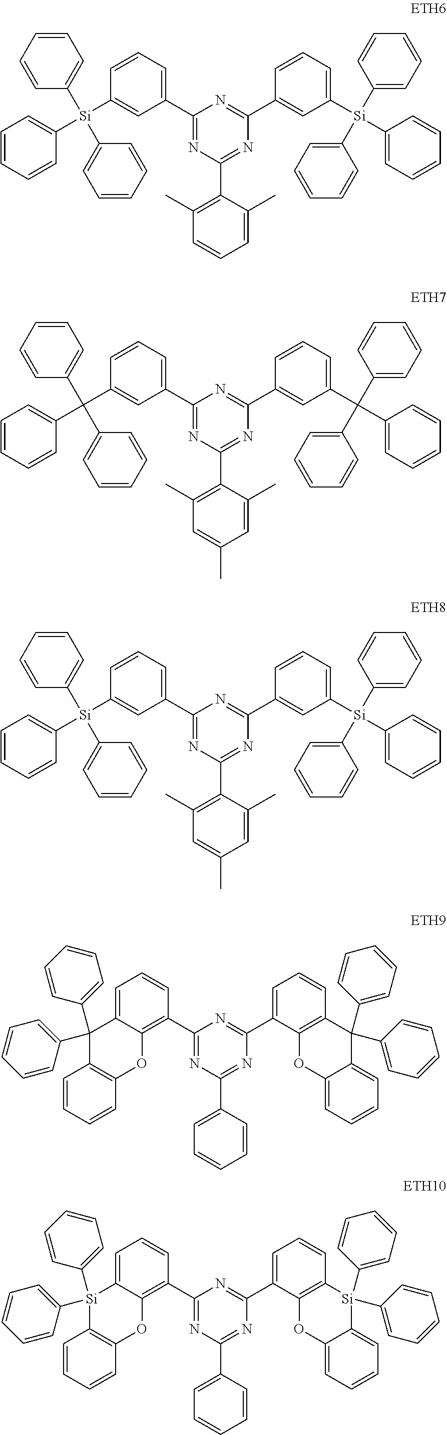

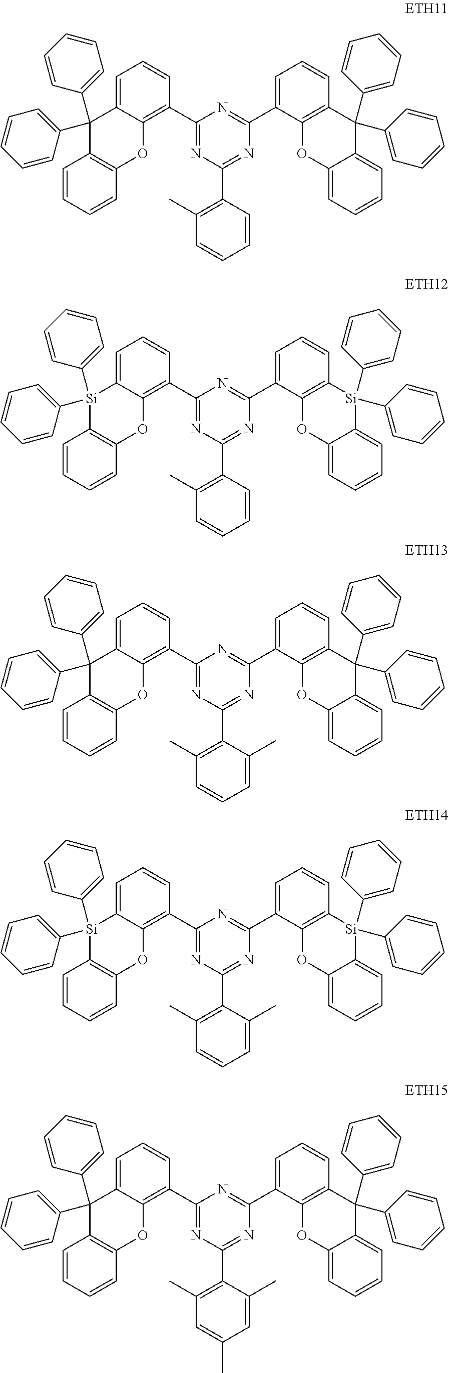

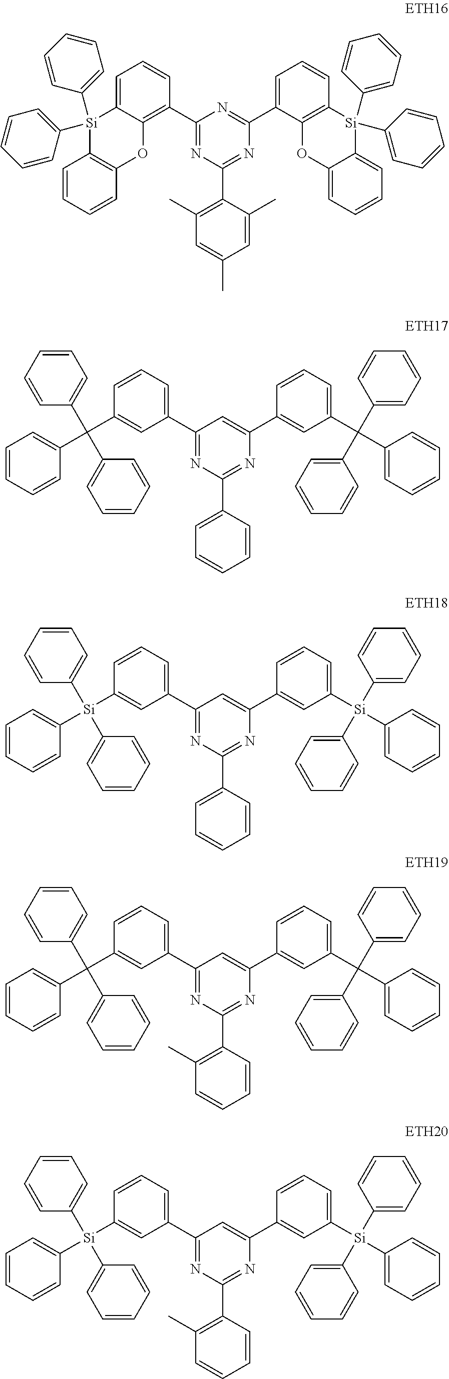

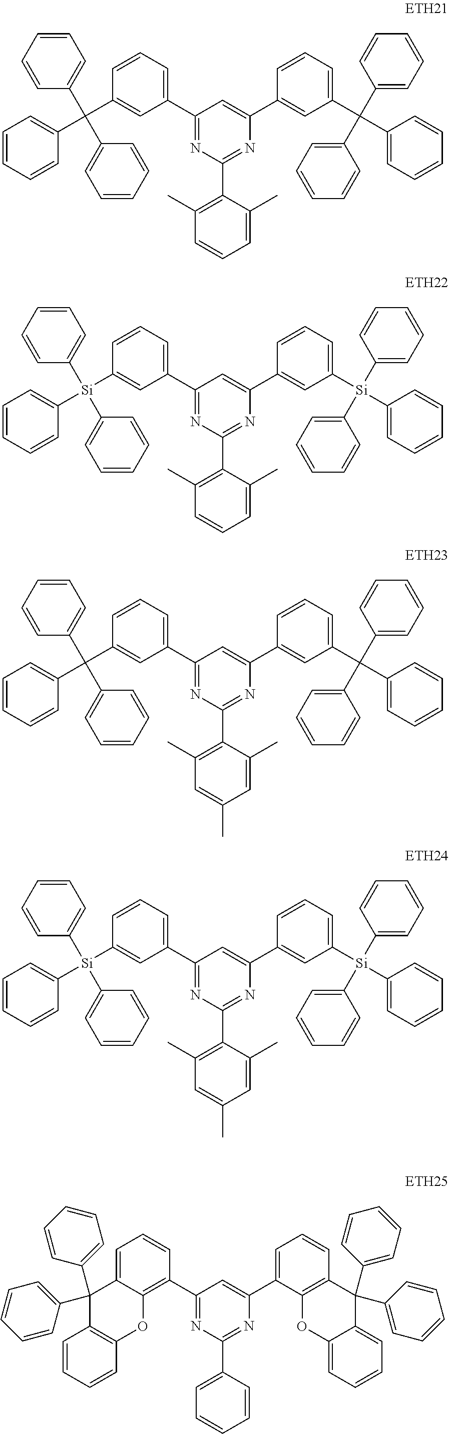

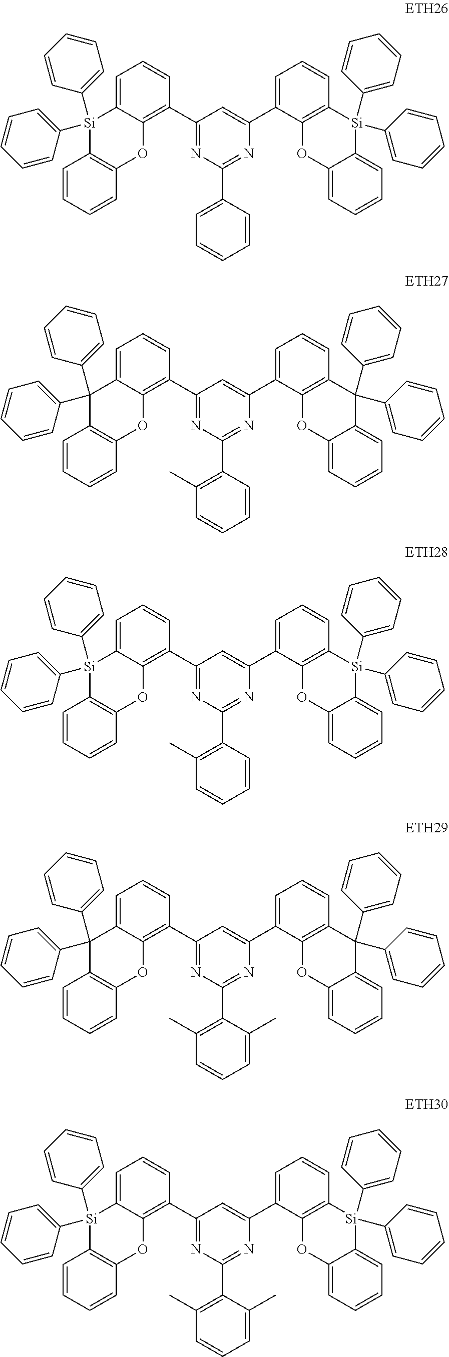

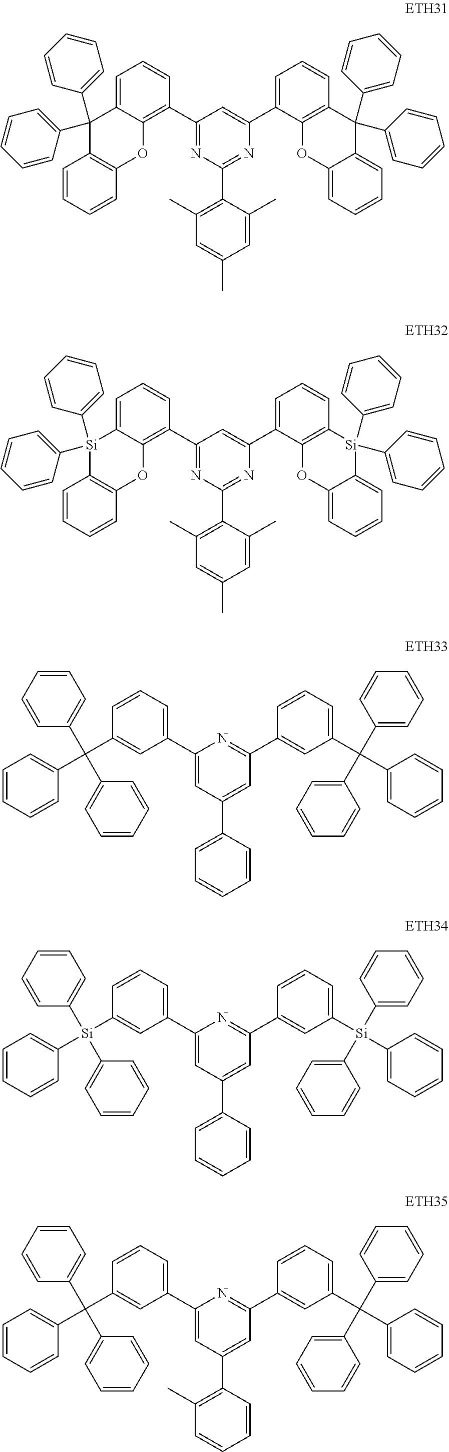

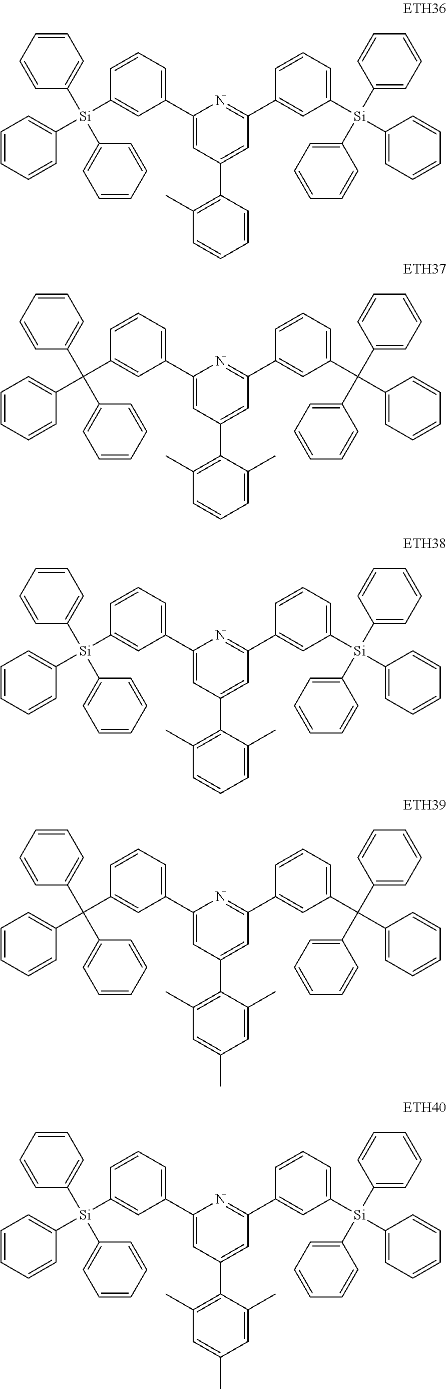

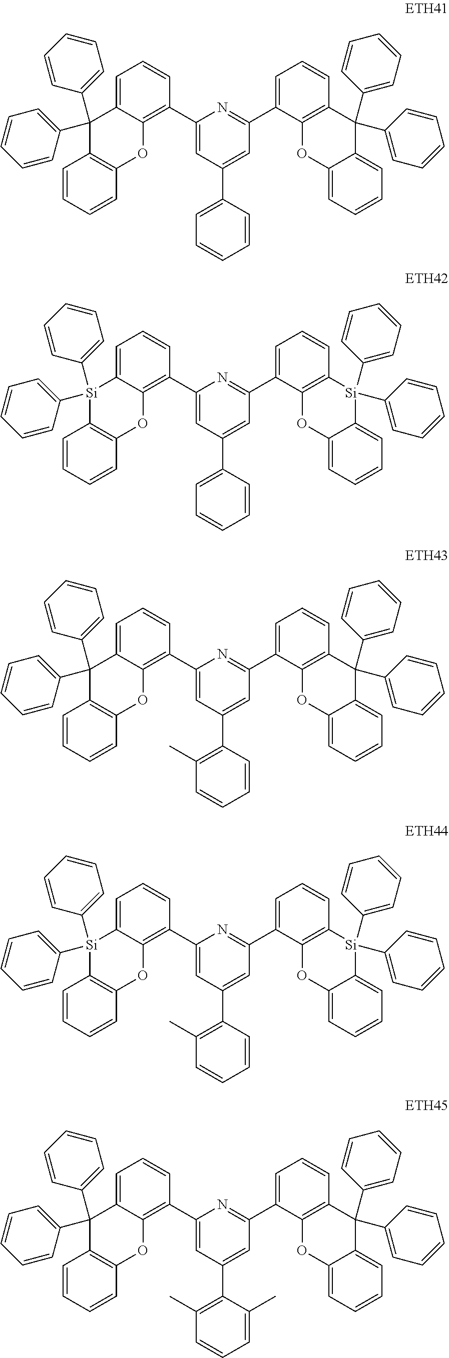

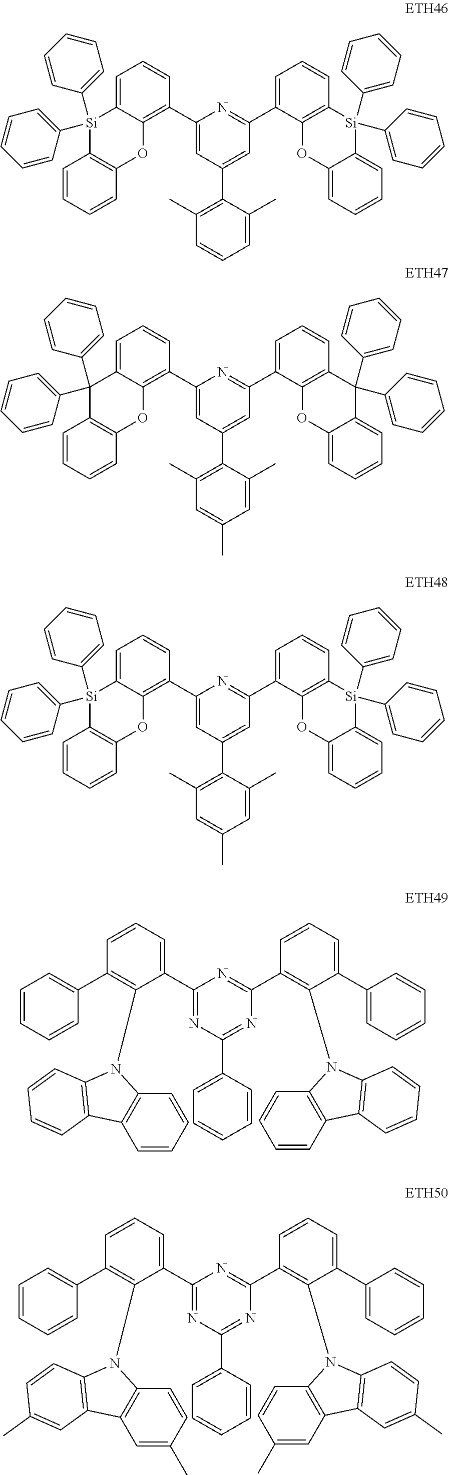

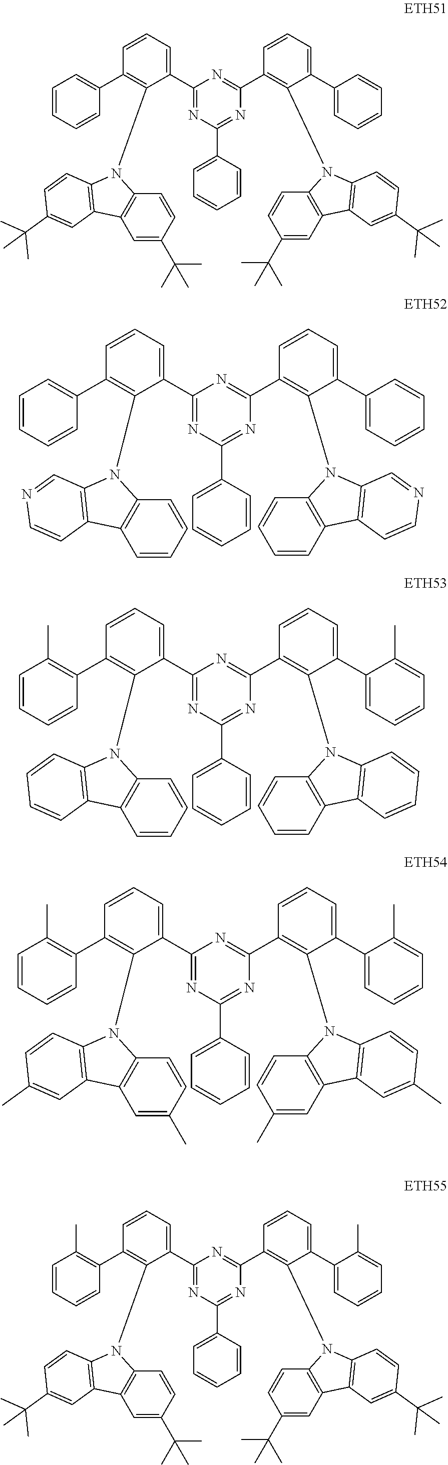

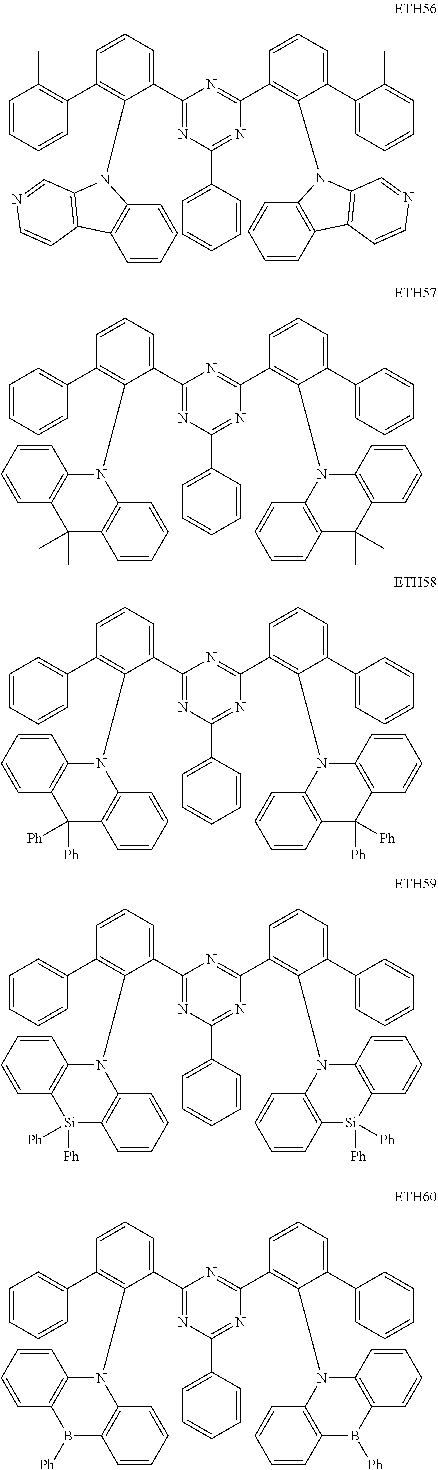

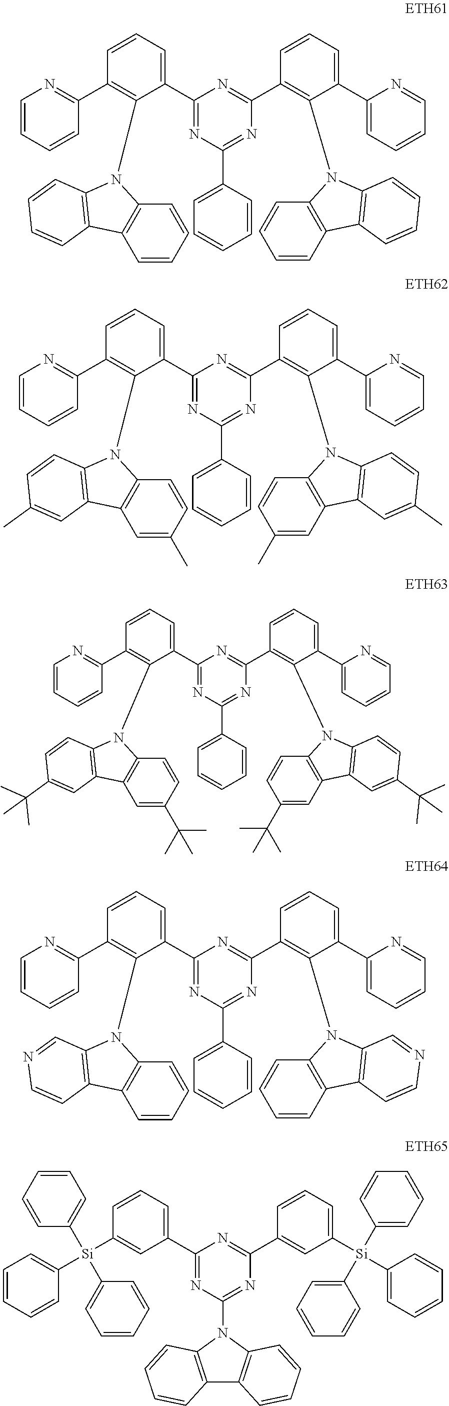

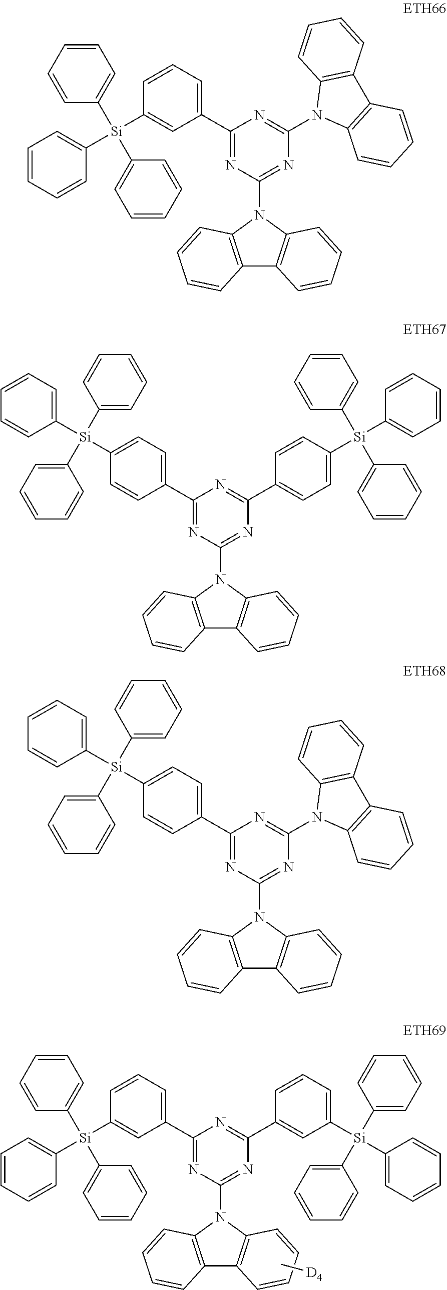

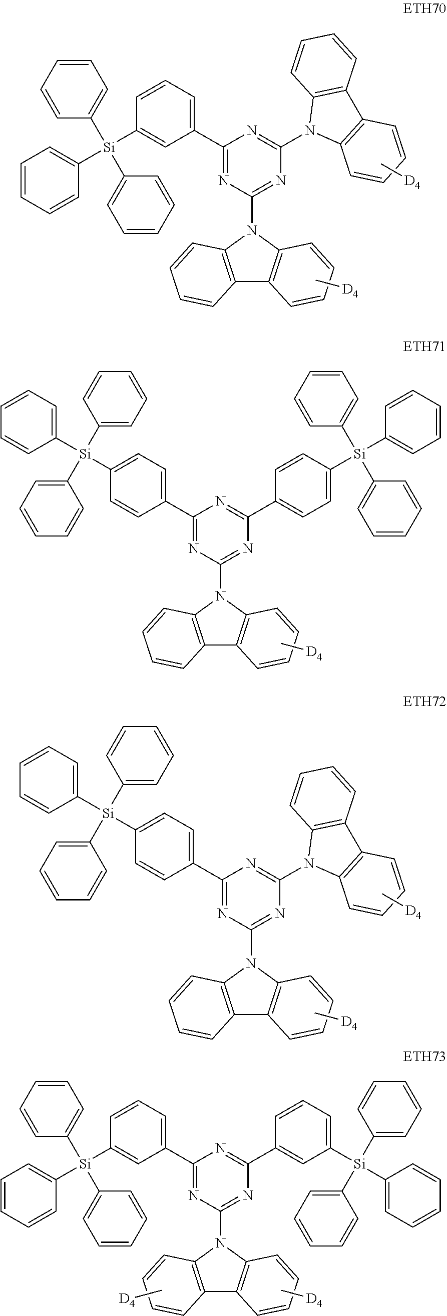

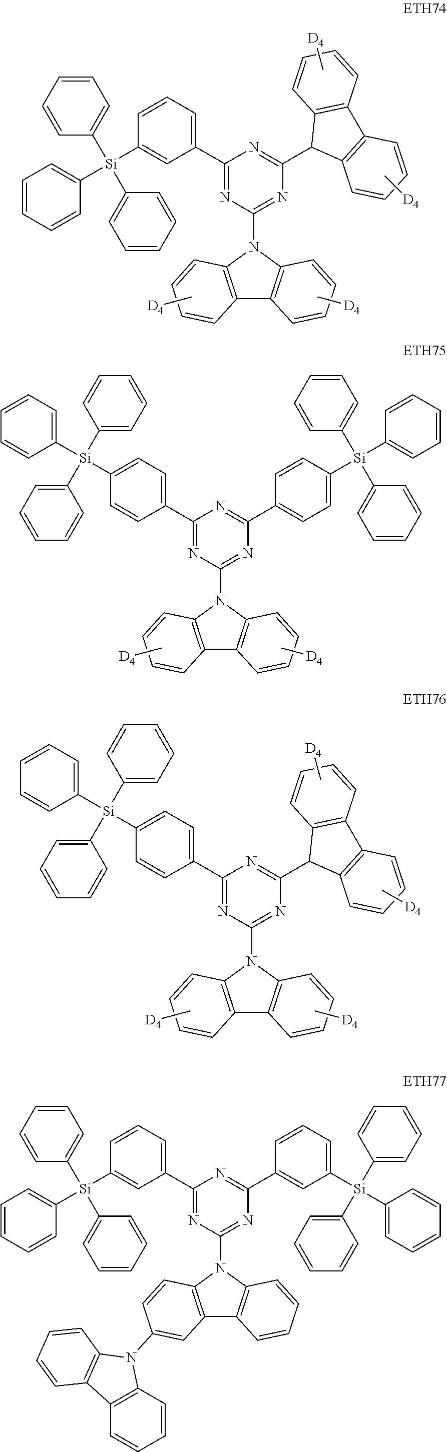

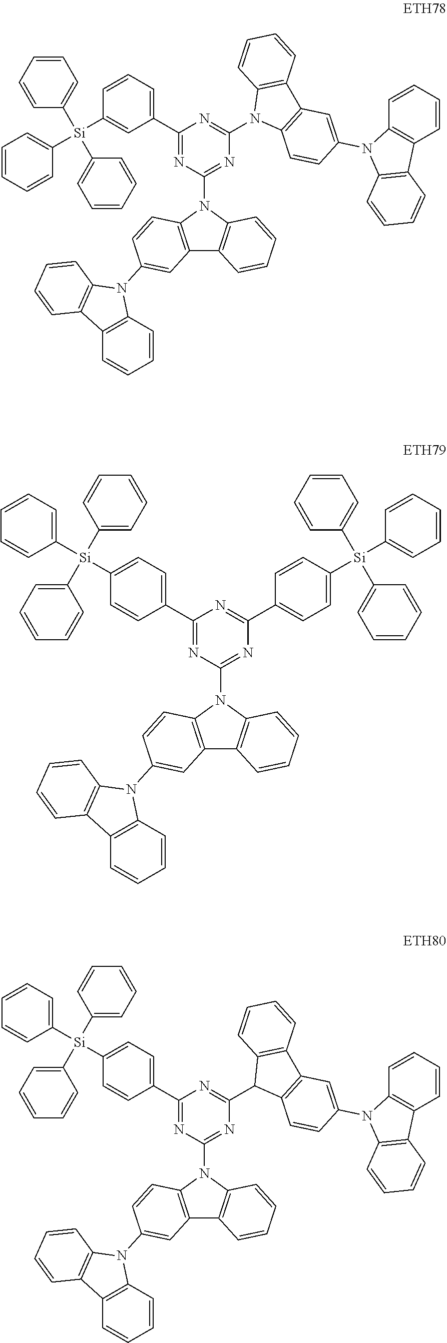 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(C4c5ccccc5-c5cc(-n6c7ccccc7c7ccccc76)ccc54)nc(-n4c5ccccc5c5cc(-n6c7ccccc7c7ccccc76)ccc54)n3)cc2)cc1]

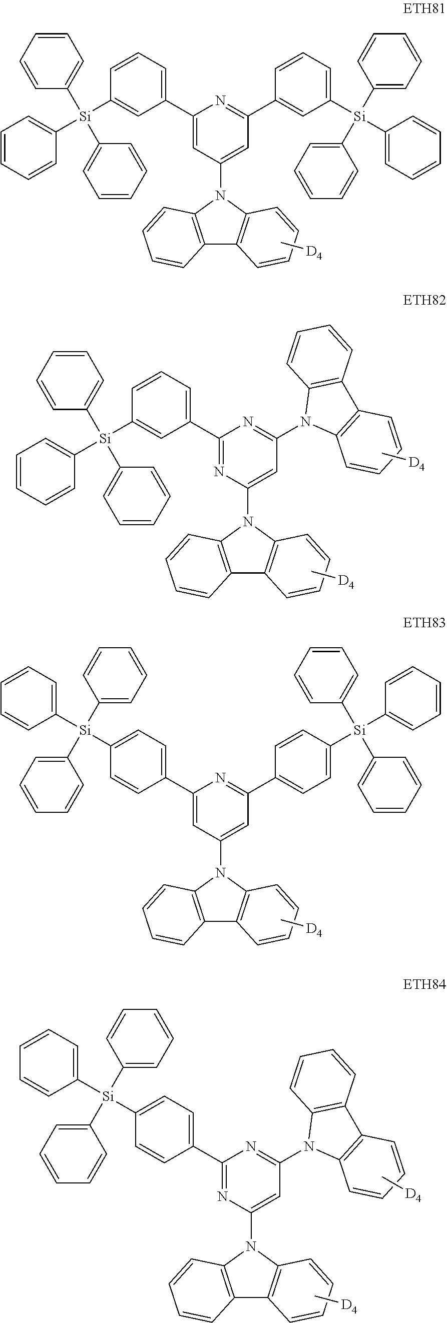

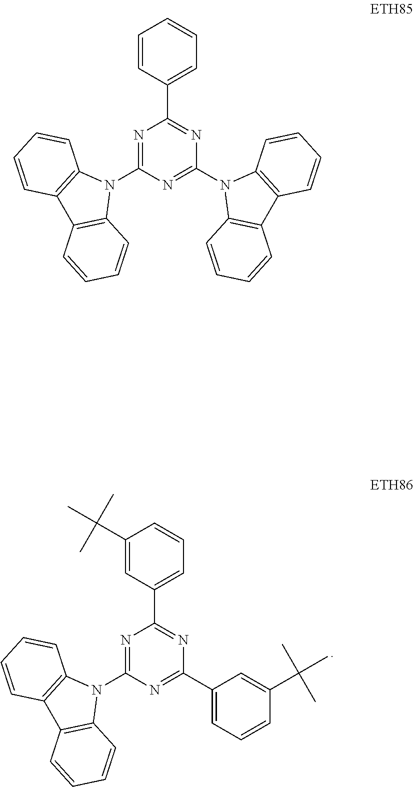 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In one or more embodiments, the emission layer EML may include a fourth compound represented by Formula M-b. For example, the fourth compound may be utilized as a phosphorescence sensitizer of the emission layer EML. Energy may transfer from the fourth compound to the first compound to emit light.

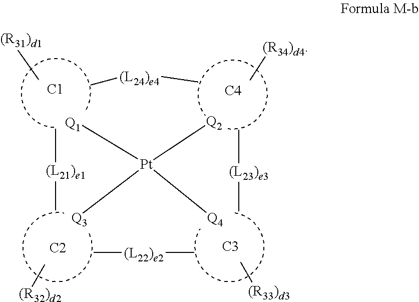

In formula M-b, Q₁ to Q₄ may each independently be C or N, and C1 and C4 may each independently be selected from a substituted hydrocarbon ring of 5 to 30 ring-forming carbon atoms and a substituted or unsubstituted heterocyclic group of 2 to 30 ring-forming carbon atoms.

e1 to e4 may each independently be 0 or 1, and L₂₁ to L₂₄ may each independently be selected from a direct linkage,

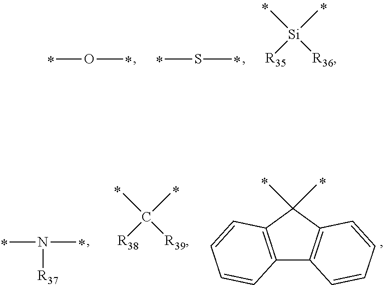

a substituted or unsubstituted divalent alkyl group of 1 to 20 carbon atoms, a substituted or unsubstituted arylene group of 6 to 30 ring-forming carbon atoms, and a substituted or unsubstituted heteroarylene group of 2 to 30 ring-forming carbon atoms.

d1 to d4 may each independently be an integer of 0 or 4. When d1 is an integer of 2 or more, each of a plurality of R₃₁s may be the same, or at least one may be different. When d2 is an integer of 2 or more, each of a plurality of R₃₂s may be the same, or at least one may be different. When d3 is an integer of 2 or more, each of a plurality of R₃₃s may be the same, or at least one may be different. When d4 is an integer of 2 or more, each of a plurality of R₃₄s may be the same, or at least one may be different.

R₃₁ to R₃₉ may each independently be selected from hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms, or may be combined with an adjacent group to form a ring.

The fourth compound may be represented by any one selected from among the compounds in Compound Group 1. In one or more embodiments, the light emitting element ED may include any one selected from among the compounds in Compound Group 4.

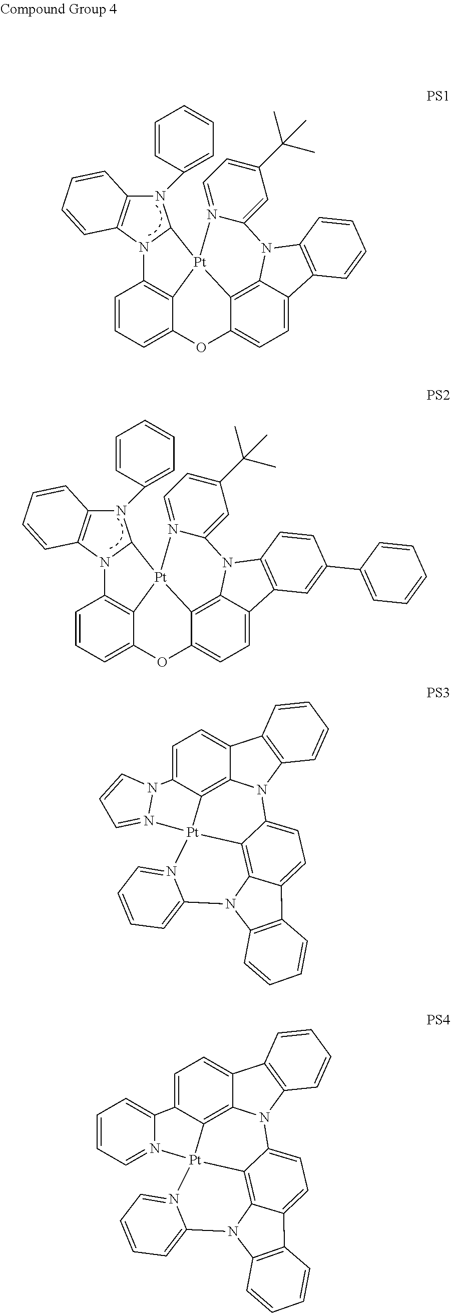

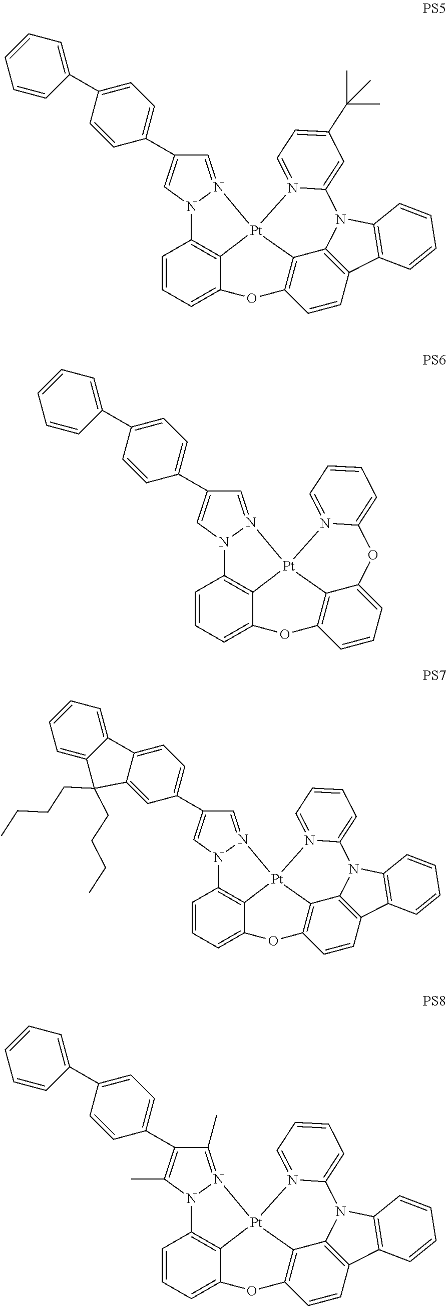

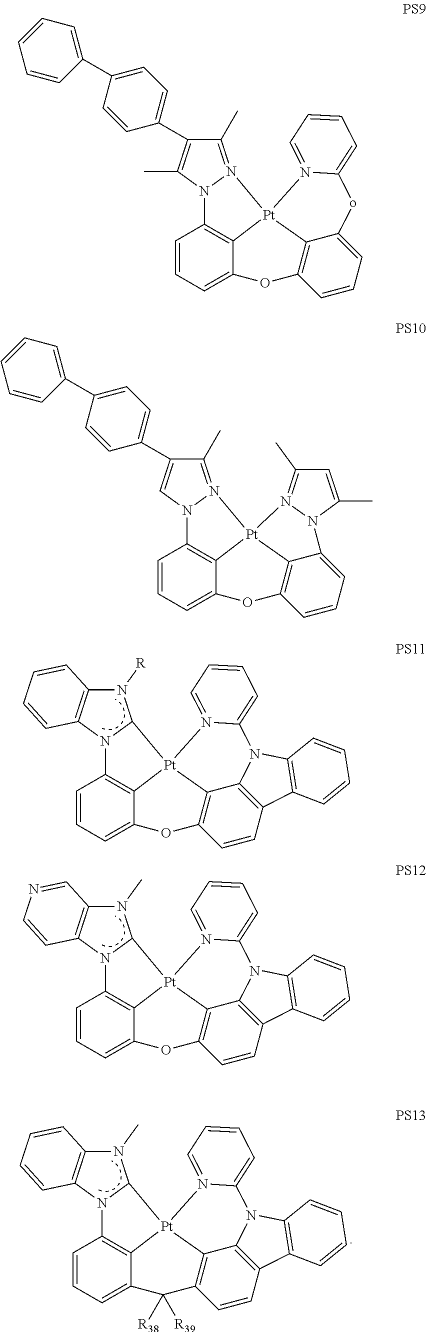

In the compounds, R, R₃₈ and R₃₉ may each independently be selected from hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms.

In one or more embodiments, the emission layer EML may include the first compound that is a polycyclic compound, and at least one selected from among the second to fourth compounds. For example, in one or more embodiments, the emission layer EML may include the first compound, the second compound, and the third compound. In the emission layer EML, the second compound and the third compound may form exciplexes, and energy transfer from the exciplex to the first compound may occur to emit light.

In some embodiments, the emission layer EML may include the first compound, the second compound, the third compound, and the fourth compound. In the emission layer, the second compound and the third compound may form exciplexes, and energy transfer from the exciplex to the fourth compound and the first compound may occur to emit light. In some embodiments, the fourth compound may be referred to as a sensitizer. The fourth compound may be to emit phosphorescence, or transfer energy to the first compound as an auxiliary dopant. However, the suggested functions of the compounds are only illustration, and embodiments of the present disclosure are not limited thereto.

In one or more embodiments, the fourth compound may perform the role of transferring energy to the first compound that is a light emitting dopant. For example, the fourth compound that plays the role of an auxiliary dopant may accelerate and/or promote the energy transfer to the first compound that is a light emitting dopant to increase the light emitting ratio of the first compound. Accordingly, the emission efficiency of the emission layer EML may be improved. In some embodiments, when the energy transfer to the first compound increases, excitons formed in the emission layer EML may not be accumulated in the emission layer EML but rapidly emit light, thereby reducing the deterioration of an element. Accordingly, the lifetime of the light emitting element ED may be increased.

In one or more embodiments, in the light emitting element ED, when the emission layer EML includes all the first compound, the second compound, the third compound, and the fourth compound, the amount of the first compound may be about 1 wt % to about 5 wt %, and the amount of the fourth compound may be about 10 wt % to about 15 wt %, based on the total weight of the first compound, the second compound, the third compound, and the fourth compound.

When the amounts of the first compound and the fourth compound satisfy the above-described ratios, energy transfer from the fourth compound to the first compound may be efficiently conducted, and accordingly, emission efficiency and element life may be improved.

The total amount of the second compound and the third compound in the emission layer EML may be a remaining amount excluding the weights of the first compound and the fourth compound. For example, in the emission layer EML, the total amount of the second compound and the third compound may be about 80 wt % to about 89 wt % based on the total weight of the first compound, the second compound, the third compound, and the fourth compound. In the total weight of the second compound and the third compound, the weight ratio of the second compound and the third compound may be about 3:7 to about 7:3. For example, in the total weight of the second compound and the third compound, the weight ratio of the second compound and the third compound may be about 5:5.

When the amounts of the second compound and the third compound satisfy the above-described ratio, charge balance properties in the emission layer EML may be improved, and emission efficiency and element life may be increased. When the amounts of the second compound and the third compound deviate from the above-described ratio range, charge balance in the emission layer EML may be broken, emission efficiency may be degraded, and the element may be easily deteriorated.

When each of the first compound, the second compound, the third compound, and the fourth compound included in the emission layer EML satisfies the above-described amount ratio range, excellent or suitable emission efficiency and long lifetime may be achieved.

In some embodiments, the emission layer EML may further include suitable materials for an emission layer in addition to the suggested first to fourth compounds. In one or more embodiments, in the light emitting element ED, the emission layer EML may include anthracene derivatives, pyrene derivatives, fluoranthene derivatives, chrysene derivatives, dihydrobenzanthracene derivatives, and/or triphenylene derivatives. For example, the emission layer EML may include anthracene derivatives and/or pyrene derivatives.

In one or more embodiments, in the light emitting elements ED shown in FIG. 3 to FIG. 6, the emission layer EML may include a compound represented by Formula E-1. The compound represented by Formula E-1 may be utilized as a fluorescence host material.

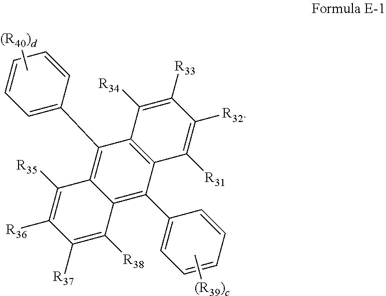

In Formula E-1, R₃₁ to R₄₀ may each independently be selected from hydrogen, deuterium, a halogen, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, and a substituted or unsubstituted heteroaryl group of 2 to 30 ring-forming carbon atoms, or may be combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

Formula E-1 may be represented by any one selected from among Compound E1 to Compound E19.

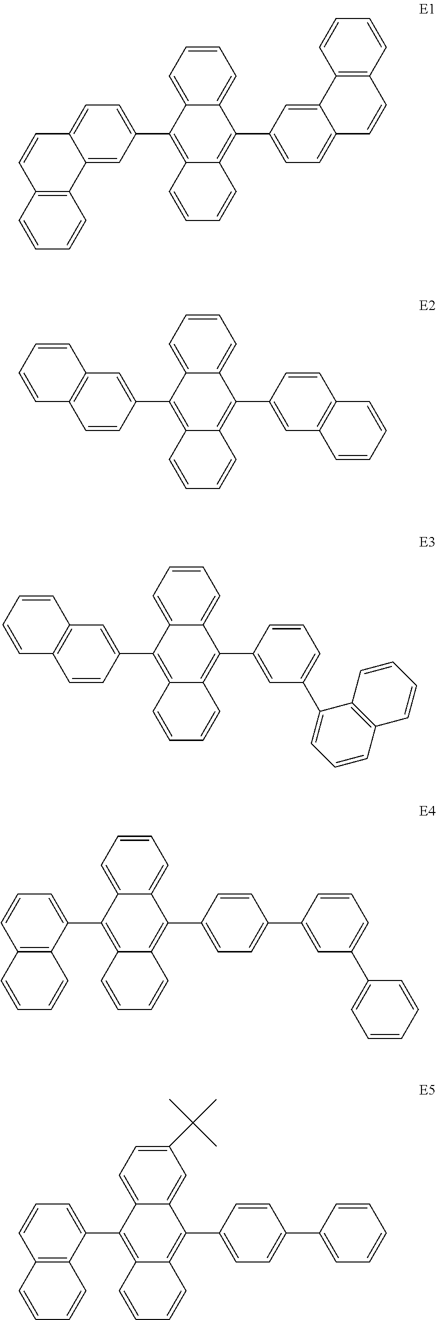

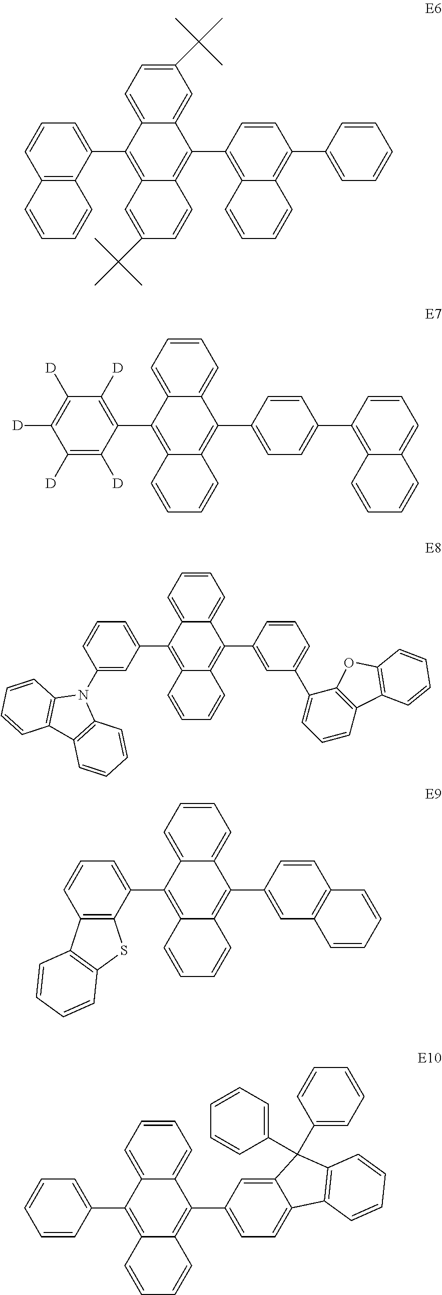

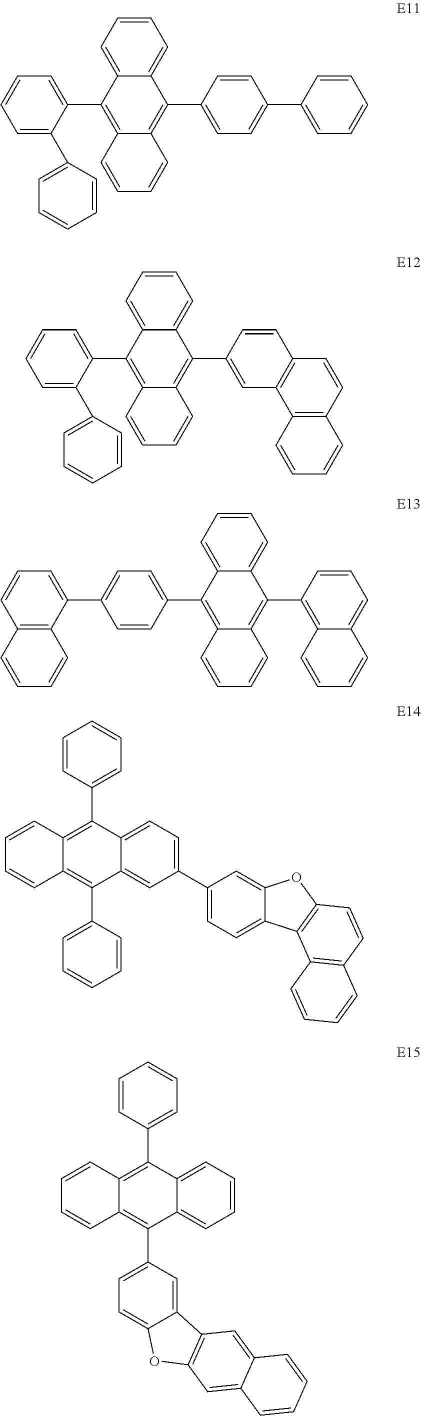

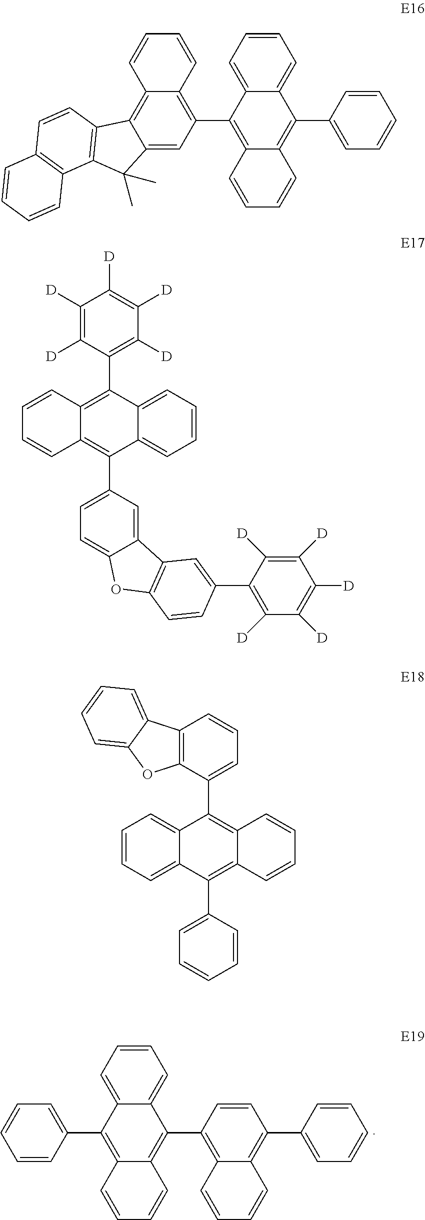

In one or more embodiments, the emission layer EML may include a compound represented by Formula E-2a or Formula E-2b. The compound represented by Formula E-2a or Formula E-2b may be utilized as a phosphorescence host material.

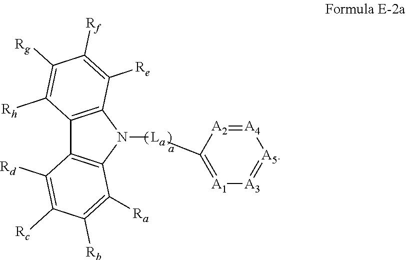

In Formula E-2a, “a” may be an integer of 0 to 10. Lₐ may be selected from a direct linkage, a substituted or unsubstituted arylene group of 6 to 30 ring-forming carbon atoms, and a substituted or unsubstituted heteroarylene group of 2 to 30 ring-forming carbon atoms. In some embodiments, when “a” is an integer of 2 or more, a plurality of Lₐs may each independently be selected from a substituted or unsubstituted arylene group of 6 to 30 ring-forming carbon atoms and a substituted or unsubstituted heteroarylene group of 2 to 30 ring-forming carbon atoms.

In some embodiments, in Formula E-2a, A₁ to A₅ may each independently be N or CRᵢ. Rₐ to Rᵢ may each independently be selected from hydrogen, deuterium, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, and a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder may be CRᵢ.

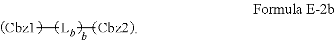

In Formula E-2b, Cbz1 and Cbz2 may each independently be selected from an unsubstituted carbazole group and a carbazole group substituted with an aryl group of 6 to 30 ring-forming carbon atoms. L_{b} may be selected from a direct linkage, a substituted or unsubstituted arylene group of 6 to 30 ring-forming carbon atoms, and a substituted or unsubstituted heteroarylene group of 2 to 30 ring-forming carbon atoms. “b” may be an integer of 0 to 10, and when “b” is an integer of 2 or more, a plurality of L_{b}s may each independently be selected from a substituted or unsubstituted arylene group of 6 to 30 ring-forming carbon atoms and a substituted or unsubstituted heteroarylene group of 2 to 30 ring-forming carbon atoms.

The compound represented by Formula E-2a or Formula E-2b may be represented by any one selected from among the compounds in Compound Group E-2. However, the compounds shown in Compound Group E-2 are only illustrations, and the compound represented by Formula E-2a or Formula E-2b is not limited to the compounds represented in Compound Group E-2.

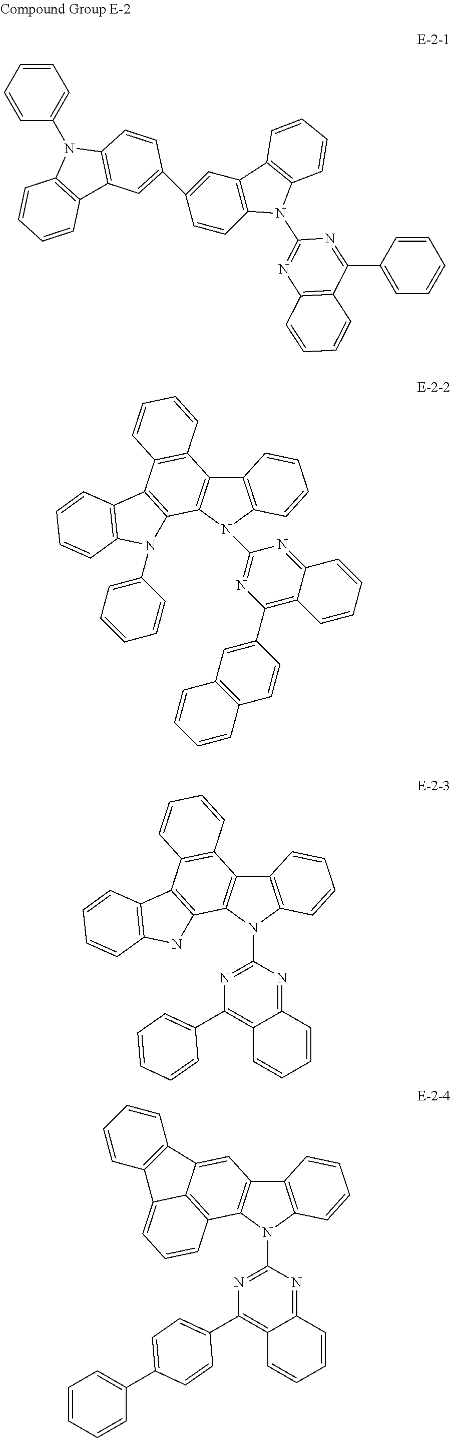

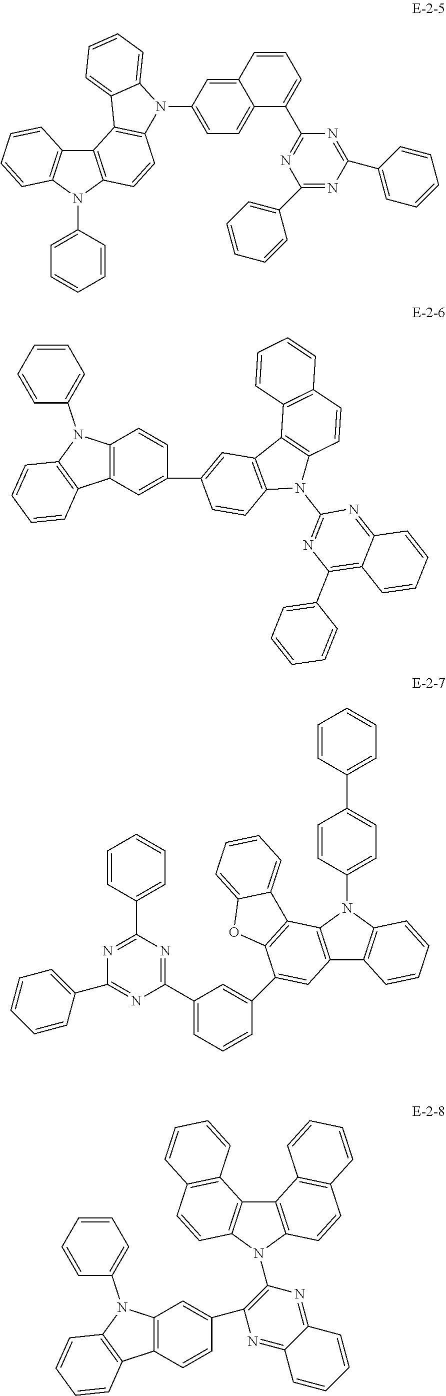 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

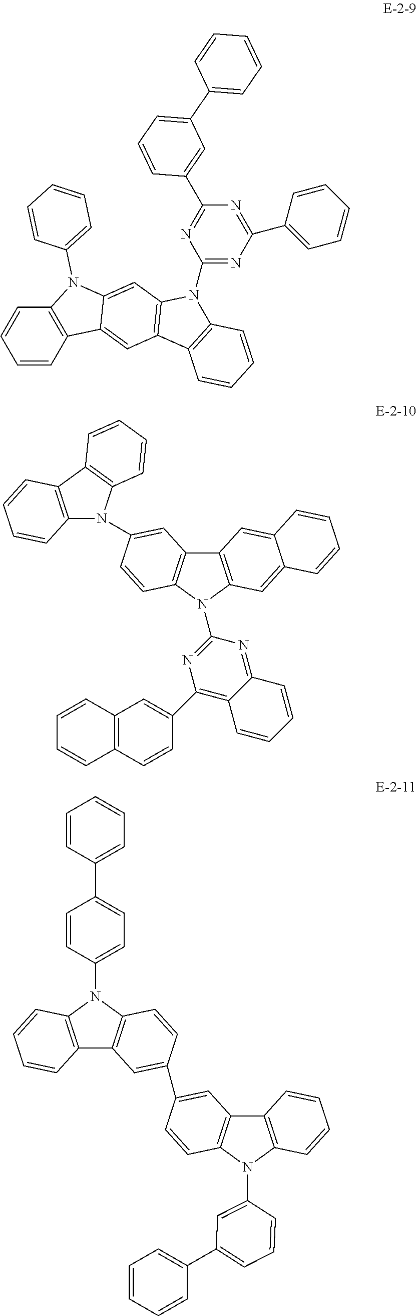

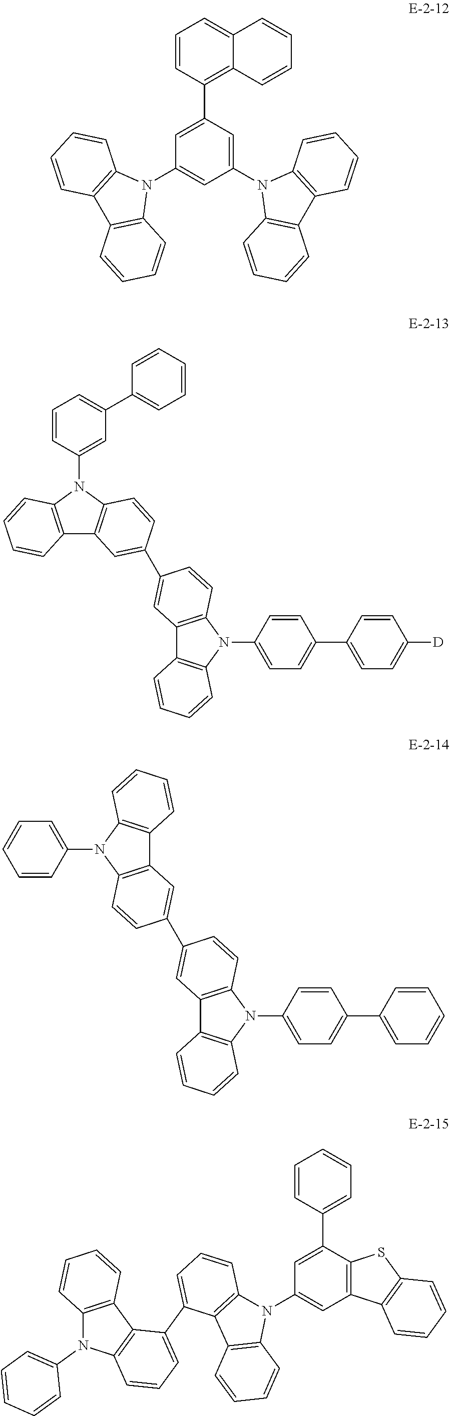 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

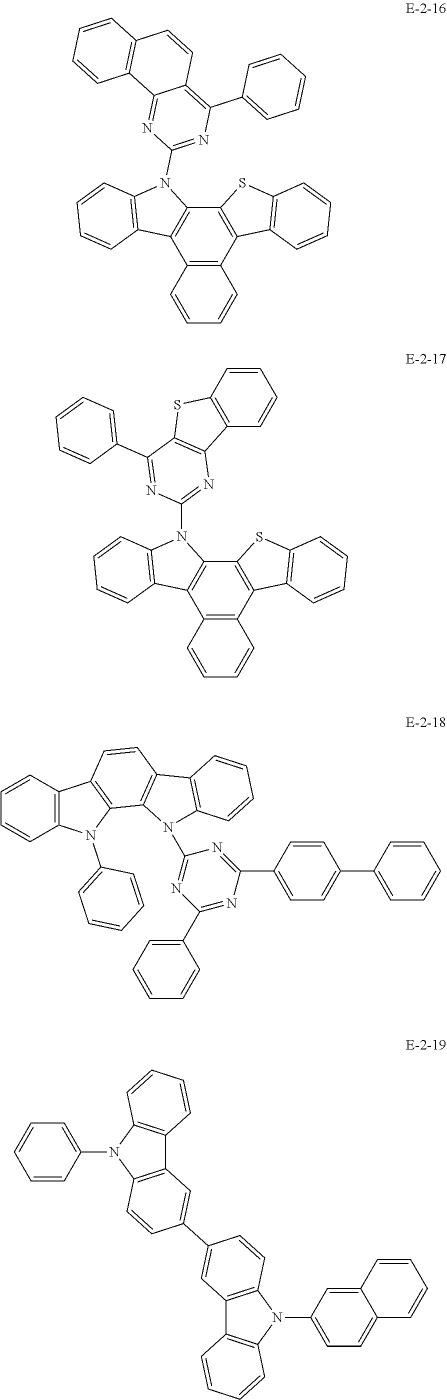

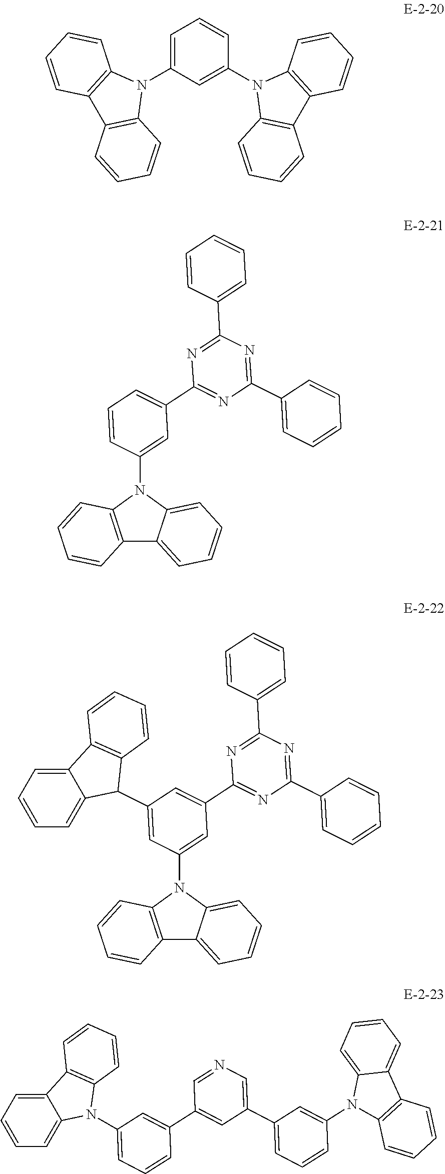 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(C4c5ccccc5-c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

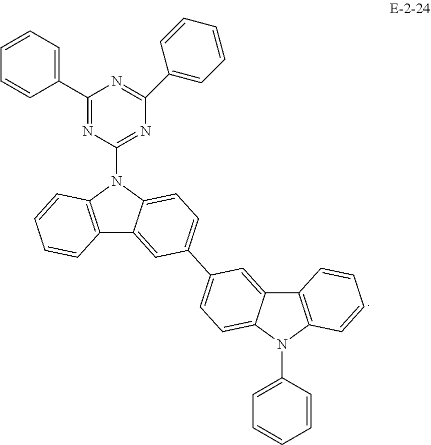 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material suitable in the art as a host material. For example, the emission layer EML may include as a host material, at least one selected from bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments of the present disclosure are not limited thereto. For example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

In one or more embodiments, the emission layer EML may include a compound represented by Formula M-a. The compound represented by Formula M-a may be utilized as a phosphorescence dopant material. In some embodiments, the compound represented by Formula M-a may be utilized as an auxiliary dopant material.

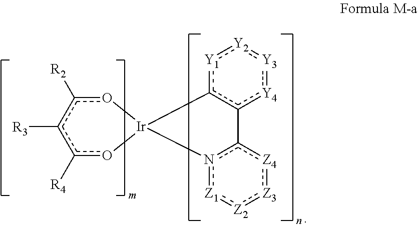

In Formula M-a, Y₁ to Y₄, and Z₁ to Z₄ may each independently be CR₁ or N, and R₁ to R₄ may each independently be selected from hydrogen, deuterium, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, and a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be represented by any one selected from among Compounds M-a1 to M-a25. However, Compounds M-a1 to M-a25 are illustrations, and the compound represented by Formula M-a is not limited to the compounds represented by Compounds M-a1 to M-a25.

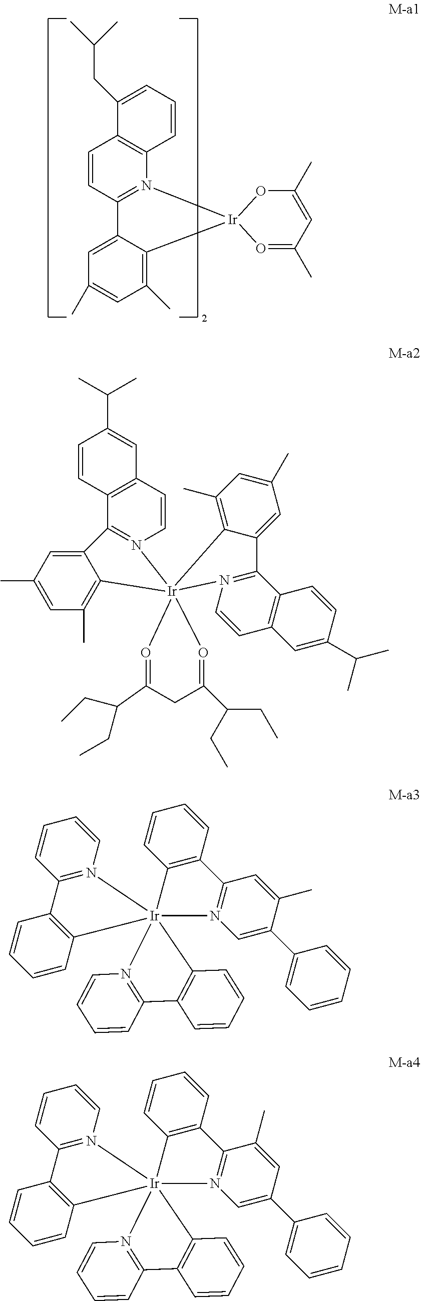

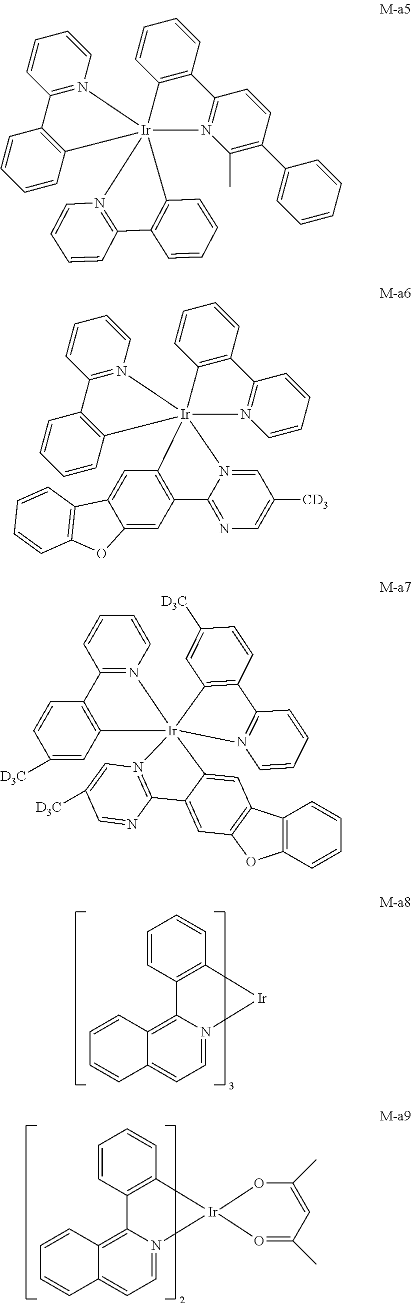

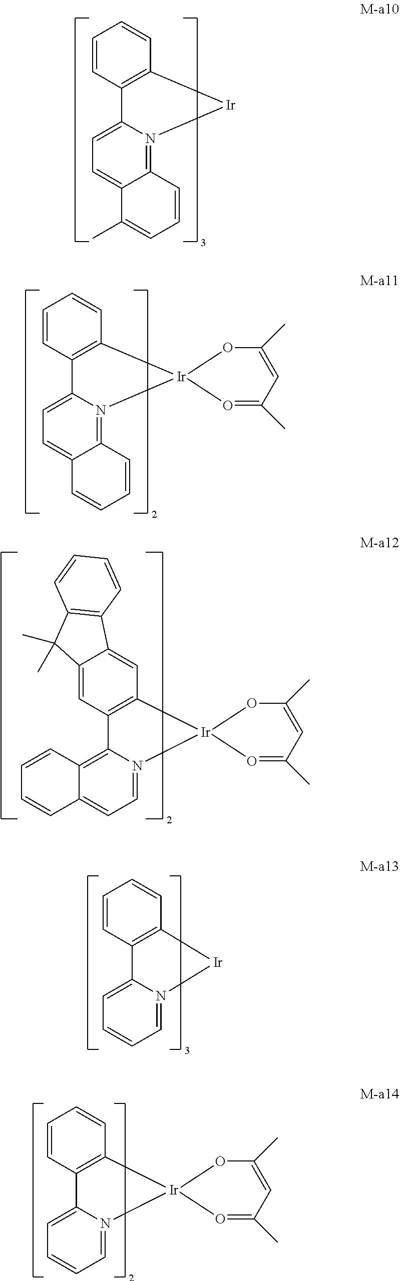

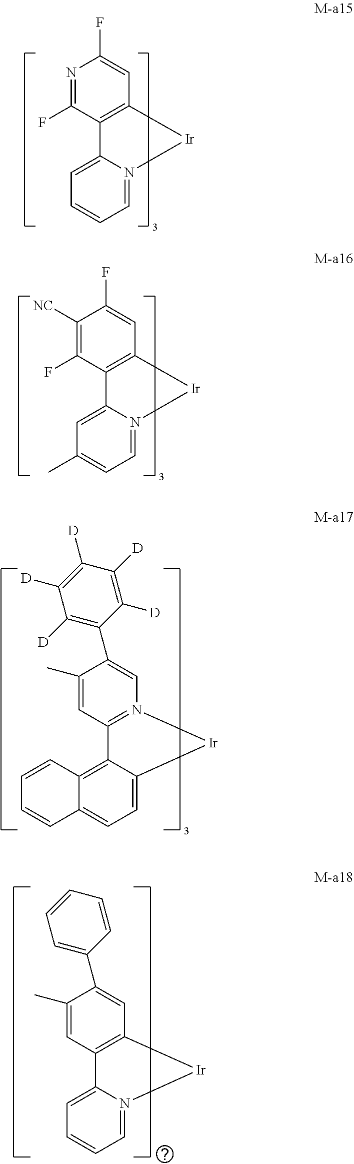

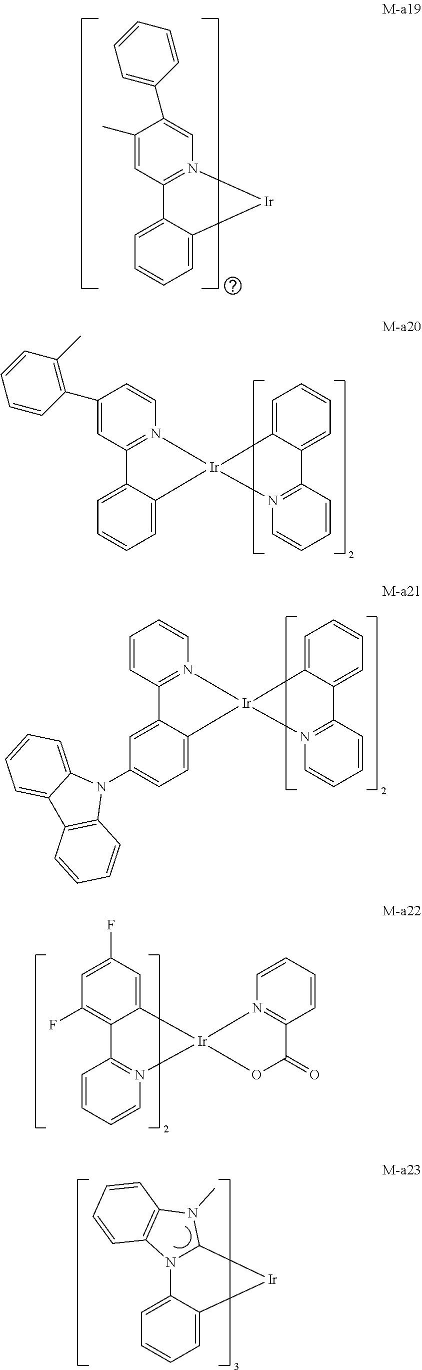

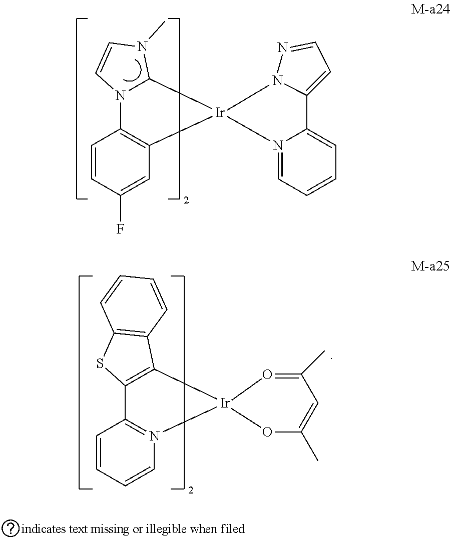

Compound M-a1 and Compound M-a2 may be utilized as red dopant materials, and Compound M-a3 to Compound M-a7 may be utilized as green dopant materials.

In one or more embodiments, the emission layer EML may include any one selected from among Formula F-a to Formula F-c. The compounds represented by Formula F-a to Formula F-c may be utilized as fluorescence dopant materials.

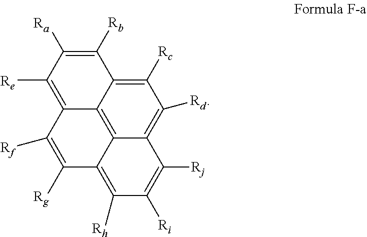

In Formula F-a, two selected from Rₐ to Rⱼ may each independently be substituted with [symbol] NAr₁Ar₂. The remainder not substituted with [symbol] NAr₁Ar₂ among Rₐ to Rⱼ may each independently be selected from hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms.

In [symbol] NAr₁Ar₂, Ar₁ and Ar₂ may each independently be a substituted or [symbol] unsubstituted aryl group of 6 to 30 ring-forming carbon atoms, or a substituted or unsubstituted heteroaryl group of 2 to 30 ring-forming carbon atoms. For example, at least one selected from among Ar₁ and Ar₂ may be a heteroaryl group including O or S as a ring-forming atom.

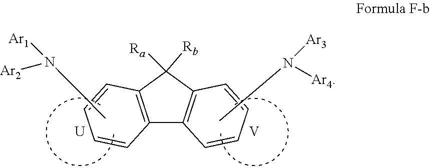

In Formula F-b, Rₐ and R_{b} may each independently be selected from hydrogen, deuterium, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, and a substituted or unsubstituted heteroaryl group of 2 to 30 ring-forming carbon atoms, or may be combined with an adjacent group to form a ring. Ar₁ to Ar₄ may each independently be selected from a substituted or unsubstituted aryl group of 6 to 30 ring-forming carbon atoms and a substituted or unsubstituted heteroaryl group of 2 to 30 ring-forming carbon atoms.

In Formula F-b, U and V may each independently be selected from a substituted or unsubstituted hydrocarbon ring of 5 to 30 ring-forming carbon atoms and a substituted or unsubstituted heterocycle of 2 to 30 ring-forming carbon atoms.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both U and V is 0, the fused ring of Formula F-b may be a ring compound with three rings. In some embodiments, when the number of both U and V is 1, a fused ring having the fluorene core of Formula F-b may be a ring compound with five rings.

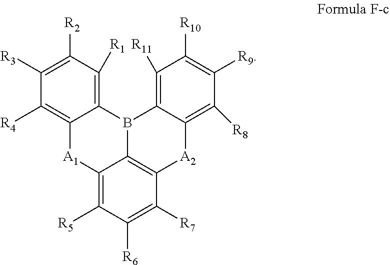

In Formula F-c, A₁ and A2 may each independently be selected from O, S, Se, and NRₘ, and Rₘ may be selected from hydrogen, deuterium, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms. R₁ to R₁₁ may each independently be selected from hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms, and/or may be combined with an adjacent group to form a ring.

In Formula F-c, A₁ and A₂ may each independently be combined with the substituents of an adjacent ring to form a fused ring. For example, in some embodiments, when A₁ and A₂ may each independently be NRₘ, A₁ may be combined with R₄ or R₅ to form a ring. In addition, A₂ may be combined with R₇ or R₈ to form a ring.

In one or more embodiments, the emission layer EML may include as a suitable dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1′-dipyrene, 1,4-dipyrenylbenzene, and/or 1,4-bis(N,N-diphenylamino)pyrene), etc.

In one or more embodiments, When a plurality of emission layers EML are included, at least one emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb), or thulium (Tm). For example, in some embodiments, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), and/or platinum octaethyl porphyrin (PtOEP) may be utilized as the phosphorescence dopant. However, embodiments of the present disclosure are not limited thereto.

In one or more embodiments, at least one emission layer EML may include a quantum dot material. The core of the quantum dot may be selected from a II-VI group compound, a III-VI group compound, a I-III-VI group compound, a III-V group compound, a III-II-V group compound, a IV-VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as In₂S₃, and In₂Se₃, a ternary compound such as InGaS₃, and InGaSe₃, or optional combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂, and mixtures thereof, and a quaternary compound such as AgInGaS₂ and/or CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In some embodiments, the III-V group compound may further include a IIB group metal. For example, InZnP, etc. may be selected as a III-IIB-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In one or more embodiments, the binary compound, the ternary compound or the quaternary compound may be present at substantially uniform concentration in a particle or may be present at a partially different concentration distribution state in substantially the same particle. In some embodiments, a core/shell structure in which one quantum dot wraps another quantum dot may be possible. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide suitable as a shell may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄ and NiO, or a ternary compound such as MgAl₂O₄, CoFe₂O₄, NiFe₂O₄ and CoMn₂O₄, but embodiments of the present disclosure are not limited thereto.

Also, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of emission wavelength spectrum of about 45 nm or less, about 40 nm or less, or about 30 nm or less. Within this range, color purity or color reproducibility may be improved. In some embodiments, light emitted via such quantum dot is emitted in all directions, and light view angle properties may be improved.

In addition, the shape of the quantum dot may be generally utilized shapes in the art, without specific limitation. In some embodiments, the shape of spherical, pyramidal, multi-arm, or cubic nanoparticle, nanotube, nanowire, nanofiber, nanoplate particle, etc. may be utilized.

The quantum dot may control the color of light emitted according to the particle size, and accordingly, the quantum dot may have one or more suitable emission colors such as blue, red, and green.

In one or more embodiments, in the light emitting elements ED, as shown in FIG. 3 to FIG. 6, the electron transport region ETR may be provided on the emission layer EML. The electron transport region ETR may include at least one selected from among a hole blocking layer HBL, an electron transport layer ETL, and an electron injection layer EIL. However, embodiments of the present disclosure are not limited thereto.

The electron transport region ETR may have a single layer formed utilizing a single material, a single layer formed utilizing a plurality of different materials, or a multi-layered structure having a plurality of layers formed utilizing a plurality of different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing a plurality of different materials, or a structure stacked from the emission layer EML of electron transport layer ETL/electron injection layer EIL, hole blocking layer HBL/electron transport layer ETL/electron injection layer EIL, electron transport layer ETL/buffer layer/electron injection layer EIL, and/or the like, without limitation. The thickness of the electron transport region ETR may be, for example, from about 1,000 Å to about 1,500 Å.

The electron transport region ETR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The electron transport region ETR may include a compound represented by Formula ET-2.

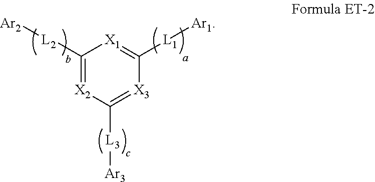

In Formula ET-2, at least one selected from among X₁ to X₃ is N, and the remainder are CRₐ. Rₐ may be selected from hydrogen, deuterium, a substituted or unsubstituted alkyl of 1 to 20 carbon atoms, a substituted or unsubstituted aryl group of 6 to 30 ring-forming carbon atoms, and a substituted or unsubstituted heteroaryl group of 2 to 30 ring-forming carbon atoms. Ar₁ to Ar₃ may each independently be selected from hydrogen, deuterium, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms.

In Formula ET-2, “a” to “c” may each independently be an integer of 0 to 10. In Formula ET-2, “L₁” to “L₃” may each independently be selected from a direct linkage, a substituted or unsubstituted arylene group of 6 to 30 ring-forming carbon atoms, and a substituted or unsubstituted heteroarylene group of 2 to 30 ring-forming carbon atoms. In some embodiments, when “a” to “c” are integers of 2 or more, “L₁” to “L₃” may each independently be selected from a substituted or unsubstituted arylene group of 6 to 30 ring-forming carbon atoms and a substituted or unsubstituted heteroarylene group of 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1, 10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), and/or one or more mixtures thereof, without limitation.

The electron transport region ETR may include at least one selected from among Compounds ET1 to ET36.

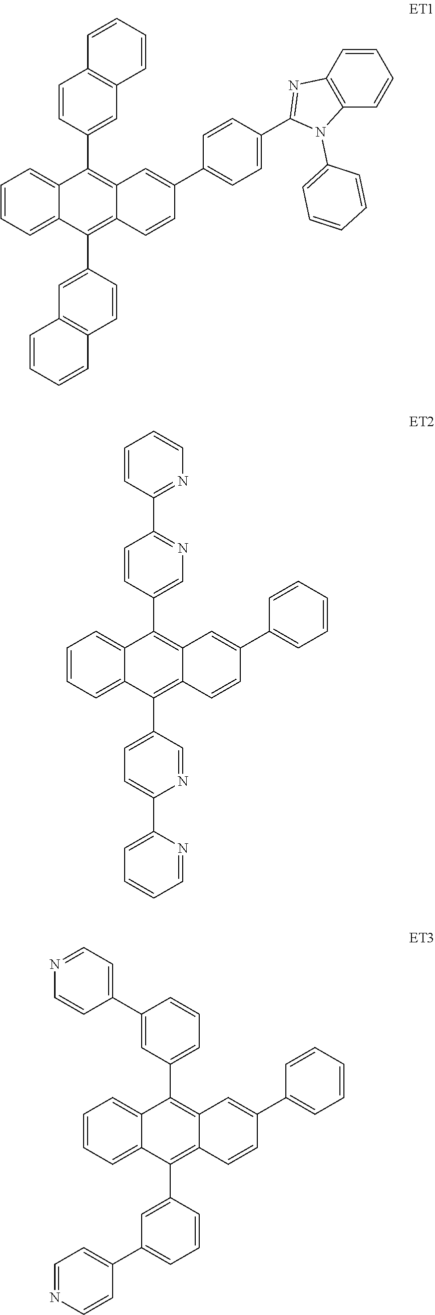 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

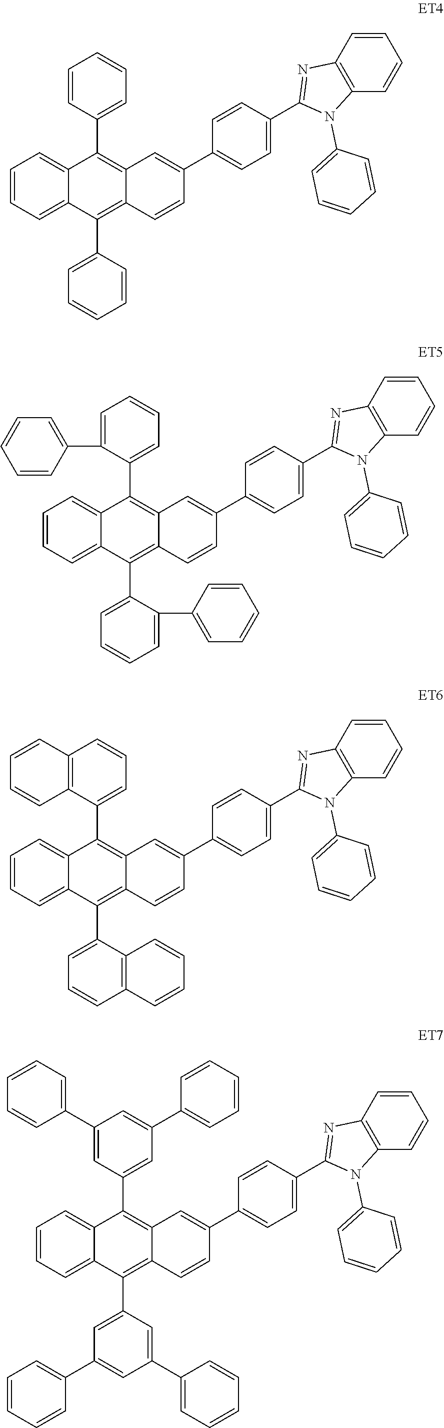 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

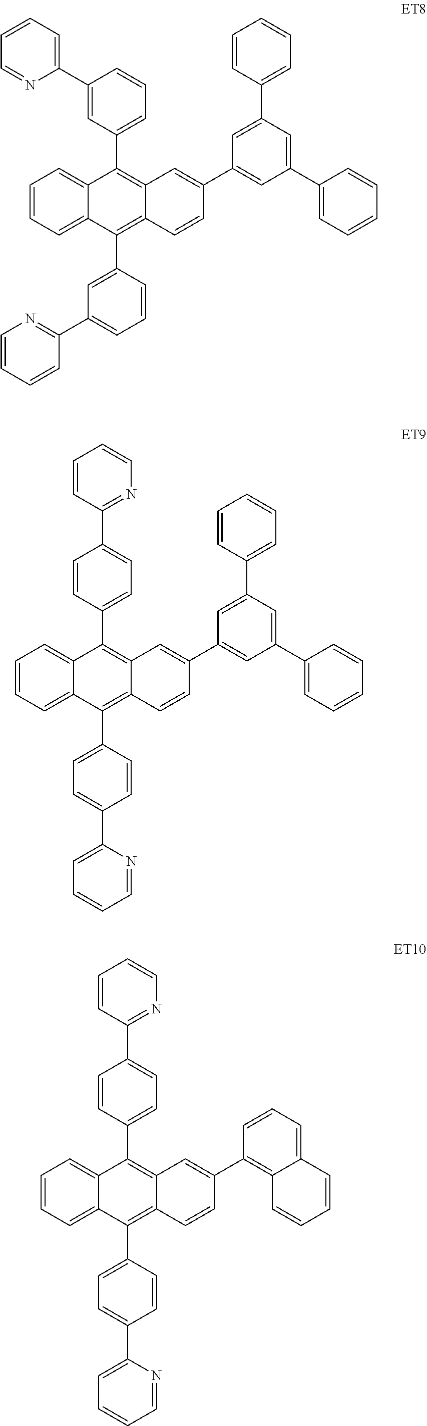 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

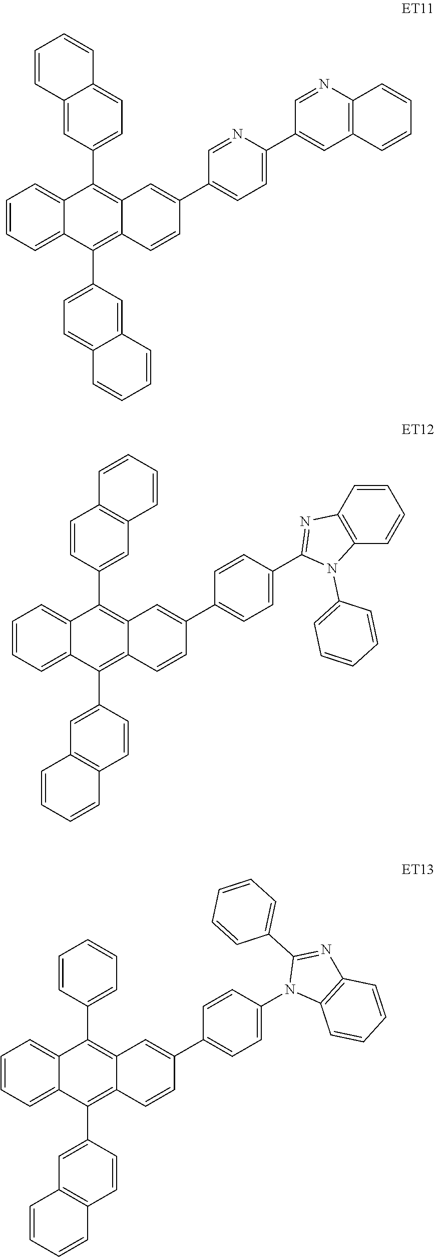 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

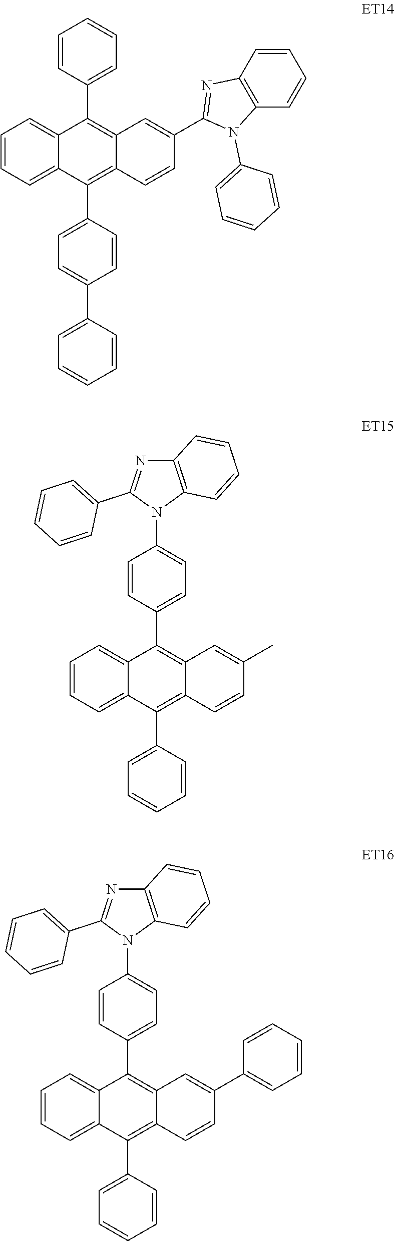 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

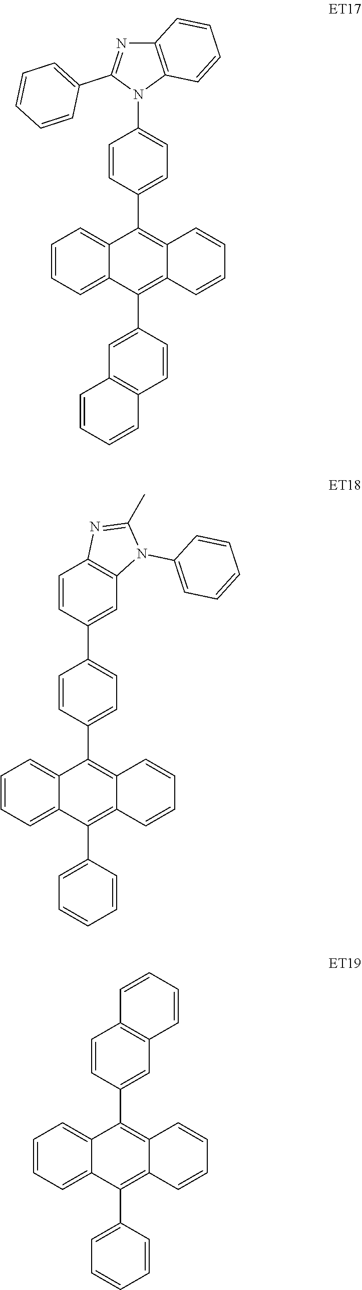

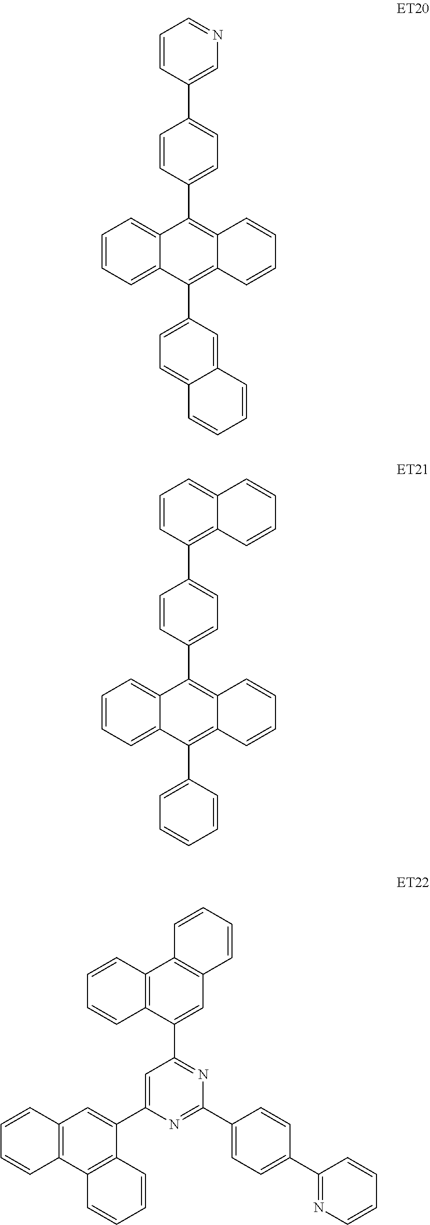

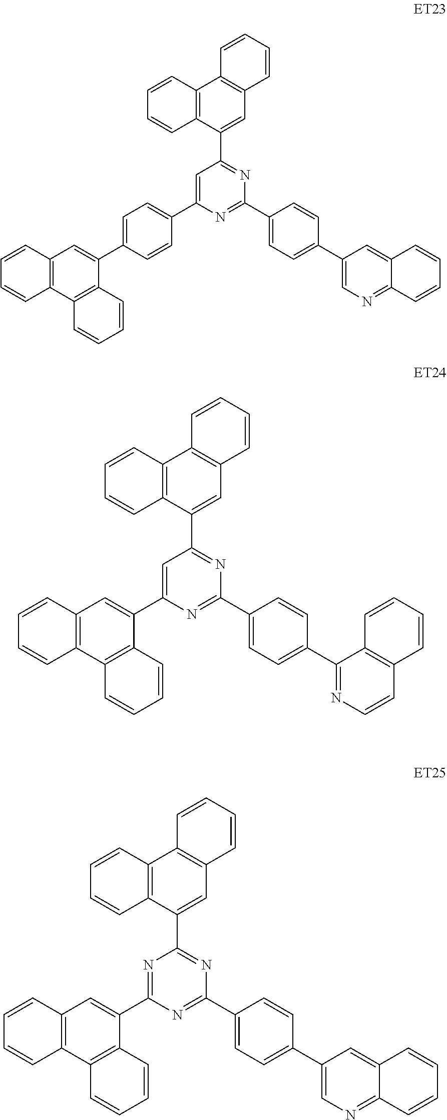 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

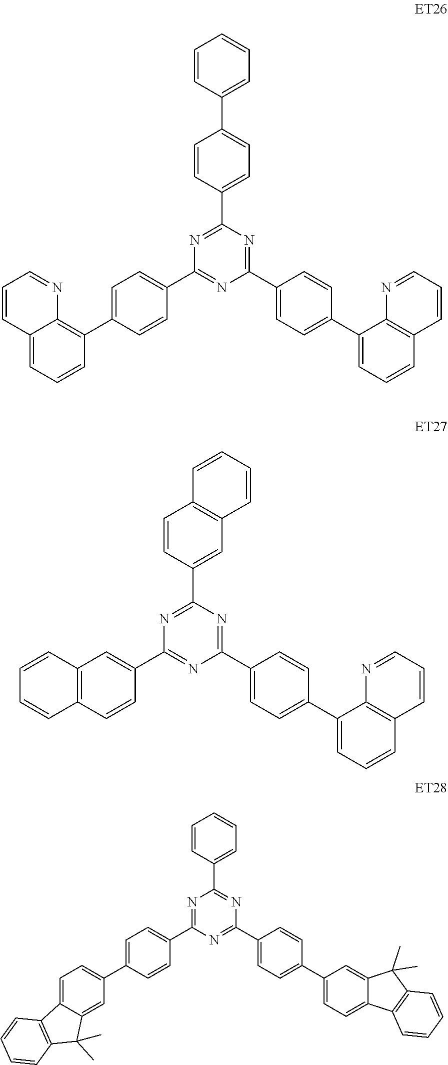 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

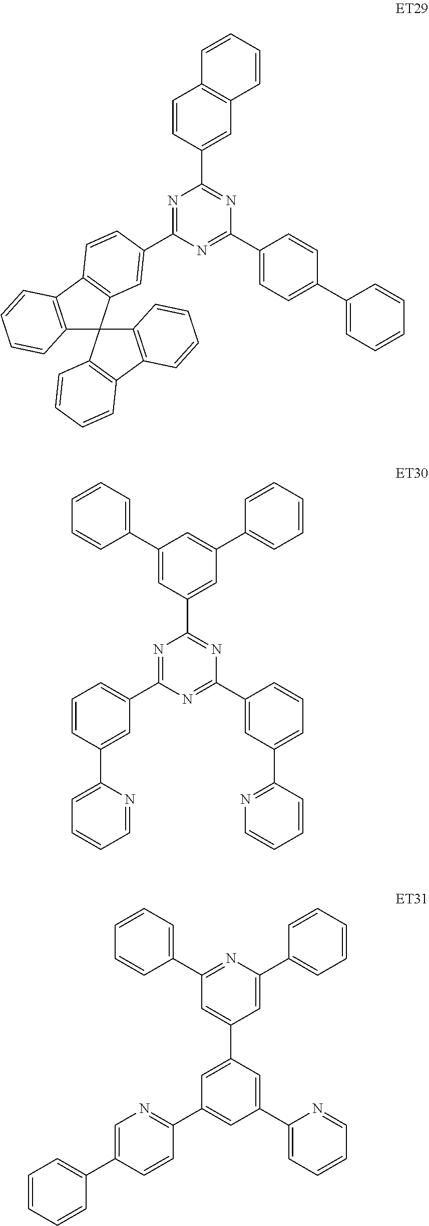 [SMILES: c1ccc(-c2ccc(-c3nc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

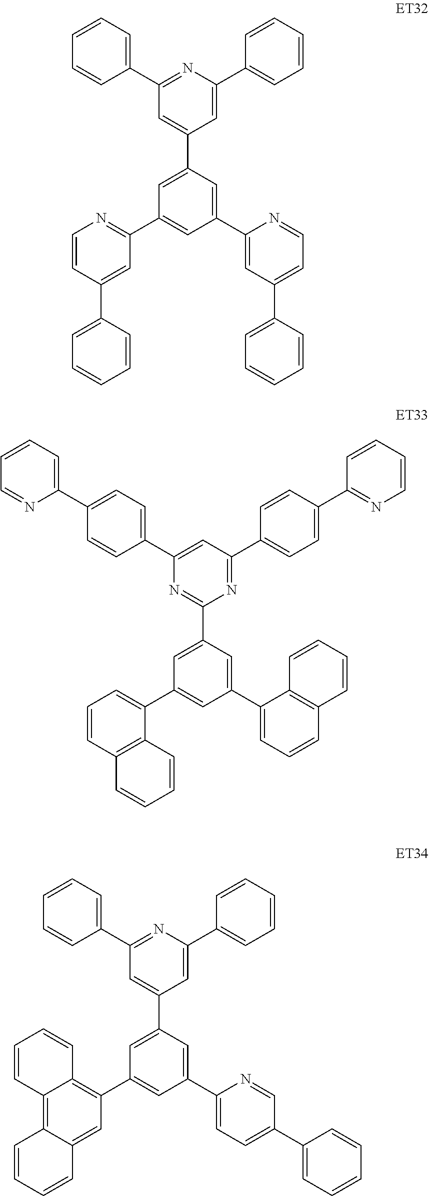 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

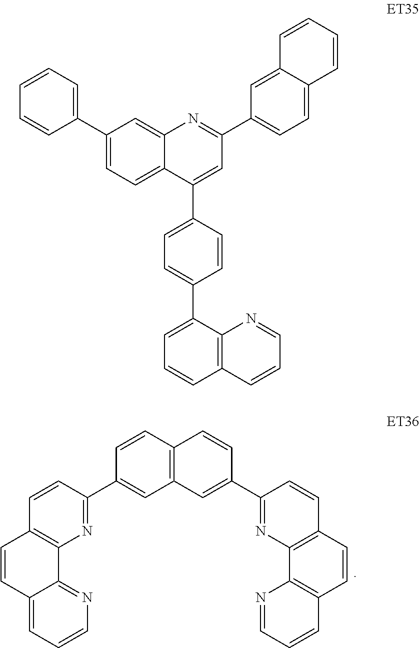 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI and KI, a lanthanide metal such as Yb, or a co-depositing material of the metal halide and the lanthanide metal. For example, the electron transport region ETR may include KI:Yb, RbI:Yb, LiF:Yb, etc., as the co-depositing material. In some embodiments, the electron transport region ETR may utilize a metal oxide such as Li₂O and BaO, and/or 8-hydroxy-lithium quinolate (Liq). However, embodiments of the present disclosure are not limited thereto. In some embodiments, the electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates.

The electron transport region ETR may include at least one selected from among 2,9-dimethyl-4,7-diphenyl-1, 10-phenanthroline (BCP), diphenyl(4-(triphenylsilyl)phenyl)phosphine oxide (TSPO1) and 4,7-diphenyl-1,10-phenanthroline (Bphen) in addition to the aforementioned materials. However, embodiments of the present disclosure are not limited thereto.

The electron transport region ETR may include the compounds of the electron transport region in at least one selected from among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the above-described range, satisfactory electron transport properties may be obtained without substantial increase of a driving voltage. When the electron transport region ETR includes the electron injection layer EIL, the thickness of the electron injection layer EIL may be from about 1 Å to about 100 Å, for example, from about 3 Å to about 90 Å. When the thickness of the electron injection layer EIL satisfies the above-described range, satisfactory electron injection properties may be obtained without inducing substantial increase of a driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second cathode EL2 may be a cathode, and when the first electrode EL1 is a cathode, the second electrode EL2 may be an anode. The second electrode may include at least one selected from among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, and oxides thereof.

The second electrode EL2 may be a transmissive electrode, a transflective electrode, or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, Yb (ytterbium), W, compounds including thereof, or mixtures thereof (for example, AgMg, AgYb, or MgYb). In some embodiments, the second electrode EL2 may have a multi-layered structure including a reflective layer or a transflective layer formed utilizing the above-described materials and a transparent conductive layer formed utilizing ITO, IZO, ZnO, ITZO, etc. For example, the second electrode EL2 may include the aforementioned metal materials, combinations of two or more metal materials selected from the aforementioned metal materials, or oxides of the aforementioned metal materials.

In some embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting element ED, a capping layer CPL may be further disposed thereon. The capping layer CPL may include a multilayer or a single layer.

In one or more embodiments, the capping layer CPL may be an organic layer and/or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or includes an epoxy resin, or acrylate such as methacrylate. In some embodiments, a capping layer CPL may include at least one selected from among Compounds P1 to P5, but embodiments of the present disclosure are not limited thereto.

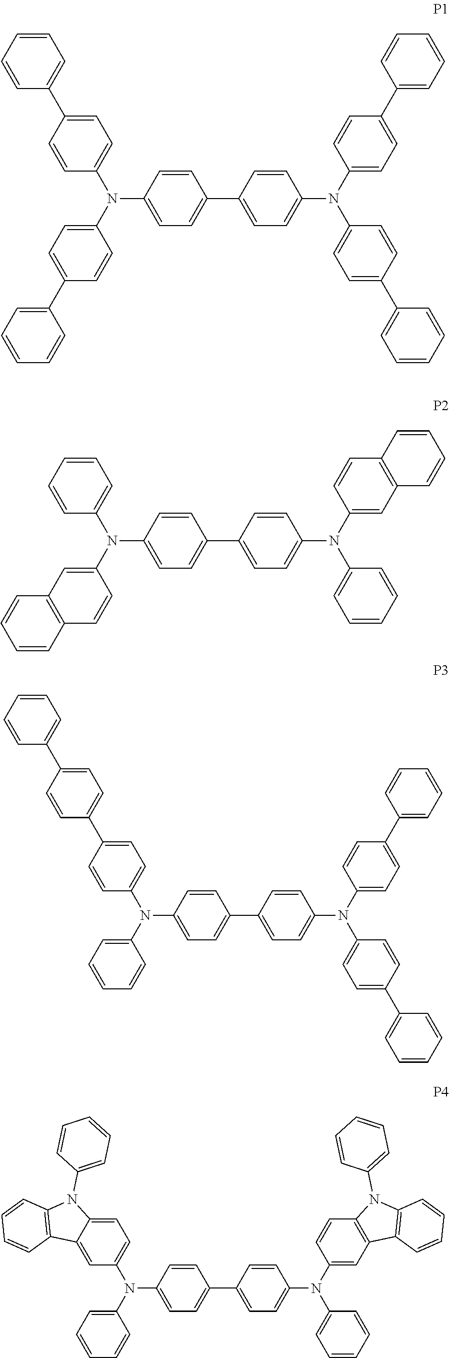 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

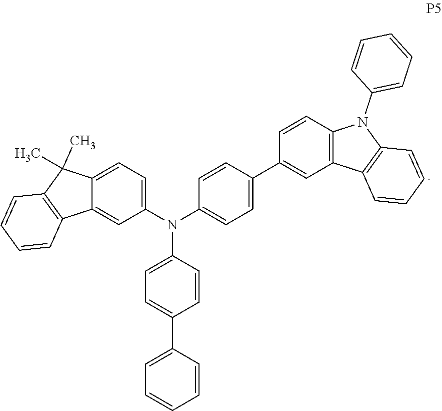 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL with respect to light in a wavelength range of about 550 nm to about 660 nm may be about 1.6 or more.

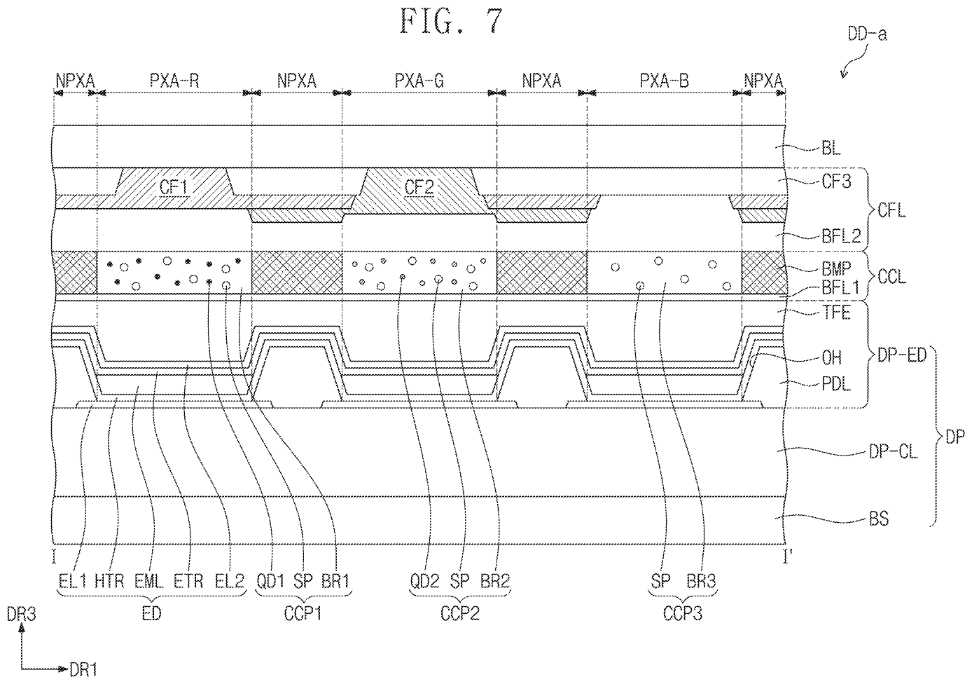

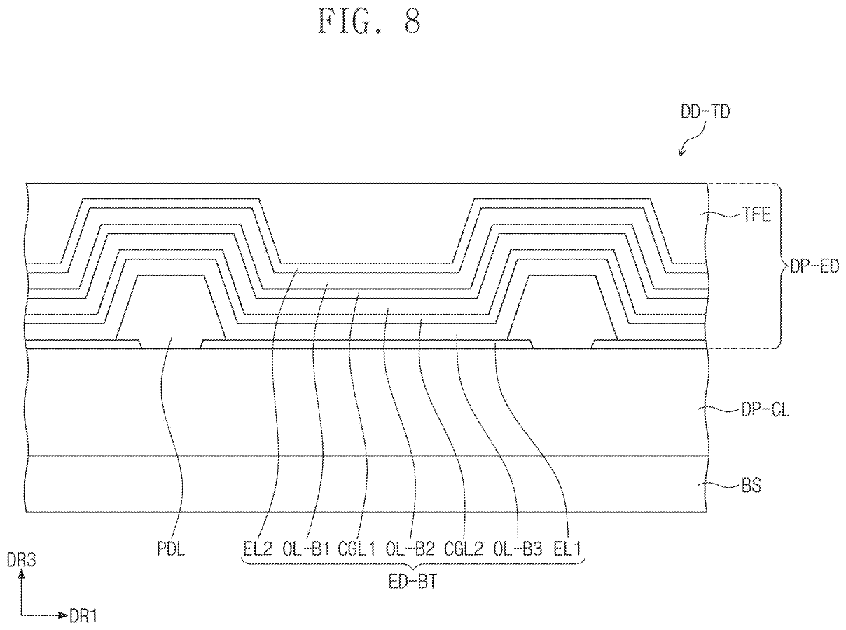

FIG. 7 to FIG. 10 are cross-sectional views on display devices according to one or more embodiments of the present disclosure. In the explanation on the display devices of one or more embodiments, referring to FIG. 7 to FIG. 10, the overlapping parts with the explanation on FIG. 1 to FIG. 6 will not be explained again for conciseness, and the different features will be explained chiefly.

Referring to FIG. 7, a display device DD-a according to one or more embodiments may include a display panel DP including a display element layer DP-ED, a light controlling layer CCL disposed on the display panel DP, and a color filter layer CFL.

In one or more embodiments shown in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the same structures of the light emitting elements ED of FIG. 3 to FIG. 6 may be applied to the structure of the light emitting element ED shown in FIG. 7.

The emission layer EML of the light emitting element ED included in the display device DD-a according to one or more embodiments may include a polycyclic compound of the present disclosure.

Referring to FIG. 7, the emission layer EML may be disposed in an opening part OH defined in a pixel definition layer PDL. For example, in one or more embodiments, the emission layer EML divided by the pixel definition layer PDL and correspondingly provided to each of luminous areas PXA-R, PXA-G, and PXA-B may be to emit light in substantially the same wavelength region. In one embodiment, in the display device DD-a, the emission layer EML may be to emit blue light. In some embodiments, different from the drawings, the emission layer EML may be provided as a common layer for all luminous areas PXA-R, PXA-G, and PXA-B.

The light controlling layer CCL may be disposed on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include a plurality of light controlling parts CCP1, CCP2, and CCP3. The light controlling parts CCP1, CCP2, and CCP3 may be separated from one another.

Referring to FIG. 7, a partition pattern BMP may be disposed between the separated light controlling parts CCP1, CCP2, and CCP3, but embodiments of the present disclosure are not limited thereto. In FIG. 7, the partition pattern BMP is shown not to be overlapped with the light controlling parts CCP1, CCP2, and CCP3, but at least a portion of the edge of the light controlling parts CCP1, CCP2, and CCP3 may be overlapped with the partition pattern BMP.

The light controlling layer CCL may include a first light controlling part CCP1 including a first quantum dot QD1 converting first color light provided from the light emitting element ED into second color light, a second light controlling part CCP2 including a second quantum dot QD2 converting the first color light into third color light, and a third light controlling part CCP3 transmitting the first color light.

In one or more embodiments, the first light controlling part CCP1 may provide red light which is the second color light, and the second light controlling part CCP2 may provide green light which is the third color light. The third color controlling part CCP3 may be to transmit and provide blue light which is the first color light provided from the light emitting element ED. For example, the first quantum dot QD1 may be a red quantum dot (e.g., emitting red light), and the second quantum dot QD2 may be a green quantum dot (e.g., emitting green light). On the quantum dots QD1 and QD2, the same contents as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot but include the scatterer SP.

The scatterer SP may be an inorganic particle. For example, the scatterer SP may include at least one selected from among TiO₂, ZnO, Al₂O₃, SiO₂, and hollow silica. In one or more embodiments, the scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

the first light controlling part CCP1, the second light controlling part CCP2, and the third light controlling part CCP3 may include base resins BR1, BR2, and BR3, respectively, dispersing the quantum dots QD1 and/or QD2 and the scatterer SP. In one or more embodiments, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2, and BR3 are mediums in which the quantum dots QD1 and/or QD2 and the scatterer SP are dispersed, and may be composed of one or more suitable resin compositions which may be generally referred to as a binder. For example, the base resins BR1, BR2 and BR3 may be selected from among acrylic resins, urethane-based resins, silicone-based resins, epoxy-based resins, etc. The base resins BR1, BR2 and BR3 may be transparent resins. In one or more embodiments, the first base resin BR1, the second base resin BR2, and the third base resin BR3 may be the same or different from each other.

The light controlling layer CCL may include a barrier layer BFL1. The barrier layer BFL1 may play the role of blocking/reducing the penetration of moisture and/or oxygen (hereinafter, will be referred to as “humidity/oxygen”). The barrier layer BFL1 may be disposed on the light controlling parts CCP1, CCP2, and CCP3 to block or reduce the exposure of the light controlling parts CCP1, CCP2, and CCP3 to humidity/oxygen. In some embodiments, the barrier layer BFL1 may cover the light controlling parts CCP1, CCP2, and CCP3. In some embodiments, a barrier layer BFL2 may be provided between the light controlling parts CCP1, CCP2, and CCP3 and the color filter layer CFL.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride and/or a thin metal film securing light transmittance. In some embodiments, the barrier layers BFL1 and BFL2 may further include an organic layer. The barrier layers BFL1 and BFL2 may be composed of a single layer of a plurality of layers.

In one or more embodiments, in the display device DD-a, the color filter layer CFL may be disposed on the light controlling layer CCL. For example, in one embodiment, the color filter layer CFL may be disposed directly on the light controlling layer CCL. In this embodiment, the barrier layer BFL2 may not be provided.

The color filter layer CFL may include filters CF1, CF2, and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye. However, embodiments of the present disclosure are not limited thereto. For example, in some embodiments, the third filter CF3 may not include (e.g., may exclude) the pigment or dye. The third filter CF3 may include a polymer photosensitive resin and not include a pigment or dye. The third filter CF3 may be transparent. The third filter CF3 may be formed utilizing a transparent photosensitive resin.

In some embodiments, the first filter CF1 and the second filter CF2 may be yellow filters. The first filter CF1 and the second filter CF2 may be provided in one body without distinction. The first to third filters CF1, CF2, and CF3 may be disposed corresponding to a red luminous area PXA-R, green luminous area PXA-G, and blue luminous area PXA-B, respectively.

The color filter layer CFL may include a light blocking part (BM). The color filter layer CFL may include the light blocking part (BM) disposed so as to overlap with the boundaries of the neighboring filters CF1, CF2 and CF3. The light blocking part (BM) may be a black matrix. The light blocking part (BM) may be formed by including an organic light blocking material or an inorganic light blocking material, including a black pigment or black dye. The light blocking part BM may divide the boundaries among adjacent filters CF1, CF2 and CF3. In some embodiments, the light blocking part BM may be formed as a blue filter.

On the color filter layer CFL, a base substrate BL may be disposed. The base substrate BL may be a member providing a base surface on which the color filter layer CFL, the light controlling layer CCL, etc. are disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, different from the drawing, the base substrate BL may not be provided.

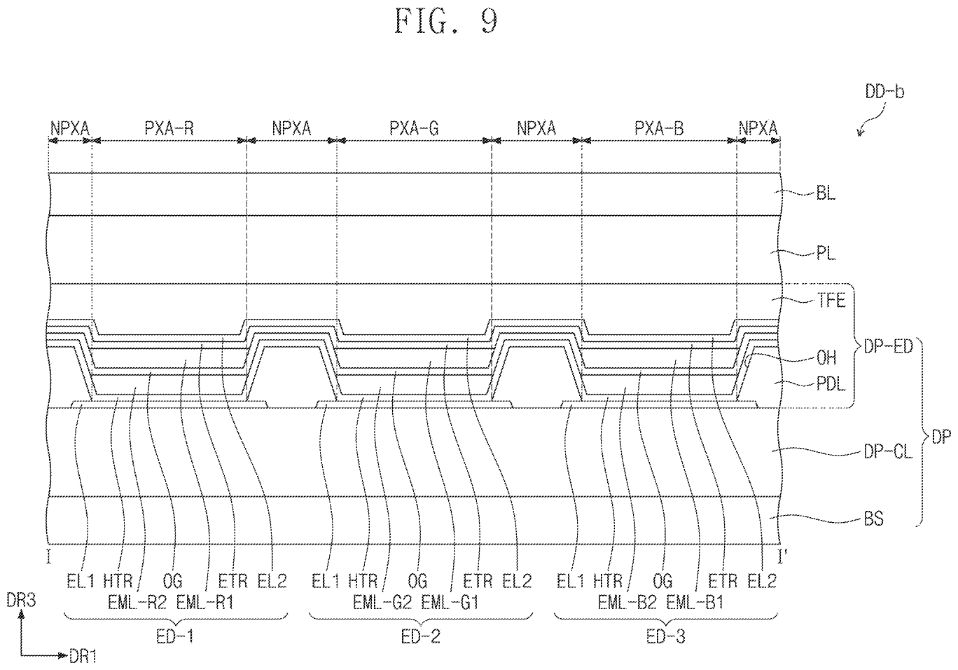

FIG. 8 is a cross-sectional view showing a portion of the display device according to one or more embodiments. In FIG. 8, the cross-sectional view of a portion corresponding to the display panel DP in FIG. 7 is shown. In one or more embodiments, in a display device DD-TD, a light emitting element ED-BT may include a plurality of light emitting structures OL-B1, OL-B2, and OL-B3. The light emitting element ED-BT may include oppositely disposed first electrode EL1 and second electrode EL2, and the a plurality of light emitting structures OL-B1, OL-B2, and OL-B3 stacked in order (in the stated order) in a thickness direction and provided between the first electrode EL1 and the second electrode EL2. Each of the light emitting structures OL-B1, OL-B2 and OL-B3 may include an emission layer EML (FIG. 7), a hole transport region HTR, and an electron transport region ETR disposed with the emission layer EML (FIG. 7) therebetween.

For example, in some embodiments, the light emitting element ED-BT included in the display device DD-TD may be a light emitting element of a tandem structure including a plurality of emission layers.

In one or more embodiments shown in FIG. 8, light emitted from the light emitting structures OL-B1, OL-B2, and OL-B3 may be all blue light. However, embodiments of the present disclosure are not limited thereto, and the wavelength regions of light emitted from the light emitting structures OL-B1, OL-B2 and OL-B3 may be different from each other. For example, in some embodiment, the light emitting element ED-BT including the a plurality of light emitting structures OL-B1, OL-B2, and OL-B3 emitting light in different wavelength regions may be to emit white light (e.g., a combined white light).

Between neighboring light emitting structures OL-B1, OL-B2, and OL-B3, charge generating layers CGL1 and CGL2 may be disposed. The charge generating layers CGL1 and CGL2 may include a p-type or kind charge generating layer and/or an n-type or kind charge generating layer.

In one or more embodiments, in at least one selected from among the light emitting structures OL-B1, OL-B2, and OL-B3, included in the display device DD-TD, a polycyclic compound of the present disclosure may be included. For example, at least one selected from among a plurality of emission layers included in the light emitting element ED-BT, a polycyclic compound of the present disclosure may be included.

Referring to FIG. 9, a display device DD-b according to one or more embodiments may include light emitting elements ED-1, ED-2, and ED-3, formed by stacking two emission layers. Compared to the display device DD shown in FIG. 2, the display device DD-b shown in FIG. 9 is different in that first to third light emitting elements ED-1, ED-2, and ED-3 include two emission layers stacked in a thickness direction, each. In the first to third light emitting elements ED-1, ED-2, and ED-3, two emission layers may be to emit light in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. In some embodiments, the emission auxiliary part OG may include an electron transport region, a charge generating layer, and a hole transport region stacked in order (in the stated order). The emission auxiliary part OG may be provided as a common layer in all of the first to third light emitting elements ED-1, ED-2, and ED-3. However, embodiments of the present disclosure are not limited thereto, and the emission auxiliary part OG may be patterned and provided in an opening part OH defined in a pixel definition layer PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, stacked in order (in the stated order). The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in order (in the stated order). The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order (in the stated order).

In some embodiments, an optical auxiliary layer PL may be disposed on a display element layer DP-ED. The optical auxiliary layer PL may include a polarization layer. The optical auxiliary layer PL may be disposed on a display panel DP and may control reflected light at the display panel DP by external light. In one or more embodiments, different from the drawings, the optical auxiliary layer PL may not be provided in the display device.

In one or more embodiments, at least one emission layer included in the display device DD-b, shown in FIG. 9, may include a polycyclic compound of the present disclosure. For example, in one or more embodiments, at least one selected from among the first blue emission layer EML-B1 and the second blue emission layer EML-B2 may include the polycyclic compound of the present disclosure.

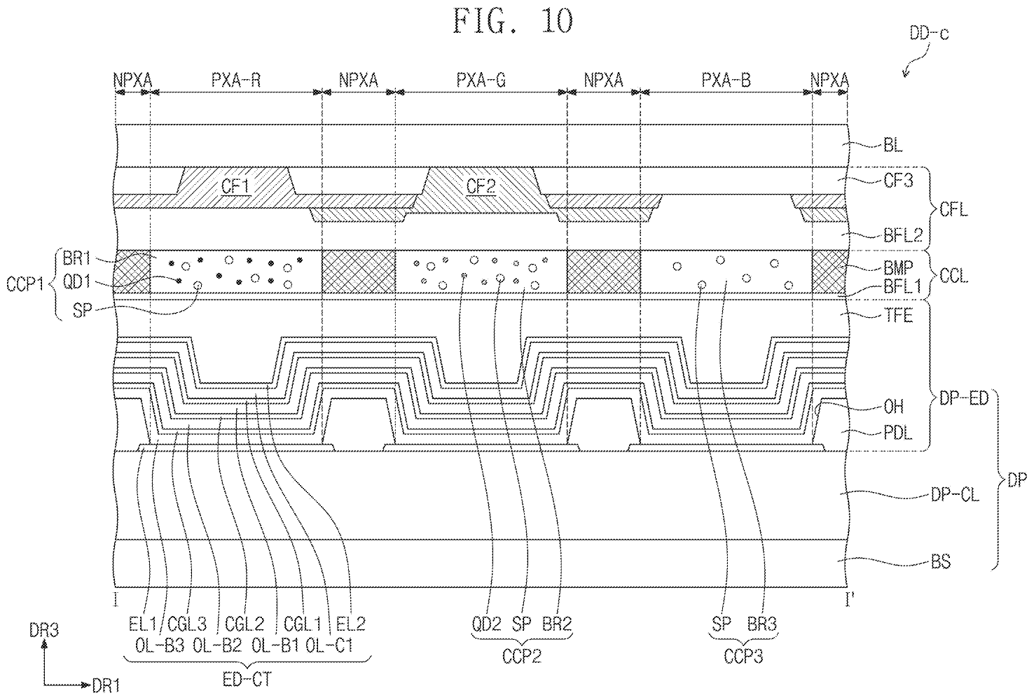

Different from FIG. 8 and FIG. 9, according to one or more embodiments, a display device DD-c shown in FIG. 10 may include four light emitting structures OL-B1, OL-B2, OL-B3, and OL-C1. A light emitting element ED-CT may include oppositely disposed first electrode EL1 and second electrode EL2, and first to fourth light emitting structures OL-B1, OL-B2, OL-B3, and OL-C1 stacked in order (in the stated order) in a thickness direction between the first electrode EL1 and the second electrode EL2. Between the first to fourth light emitting structures OL-B1, OL-B2, OL-B3, and OL-C1, charge generating layers CGL1, CGL2, and CGL3 may be disposed. Among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit different wavelengths of light.

Charge generating layers CGL1, CGL2, and CGL3 disposed among neighboring light emitting structures OL-B1, OL-B2, OL-B3, and OL-C1 may include a p-type or kind charge generating layer and/or an n-type or kind charge generating layer.

In one or more embodiments, in at least one selected from among the light emitting structures OL-B1, OL-B2, OL-B3, and OL-C1, included in the display device DD-c, a polycyclic compound of the present disclosure may be included. For example, in one or more embodiments, at least one selected from among the light emitting structures OL-B1, OL-B2, OL-B3 may include the polycyclic compound of present disclosure.

The light emitting element ED according to one or more embodiments of the present disclosure may include the polycyclic compound of present disclosure in at least one functional layer disposed between the first electrode EL1 and the second electrode EL2 to show excellent or suitable emission efficiency and improved life characteristics. For example, in one or more embodiments, the polycyclic compound of present disclosure may be included in the emission layer EML of the light emitting element ED, and the light emitting element may show high emission efficiency and long-life characteristics concurrently (e.g., simultaneously).

The polycyclic compound of the present disclosure may include a core part of a fused ring including boron, in which an electron donating group of a dibenzoheterole skeleton is bonded at the para position to a boron atom, and may have high stability. In some embodiments, the polycyclic compound of the present disclosure may include an electron donating group of a dibenzoheterole skeleton, bonded to the core part at carbon at position 2 of the dibenzoheterole and introducing a substituent at carbon at position 4 of the dibenzoheterole, and may contribute to the improvement of emission efficiency and lifetime of the light emitting element.

Hereinafter, referring to embodiments and comparative embodiments, the polycyclic compound according to one or more embodiments and the light emitting element according to one or more embodiments of the present disclosure will be explained in more detail. In addition, the embodiments are illustrations to assist the understanding of the present disclosure, but the scope of the present disclosure is not limited thereto.

### EXAMPLES

### 1. Synthesis of Polycyclic Compounds of Embodiments

First, the synthetic method of the polycyclic compound according to one or more embodiments will be explained in more detail illustrating the synthetic methods of Compounds 3, 27, 62, 67, and 88. In addition, the synthetic methods of the polycyclic compounds explained hereinafter are embodiments, and the synthetic method of the polycyclic compound of the present disclosure is not limited to the embodiments.

### (1) Synthesis of Compound 3

Polycyclic Compound 3 according to one or more embodiments may be synthesized, for example, by the steps of Reaction 1.

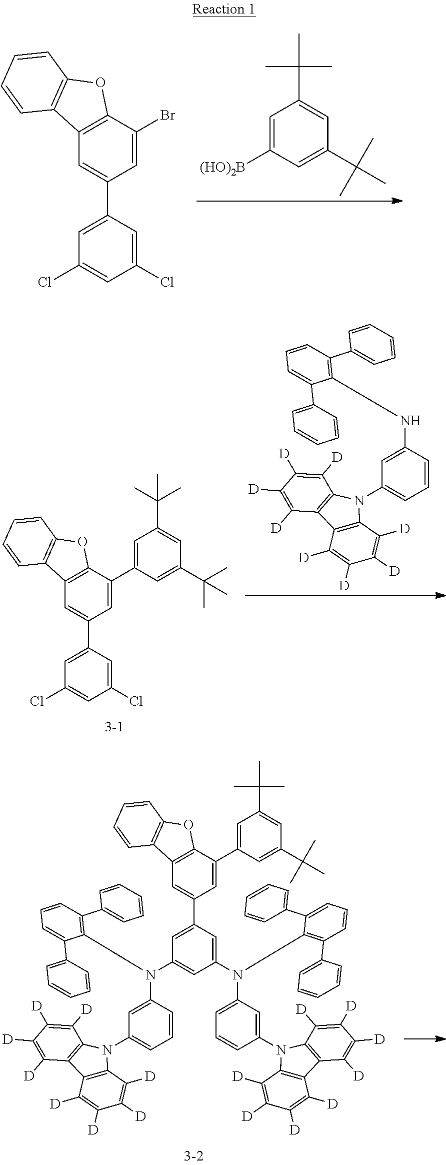

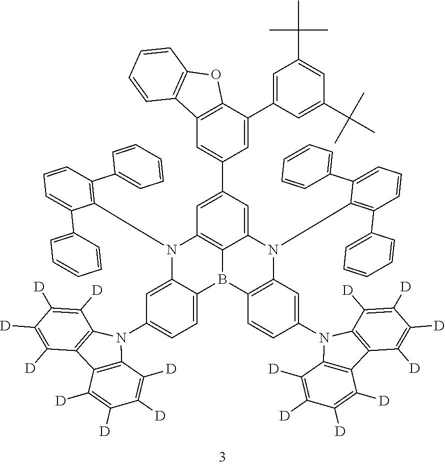

### 1) Synthesis of Intermediate Compound 3-1

4-Bromo-2-(3,5-dichlorophenyl)dibenzo[b,d]furan (1 eq), (3,5-di-tert-butylphenyl)boronic acid (1.2 eq), Pd(PPh₃)₄ (0.05 eq), and K₂CO₃ (3 eq) were dissolved in a mixture solution of water and THF in a ratio (e.g., a volume ratio) of 2:1, and stirred at about 80° C. for about 12 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 3-1 was obtained (yield: 78%).

### 2) Synthesis of Intermediate Compound 3-2

Intermediate Compound 3-1 (1 eq), N-(3-(9H-carbazol-D8-9-yl)phenyl)-[1,1′:3′,1″-terphenyl]-2′-amine (2 eq), tris(dibenzylideneacetone)dipalladium(0) (0.2 eq), tri-tert-butylphosphine (0.4 eq), and sodium tert-butoxide (3 eq) were dissolved in o-xylene, and stirred at about 150° C. for about 36 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 3-2 was obtained (yield: 36%).

### 3) Synthesis of Compound 3

Intermediate Compound 3-2 (1 eq) was dissolved in ortho dichlorobenzene and cooled to about 0° C. Under a nitrogen atmosphere, BBr₃ (5 eq) was slowly injected. After finishing the dropwise addition, the temperature was raised to about 150° C., followed by stirring for about 24 hours. After cooling, triethylamine was slowly and dropwise added to a flask containing the reaction solution to quench the reaction, and ethyl alcohol was added to the reaction solution to precipitate. The precipitate was filtered to obtain a reaction product. The solid thus obtained was purified by column chromatography utilizing methylene chloride (DCM) and n-hexane, and recrystallized utilizing toluene and acetone to obtain Compound 3 (yield: 18%).

### (2) Synthesis of Compound 27

Polycyclic Compound 27 according to one or more embodiments may be synthesized, for example, by the steps of Reaction 2.

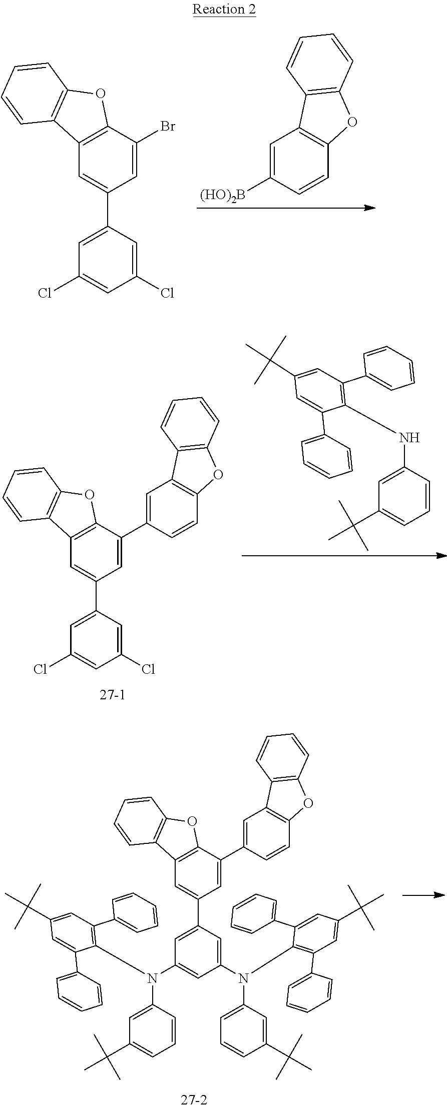

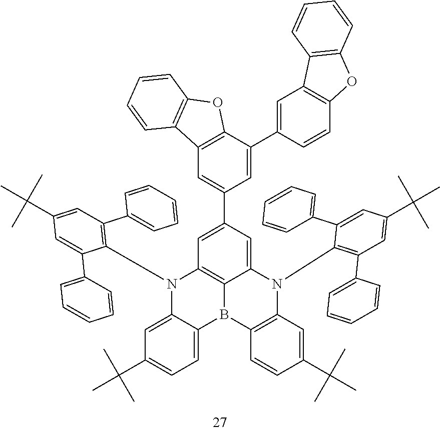

### 1) Synthesis of Intermediate Compound 27-1

4-Bromo-2-(3,5-dichlorophenyl)dibenzo[b,d]furan (1 eq), dibenzo[b,d]furan-2-ylboronic acid (1.3 eq), Pd(PPh₃)₄ (0.05 eq), and K₂CO₃ (3 eq) were dissolved in a mixture solution of water and THE in a ratio (e.g., a volume ratio) of 2:1, and stirred at about 80° C. for about 12 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 27-1 was obtained (yield: 66%).

### 2) Synthesis of Intermediate Compound 27-2

Intermediate Compound 27-1 (1 eq), 5′-(tert-butyl)-N-(3-(tert-butyl)phenyl)-[1,1′:3′,1″-terphenyl]-2′-amine (2 eq), tris(dibenzylideneacetone)dipalladium(0) (0.15 eq), tri-tert-butylphosphine (0.3 eq), and sodium tert-butoxide (3 eq) were dissolved in o-xylene, and stirred at about 150° C. for about 36 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 27-2 was obtained (yield: 32%).

### 3) Synthesis of Compound 27

Intermediate Compound 27-2 (1 eq) was dissolved in ortho dichlorobenzene and cooled to about 0° C. Under a nitrogen atmosphere, BBr₃ (5 eq) was slowly injected. After finishing the dropwise addition, the temperature was raised to about 150° C., followed by stirring for about 24 hours. After cooling, triethylamine was slowly and dropwise added to a flask containing the reaction solution to quench the reaction, and ethyl alcohol was added to the reaction solution to precipitate. The precipitate was filtered to obtain a reaction product. The solid thus obtained was purified by column chromatography utilizing methylene chloride (DCM) and n-hexane, and recrystallized utilizing toluene and acetone to obtain Compound 27 (yield: 21%).

### (3) Synthesis of Compound 62

Polycyclic Compound 62 according to one or more embodiments may be synthesized, for example, by the steps of Reaction 3.

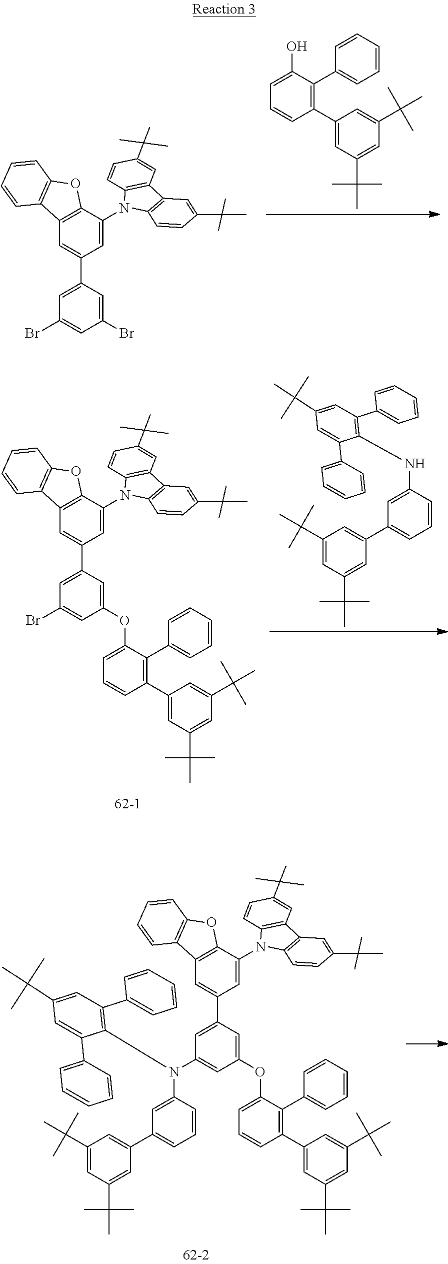

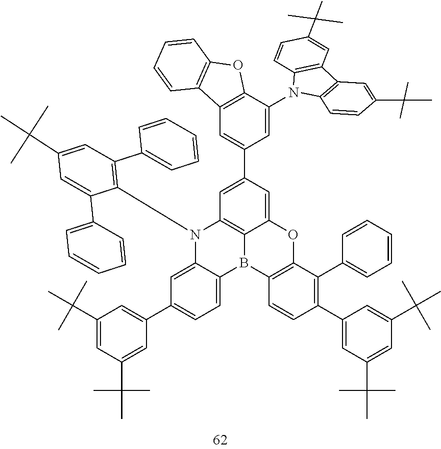 [SMILES: CC(C)(C)c1cc(-c2ccc3c(c2)N(c2c(-c4ccccc4)cc(C(C)(C)C)cc2-c2ccccc2)c2cc(-c4cc(-n5c6ccc(C(C)(C)C)cc6c6cc(C(C)(C)C)ccc65)c5oc6ccccc6c5c4)cc4c2B3c2ccc(-c3cc(C(C)(C)C)cc(C(C)(C)C)c3)c(-c3ccccc3)c2O4)cc(C(C)(C)C)c1]

### 1) Synthesis of Intermediate Compound 62-1

3,6-Di-tert-butyl-9-(2-(3,5-dibromophenyl)dibenzo[b,d]furan-4-yl)-9H-carbazole (1 eq), 3,5-di-tert-butyl-[1,1′:2′,1″-terphenyl]-3′-ol (0.7 eq), CuI (0.1 eq), 1,10-Phen. (0.1 eq), and K₂CO₃ (3 eq) were dissolved in DMF, and stirred at about 160 degrees centigrade for about 12 hours. After cooling, the solvent was removed under a reduced pressure, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 62-1 was obtained (yield: 45%).

### 2) Synthesis of Intermediate Compound 62-2

Intermediate Compound 62-1 (1 eq), 5′-(tert-butyl)-N-(3′,5′-di-tert-butyl-[1,1′-biphenyl]-3-yl)-[1,1′:3′,1″-terphenyl]-2′-amine (1.1 eq), tris(dibenzylideneacetone)dipalladium(0) (0.05 eq), tri-tert-butylphosphine (0.1 eq), and sodium tert-butoxide (3 eq) were dissolved in o-xylene, and stirred at about 150° C. for about 24 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 62-2 was obtained (yield: 47%).

### 3) Synthesis of Compound 62

Intermediate Compound 62-2 (1 eq) was dissolved in ortho dichlorobenzene and cooled to about 0° C. Under a nitrogen atmosphere, BBr₃ (5 eq) was slowly injected. After finishing the dropwise addition, the temperature was raised to about 150° C., followed by stirring for about 24 hours. After cooling, triethylamine was slowly and dropwise added to a flask containing the reaction solution to quench the reaction, and ethyl alcohol was added to the reaction solution to precipitate. The precipitate was filtered to obtain a reaction product. The solid thus obtained was purified by column chromatography utilizing methylene chloride (DCM) and n-hexane, and recrystallized utilizing toluene and acetone to obtain Compound 62 (yield: 14%).

### (4) Synthesis of Compound 67

Polycyclic Compound 67 according to one or more embodiments may be synthesized, for example, by the steps of Reaction 4.

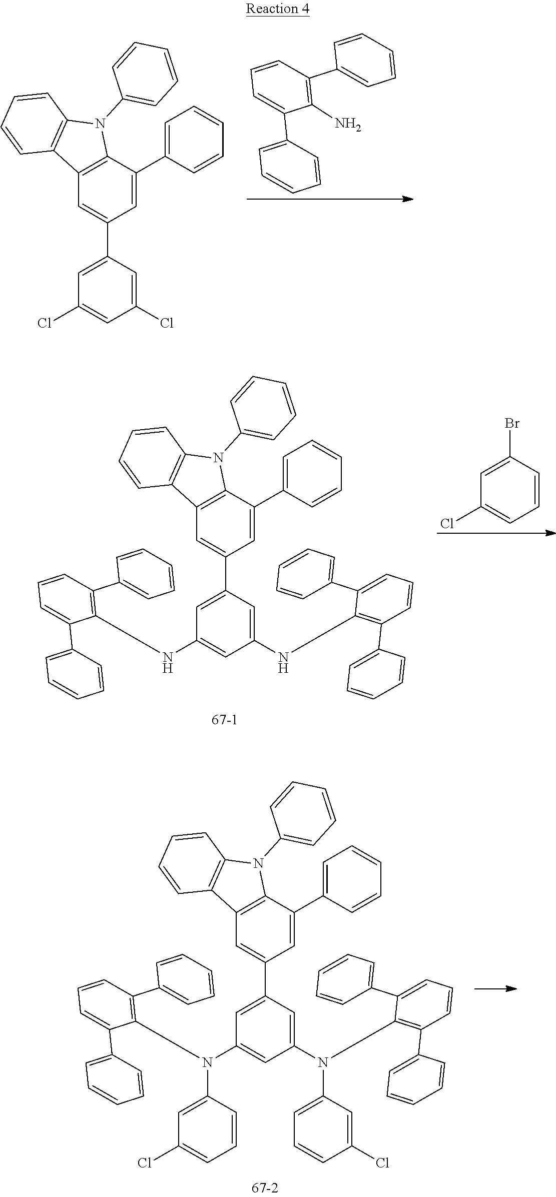

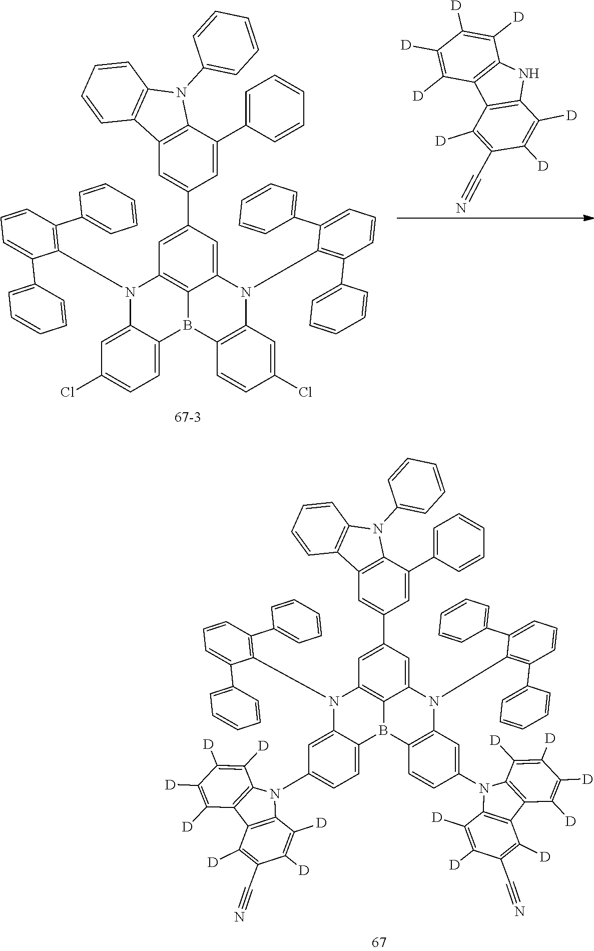

### 5) Synthesis of Intermediate Compound 67-1

3-(3,5-Dichlorophenyl)-1,9-diphenyl-9H-carbazole (1 eq), [1,1′:3′,1″-terphenyl]-2′-amine (2 eq), tris(dibenzylideneacetone)dipalladium(0) (0.1 eq), tri-tert-butylphosphine (0.2 eq), and sodium tert-butoxide (3 eq) were dissolved in o-xylene, and stirred at about 150° C. for about 36 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 67-1 was obtained (yield: 71%).

### 2) Synthesis of Intermediate Compound 67-2

Intermediate Compound 67-1 (1 eq), 1-bromo-3-chlorobenzene (3 eq), tris(dibenzylideneacetone)dipalladium(0) (0.1 eq), tri-tert-butylphosphine (0.2 eq), and sodium tert-butoxide (3 eq) were dissolved in o-xylene, and stirred at about 150° C. for about 24 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 67-2 was obtained (yield: 44%).

### 3) Synthesis of Intermediate Compound 67-3

Intermediate Compound 67-2 (1 eq) was dissolved in ortho dichlorobenzene and cooled to about 0° C. Under a nitrogen atmosphere, BBr₃ (5 eq) was slowly injected. After finishing the dropwise addition, the temperature was raised to about 150° C., followed by stirring for about 24 hours. After cooling, triethylamine was slowly and dropwise added to a flask containing the reaction solution to quench the reaction, and ethyl alcohol was added to the reaction solution to precipitate. The precipitate was filtered to obtain a reaction product. The solid thus obtained was purified by column chromatography utilizing methylene chloride (DCM) and n-hexane, and recrystallized utilizing toluene and acetone to obtain Intermediate Compound 67-3 (yield: 12%).

### 4) Synthesis of Compound 67

Intermediate Compound 67-3 (1 eq), 9H-carbazole-3-carbonitrile-D7 (2.1 eq), tris(dibenzylideneacetone)dipalladium(0) (0.15 eq), tri-tert-butylphosphine (0.30 eq), and sodium tert-butoxide (3 eq) were dissolved in o-xylene, and stirred at about 150° C. for about 24 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Compound 67 was obtained (yield: 47%).

### (5) Synthesis of Compound 88

Polycyclic Compound 88 according to one or more embodiments may be synthesized, for example, by the steps of Reaction 5.

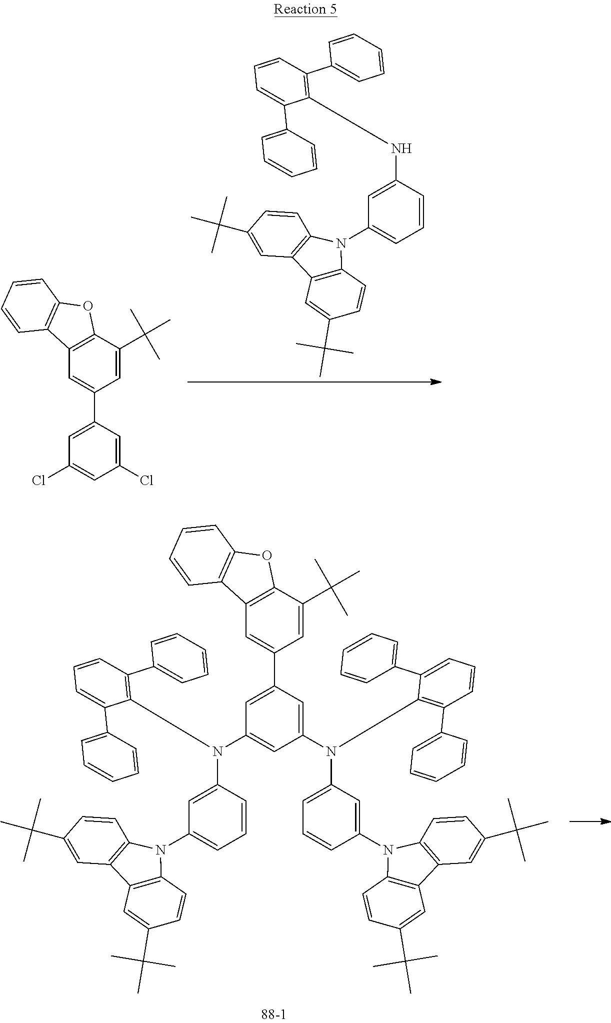

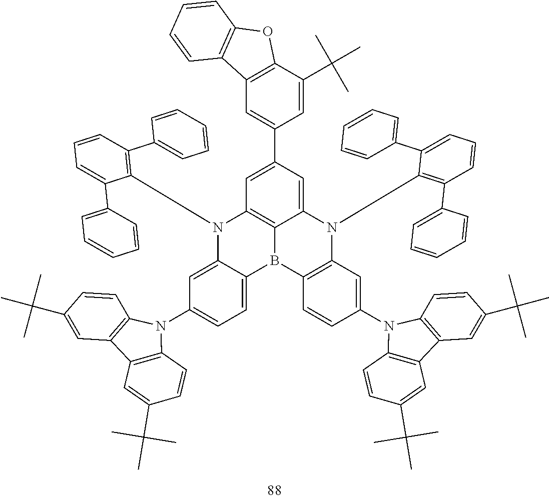

### 1) Synthesis of Intermediate Compound 88-1

4-(Tert-butyl)-2-(3,5-dichlorophenyl)dibenzo[b,d]furan (1 eq), N-(3-(3,6-di-tert-butyl-9H-carbazol-9-yl)phenyl)-[1,1′:3′,1″-terphenyl]-2′-amine (2 eq), tris(dibenzylideneacetone)dipalladium(0) (0.15 eq), tri-tert-butylphosphine (0.3 eq), and sodium tert-butoxide (3 eq) were dissolved in o-xylene, and stirred at about 150° C. for about 24 hours. After cooling, the resultant was washed with ethyl acetate and water three times, and an organic layer obtained by layer separation was dried over MgSO₄, and dried under a reduced pressure. Through purification by column chromatography utilizing methylene chloride (DCM) and n-hexane, Intermediate Compound 88-1 was obtained (yield: 36%).

### 2) Synthesis of Compound 88

Intermediate Compound 88-1 (1 eq) was dissolved in ortho dichlorobenzene and cooled to about 0° C. Under a nitrogen atmosphere, BBr₃ (5 eq) was slowly injected. After finishing the dropwise addition, the temperature was raised to about 150° C., followed by stirring for about 24 hours. After cooling, triethylamine was slowly and dropwise added to a flask containing the reaction solution to quench the reaction, and ethyl alcohol was added to the reaction solution to precipitate. The precipitate was filtered to obtain a reaction product. The solid thus obtained was purified by column chromatography utilizing methylene chloride (DCM) and n-hexane, and recrystallized utilizing toluene and acetone to obtain Compound 88 (yield: 16%).

¹H NMR and MS of Compounds 3, 27, 62, 67, and 88 are shown in Table 1. Synthesis methods of compounds other than Compounds shown in Table 1 may also be easily recognized by those of ordinary skill in the art by referring to the synthesis mechanisms and source materials described above.

TABLE 1

| Compound | ¹H NMR (ppm) | MS-Cal | MS-Meas. |
|---|---|---|---|
| 3 | 8.53-8.47 (2H, d), 7.99-7.93 (2H, m), 7.82-7.78 | 1425.660 | 1425.652 |
| | (2H, m)7.63-7.55 (10H, m), 7.52-7.36 (11H, m), | | |
| | 7.34-7.30 (4H, t) 7.16-7.06 (6H, d), 6.83-6.77 | | |
| | (4H, m), 6.62-6.55 (2H, s) 1.47-1.43 (18H, s) | | |
| 27 | 8.61-8.56 (2H, d), 7.97-7.92 (4H, m), 7.63-7.58 | 1281.472 | 1281.466 |
| | (12H, m)7.54-7.47 (11H, m), 7.43-7.33 (6H, m), | | |
| | 7.15-7.09 (6H, d) 6.87-6.84 (2H, m), 6.63-6.58 | | |
| | (2H, m), 1.59-1.56 (18H, s) 1.53-1.49 (18H, s) | | |
| 62 | 8.83-8.79 (1H, d), 8.70-8.66 (1H, d), 8.10-8.09 | 1449.791 | 1449.780 |
| | (2H, s) 7.99-7.93 (2H, m), 7.82-7.78 (4H, s), | | |
| | 7.62-7.55 (6H, d) 7.53-7.41 (12H, m), 7.38-7.31 | | |
| | (7H, m), 7.25-7.21 (1H, d) 7.17-7.12 (3H, m), | | |
| | 6.99-6.85 (1H, m), 6.82-6.77 (1H, s) 6.63-6.55 | | |
| | (1H, s), 1.57-1.42 (27H, m), 1.47-1.43 (36H, m) | | |
| 67 | 8.55-8.48 (2H, d), 8.11-8.07 (6H, m), 7.60-7.48 | 1436.565 | 1436.559 |
| | (13H, d) 7.46-7.36 (20H, m), 7.34-7.30 (4H, t), | | |
| | 7.25-7.17 (5H, m) 7.15-7.06 (6H, d), 6.89-6.77 | | |
| | (4H, m), 6.64-6.60 (2H, s) | | |
| 88 | 8.53-8.47 (2H, d), 8.12-8.09 (4H, m), 7.97-7.93 | 1501.784 | 1501.777 |
| | (2H, m) 7.63-7.55 (10H, m), 7.52-7.44 (13H, m), | | |
| | 7.42-7.31 (9H, m) 7.18-7.12 (6H, d), 6.83-6.77 | | |
| | (4H, m), 6.62-6.55 (2H, s) 1.57-1.50 (36H, m), | | |
| | 1.48-1.44 (18H, s) | | |

### 2. Example Compounds and Comparative Compounds

The Example Compounds and Comparative Compounds utilized for the manufacture of the light emitting elements of the Examples and Comparative Examples are shown in Table 2.

TABLE 2

| | |
|---|---|
| Compound 3 | 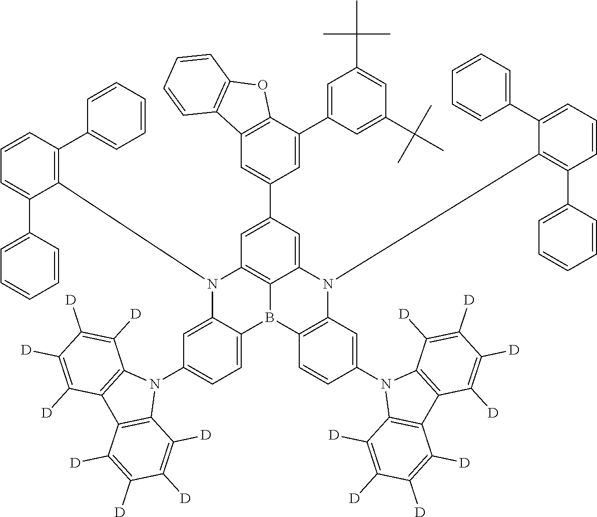 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4cc(C(C)(C)C)cc(C(C)(C)C)c4)c4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1] |
| Compound 27 | 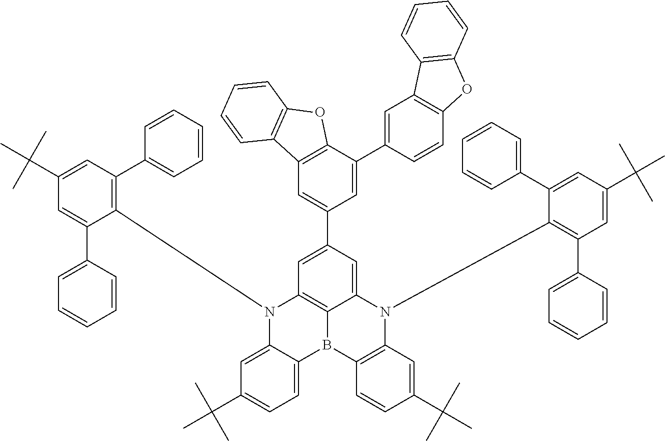 [SMILES: CC(C)(C)c1cc(-c2ccccc2)c(N2c3cc(C(C)(C)C)ccc3B3c4ccc(C(C)(C)C)cc4N(c4c(-c5ccccc5)cc(C(C)(C)C)cc4-c4ccccc4)c4cc(-c5cc(-c6ccc7oc8ccccc8c7c6)c6oc7ccccc7c6c5)cc2c43)c(-c2ccccc2)c1] |
| Compound 62 | 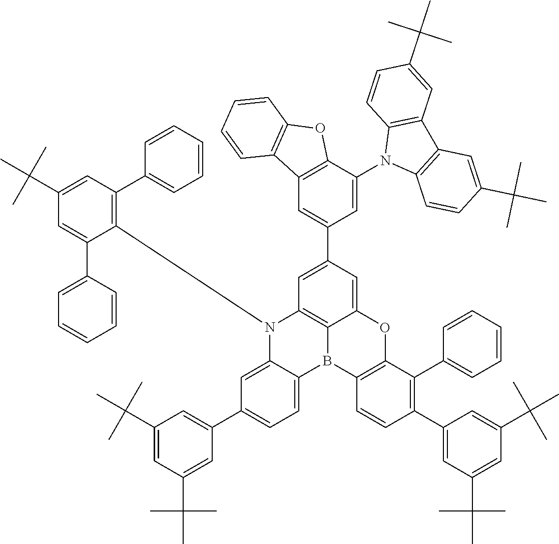 [SMILES: CC(C)(C)c1cc(-c2ccc3c(c2)N(c2c(-c4ccccc4)cc(C(C)(C)C)cc2-c2ccccc2)c2cc(-c4cc(-n5c6ccc(C(C)(C)C)cc6c6cc(C(C)(C)C)ccc65)c5oc6ccccc6c5c4)cc4c2B3c2ccc(-c3cc(C(C)(C)C)cc(C(C)(C)C)c3)c(-c3ccccc3)c2O4)cc(C(C)(C)C)c1] |
| Compound 67 | 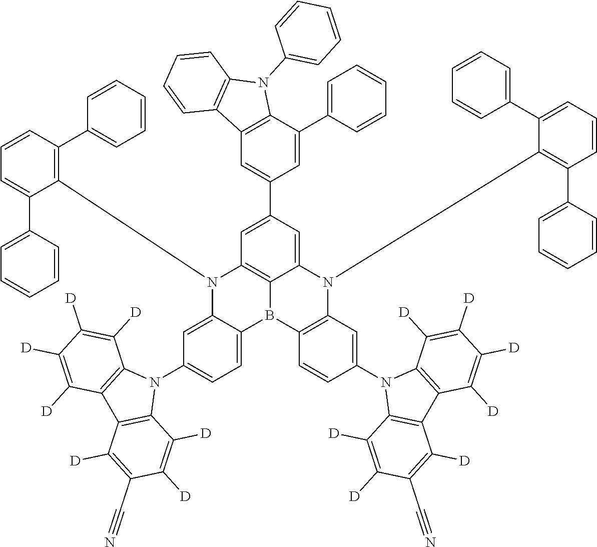 [SMILES: [2H]c1c([2H])c([2H])c2c(c1[2H])c1c([2H])c(C#N)c([2H])c([2H])c1n2-c1ccc2c(c1)N(c1c(-c3ccccc3)cccc1-c1ccccc1)c1cc(-c3cc(-c4ccccc4)c4c(c3)c3ccccc3n4-c3ccccc3)cc3c1B2c1ccc(-n2c4c([2H])c([2H])c([2H])c([2H])c4c4c([2H])c(C#N)c([2H])c([2H])c42)cc1N3c1c(-c2ccccc2)cccc1-c1ccccc1] |
| Compound 88 | 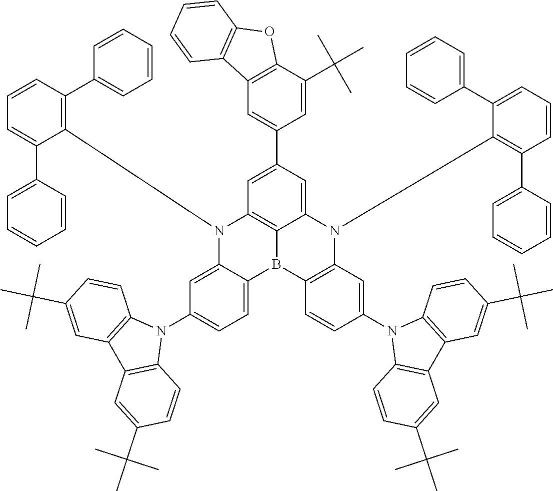 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3cc(C(C)(C)C)c4oc5ccccc5c4c3)cc3c1B2c1ccc(-n2c4ccc(C(C)(C)C)cc4c4cc(C(C)(C)C)ccc42)cc1N3c1c(-c2ccccc2)cccc1-c1ccccc1] |
| Comparative Compound C1 | 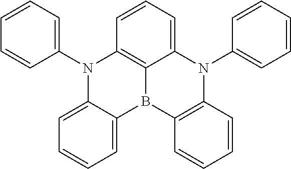 [SMILES: c1ccc(N2c3ccccc3B3c4ccccc4N(c4ccccc4)c4cccc2c43)cc1] |
| Comparative Compound C2 | 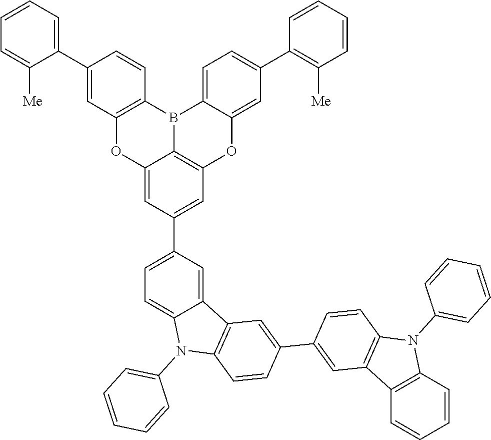 [SMILES: Cc1ccccc1-c1ccc2c(c1)Oc1cc(-c3ccc4c(c3)c3cc(-c5ccc6c(c5)c5ccccc5n6-c5ccccc5)ccc3n4-c3ccccc3)cc3c1B2c1ccc(-c2ccccc2C)cc1O3] |
| Comparative Compound C3 | 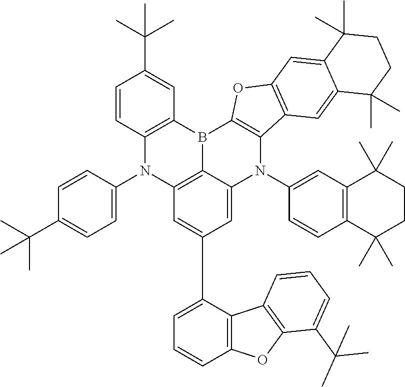 [SMILES: CC(C)(C)c1ccc(N2c3ccc(C(C)(C)C)cc3B3c4oc5cc6c(cc5c4N(c4ccc5c(c4)C(C)(C)CCC5(C)C)c4cc(-c5cccc7oc8c(C(C)(C)C)cccc8c57)cc2c43)C(C)(C)CCC6(C)C)cc1] |

### 3. Manufacture and Evaluation of Light Emitting Elements

### (1) Manufacture of Light Emitting Elements

Light emitting elements were manufactured utilizing the Example Compounds and Comparative Compounds as dopant materials of an emission layer.

A glass substrate (a product of Corning Co.) on which an ITO electrode of 15 Ω/cm² (1200 Å) was formed, was cut into a size of 50 mm×50 mm×0.7 mm as an anode, and washed utilizing ultrasonic waves utilizing isopropyl alcohol and pure water for about 5 minutes each, and cleansed by irradiating ultraviolet for about 30 minutes and exposing to ozone. The glass substrate was installed on a vacuum deposition apparatus.

On the anode, NPD was deposited to form a hole injection layer with a thickness of about 300 Å, on the hole injection layer, H-1-1 was deposited to form a hole transport layer with a thickness of about 200 Å, and on the hole transport layer, CzSi was deposited to form an emission auxiliary layer with a thickness of about 100 Å.

On the emission auxiliary layer, a host mixture, a phosphorescence sensitizer, and the dopant of the Example Compound or Comparative Compound were co-deposited in a weight ratio of about 85:14:1 to form an emission layer with a thickness of about 200 Å. The host mixture was provided by mixing a first host (HT1, HT2, HT3, HT4) and a second host (EHT85, EHT66, EHT86) in weight ratio of about 5:5, as shown in Table 3. The phosphorescence sensitizer utilized PS1 or PS2, as shown in Table 3.

After that, on the emission layer, TSPO1 was deposited to form a hole blocking layer with a thickness of about 200 Å, and on the hole blocking layer, TPBI was deposited to form an electron transport layer with a thickness of about 300 Å. On the electron transport layer, LiF was deposited to form an electron injection layer with a thickness of about 10 Å, and on the electron injection layer, Al was deposited to form a cathode with a thickness of about 3000 Å, to form a light emitting element.

The compounds utilized for the manufacture of the light emitting element are as follows.

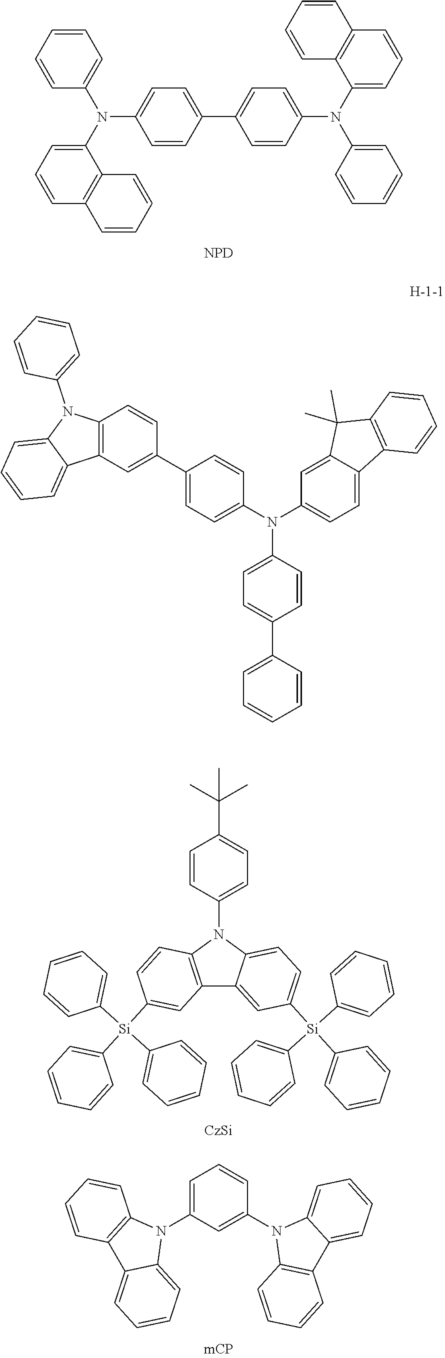

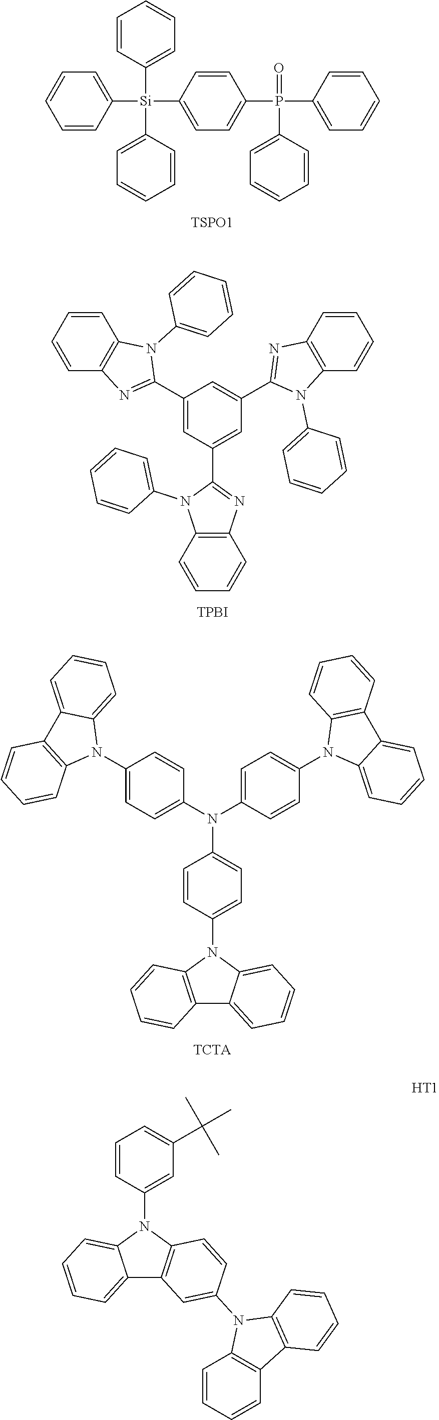

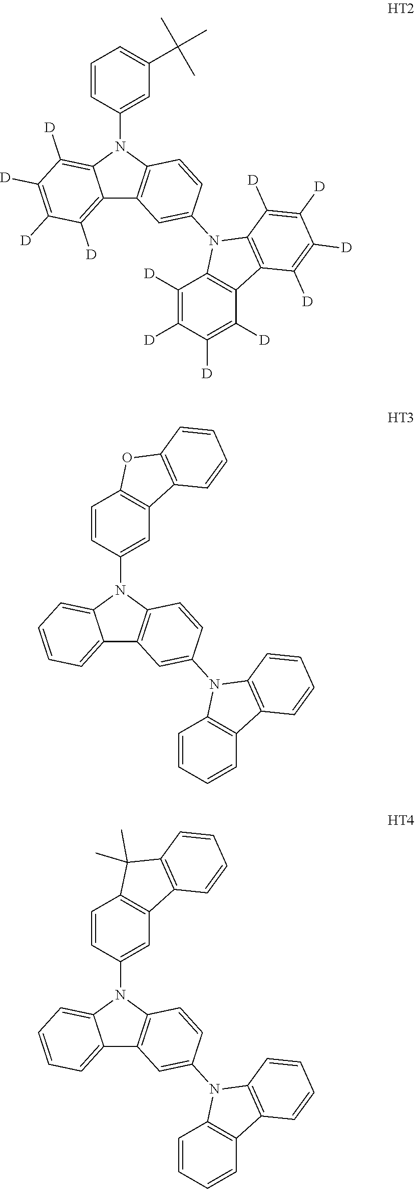 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21]

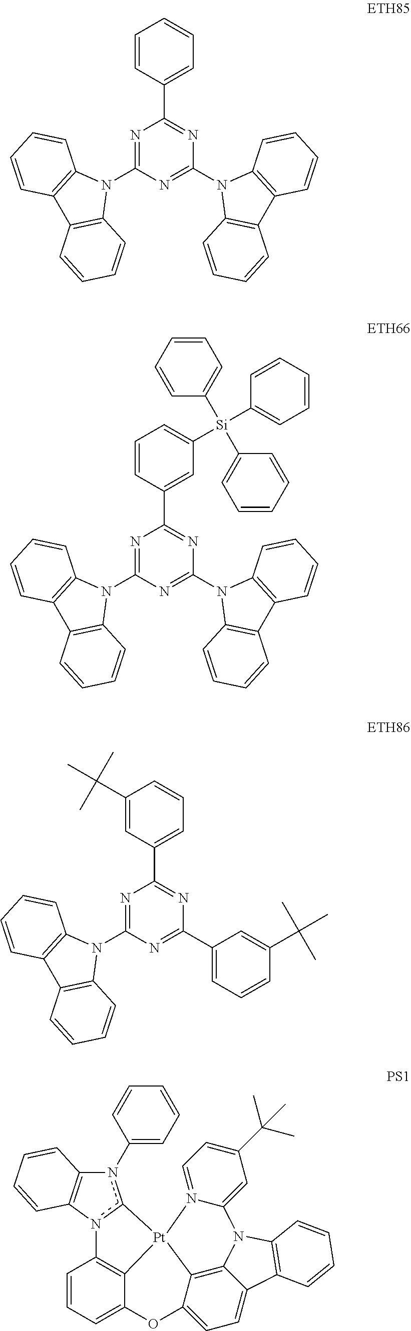

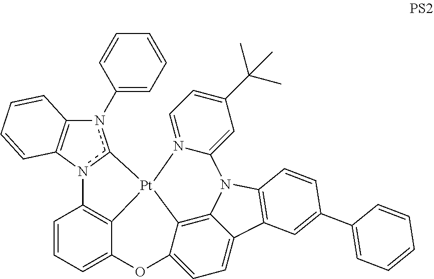

### (2) Evaluation of Light Emitting Elements

In Table 3, the driving voltage (V), emission efficiency (cd/A), emission wavelength (nm) and element lifetime were evaluated for the light emitting elements of Examples 1 to 11, and Comparative Examples 1 to 6, and the results are shown. In the evaluation results on the properties of the light emitting elements of the Examples and Comparative Examples, the driving voltage (V), emission efficiency (cd/A), and emission wavelength at a current density of about 1000 cd/m² were measured utilizing Keithley MU 236 and luminance meter PR650. The lifetime ratio (T95) was obtained by measuring a time consumed to reach about 95% luminance in contrast to an initial luminance and calculating as a relative lifetime based on Comparative Example 2, and the results are shown.

TABLE 3

| | Exciplex | | | | | | |
|---|---|---|---|---|---|---|---|
| | host | | | Driving | | Emission | Lifetime |
| | (HT:ET = | Phosphorescence | | voltage | Efficiency | wavelength | ratio |
| | 5:5) | sensitizer | Dopant | (V) | (cd/A) | (nm) | (T95) |
| Example 1 | HT2/ET2 | PS2 | 3 | 4.3 | 27.4 | 459 | 6.5 |
| Example 2 | HT2/ET2 | PS2 | 27 | 4.5 | 25.1 | 457 | 6.2 |
| Example 3 | HT2/ET2 | PS2 | 62 | 4.4 | 26.5 | 462 | 5.7 |
| Example 4 | HT2/ET2 | PS2 | 67 | 4.3 | 27.0 | 461 | 5.5 |
| Example 5 | HT2/ET2 | PS2 | 88 | 4.4 | 26.1 | 460 | 5.9 |
| Example 6 | HT3/ET3 | PS1 | 3 | 4.4 | 26.5 | 460 | 6.2 |
| Example 7 | HT3/ET3 | PS1 | 62 | 4.3 | 26.4 | 462 | 5.5 |
| Example 8 | HT1/ET3 | PS1 | 27 | 4.2 | 26.0 | 460 | 6.9 |
| Example 9 | HT1/ET3 | PS1 | 67 | 4.2 | 26.7 | 461 | 6.2 |
| Example 10 | HT4/ET1 | PS2 | 27 | 4.2 | 25.8 | 461 | 6.3 |
| Example 11 | HT4/ET1 | PS2 | 88 | 4.3 | 27.1 | 461 | 5.7 |
| Comparative | HT2/ET2 | X | C1 | 5.5 | 12.8 | 458 | — |
| Example 1 | | | | | | | |
| Comparative | HT2/ET2 | PS2 | C1 | 5.3 | 14.8 | 464 | 1.0 |
| Example 2 | | | | | | | |
| Comparative | HT2/ET2 | X | C2 | 5.6 | 9.7 | 455 | — |
| Example 3 | | | | | | | |
| Comparative | HT2/ET2 | PS2 | C2 | 5.0 | 15.6 | 462 | 2.3 |
| Example 4 | | | | | | | |
| Comparative | HT2/ET2 | X | C3 | 5.2 | 10.9 | 466 | — |
| Example 5 | | | | | | | |
| Comparative | HT2/ET2 | PS2 | C3 | 4.9 | 16.2 | 464 | 1.8 |
| Example 6 | | | | | | | |

Referring to the results of Table 3, it can be seen that the light emitting elements of Examples 1 to 11 exhibit long lifetime and high emission efficiency properties as well as low driving voltage properties when compared to the light emitting elements of Comparative Examples 1 to 6. Therefore, when the polycyclic compound of the present disclosure is utilized in an emission layer of a light emitting element, element properties, in terms of driving voltage, emission efficiency, and lifetime, of the light emitting element are markedly improved.

The polycyclic compound of the present disclosure includes a core part of a fused ring in which an electron donating group of a dibenzoheterole skeleton is bonded at the para position to a boron atom, and may have high stability. In some embodiments, the polycyclic compound includes an electron donating group of a dibenzoheterole skeleton, bonded to the core part at carbon at position 2 of the dibenzoheterole and introducing a substituent at carbon at position 4 of the dibenzoheterole, and may contribute to the improvement of emission efficiency and lifetime.

In contrast, when Comparative Compounds C1 to C3 utilized in Comparative Examples 1 to 6 were utilized as the materials of an emission layer, degraded emission efficiency and life characteristics were shown, and relatively high driving voltage properties were shown in contrast to the Examples.

The light emitting element according to one or more embodiments includes a polycyclic compound of the present disclosure in an emission layer and may show high emission efficiency and long-life characteristics.

The polycyclic compound of present disclosure includes a boron-containing core part and an electron donating group of a dibenzoheterole skeleton, and may contribute to the increase of the lifetime and emission efficiency of a light emitting element.

As used herein, the term “substantially,” “about,” and similar terms are used as terms of approximation and not as terms of degree, and are intended to account for the inherent deviations in measured or calculated values that would be recognized by those of ordinary skill in the art. “About”, “substantially,” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed and equivalents thereof.

What is claimed is:

1. A light emitting element comprising:
a first electrode;
a second electrode on the first electrode; and
an emission layer between the first electrode and the second electrode,
wherein the emission layer comprises:
a first compound represented by Formula 1; and
at least one selected from among a second compound represented by Formula HT-1, a third compound represented by Formula ET-1, and a fourth compound represented by Formula M-b: 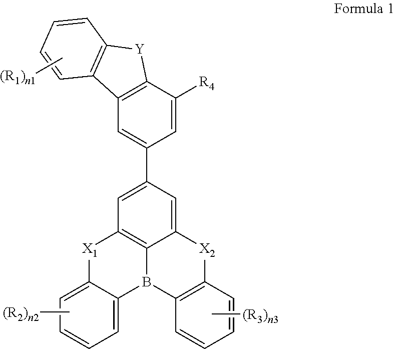
in Formula 1,
R₁ to R₃ are each independently selected from hydrogen, deuterium, a cyano group, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
R₄ is selected from a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
X₁ and X₂ are each independently selected from NRₓ and O,
Y is NR_{y} or O,
Rₓ and R_{y} are each independently selected from a substituted or unsubstituted aryl group of 6 to 30 ring-forming carbon atoms and a substituted or unsubstituted heteroaryl group of 2 to 30 ring-forming carbon atoms, and
n1 to n3 are each independently an integer of 0 to 4: 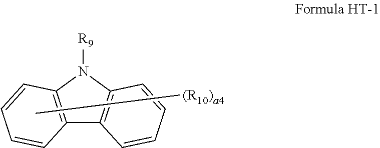
in Formula HT-1,
a4 is an integer of 0 to 8, and
R₉ and R₁₀ are each independently selected from hydrogen, deuterium, a substituted or unsubstituted aryl group of 6 to 60 ring-forming carbon atoms, and a substituted or unsubstituted heteroaryl group of 2 to 60 ring-forming carbon atoms: 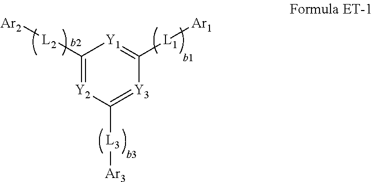
in Formula ET-1,
at least one selected from among Y₁ to Y₃ is N, and the remainder are CRₐ,
Rₐ is selected from hydrogen, deuterium, a substituted or unsubstituted alkyl group of 1 to 20 carbon atoms, a substituted or unsubstituted aryl group of 6 to 60 ring-forming carbon atoms, and a substituted or unsubstituted heteroaryl group of 2 to 60 ring-forming carbon atoms,
b1 to b3 are each independently an integer of 0 to 10,
L₁ to L₃ are each independently selected from a direct linkage, a substituted or unsubstituted arylene group of 6 to 30 ring-forming carbon atoms, and a substituted or unsubstituted heteroarylene group of 2 to 30 ring-forming carbon atoms, and
Ar₁ to Ar₃ are each independently selected from hydrogen, deuterium, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms: 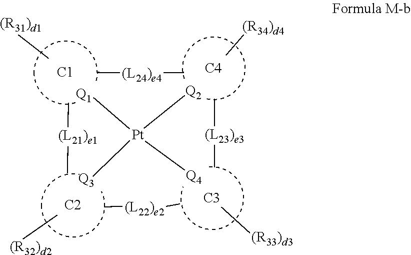
in Formula M-b,
Q₁ to Q₄ are each independently selected from C and N,
C1 to C4 are each independently selected from a substituted or unsubstituted hydrocarbon ring of 5 to 30 ring-forming carbon atoms and a substituted or unsubstituted heterocyclic group of 2 to 30 ring-forming carbon atoms,
e1 to e4 are each independently 0 or 1,
L₂₁ to L₂₄ are each independently selected from a direct linkage, 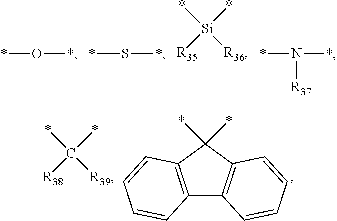
a substituted or unsubstituted divalent alkyl group of 1 to 20 carbon atoms, a substituted or unsubstituted arylene group of 6 to 30 ring-forming carbon atoms, and a substituted or unsubstituted heteroarylene group of 2 to 30 ring-forming carbon atoms,
d1 to d4 are each independently an integer of 0 or 4, and
R₃₁ to R₃₉ are each independently selected from hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, and a substituted or unsubstituted heteroaryl group of 2 to 30 ring-forming carbon atoms, and/or combined with an adjacent group to form a ring.

2. The light emitting element of claim 1, wherein at least one selected from among X₁ and X₂ is NRₓ.

3. The light emitting element of claim 1, wherein the first compound represented by Formula 1 is represented by Formula 2: 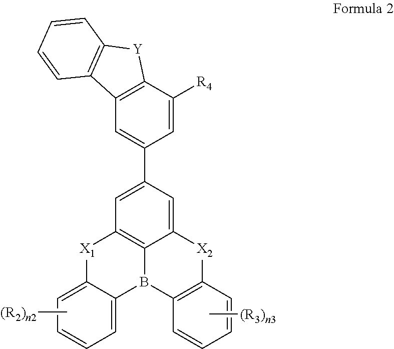
in Formula 2, R₂, R₃, R₄, X₁, X₂, Y, n2, and n3 are the same as defined in Formula 1.

4. The light emitting element of claim 1, wherein the first compound represented by Formula 1 is represented by Formula 3-1 or Formula 3-2: 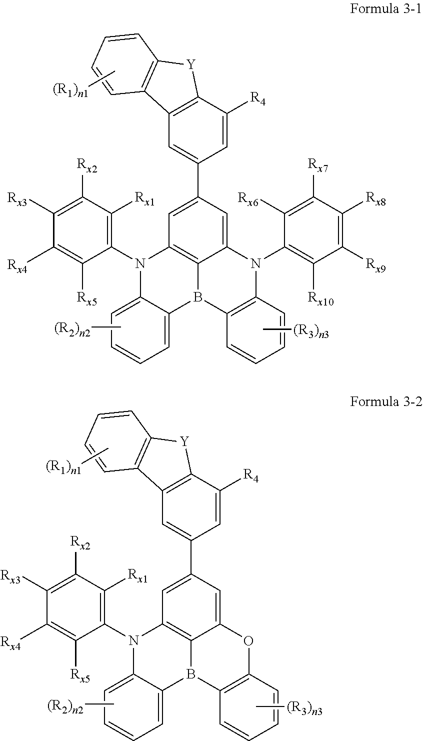
in Formula 3-1 and Formula 3-2,
Rₓ₁ to Rₓ₁₀ are each independently selected from hydrogen, deuterium, a substituted or unsubstituted alkyl group of 1 to 20 carbon atoms, and a substituted or unsubstituted aryl group of 6 to 20 ring-forming carbon atoms, and
R₁ to R₄, Y, and n1 to n3 are the same as defined in Formula 1.

5. The light emitting element of claim 4, wherein the first compound represented by Formula 3-1 is represented by Formula 3-1-1 or Formula 3-1-2: 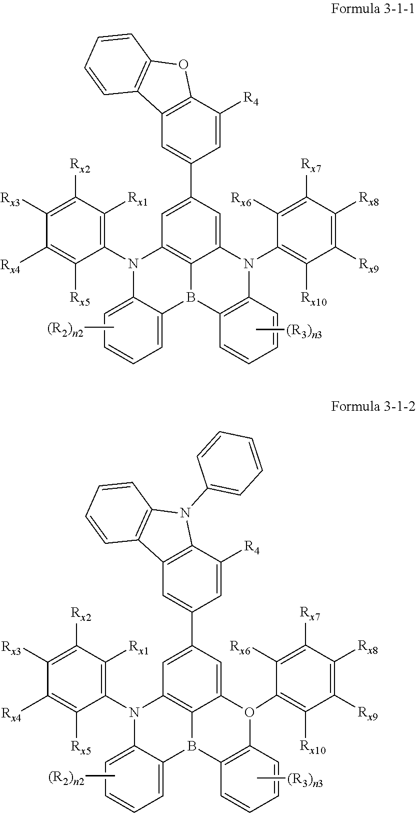
in Formula 3-1-1 and Formula 3-1-2,
R₂ to R₄, n2, and n3 are the same as defined in Formula 1, and
Rₓ₁ to Rₓ₁₀ are the same as defined in Formula 3-1.

6. The light emitting element of claim 4, wherein the first compound represented by Formula 3-2 is represented by Formula 3-2-1 or Formula 3-2-2: 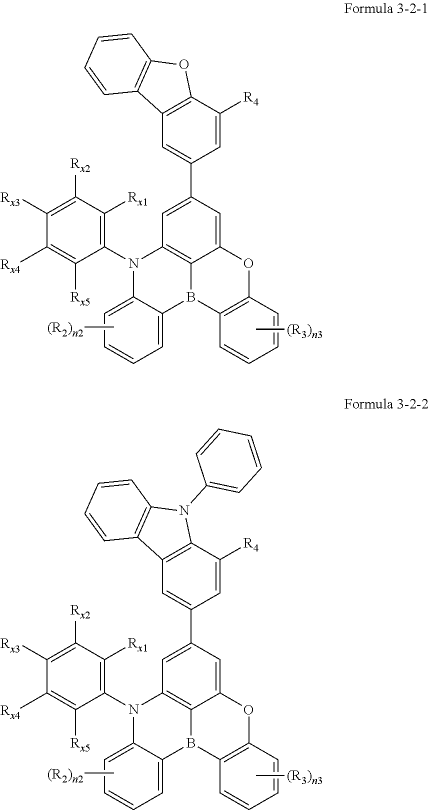
in Formula 3-2-1 and Formula 3-2-2,
R₂ to R₄, n2, and n3 are the same as defined in Formula 1, and
Rₓ₁ to Rₓ₅ are the same as defined in Formula 3-2.

7. The light emitting element of claim 1, wherein the first compound represented by Formula 1 is represented by any one selected from among Formula 4-1 to Formula 4-3: 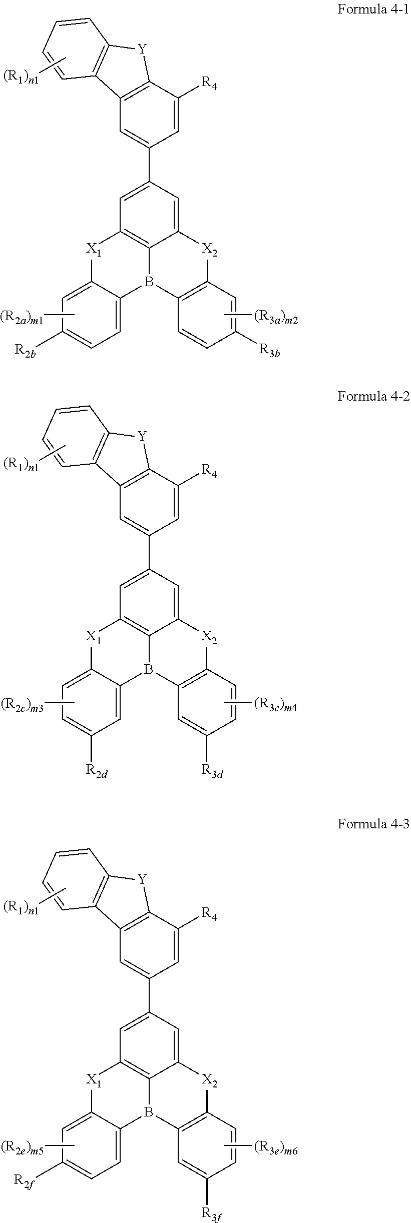
in Formula 4-1 to Formula 4-3,
R₂ₐ, R₃ₐ, R_{2c}, R_{3c}, R₂ₑ, and R₃ₑ are each independently selected from hydrogen, deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
R_{2b}, R_{3b}, R_{2d}, R_{3d}, R_{2f}, and R_{3f} are each independently selected from deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
m1 to m6 are each independently an integer of 0 to 3, and
R₁, R₄, X₁, X₂, Y, and n1 are the same as defined in Formula 1.

8. The light emitting element of claim 1, wherein R₂ and R₃ are each independently selected from hydrogen, deuterium, a substituted or unsubstituted t-butyl group, a substituted or unsubstituted phenyl group, a substituted or unsubstituted carbazole group, and a substituted or unsubstituted dibenzofuran group.

9. The light emitting element of claim 1, wherein R₄ is selected from a substituted or unsubstituted t-butyl group, a substituted or unsubstituted phenyl group, a substituted or unsubstituted carbazole group, a substituted or unsubstituted dibenzofuran group, and a substituted or unsubstituted tetralinyl group.

10. The light emitting element of claim 1, wherein the emission layer comprises the first compound, the second compound, and the third compound.

11. The light emitting element of claim 1, wherein the emission layer comprises the first compound, the second compound, the third compound, and the fourth compound.

12. The light emitting element of claim 1, wherein the emission layer is to emit thermally activated delayed fluorescence.

13. The light emitting element of claim 1, wherein the emission layer is to emit light having an emission center wavelength of about 430 nm to about 490 nm.

14. The light emitting element of claim 1, wherein Formula 1 is represented by any one selected from among compounds in Compound Group 1:
Compound Group 1

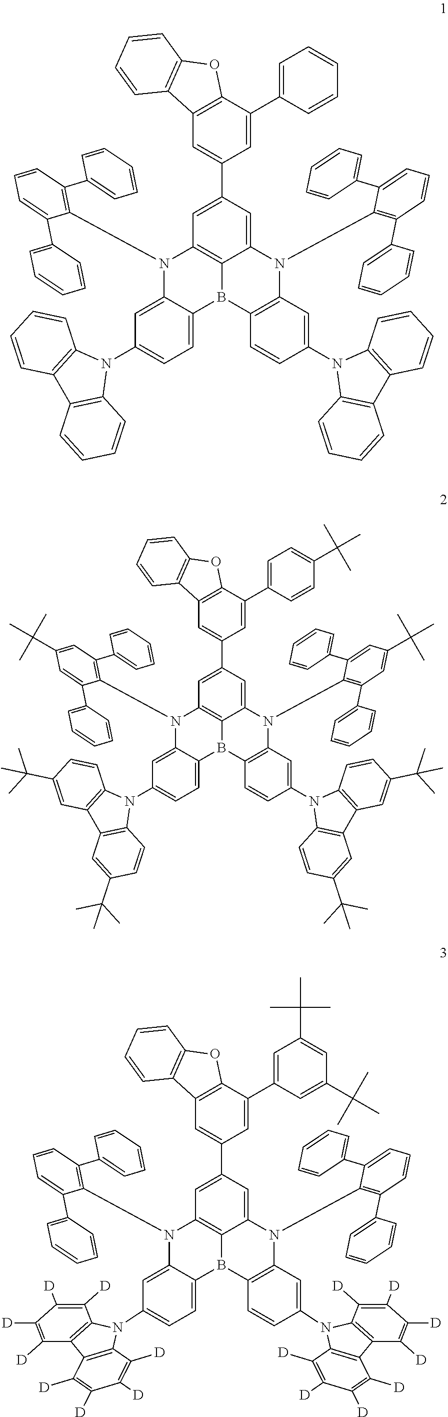

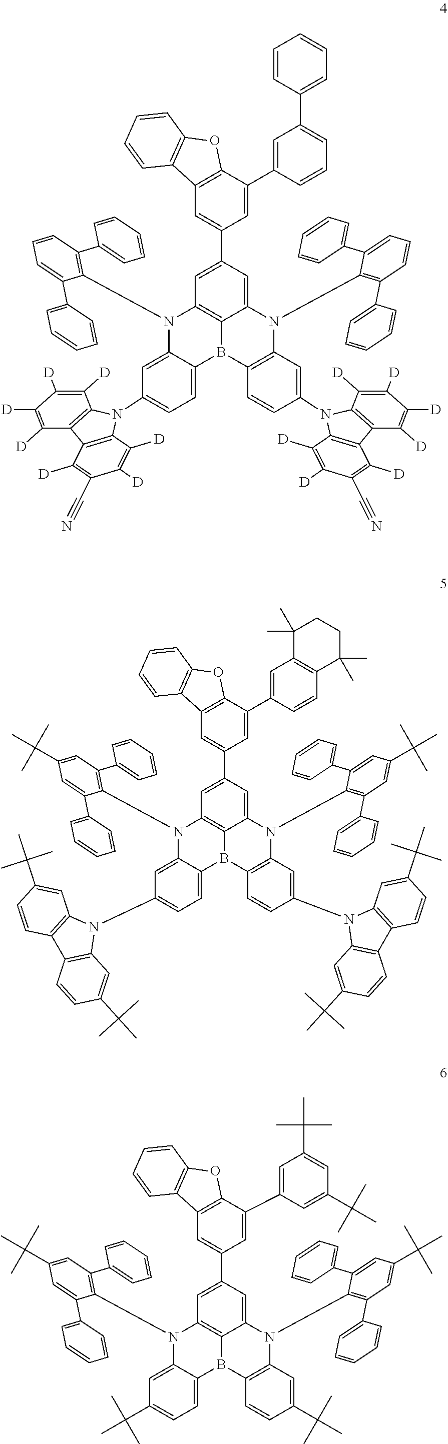

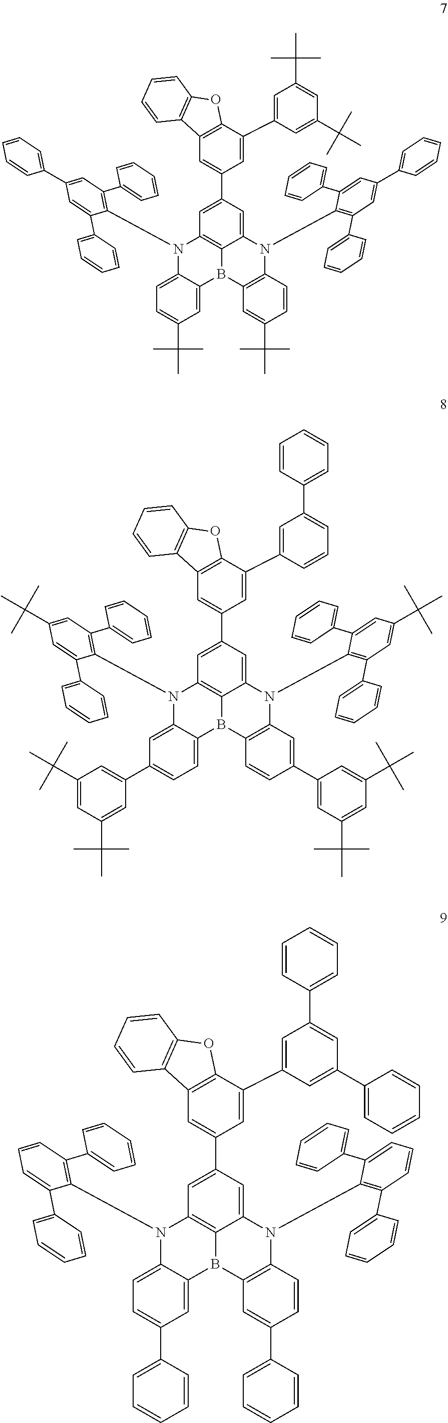

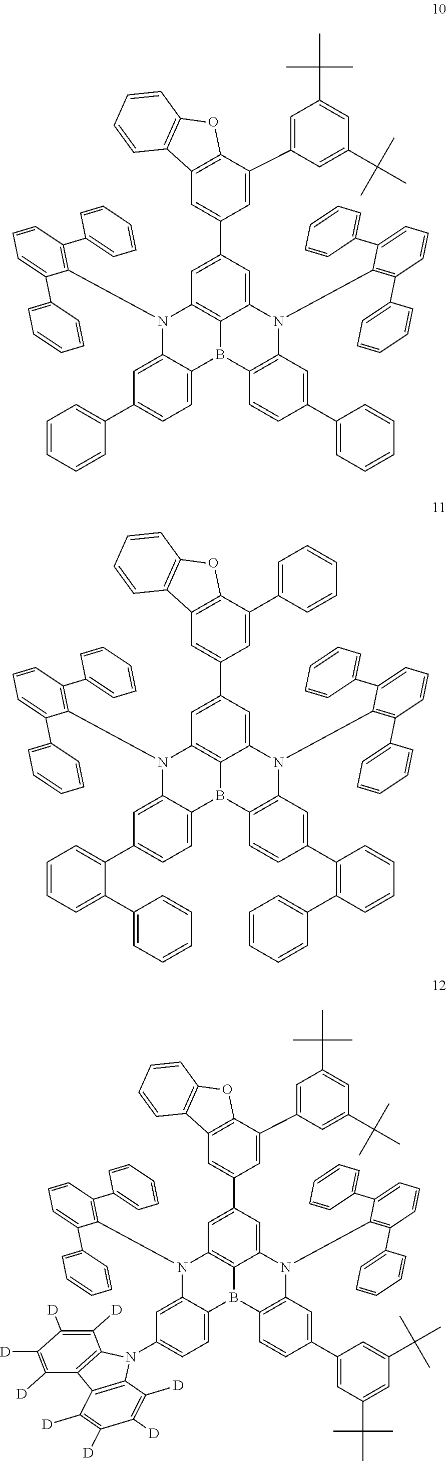

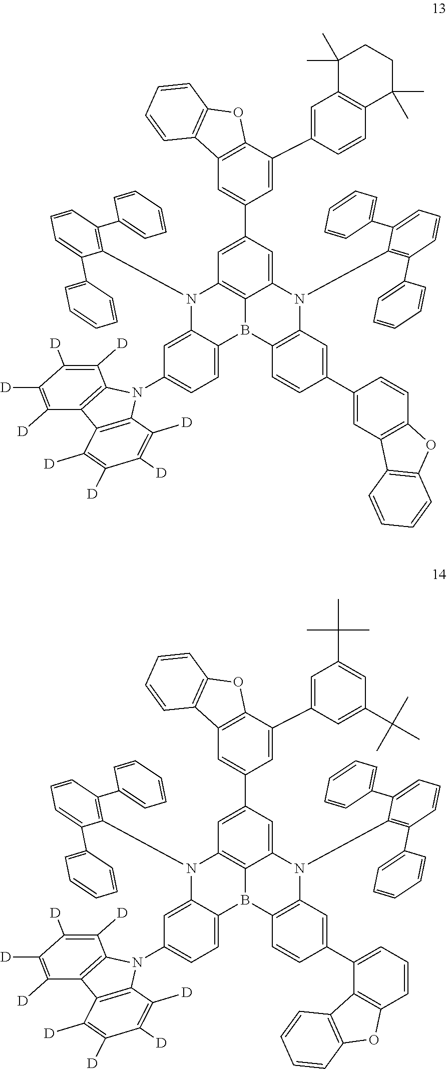 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4ccc5c(c4)C(C)(C)CCC5(C)C)c4oc5ccccc5c4c3)cc3c1B2c1ccc(-c2ccc4oc5ccccc5c4c2)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4cc(C(C)(C)C)cc(C(C)(C)C)c4)c4oc5ccccc5c4c3)cc3c1B2c1ccc(-c2cccc4oc5ccccc5c24)cc1N3c1c(-c2ccccc2)cccc1-c1ccccc1]

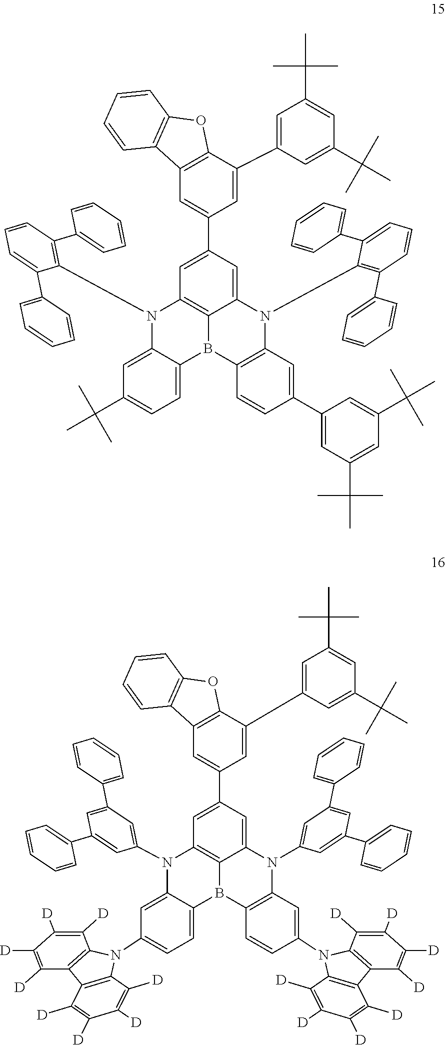 [SMILES: CC(C)(C)c1cc(-c2ccc3c(c2)N(c2c(-c4ccccc4)cccc2-c2ccccc2)c2cc(-c4cc(-c5cc(C(C)(C)C)cc(C(C)(C)C)c5)c5oc6ccccc6c5c4)cc4c2B3c2ccc(C(C)(C)C)cc2N4c2c(-c3ccccc3)cccc2-c2ccccc2)cc(C(C)(C)C)c1 ; [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-c3cc(-c4cc(C(C)(C)C)cc(C(C)(C)C)c4)c4oc5ccccc5c4c3)cc3c1B2c1ccc(-n2c4c([2H])c([2H])c([2H])c([2H])c4c4c([2H])c([2H])c([2H])c([2H])c42)cc1N3c1cc(-c2ccccc2)cc(-c2ccccc2)c1]

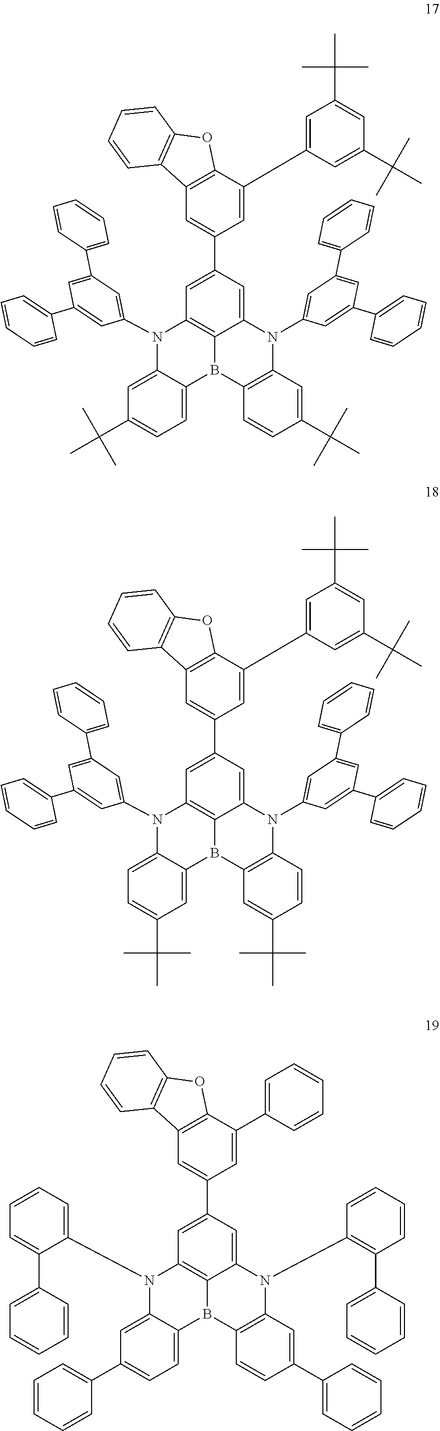 [SMILES: CC(C)(C)c1cc(-c2cc(-c3cc4c5c(c3)N(c3cc(-c6ccccc6)cc(-c6ccccc6)c3)c3cc(C(C)(C)C)ccc3B5c3ccc(C(C)(C)C)cc3N4c3cc(-c4ccccc4)cc(-c4ccccc4)c3)cc3c2oc2ccccc23)cc(C(C)(C)C)c1 ; CC(C)(C)c1cc(-c2cc(-c3cc4c5c(c3)N(c3cc(-c6ccccc6)cc(-c6ccccc6)c3)c3ccc(C(C)(C)C)cc3B5c3cc(C(C)(C)C)ccc3N4c3cc(-c4ccccc4)cc(-c4ccccc4)c3)cc3c2oc2ccccc23)cc(C(C)(C)C)c1 ; c1ccc(-c2ccc3c(c2)N(c2ccccc2-c2ccccc2)c2cc(-c4cc(-c5ccccc5)c5oc6ccccc6c5c4)cc4c2B3c2ccc(-c3ccccc3)cc2N4c2ccccc2-c2ccccc2)cc1]

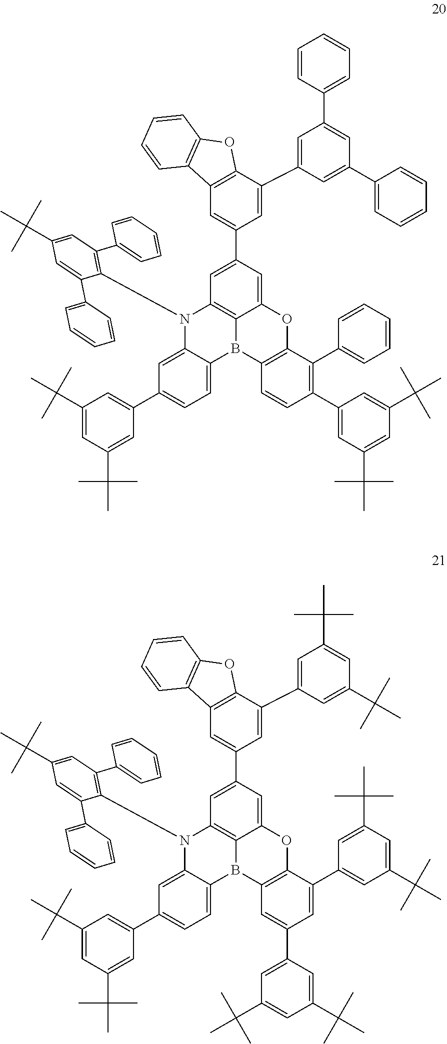

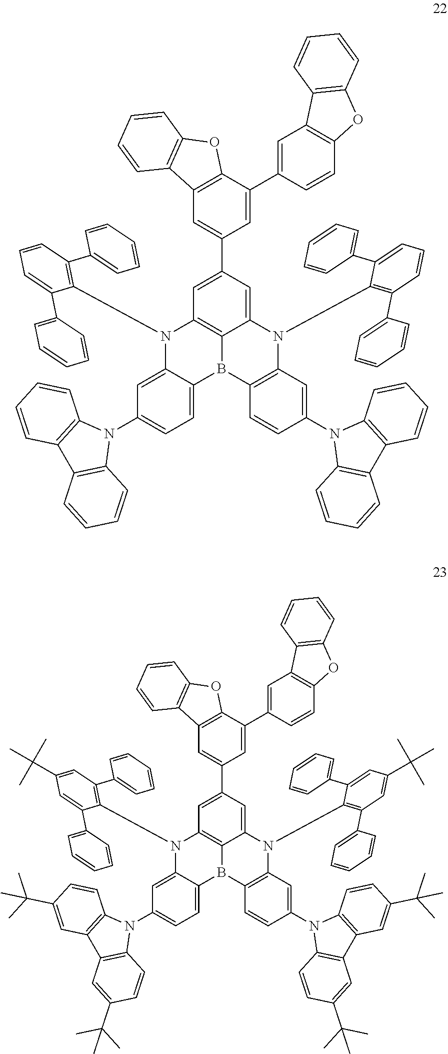 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5cc(-c6ccc7oc8ccccc8c7c6)c6oc7ccccc7c6c5)cc2c43)cc1 ; CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5cc(-c6ccc7oc8ccccc8c7c6)c6oc7ccccc7c6c5)cc2c43)c(-c2ccccc2)c1]

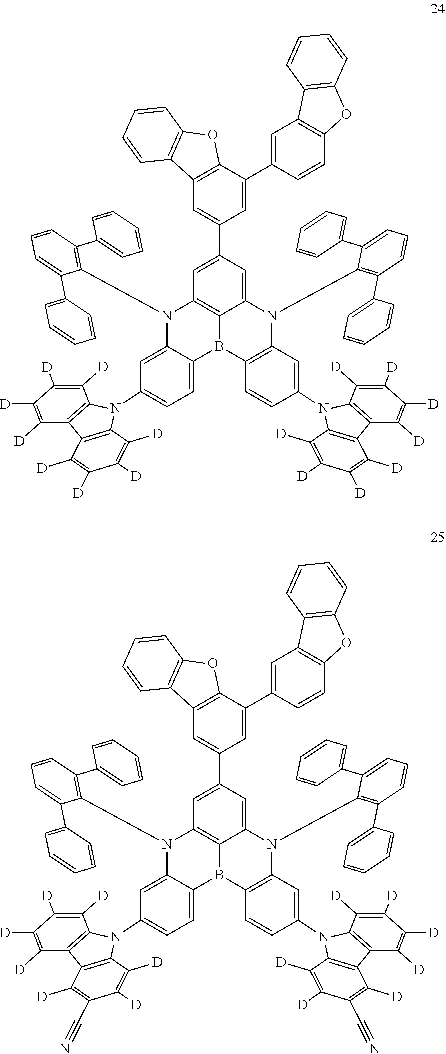

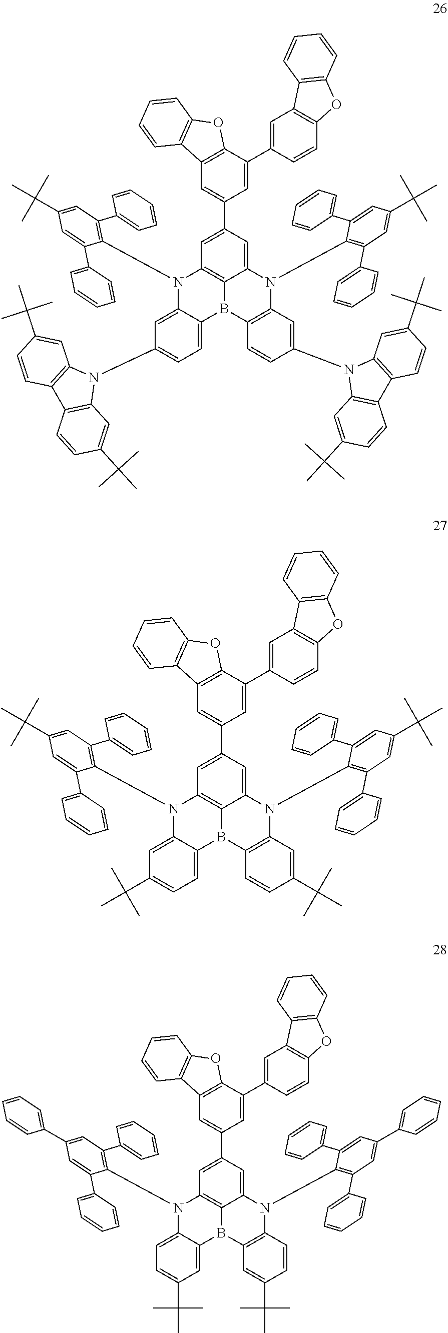

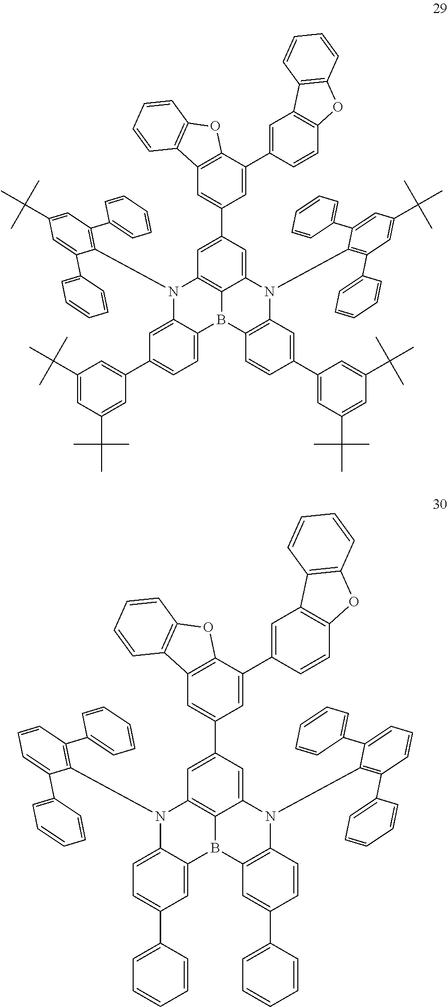 [SMILES: CC(C)(C)c1cc(-c2ccc3c(c2)N(c2c(-c4ccccc4)cc(C(C)(C)C)cc2-c2ccccc2)c2cc(-c4cc(-c5ccc6oc7ccccc7c6c5)c5oc6ccccc6c5c4)cc4c2B3c2ccc(-c3cc(C(C)(C)C)cc(C(C)(C)C)c3)cc2N4c2c(-c3ccccc3)cc(C(C)(C)C)cc2-c2ccccc2)cc(C(C)(C)C)c1 ; c1ccc(-c2ccc3c(c2)B2c4cc(-c5ccccc5)ccc4N(c4c(-c5ccccc5)cccc4-c4ccccc4)c4cc(-c5cc(-c6ccc7oc8ccccc8c7c6)c6oc7ccccc7c6c5)cc(c42)N3c2c(-c3ccccc3)cccc2-c2ccccc2)cc1]

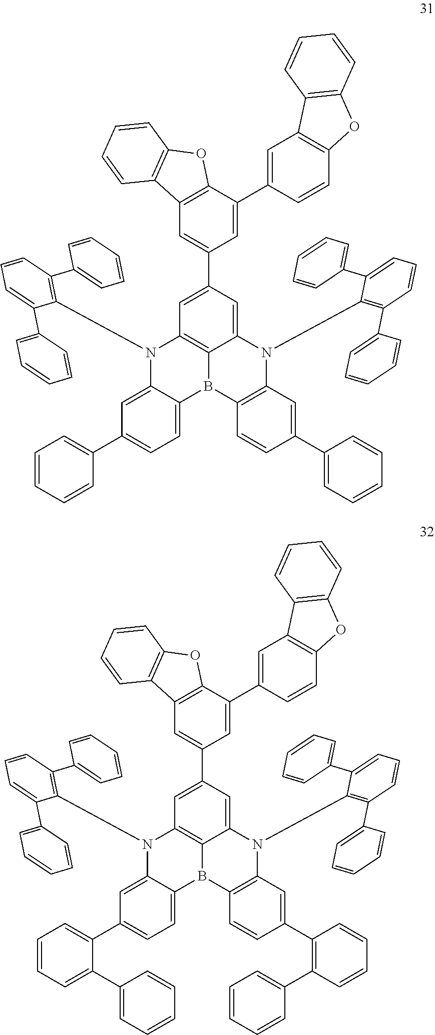 [SMILES: c1ccc(-c2ccc3c(c2)N(c2c(-c4ccccc4)cccc2-c2ccccc2)c2cc(-c4cc(-c5ccc6oc7ccccc7c6c5)c5oc6ccccc6c5c4)cc4c2B3c2ccc(-c3ccccc3)cc2N4c2c(-c3ccccc3)cccc2-c2ccccc2)cc1 ; c1ccc(-c2ccccc2-c2ccc3c(c2)N(c2c(-c4ccccc4)cccc2-c2ccccc2)c2cc(-c4cc(-c5ccc6oc7ccccc7c6c5)c5oc6ccccc6c5c4)cc4c2B3c2ccc(-c3ccccc3-c3ccccc3)cc2N4c2c(-c3ccccc3)cccc2-c2ccccc2)cc1]

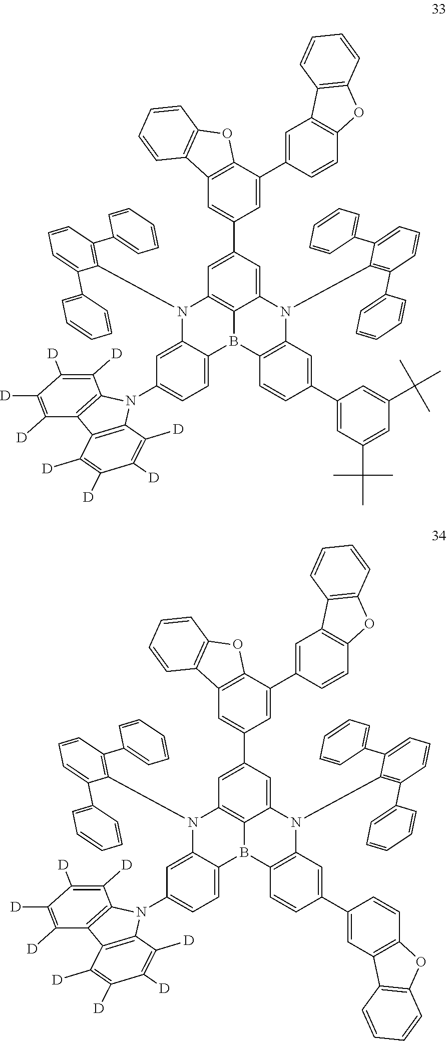

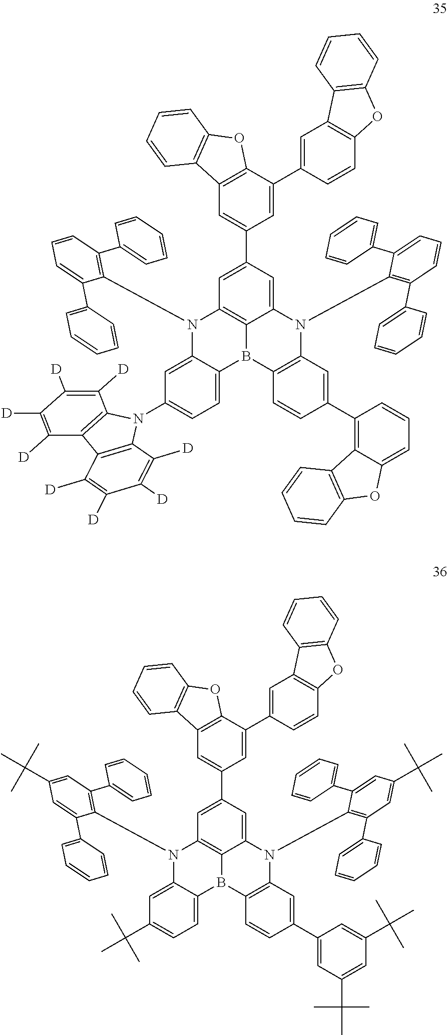 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4ccc5oc6ccccc6c5c4)c4oc5ccccc5c4c3)cc3c1B2c1ccc(-c2cccc4oc5ccccc5c24)cc1N3c1c(-c2ccccc2)cccc1-c1ccccc1 ; CC(C)(C)c1cc(-c2ccc3c(c2)N(c2c(-c4ccccc4)cc(C(C)(C)C)cc2-c2ccccc2)c2cc(-c4cc(-c5ccc6oc7ccccc7c6c5)c5oc6ccccc6c5c4)cc4c2B3c2ccc(C(C)(C)C)cc2N4c2c(-c3ccccc3)cc(C(C)(C)C)cc2-c2ccccc2)cc(C(C)(C)C)c1]

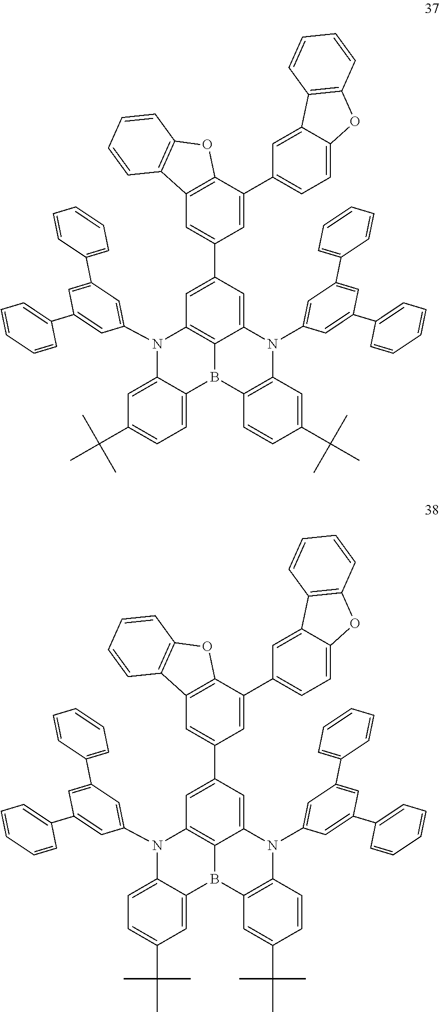 [SMILES: CC(C)(C)c1ccc2c(c1)N(c1cc(-c3ccccc3)cc(-c3ccccc3)c1)c1cc(-c3cc(-c4ccc5oc6ccccc6c5c4)c4oc5ccccc5c4c3)cc3c1B2c1ccc(C(C)(C)C)cc1N3c1cc(-c2ccccc2)cc(-c2ccccc2)c1 ; CC(C)(C)c1ccc2c(c1)B1c3cc(C(C)(C)C)ccc3N(c3cc(-c4ccccc4)cc(-c4ccccc4)c3)c3cc(-c4cc(-c5ccc6oc7ccccc7c6c5)c5oc6ccccc6c5c4)cc(c31)N2c1cc(-c2ccccc2)cc(-c2ccccc2)c1]

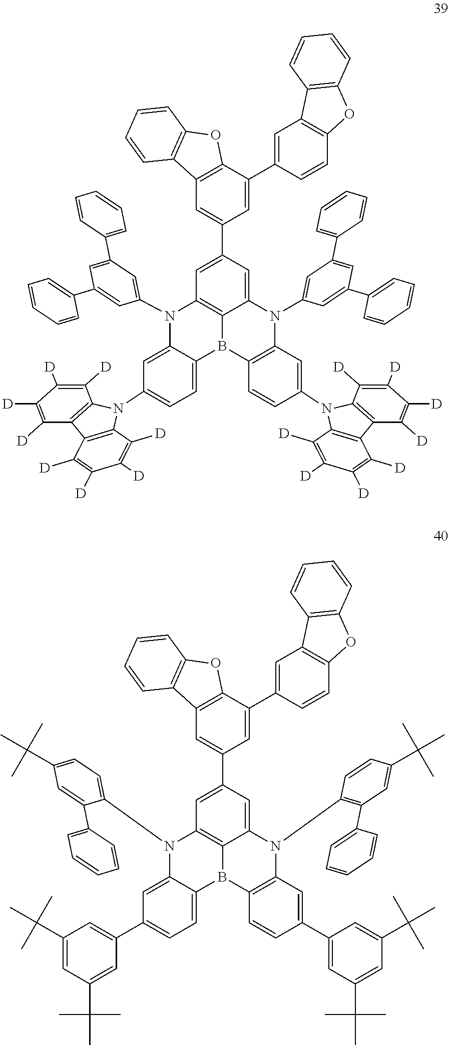 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-c3cc(-c4ccc5oc6ccccc6c5c4)c4oc5ccccc5c4c3)cc3c1B2c1ccc(-n2c4c([2H])c([2H])c([2H])c([2H])c4c4c([2H])c([2H])c([2H])c([2H])c42)cc1N3c1cc(-c2ccccc2)cc(-c2ccccc2)c1 ; CC(C)(C)c1cc(-c2ccc3c(c2)N(c2ccc(C(C)(C)C)cc2-c2ccccc2)c2cc(-c4cc(-c5ccc6oc7ccccc7c6c5)c5oc6ccccc6c5c4)cc4c2B3c2ccc(-c3cc(C(C)(C)C)cc(C(C)(C)C)c3)cc2N4c2ccc(C(C)(C)C)cc2-c2ccccc2)cc(C(C)(C)C)c1]

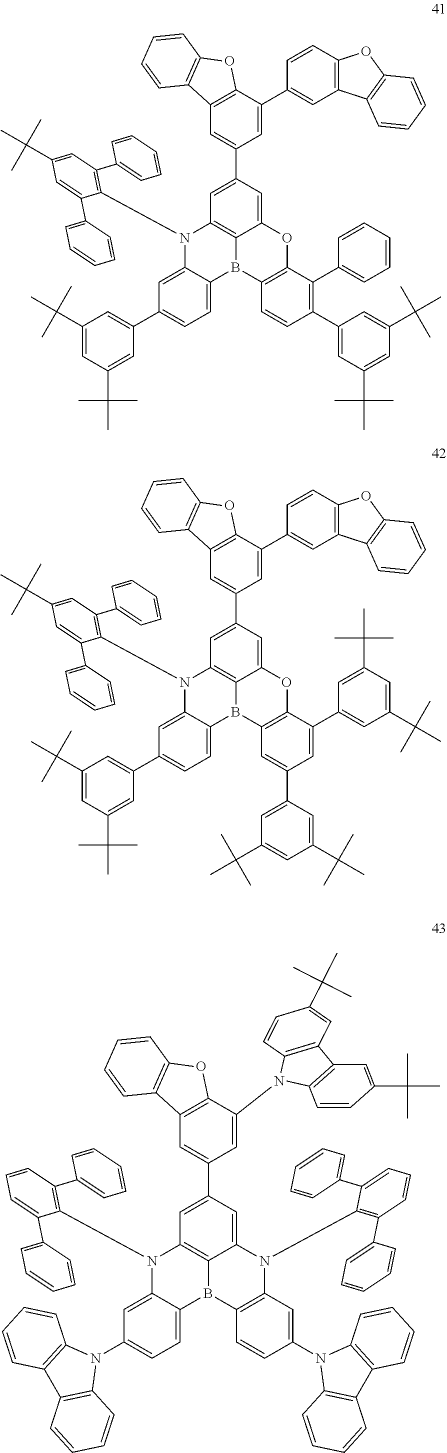

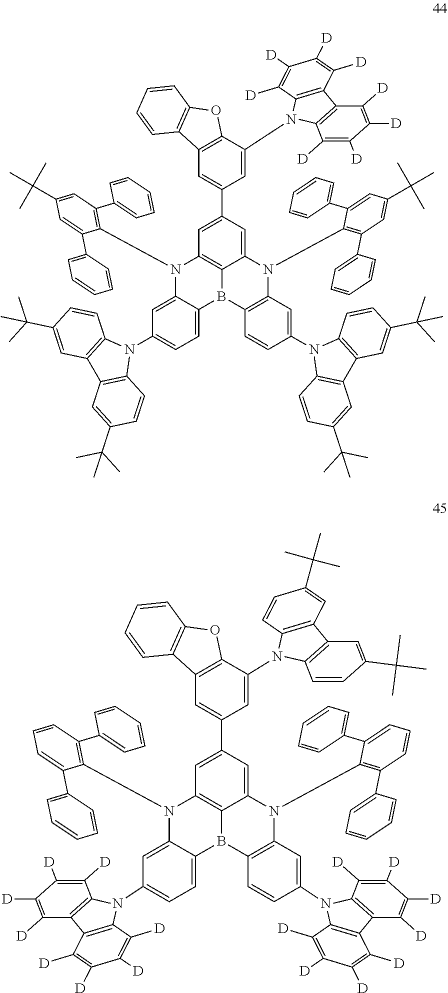

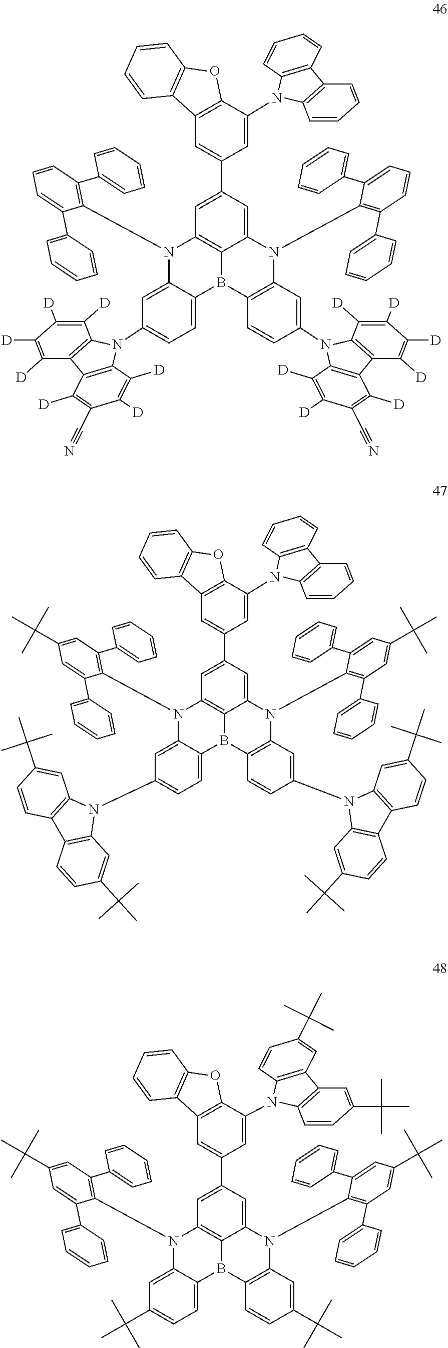

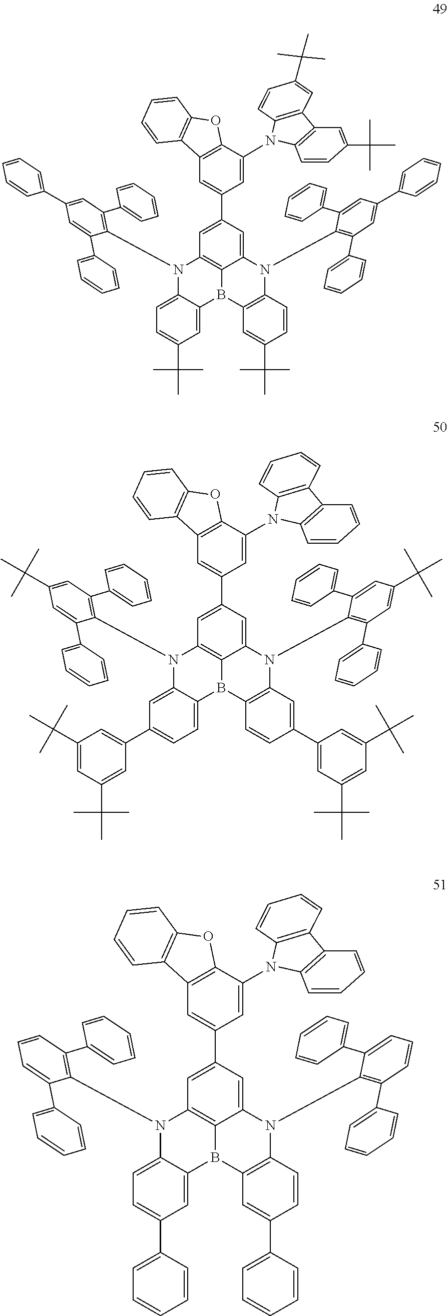

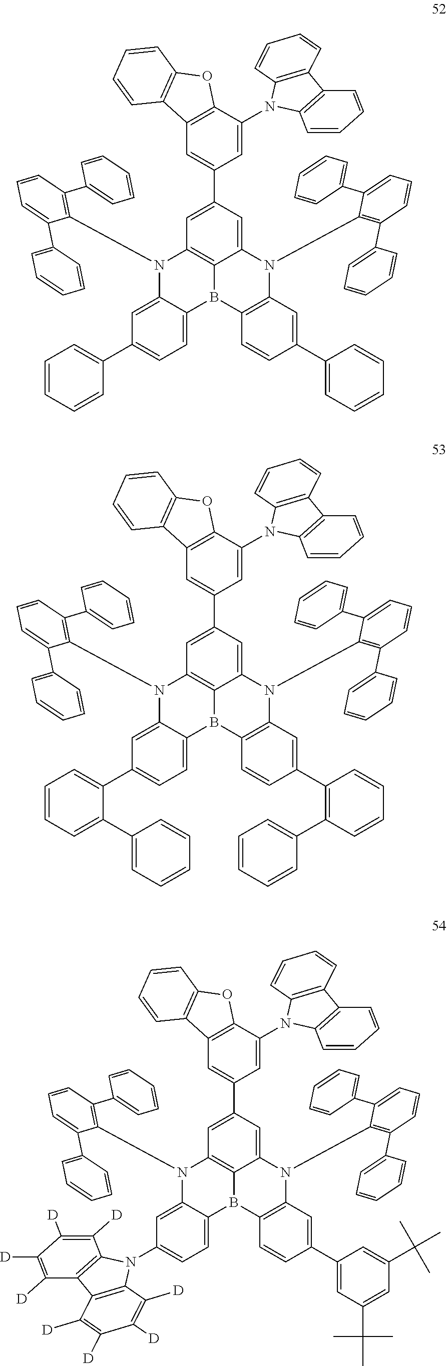

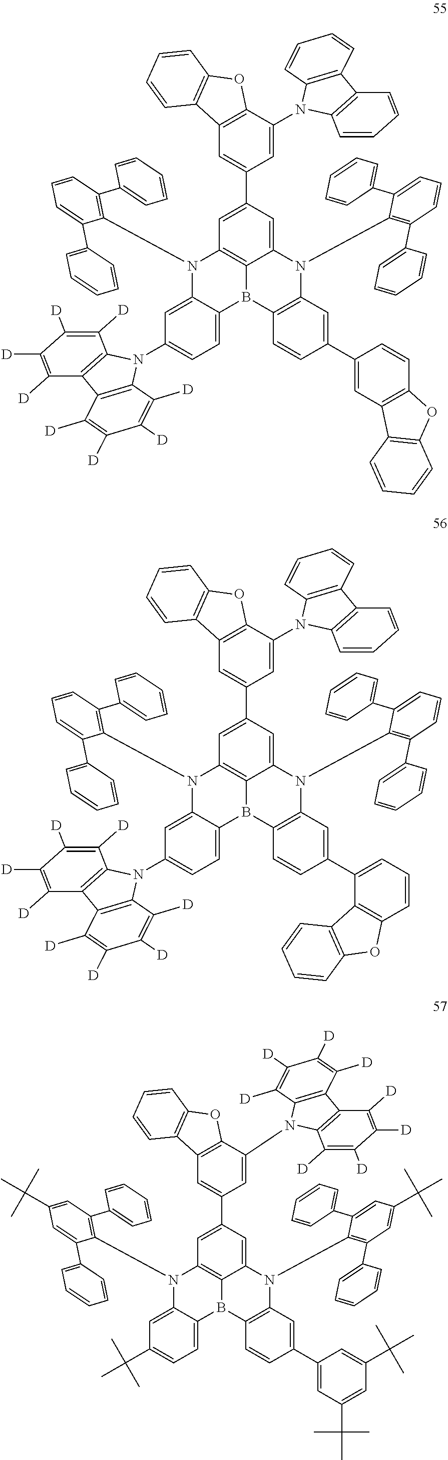

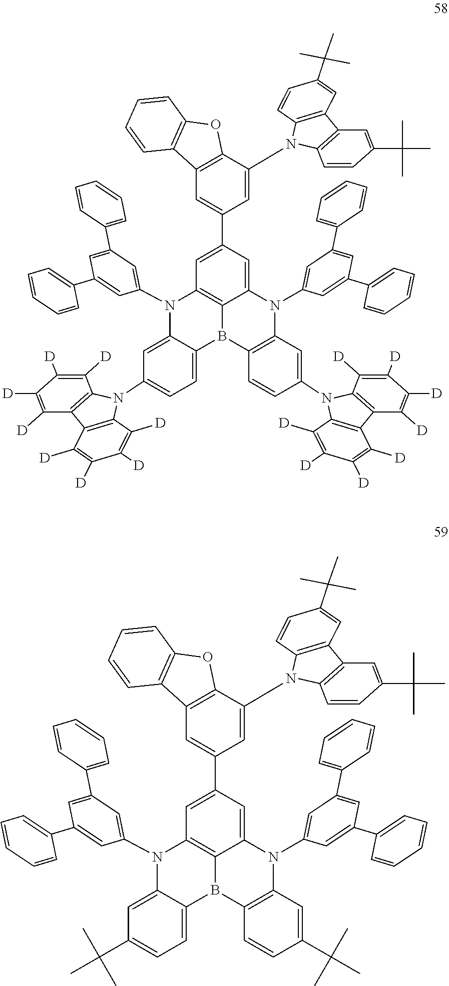 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-c3cc(-n4c5ccc(C(C)(C)C)cc5c5cc(C(C)(C)C)ccc54)c4oc5ccccc5c4c3)cc3c1B2c1ccc(-n2c4c([2H])c([2H])c([2H])c([2H])c4c4c([2H])c([2H])c([2H])c([2H])c42)cc1N3c1cc(-c2ccccc2)cc(-c2ccccc2)c1 ; CC(C)(C)c1ccc2c(c1)N(c1cc(-c3ccccc3)cc(-c3ccccc3)c1)c1cc(-c3cc(-n4c5ccc(C(C)(C)C)cc5c5cc(C(C)(C)C)ccc54)c4oc5ccccc5c4c3)cc3c1B2c1ccc(C(C)(C)C)cc1N3c1cc(-c2ccccc2)cc(-c2ccccc2)c1]

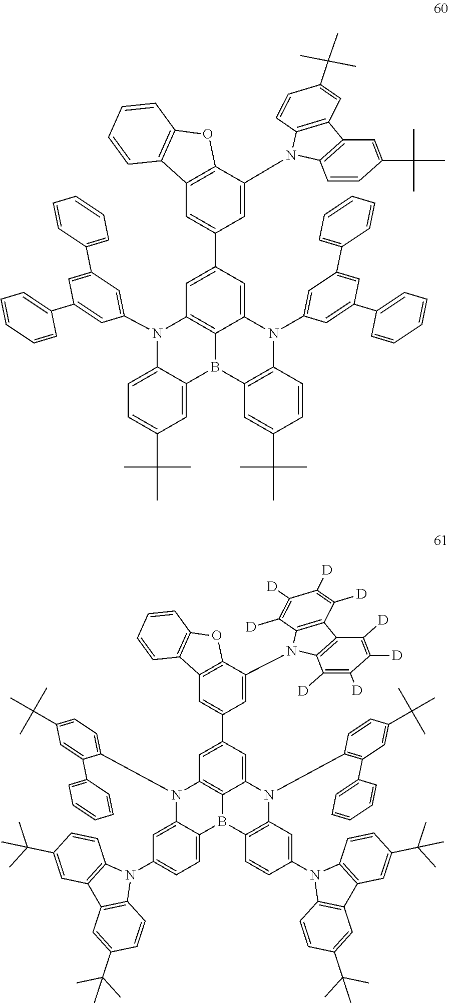

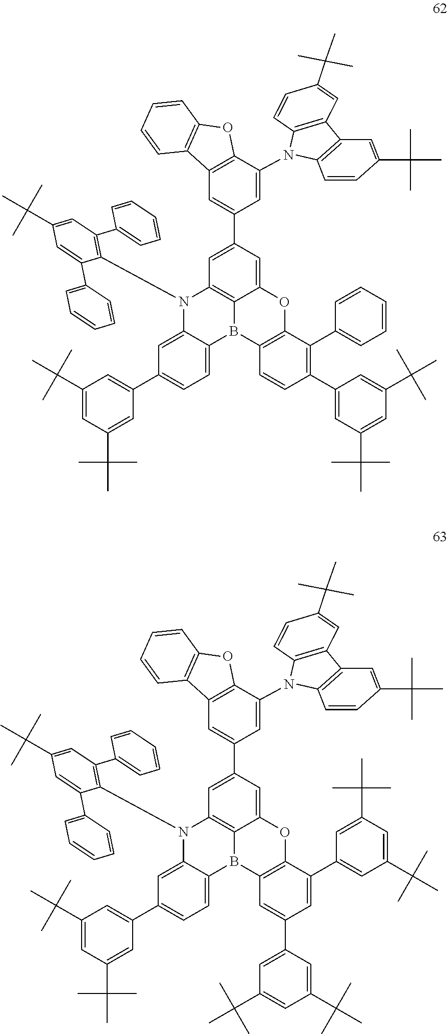

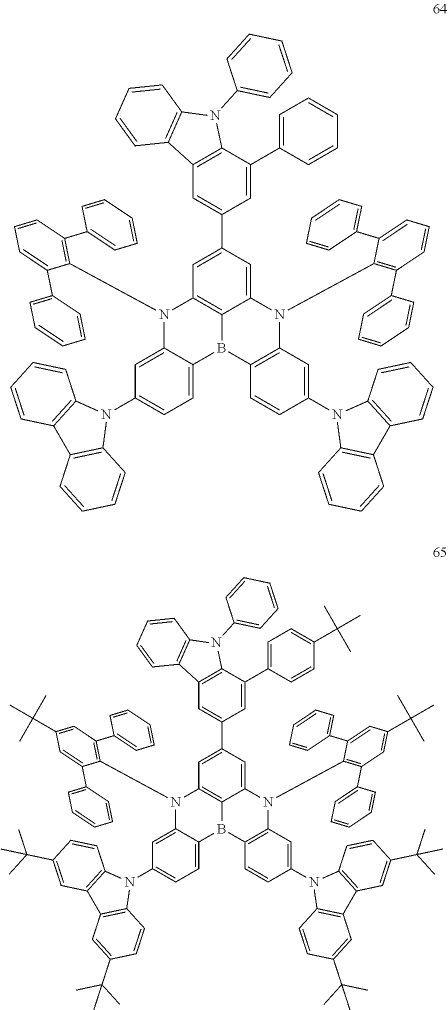 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5cc(-c6ccccc6)c6c(c5)c5ccccc5n6-c5ccccc5)cc2c43)cc1 ; CC(C)(C)c1ccc(-c2cc(-c3cc4c5c(c3)N(c3c(-c6ccccc6)cc(C(C)(C)C)cc3-c3ccccc3)c3cc(-n6c7ccc(C(C)(C)C)cc7c7cc(C(C)(C)C)ccc76)ccc3B5c3ccc(-n5c6ccc(C(C)(C)C)cc6c6cc(C(C)(C)C)ccc65)cc3N4c3c(-c4ccccc4)cc(C(C)(C)C)cc3-c3ccccc3)cc3c4ccccc4n(-c4ccccc4)c23)cc1]

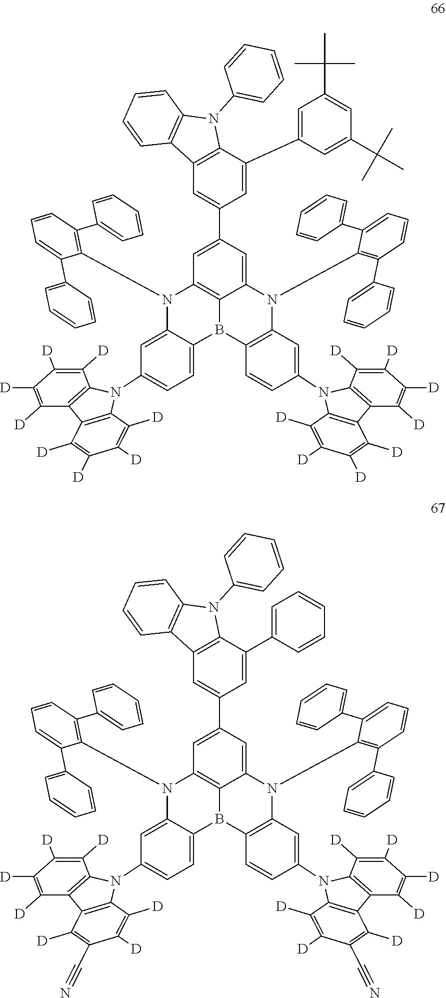

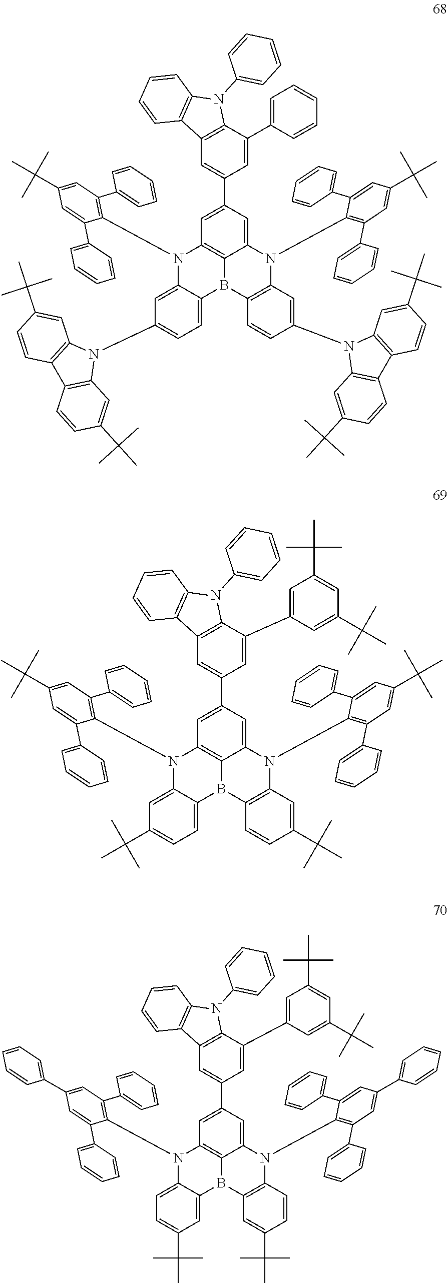

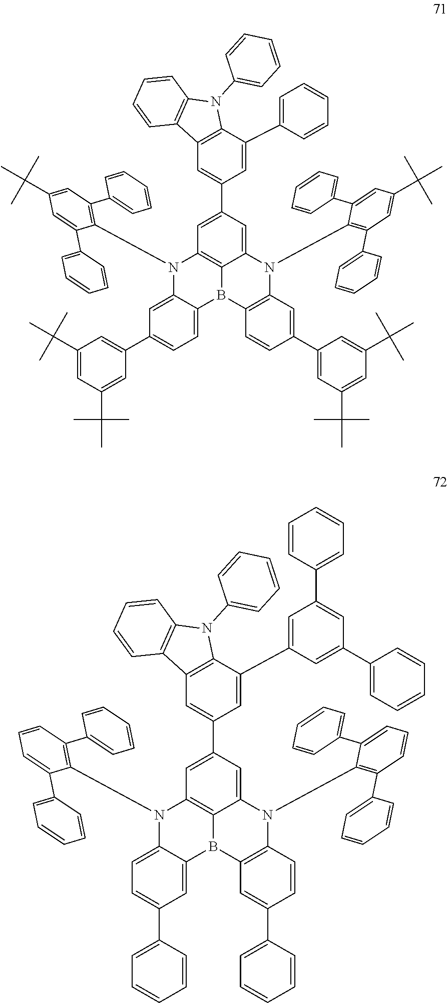 [SMILES: CC(C)(C)c1cc(-c2ccc3c(c2)N(c2c(-c4ccccc4)cc(C(C)(C)C)cc2-c2ccccc2)c2cc(-c4cc(-c5ccccc5)c5c(c4)c4ccccc4n5-c4ccccc4)cc4c2B3c2ccc(-c3cc(C(C)(C)C)cc(C(C)(C)C)c3)cc2N4c2c(-c3ccccc3)cc(C(C)(C)C)cc2-c2ccccc2)cc(C(C)(C)C)c1 ; c1ccc(-c2cc(-c3ccccc3)cc(-c3cc(-c4cc5c6c(c4)N(c4c(-c7ccccc7)cccc4-c4ccccc4)c4ccc(-c7ccccc7)cc4B6c4cc(-c6ccccc6)ccc4N5c4c(-c5ccccc5)cccc4-c4ccccc4)cc4c5ccccc5n(-c5ccccc5)c34)c2)cc1]

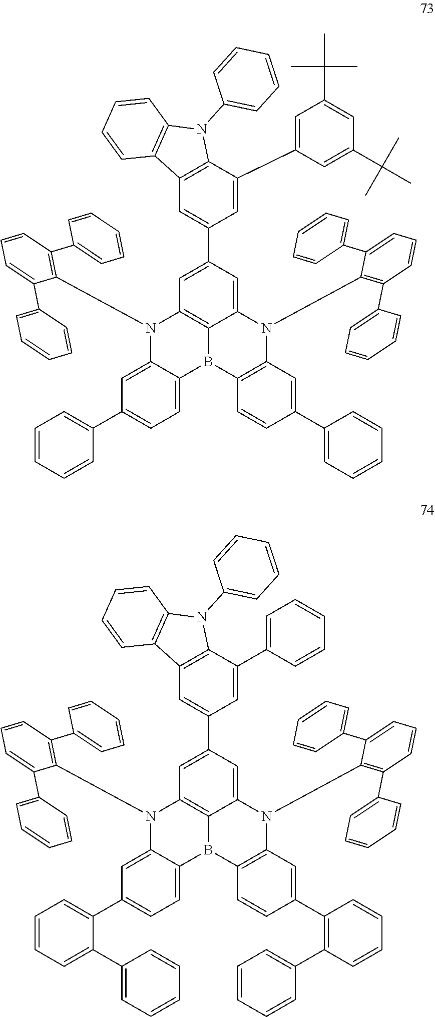 [SMILES: CC(C)(C)c1cc(-c2cc(-c3cc4c5c(c3)N(c3c(-c6ccccc6)cccc3-c3ccccc3)c3cc(-c6ccccc6)ccc3B5c3ccc(-c5ccccc5)cc3N4c3c(-c4ccccc4)cccc3-c3ccccc3)cc3c4ccccc4n(-c4ccccc4)c23)cc(C(C)(C)C)c1 ; c1ccc(-c2ccccc2-c2ccc3c(c2)N(c2c(-c4ccccc4)cccc2-c2ccccc2)c2cc(-c4cc(-c5ccccc5)c5c(c4)c4ccccc4n5-c4ccccc4)cc4c2B3c2ccc(-c3ccccc3-c3ccccc3)cc2N4c2c(-c3ccccc3)cccc2-c2ccccc2)cc1]

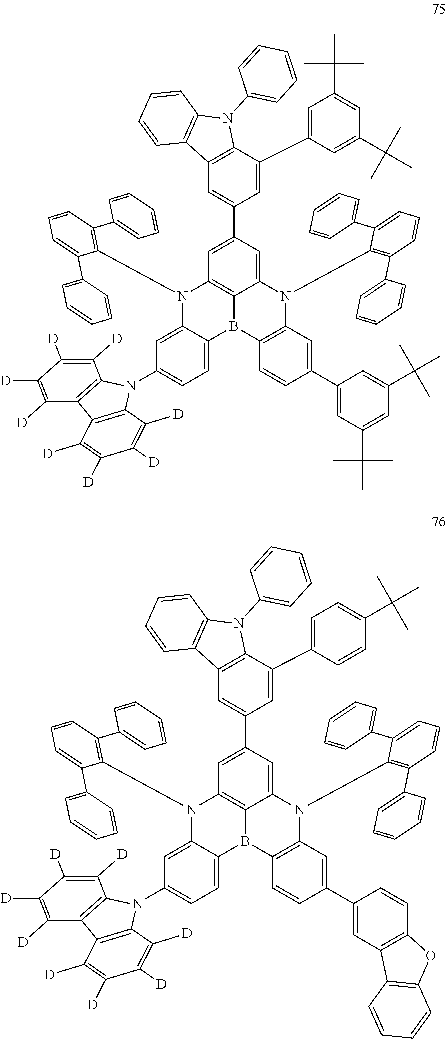 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4cc(C(C)(C)C)cc(C(C)(C)C)c4)c4c(c3)c3ccccc3n4-c3ccccc3)cc3c1B2c1ccc(-c2cc(C(C)(C)C)cc(C(C)(C)C)c2)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4ccc(C(C)(C)C)cc4)c4c(c3)c3ccccc3n4-c3ccccc3)cc3c1B2c1ccc(-c2ccc4oc5ccccc5c4c2)cc1N3c1c(-c2ccccc2)cccc1-c1ccccc1]

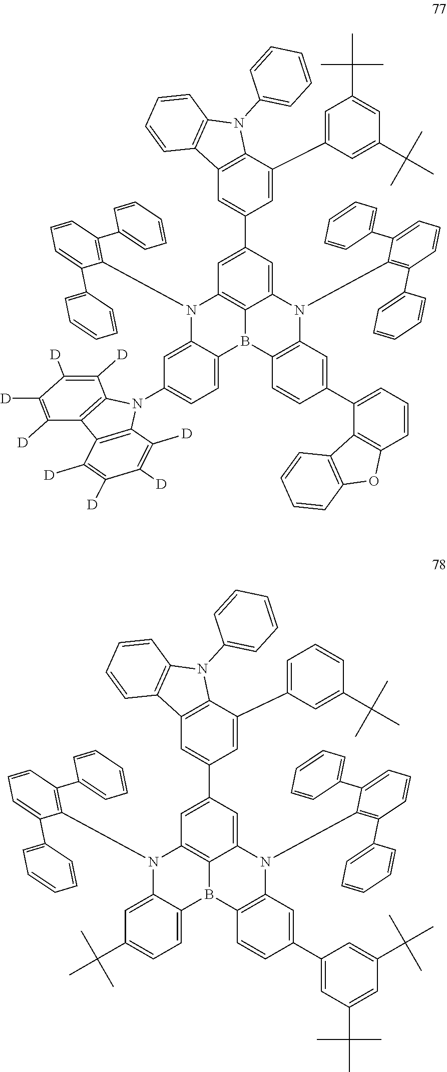 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4cc(C(C)(C)C)cc(C(C)(C)C)c4)c4c(c3)c3ccccc3n4-c3ccccc3)cc3c1B2c1ccc(-c2cccc4oc5ccccc5c24)cc1N3c1c(-c2ccccc2)cccc1-c1ccccc1 ; CC(C)(C)c1cccc(-c2cc(-c3cc4c5c(c3)N(c3c(-c6ccccc6)cccc3-c3ccccc3)c3cc(C(C)(C)C)ccc3B5c3ccc(-c5cc(C(C)(C)C)cc(C(C)(C)C)c5)cc3N4c3c(-c4ccccc4)cccc3-c3ccccc3)cc3c4ccccc4n(-c4ccccc4)c23)c1]

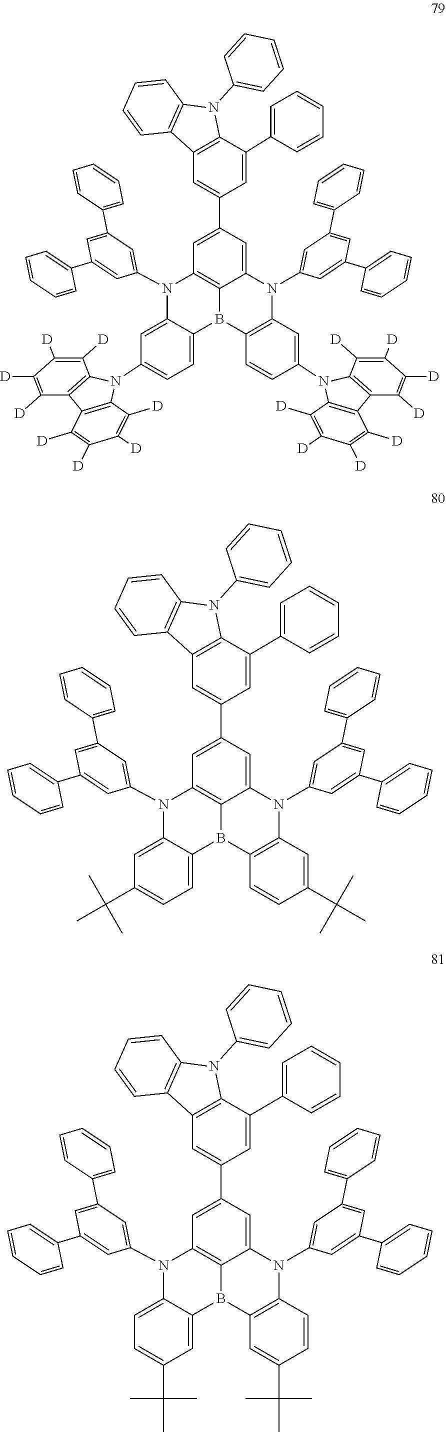

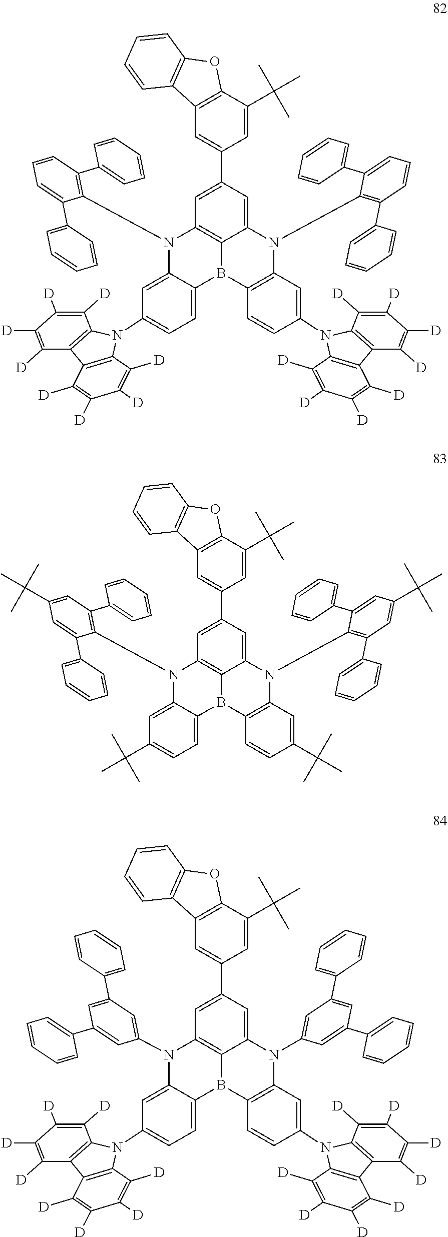

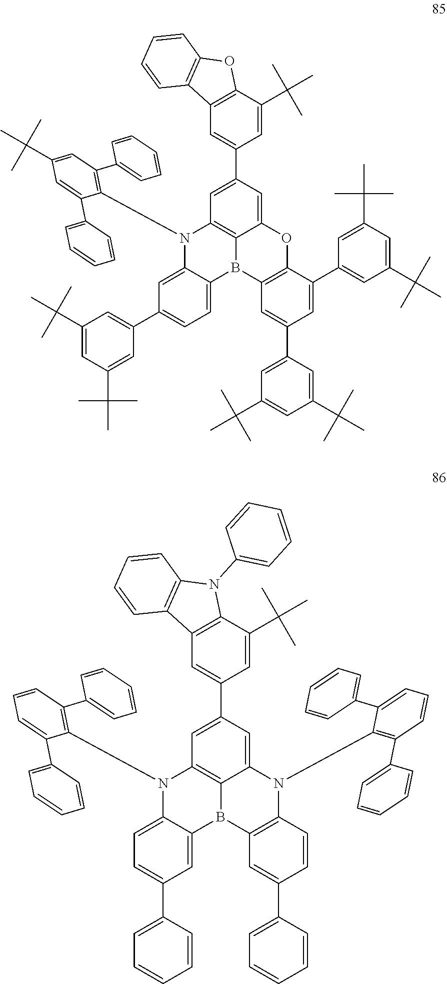 [SMILES: CC(C)(C)c1cc(-c2cc3c(c(-c4cc(C(C)(C)C)cc(C(C)(C)C)c4)c2)Oc2cc(-c4cc(C(C)(C)C)c5oc6ccccc6c5c4)cc4c2B3c2ccc(-c3cc(C(C)(C)C)cc(C(C)(C)C)c3)cc2N4c2c(-c3ccccc3)cc(C(C)(C)C)cc2-c2ccccc2)cc(C(C)(C)C)c1 ; CC(C)(C)c1cc(-c2cc3c4c(c2)N(c2c(-c5ccccc5)cccc2-c2ccccc2)c2ccc(-c5ccccc5)cc2B4c2cc(-c4ccccc4)ccc2N3c2c(-c3ccccc3)cccc2-c2ccccc2)cc2c3ccccc3n(-c3ccccc3)c12]

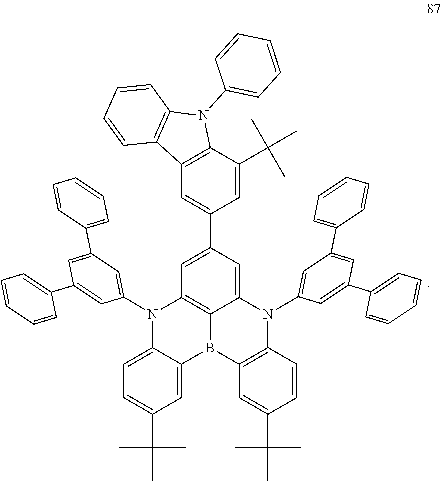 [SMILES: CC(C)(C)c1ccc2c(c1)B1c3cc(C(C)(C)C)ccc3N(c3cc(-c4ccccc4)cc(-c4ccccc4)c3)c3cc(-c4cc(C(C)(C)C)c5c(c4)c4ccccc4n5-c4ccccc4)cc(c31)N2c1cc(-c2ccccc2)cc(-c2ccccc2)c1]

15. A polycyclic compound represented by Formula 1: 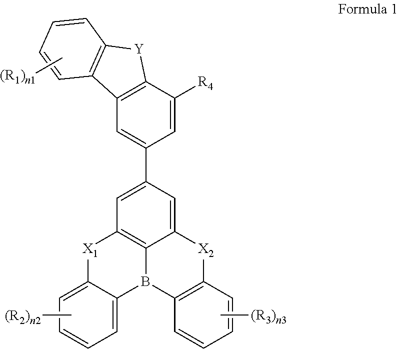
in Formula 1,
R₁ to R₃ are each independently selected from hydrogen, deuterium, a cyano group, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
R₄ is selected from a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
X₁ and X₂ are each independently selected from NRₓ and O,
Y is NR_{y} or O,
Rₓ and R_{y} are each independently selected from a substituted or unsubstituted aryl group of 6 to 30 ring-forming carbon atoms, and a substituted or unsubstituted heteroaryl group of 2 to 30 ring-forming carbon atoms, and
n1 to n3 are each independently an integer of 0 to 4.

16. The polycyclic compound of claim 15, wherein Formula 1 is represented by Formula 2: 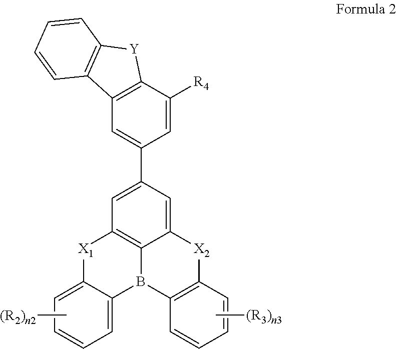
in Formula 2, R₂, R₃, R₄, X₁, X₂, Y, n2, and n3 are the same as defined in Formula 1.

17. The polycyclic compound of claim 15, wherein Formula 1 is represented by Formula 3-1 or Formula 3-2: 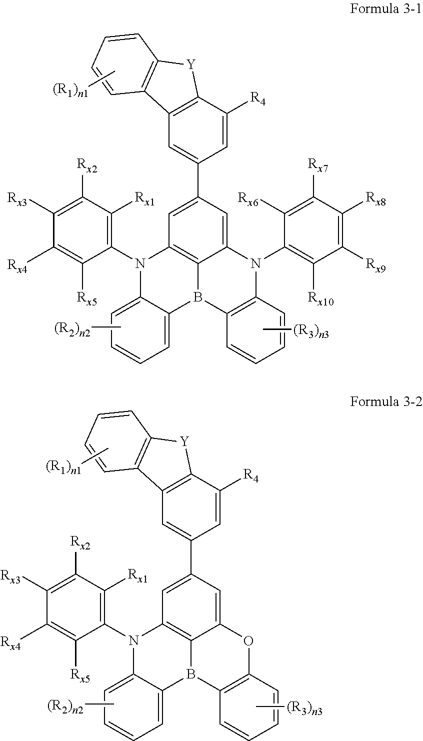
in Formula 3-1 and Formula 3-2,
Rₓ₁ to Rₓ₁₀ are each independently selected from hydrogen, deuterium, a substituted or unsubstituted alkyl group of 1 to 20 carbon atoms, and a substituted or unsubstituted aryl group of 6 to 20 ring-forming carbon atoms, and
R₁ to R₄, Y, and n1 to n3 are the same as defined in Formula 1.

18. The polycyclic compound of claim 17, wherein the polycyclic compound represented by Formula 3-1 is represented by Formula 3-1-1 or Formula 3-1-2, and the polycyclic compound represented by Formula 3-2 is represented by Formula 3-2-1 or Formula 3-2-2: 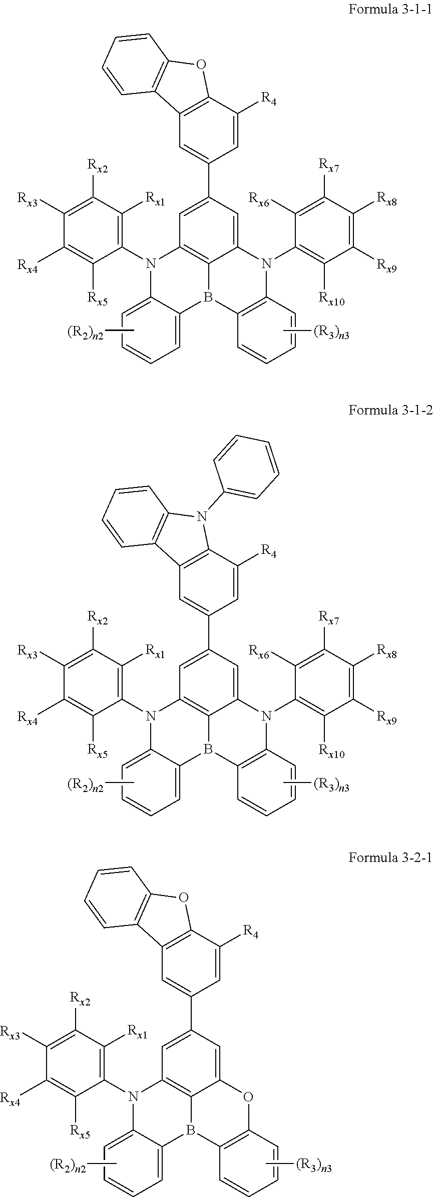 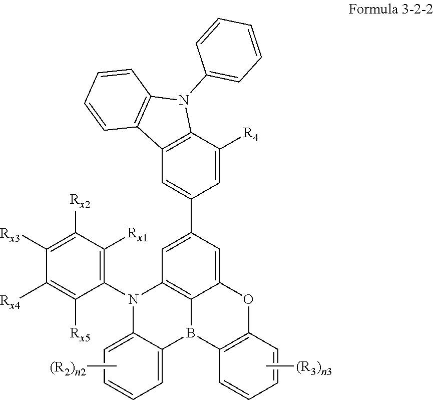
in Formula 3-1-1, Formula 3-1-2, Formula 3-2-1 and Formula 3-2-2, Rₓ₁ to Rₓ₀ are the same as defined in Formula 3-1 and Formula 3-2.

19. The polycyclic compound of claim 15, wherein Formula 1 is represented by any one selected from among Formula 4-1 to Formula 4-3: 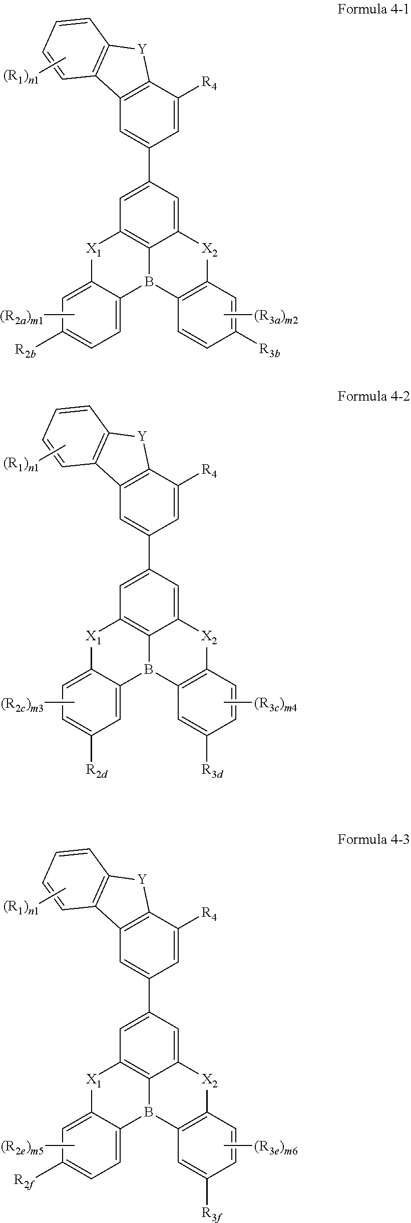
in Formula 4-1 to Formula 4-3,
R₂ₐ, R₃ₐ, R_{2c}, R_{3c}, R₂ₑ, and R₃ₑ are each independently selected from hydrogen, deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
R_{2b}, R_{3b}, R_{2d}, R_{3d}, R_{2f}, and R_{3f} are each independently selected from deuterium, a substituted or unsubstituted alkyl group of 1 to 30 carbon atoms, a substituted or unsubstituted aryl group of 6 to 30 ring-forming carbon atoms, and a substituted or unsubstituted heteroaryl group of 2 to 30 ring-forming carbon atoms,
m1 to m6 are each independently selected from an integer of 0 to 3, and
R₁, R₄, X₁, X₂, Y, and n1 are the same as defined in Formula 1.

20. The polycyclic compound of claim 15, wherein Formula 1 is represented by any one selected from among compounds in Compound Group 1: 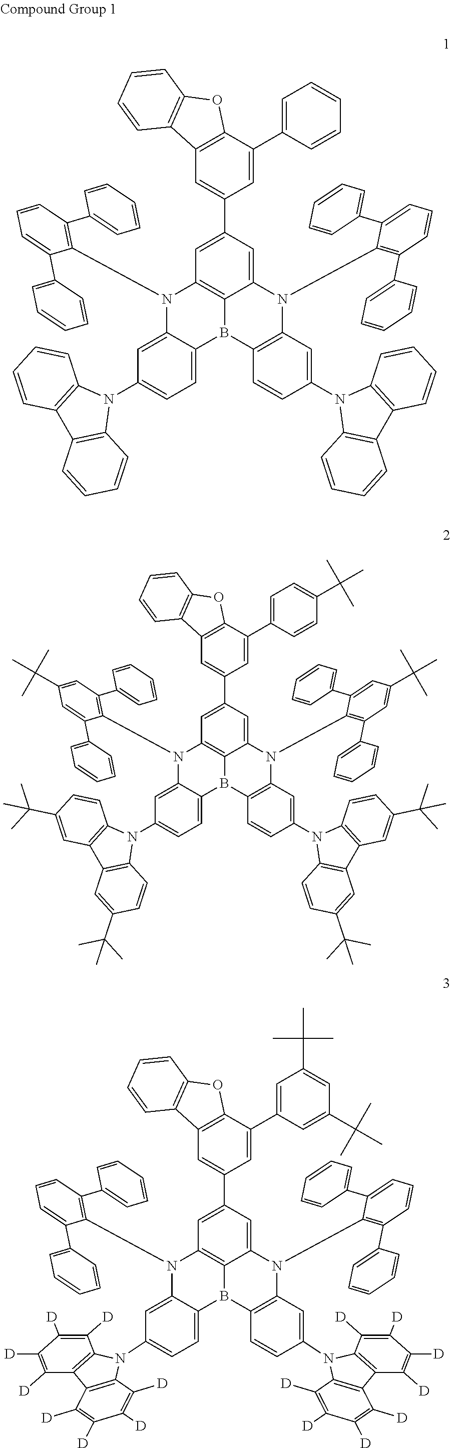 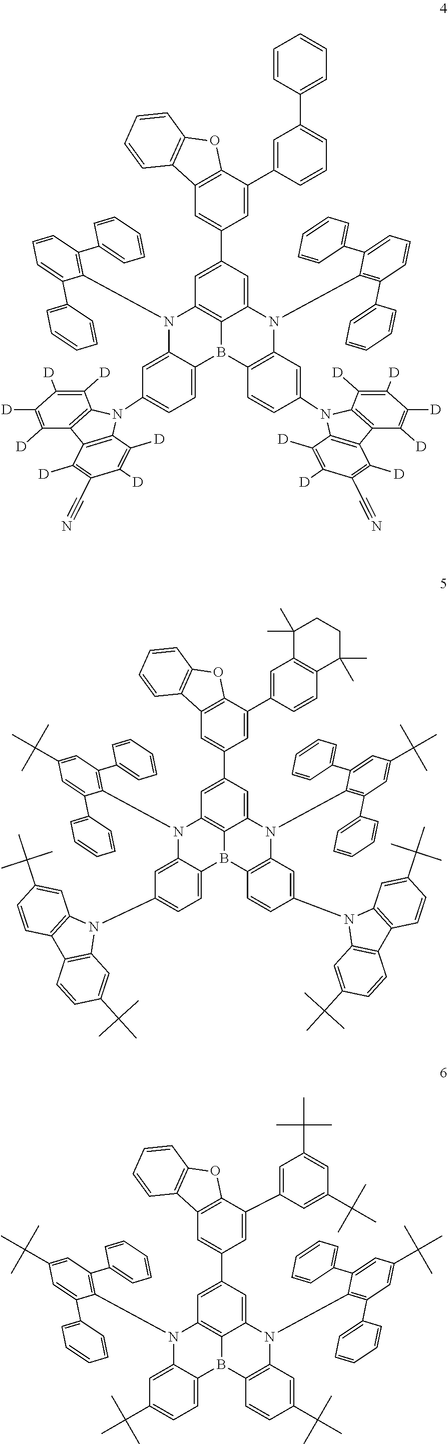 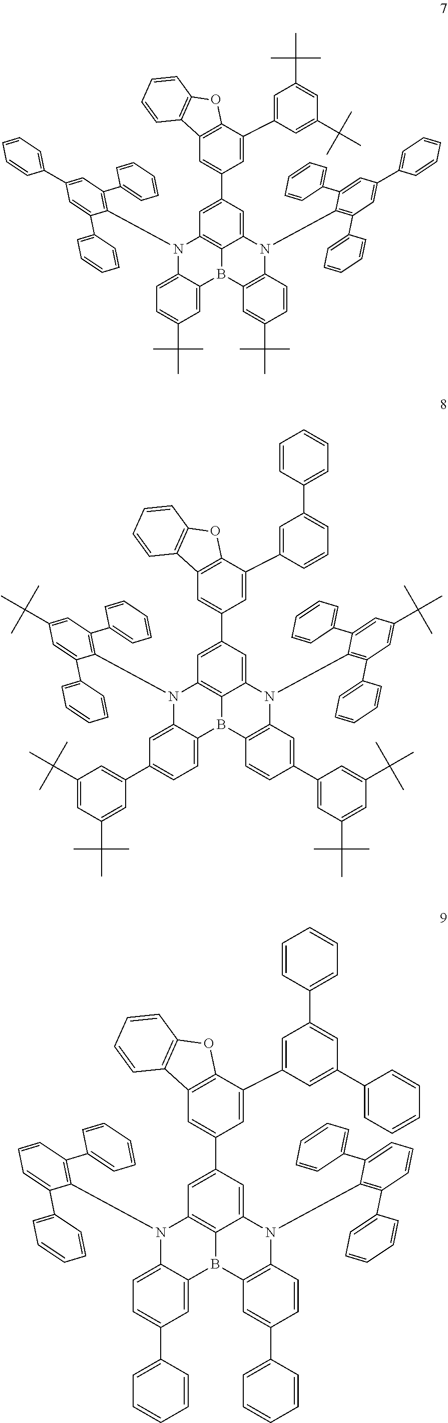 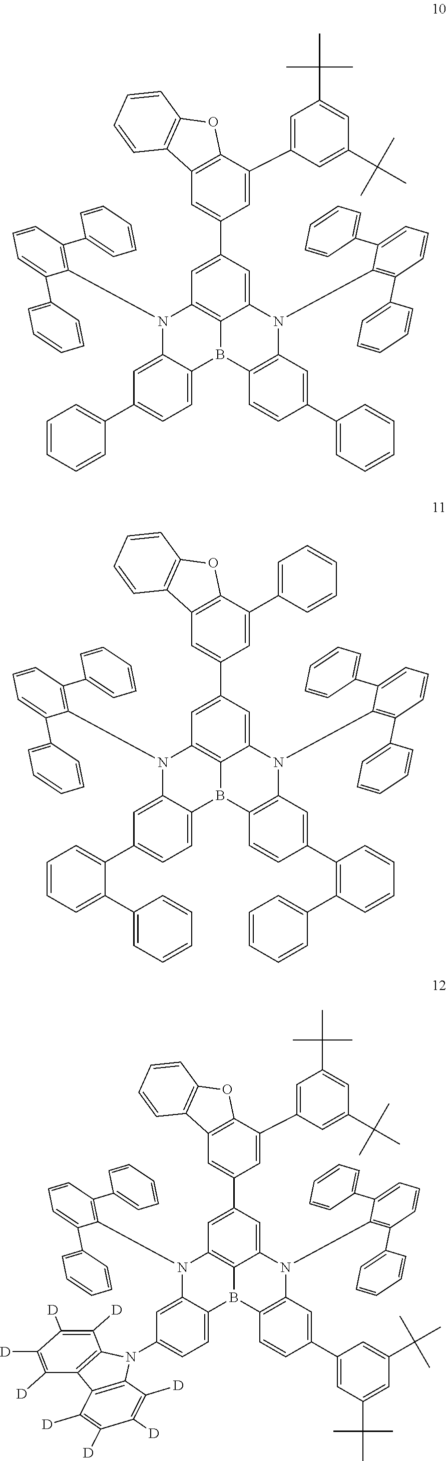 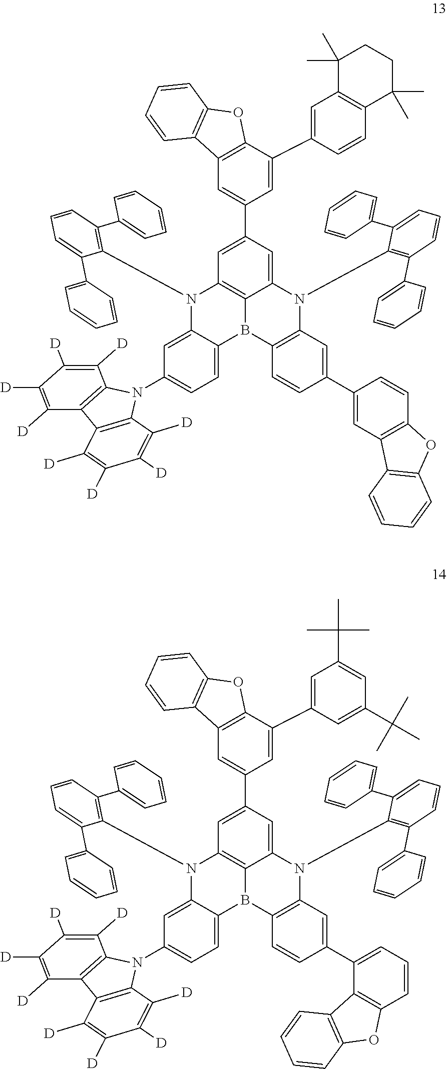 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4ccc5c(c4)C(C)(C)CCC5(C)C)c4oc5ccccc5c4c3)cc3c1B2c1ccc(-c2ccc4oc5ccccc5c4c2)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4cc(C(C)(C)C)cc(C(C)(C)C)c4)c4oc5ccccc5c4c3)cc3c1B2c1ccc(-c2cccc4oc5ccccc5c24)cc1N3c1c(-c2ccccc2)cccc1-c1ccccc1] 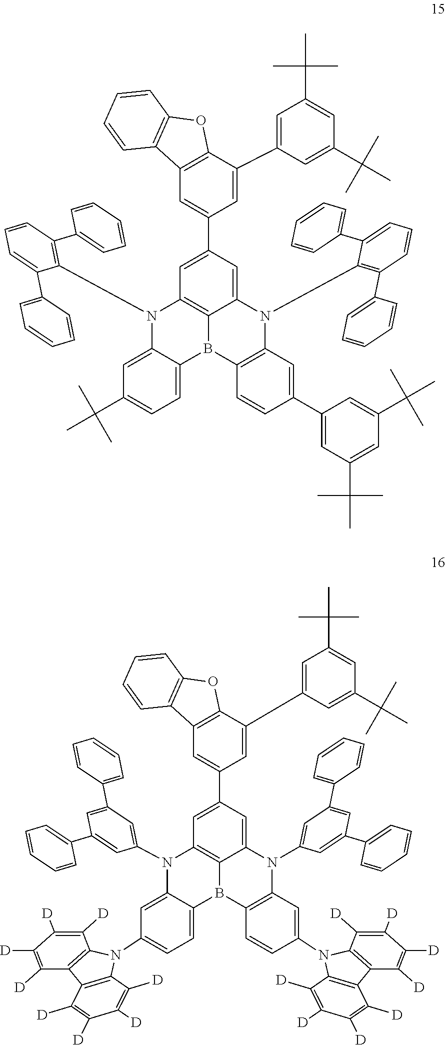 [SMILES: CC(C)(C)c1cc(-c2ccc3c(c2)N(c2c(-c4ccccc4)cccc2-c2ccccc2)c2cc(-c4cc(-c5cc(C(C)(C)C)cc(C(C)(C)C)c5)c5oc6ccccc6c5c4)cc4c2B3c2ccc(C(C)(C)C)cc2N4c2c(-c3ccccc3)cccc2-c2ccccc2)cc(C(C)(C)C)c1 ; [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-c3cc(-c4cc(C(C)(C)C)cc(C(C)(C)C)c4)c4oc5ccccc5c4c3)cc3c1B2c1ccc(-n2c4c([2H])c([2H])c([2H])c([2H])c4c4c([2H])c([2H])c([2H])c([2H])c42)cc1N3c1cc(-c2ccccc2)cc(-c2ccccc2)c1] 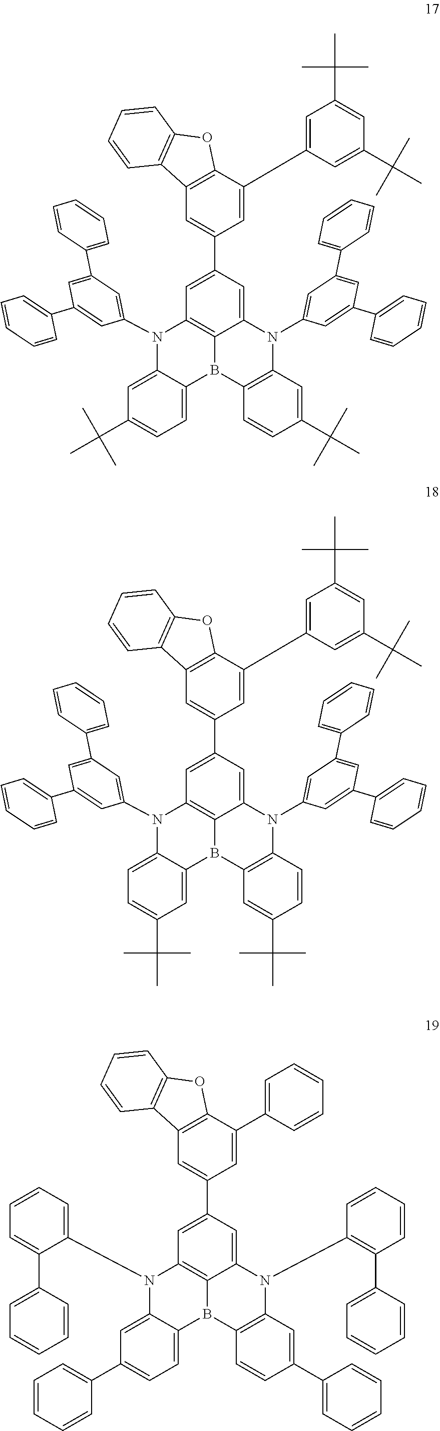 [SMILES: CC(C)(C)c1cc(-c2cc(-c3cc4c5c(c3)N(c3cc(-c6ccccc6)cc(-c6ccccc6)c3)c3cc(C(C)(C)C)ccc3B5c3ccc(C(C)(C)C)cc3N4c3cc(-c4ccccc4)cc(-c4ccccc4)c3)cc3c2oc2ccccc23)cc(C(C)(C)C)c1 ; CC(C)(C)c1cc(-c2cc(-c3cc4c5c(c3)N(c3cc(-c6ccccc6)cc(-c6ccccc6)c3)c3ccc(C(C)(C)C)cc3B5c3cc(C(C)(C)C)ccc3N4c3cc(-c4ccccc4)cc(-c4ccccc4)c3)cc3c2oc2ccccc23)cc(C(C)(C)C)c1 ; c1ccc(-c2ccc3c(c2)N(c2ccccc2-c2ccccc2)c2cc(-c4cc(-c5ccccc5)c5oc6ccccc6c5c4)cc4c2B3c2ccc(-c3ccccc3)cc2N4c2ccccc2-c2ccccc2)cc1] 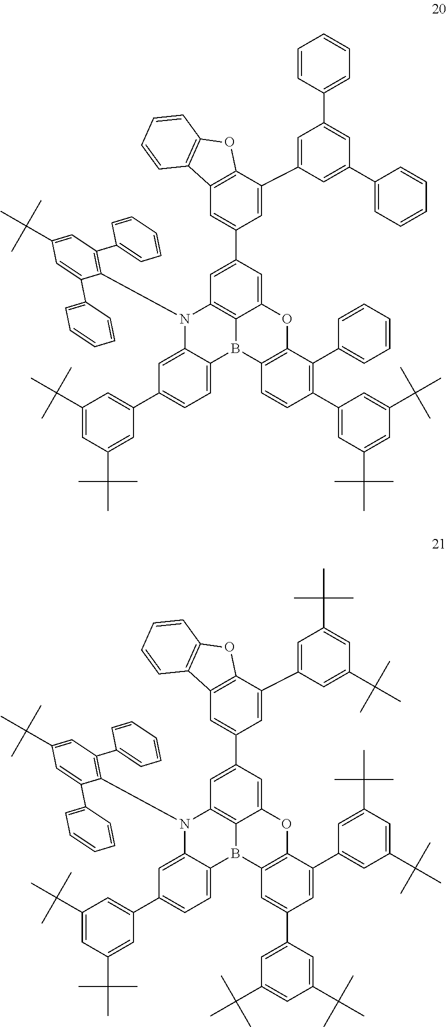 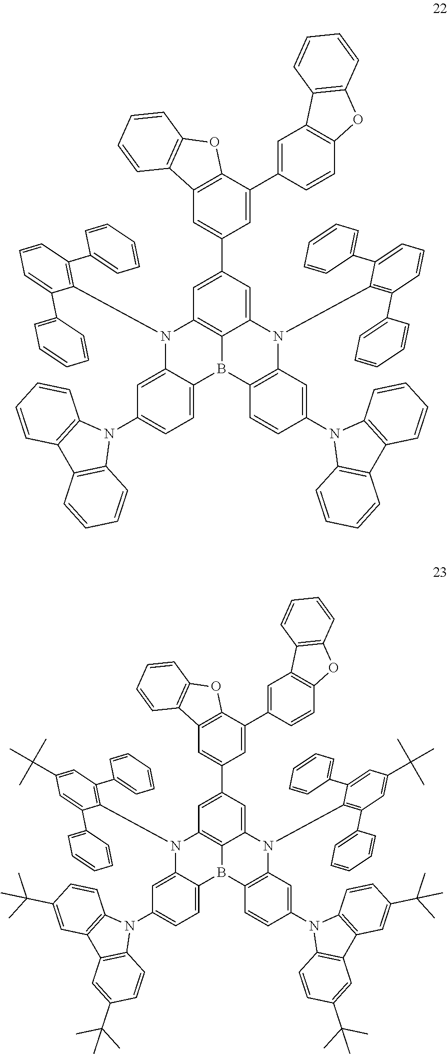 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5cc(-c6ccc7oc8ccccc8c7c6)c6oc7ccccc7c6c5)cc2c43)cc1 ; CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-c5cc(-c6ccc7oc8ccccc8c7c6)c6oc7ccccc7c6c5)cc2c43)c(-c2ccccc2)c1] 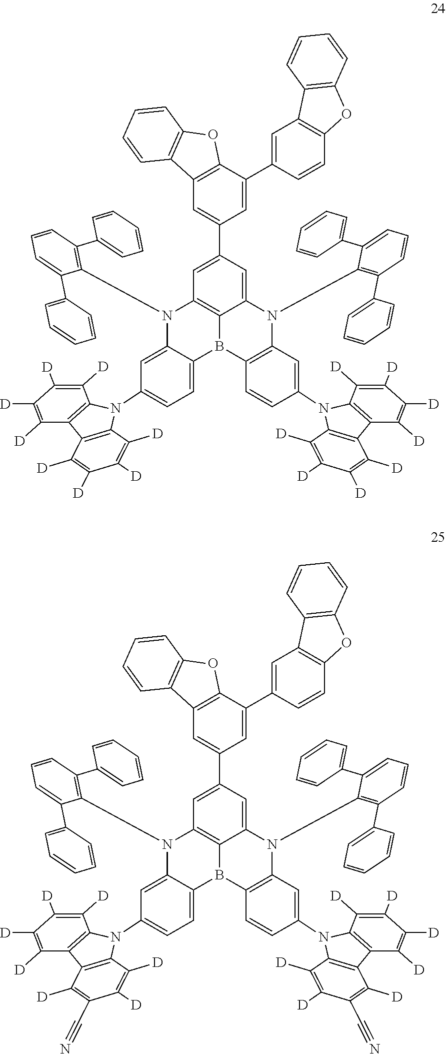 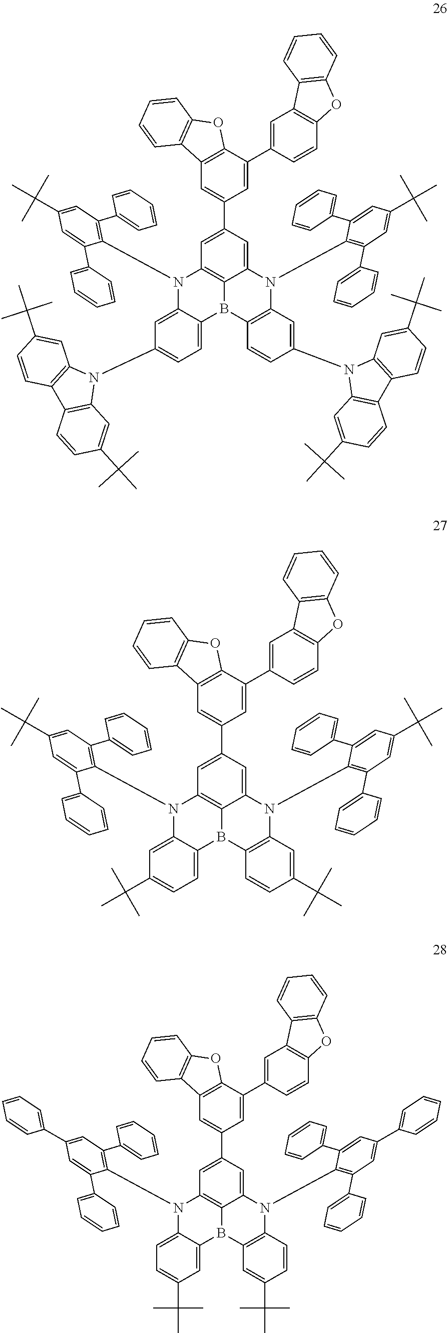 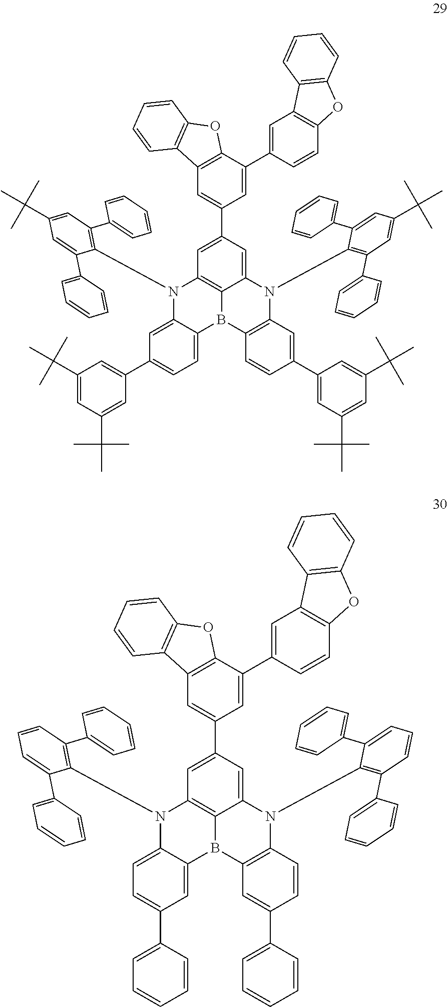 [SMILES: CC(C)(C)c1cc(-c2ccc3c(c2)N(c2c(-c4ccccc4)cc(C(C)(C)C)cc2-c2ccccc2)c2cc(-c4cc(-c5ccc6oc7ccccc7c6c5)c5oc6ccccc6c5c4)cc4c2B3c2ccc(-c3cc(C(C)(C)C)cc(C(C)(C)C)c3)cc2N4c2c(-c3ccccc3)cc(C(C)(C)C)cc2-c2ccccc2)cc(C(C)(C)C)c1 ; c1ccc(-c2ccc3c(c2)B2c4cc(-c5ccccc5)ccc4N(c4c(-c5ccccc5)cccc4-c4ccccc4)c4cc(-c5cc(-c6ccc7oc8ccccc8c7c6)c6oc7ccccc7c6c5)cc(c42)N3c2c(-c3ccccc3)cccc2-c2ccccc2)cc1] 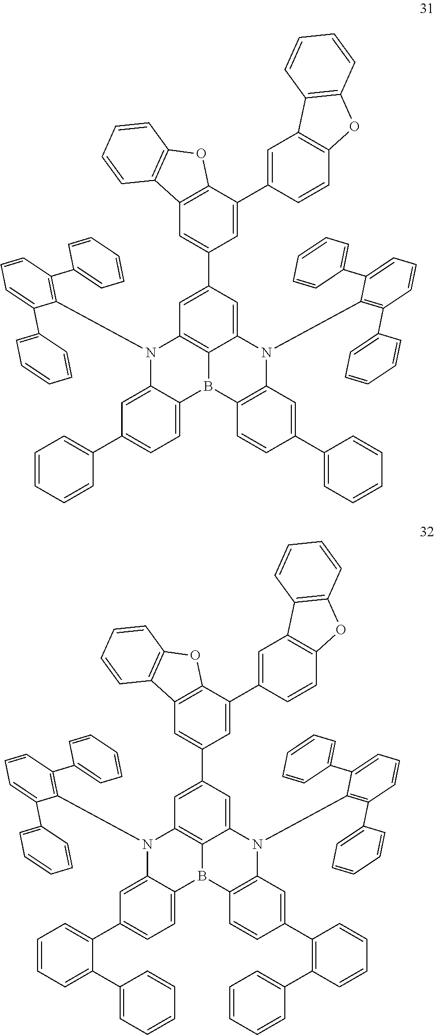 [SMILES: c1ccc(-c2ccc3c(c2)N(c2c(-c4ccccc4)cccc2-c2ccccc2)c2cc(-c4cc(-c5ccc6oc7ccccc7c6c5)c5oc6ccccc6c5c4)cc4c2B3c2ccc(-c3ccccc3)cc2N4c2c(-c3ccccc3)cccc2-c2ccccc2)cc1 ; c1ccc(-c2ccccc2-c2ccc3c(c2)N(c2c(-c4ccccc4)cccc2-c2ccccc2)c2cc(-c4cc(-c5ccc6oc7ccccc7c6c5)c5oc6ccccc6c5c4)cc4c2B3c2ccc(-c3ccccc3-c3ccccc3)cc2N4c2c(-c3ccccc3)cccc2-c2ccccc2)cc1] 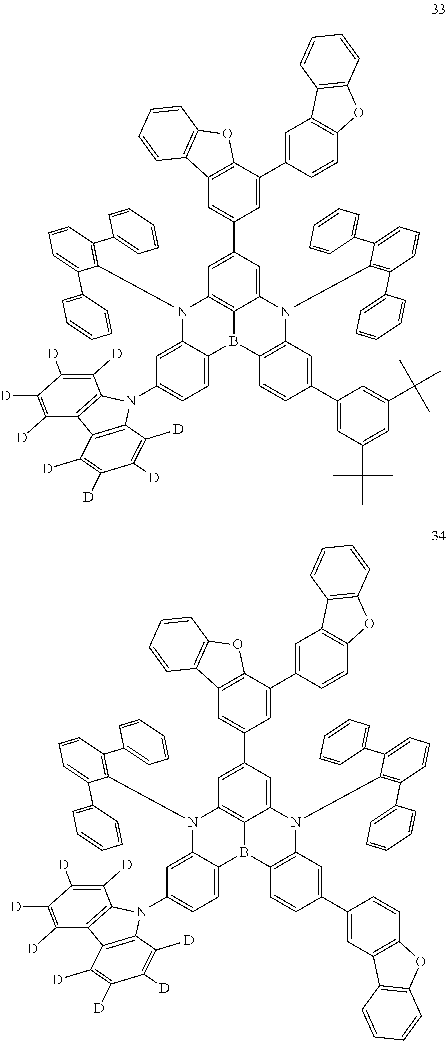 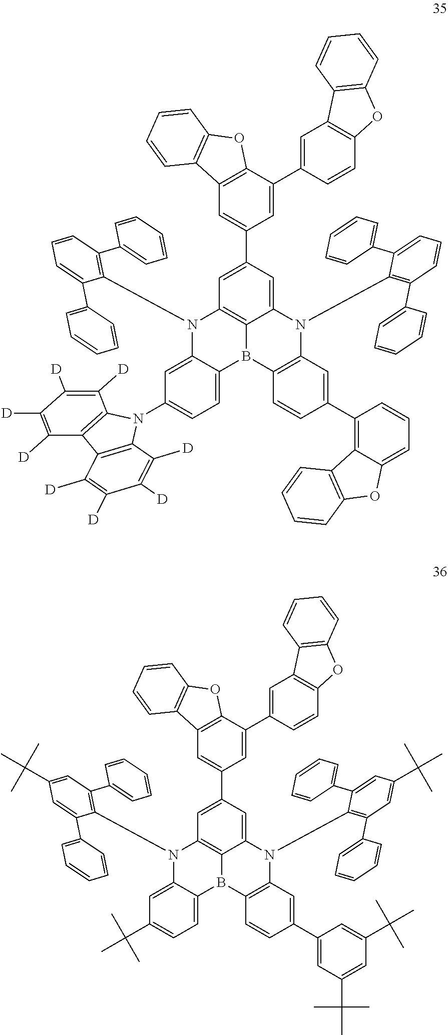 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4ccc5oc6ccccc6c5c4)c4oc5ccccc5c4c3)cc3c1B2c1ccc(-c2cccc4oc5ccccc5c24)cc1N3c1c(-c2ccccc2)cccc1-c1ccccc1 ; CC(C)(C)c1cc(-c2ccc3c(c2)N(c2c(-c4ccccc4)cc(C(C)(C)C)cc2-c2ccccc2)c2cc(-c4cc(-c5ccc6oc7ccccc7c6c5)c5oc6ccccc6c5c4)cc4c2B3c2ccc(C(C)(C)C)cc2N4c2c(-c3ccccc3)cc(C(C)(C)C)cc2-c2ccccc2)cc(C(C)(C)C)c1] 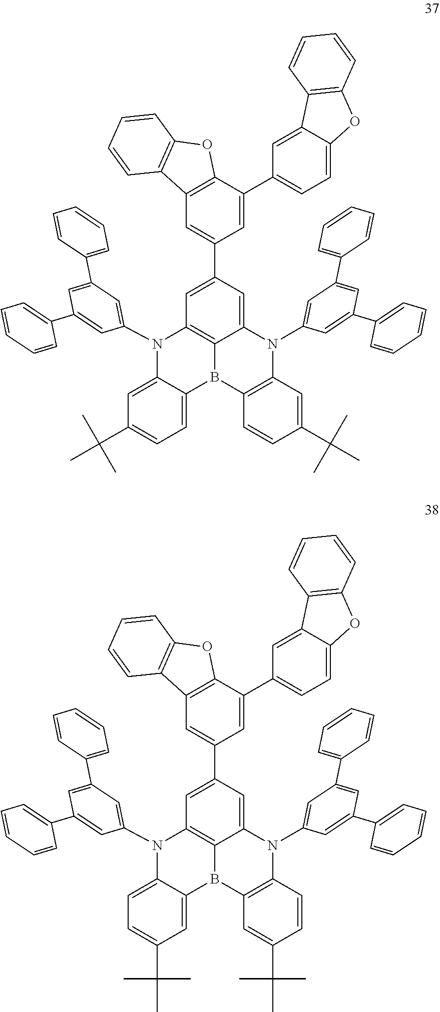 [SMILES: CC(C)(C)c1ccc2c(c1)N(c1cc(-c3ccccc3)cc(-c3ccccc3)c1)c1cc(-c3cc(-c4ccc5oc6ccccc6c5c4)c4oc5ccccc5c4c3)cc3c1B2c1ccc(C(C)(C)C)cc1N3c1cc(-c2ccccc2)cc(-c2ccccc2)c1 ; CC(C)(C)c1ccc2c(c1)B1c3cc(C(C)(C)C)ccc3N(c3cc(-c4ccccc4)cc(-c4ccccc4)c3)c3cc(-c4cc(-c5ccc6oc7ccccc7c6c5)c5oc6ccccc6c5c4)cc(c31)N2c1cc(-c2ccccc2)cc(-c2ccccc2)c1] 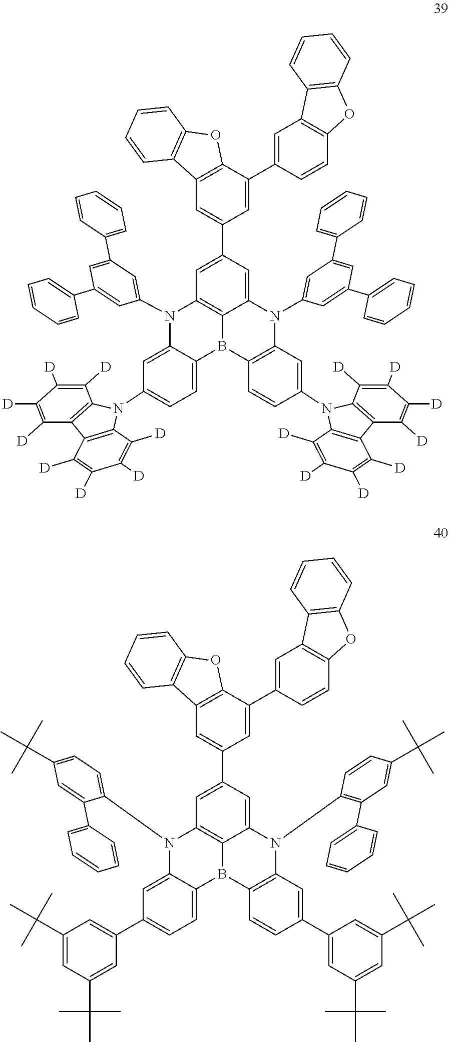 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-c3cc(-c4ccc5oc6ccccc6c5c4)c4oc5ccccc5c4c3)cc3c1B2c1ccc(-n2c4c([2H])c([2H])c([2H])c([2H])c4c4c([2H])c([2H])c([2H])c([2H])c42)cc1N3c1cc(-c2ccccc2)cc(-c2ccccc2)c1 ; CC(C)(C)c1cc(-c2ccc3c(c2)N(c2ccc(C(C)(C)C)cc2-c2ccccc2)c2cc(-c4cc(-c5ccc6oc7ccccc7c6c5)c5oc6ccccc6c5c4)cc4c2B3c2ccc(-c3cc(C(C)(C)C)cc(C(C)(C)C)c3)cc2N4c2ccc(C(C)(C)C)cc2-c2ccccc2)cc(C(C)(C)C)c1] 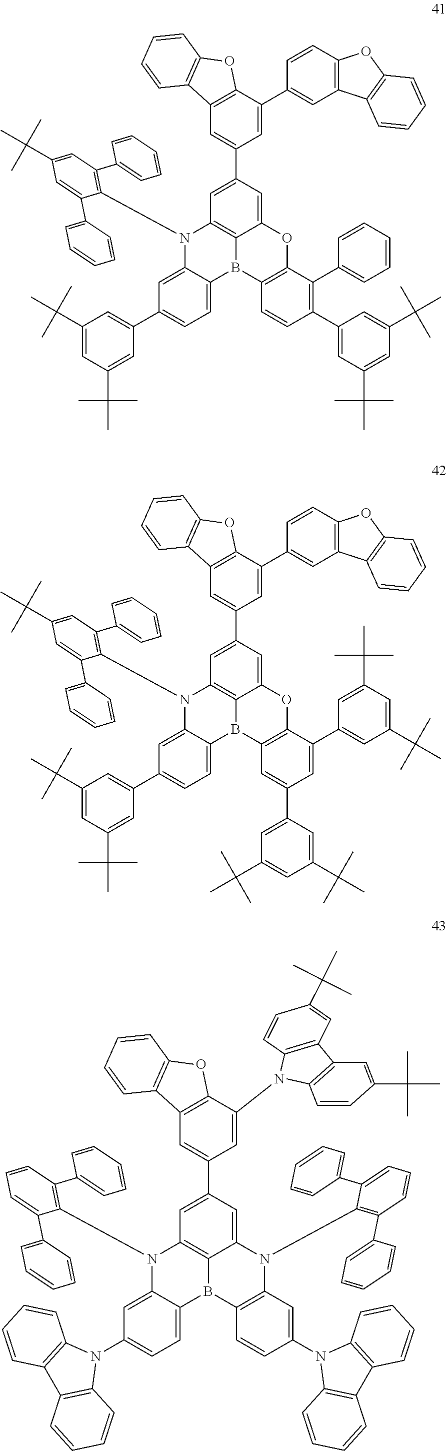 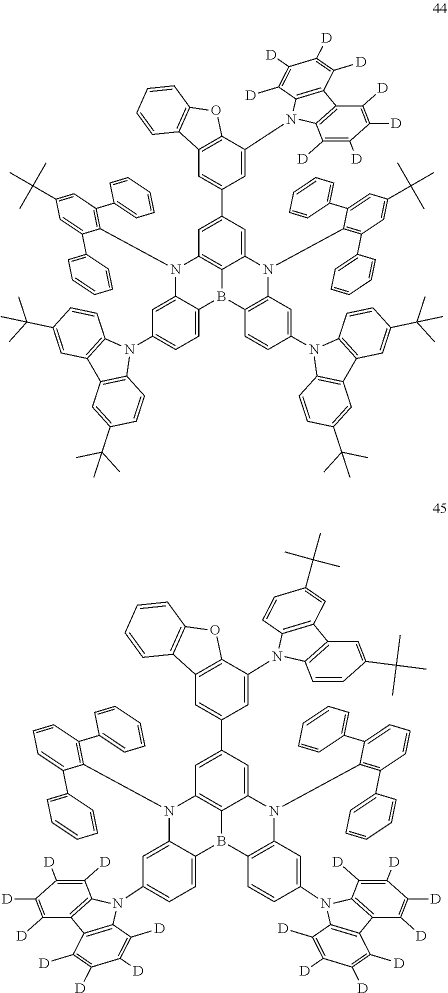 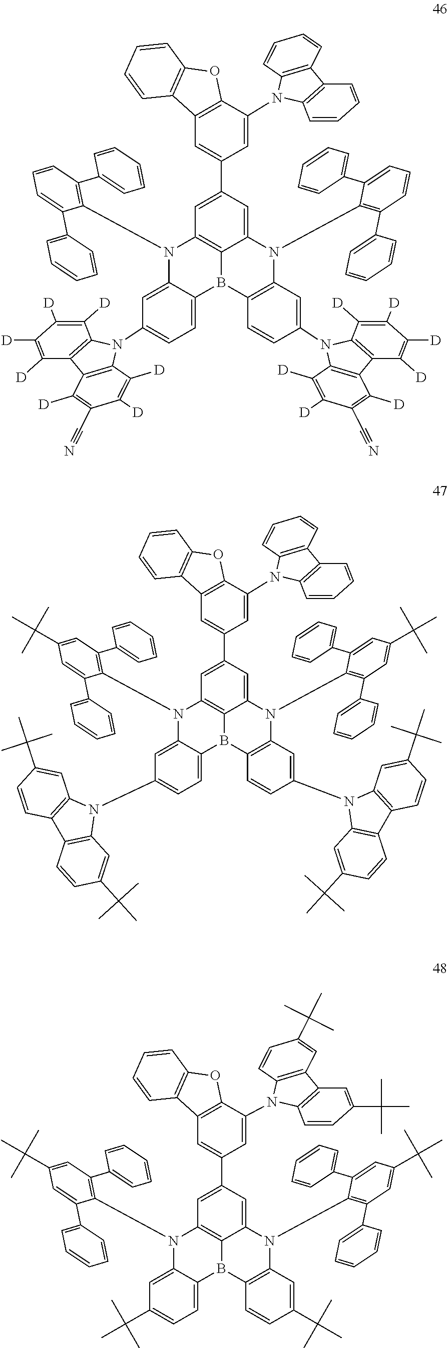 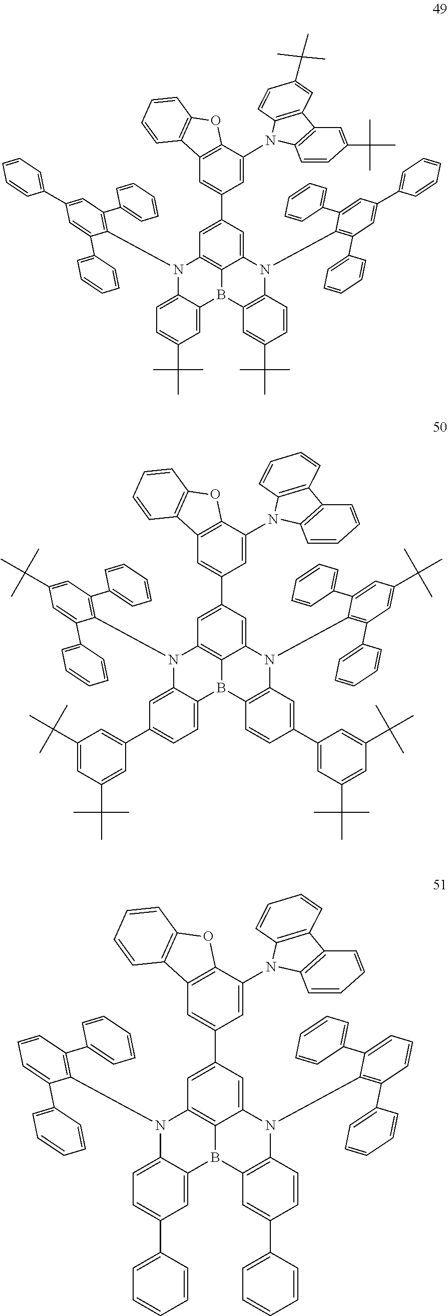 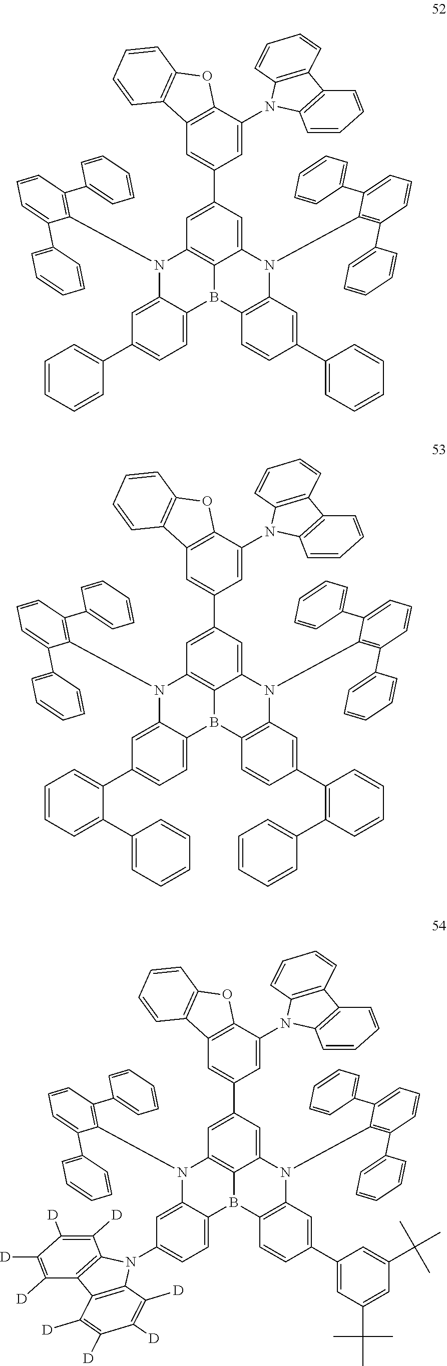 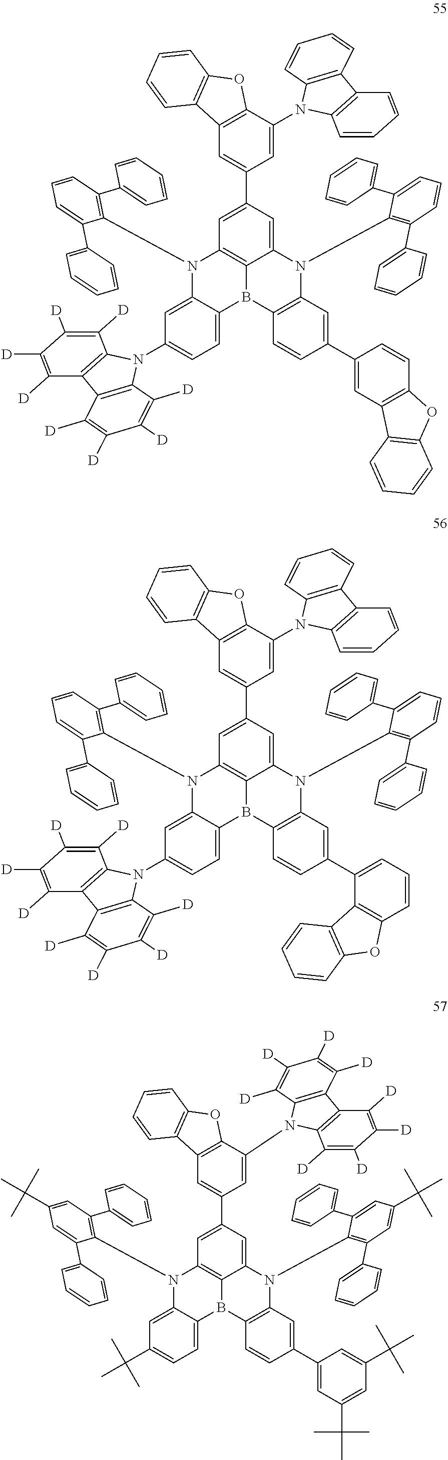 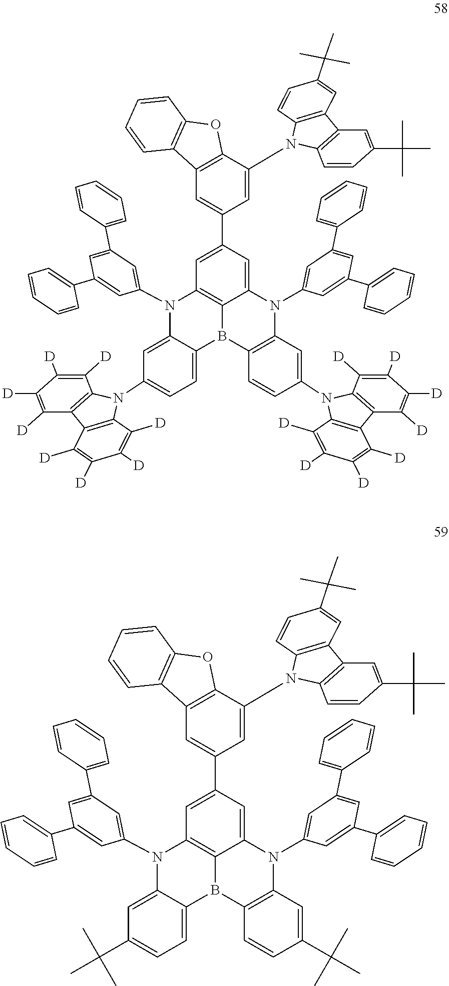 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1cc(-c3cc(-n4c5ccc(C(C)(C)C)cc5c5cc(C(C)(C)C)ccc54)c4oc5ccccc5c4c3)cc3c1B2c1ccc(-n2c4c([2H])c([2H])c([2H])c([2H])c4c4c([2H])c([2H])c([2H])c([2H])c42)cc1N3c1cc(-c2ccccc2)cc(-c2ccccc2)c1 ; CC(C)(C)c1ccc2c(c1)N(c1cc(-c3ccccc3)cc(-c3ccccc3)c1)c1cc(-c3cc(-n4c5ccc(C(C)(C)C)cc5c5cc(C(C)(C)C)ccc54)c4oc5ccccc5c4c3)cc3c1B2c1ccc(C(C)(C)C)cc1N3c1cc(-c2ccccc2)cc(-c2ccccc2)c1] 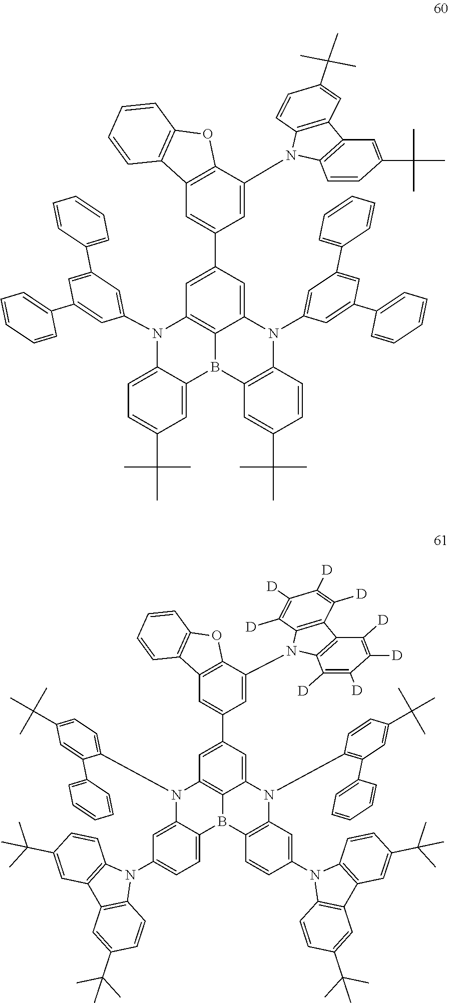 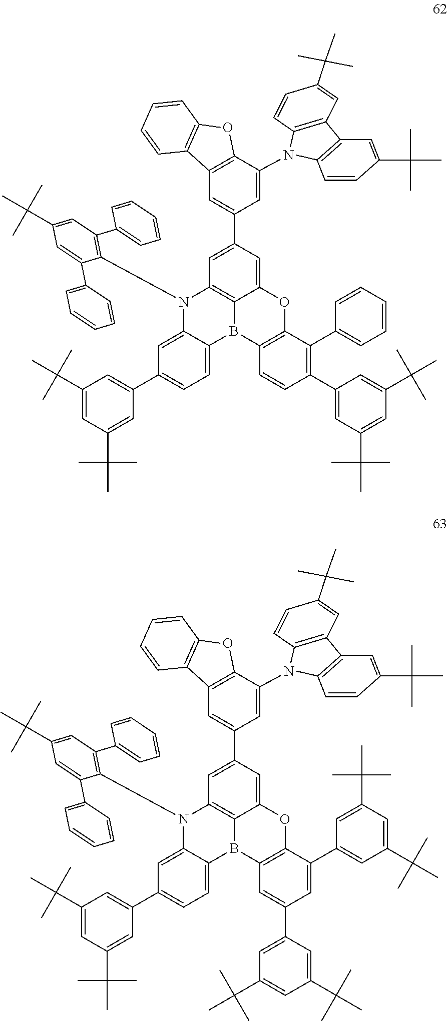 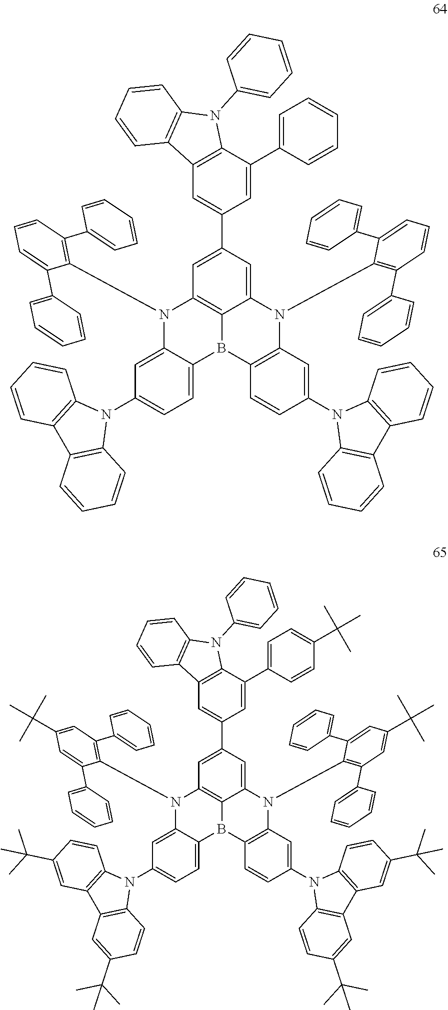 [SMILES: c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(-c5cc(-c6ccccc6)c6c(c5)c5ccccc5n6-c5ccccc5)cc2c43)cc1 ; CC(C)(C)c1ccc(-c2cc(-c3cc4c5c(c3)N(c3c(-c6ccccc6)cc(C(C)(C)C)cc3-c3ccccc3)c3cc(-n6c7ccc(C(C)(C)C)cc7c7cc(C(C)(C)C)ccc76)ccc3B5c3ccc(-n5c6ccc(C(C)(C)C)cc6c6cc(C(C)(C)C)ccc65)cc3N4c3c(-c4ccccc4)cc(C(C)(C)C)cc3-c3ccccc3)cc3c4ccccc4n(-c4ccccc4)c23)cc1] 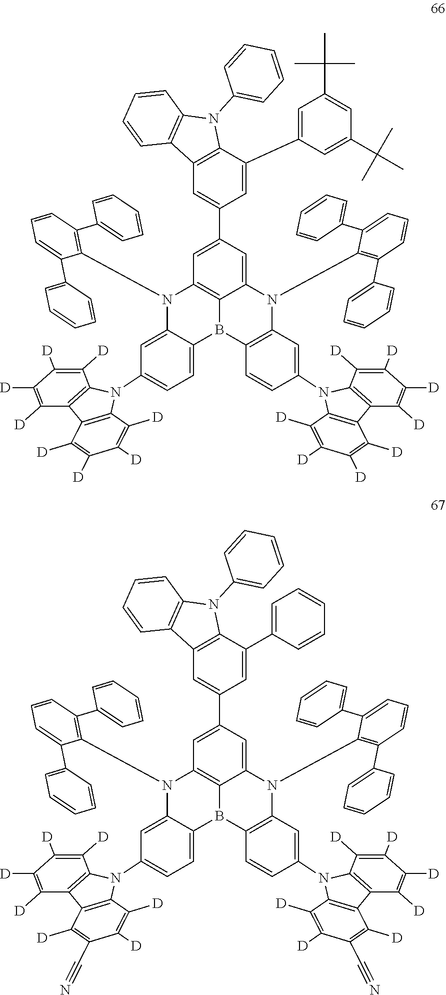 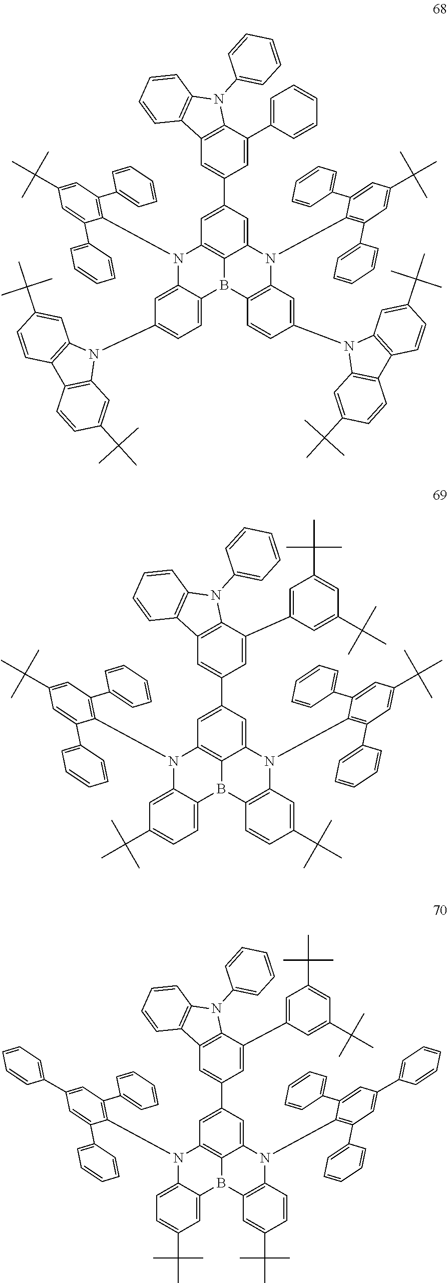 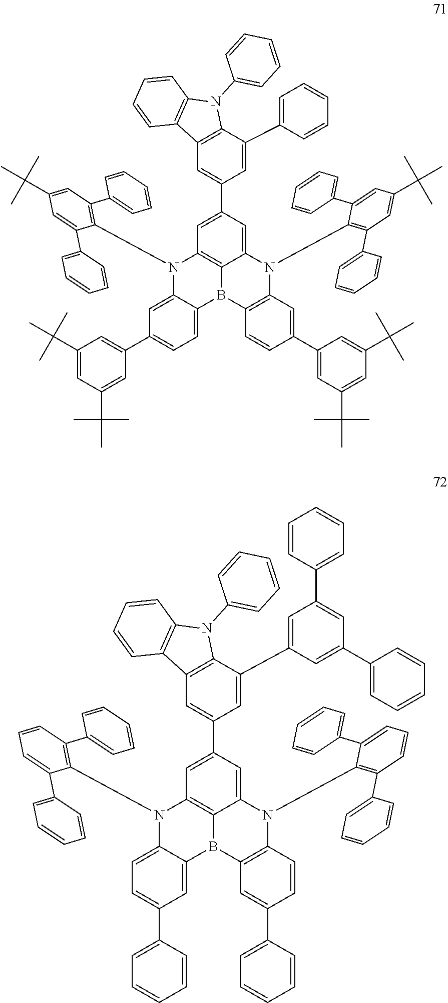 [SMILES: CC(C)(C)c1cc(-c2ccc3c(c2)N(c2c(-c4ccccc4)cc(C(C)(C)C)cc2-c2ccccc2)c2cc(-c4cc(-c5ccccc5)c5c(c4)c4ccccc4n5-c4ccccc4)cc4c2B3c2ccc(-c3cc(C(C)(C)C)cc(C(C)(C)C)c3)cc2N4c2c(-c3ccccc3)cc(C(C)(C)C)cc2-c2ccccc2)cc(C(C)(C)C)c1 ; c1ccc(-c2cc(-c3ccccc3)cc(-c3cc(-c4cc5c6c(c4)N(c4c(-c7ccccc7)cccc4-c4ccccc4)c4ccc(-c7ccccc7)cc4B6c4cc(-c6ccccc6)ccc4N5c4c(-c5ccccc5)cccc4-c4ccccc4)cc4c5ccccc5n(-c5ccccc5)c34)c2)cc1] 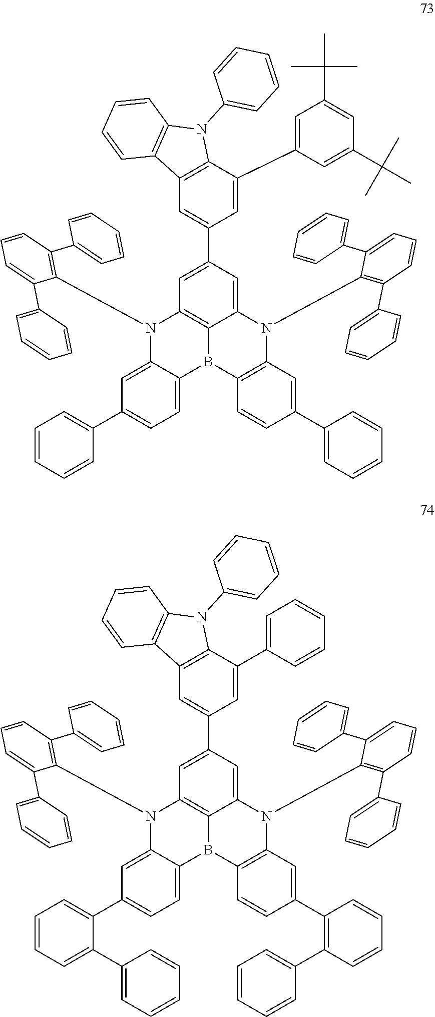 [SMILES: CC(C)(C)c1cc(-c2cc(-c3cc4c5c(c3)N(c3c(-c6ccccc6)cccc3-c3ccccc3)c3cc(-c6ccccc6)ccc3B5c3ccc(-c5ccccc5)cc3N4c3c(-c4ccccc4)cccc3-c3ccccc3)cc3c4ccccc4n(-c4ccccc4)c23)cc(C(C)(C)C)c1 ; c1ccc(-c2ccccc2-c2ccc3c(c2)N(c2c(-c4ccccc4)cccc2-c2ccccc2)c2cc(-c4cc(-c5ccccc5)c5c(c4)c4ccccc4n5-c4ccccc4)cc4c2B3c2ccc(-c3ccccc3-c3ccccc3)cc2N4c2c(-c3ccccc3)cccc2-c2ccccc2)cc1] 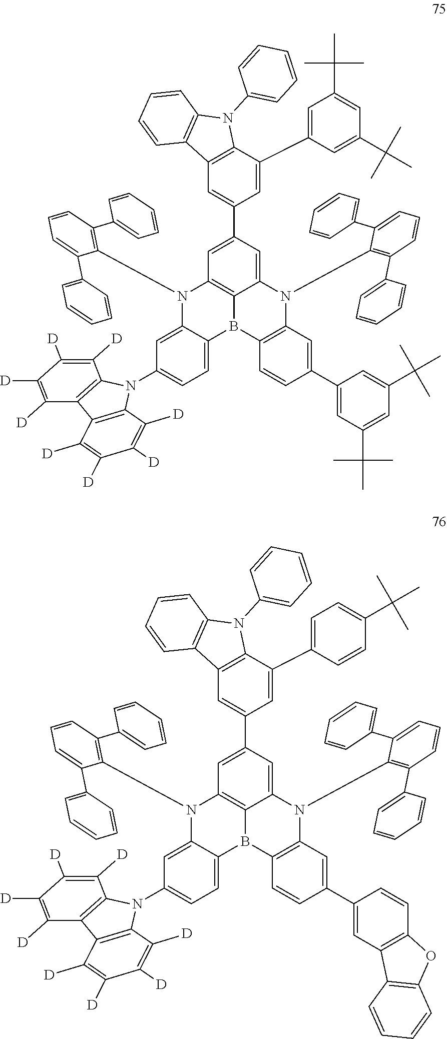 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4cc(C(C)(C)C)cc(C(C)(C)C)c4)c4c(c3)c3ccccc3n4-c3ccccc3)cc3c1B2c1ccc(-c2cc(C(C)(C)C)cc(C(C)(C)C)c2)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4ccc(C(C)(C)C)cc4)c4c(c3)c3ccccc3n4-c3ccccc3)cc3c1B2c1ccc(-c2ccc4oc5ccccc5c4c2)cc1N3c1c(-c2ccccc2)cccc1-c1ccccc1] 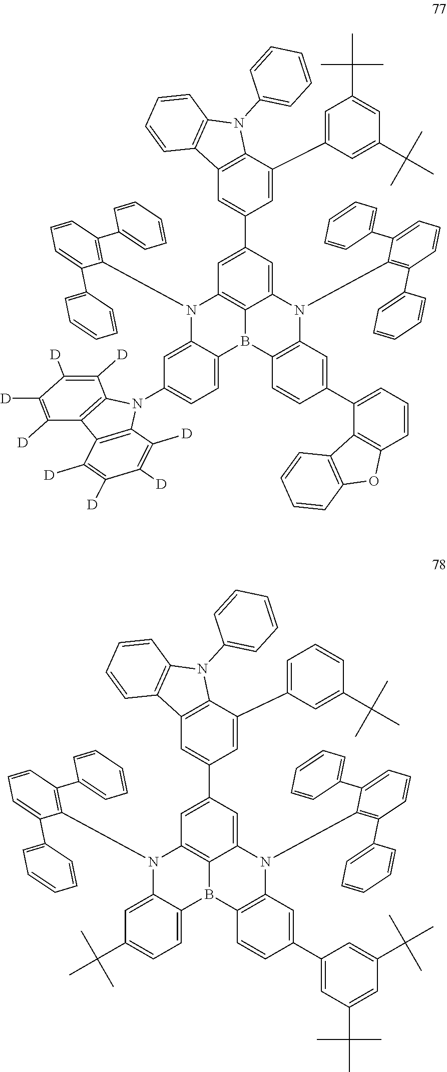 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-c3cc(-c4cc(C(C)(C)C)cc(C(C)(C)C)c4)c4c(c3)c3ccccc3n4-c3ccccc3)cc3c1B2c1ccc(-c2cccc4oc5ccccc5c24)cc1N3c1c(-c2ccccc2)cccc1-c1ccccc1 ; CC(C)(C)c1cccc(-c2cc(-c3cc4c5c(c3)N(c3c(-c6ccccc6)cccc3-c3ccccc3)c3cc(C(C)(C)C)ccc3B5c3ccc(-c5cc(C(C)(C)C)cc(C(C)(C)C)c5)cc3N4c3c(-c4ccccc4)cccc3-c3ccccc3)cc3c4ccccc4n(-c4ccccc4)c23)c1] 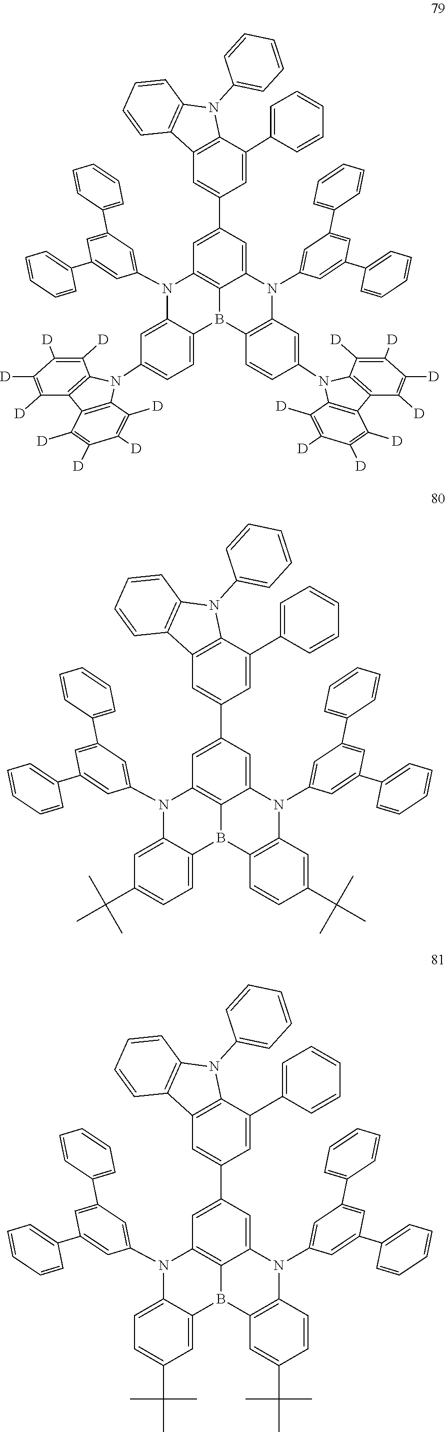 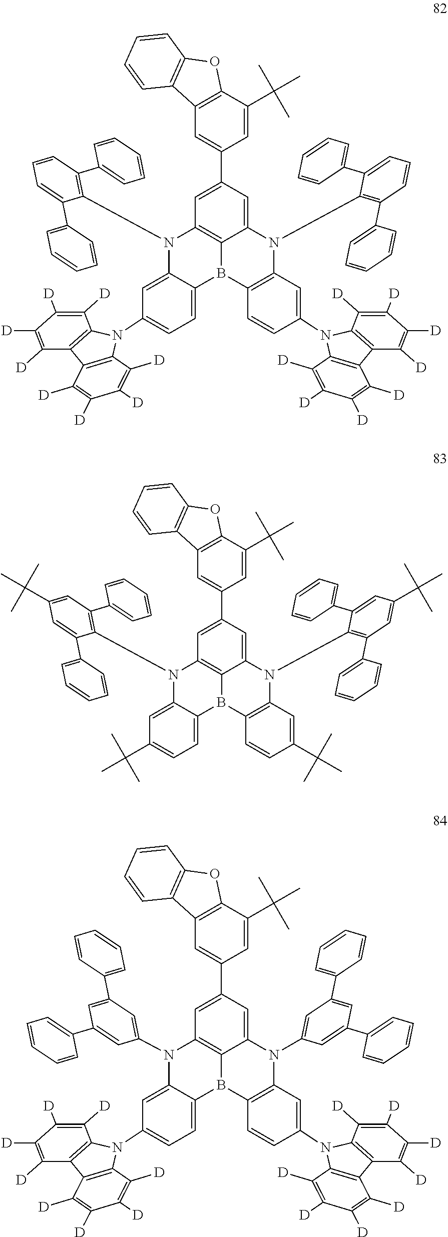 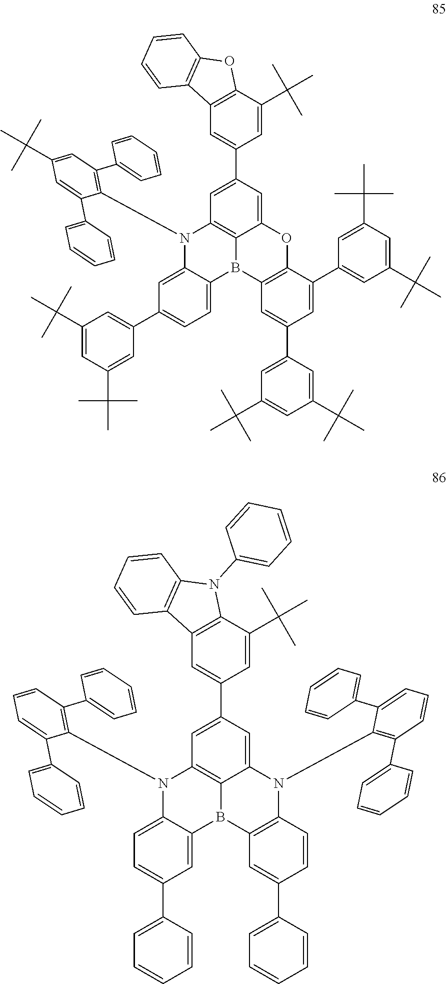 [SMILES: CC(C)(C)c1cc(-c2cc3c(c(-c4cc(C(C)(C)C)cc(C(C)(C)C)c4)c2)Oc2cc(-c4cc(C(C)(C)C)c5oc6ccccc6c5c4)cc4c2B3c2ccc(-c3cc(C(C)(C)C)cc(C(C)(C)C)c3)cc2N4c2c(-c3ccccc3)cc(C(C)(C)C)cc2-c2ccccc2)cc(C(C)(C)C)c1 ; CC(C)(C)c1cc(-c2cc3c4c(c2)N(c2c(-c5ccccc5)cccc2-c2ccccc2)c2ccc(-c5ccccc5)cc2B4c2cc(-c4ccccc4)ccc2N3c2c(-c3ccccc3)cccc2-c2ccccc2)cc2c3ccccc3n(-c3ccccc3)c12] 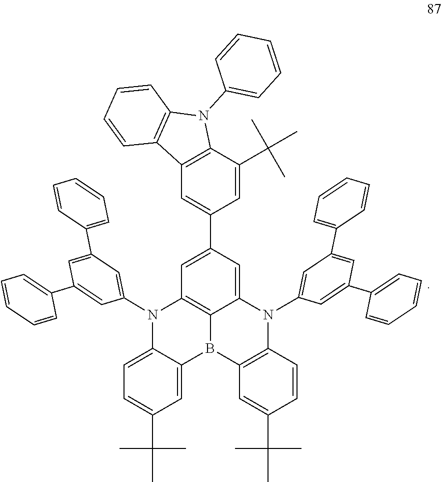 [SMILES: CC(C)(C)c1ccc2c(c1)B1c3cc(C(C)(C)C)ccc3N(c3cc(-c4ccccc4)cc(-c4ccccc4)c3)c3cc(-c4cc(C(C)(C)C)c5c(c4)c4ccccc4n5-c4ccccc4)cc(c31)N2c1cc(-c2ccccc2)cc(-c2ccccc2)c1]
